(19) United States
(12) Patent Application Publication
(10) Pub. No.: US 2024/0101892 A1
(43) Pub. Date: Mar. 28, 2024

(54) ORGANIC ELECTROLUMINESCENT COMPOUND AND ORGANIC ELECTROLUMINESCENT DEVICE COMPRISING THE SAME

(71) Applicant: ROHM AND HAAS ELECTRONIC MATERIALS KOREA LTD., Chungcheongnam-do (KR)

(72) Inventors: Jin-Ri HONG, Gyeonggi-do (KR); Young-Mook LIM, Gyeonggi-do (KR)

(21) Appl. No.: 18/522,818

(22) Filed: Nov. 29, 2023

Related U.S. Application Data
(63) Continuation of application No. 16/962,276, filed on Jul. 15, 2020, now abandoned.

(30) Foreign Application Priority Data
Jan. 25, 2018 (KR) 10-2018-0009157
Jan. 10, 2019 (KR) 10-2019-0003137

(51) Int. Cl. C09K 11/06; H10K 85/60

(52) U.S. Cl. CPC C09K 11/06; H10K 85/622; H10K 85/633; H10K 85/636; H10K 85/6572; H10K 85/6574; H10K 85/6576; C09K 2211/1029; H10K 50/156

(57) ABSTRACT

The present disclosure relates to an organic electroluminescent compound and an organic electroluminescent device comprising the same. The organic electroluminescent compound according to the present disclosure is contained in a hole transport layer and/or a hole auxiliary layer, so that an organic electroluminescent device having improved light-emitting efficiency and driving lifespan can be manufactured.

### CLAIM OF BENEFIT OF PRIOR APPLICATION

This application claims priority under 35 U.S.C. § 120 from U.S. patent application Ser. No. 16/962,276 filed Jul. 15, 2020, which is the National Stage Entry of PCT/KR2019/000998, filed Jan. 24, 2019, both of which are incorporated by reference herein in their entirety.

### TECHNICAL FIELD

The present disclosure relates to an organic electroluminescent compound and an organic electroluminescent device comprising the same.

### BACKGROUND ART

An electroluminescent device (EL device) is a self-light-emitting display device which has advantages in that it provides a wider viewing angle, a greater contrast ratio, and a faster response time. The first organic EL device was developed by Eastman Kodak in 1987, by using small aromatic diamine molecules and aluminum complexes as materials for forming a light-emitting layer [see Appl. Phys. Lett. 51, 913, 1987].

An organic EL device (OLED) changes electric energy into light by applying electricity to an organic electroluminescent material, and commonly comprises an anode, a cathode, and an organic layer formed between the two electrodes. The organic layer of the organic EL device may comprise a hole injection layer, a hole transport layer, a hole auxiliary layer, a light-emitting auxiliary layer, an electron blocking layer, a light-emitting layer (containing host and dopant materials), an electron buffer layer, a hole blocking layer, an electron transport layer, an electron injection layer, etc. The materials used in the organic layer can be classified into a hole injection material, a hole transport material, a hole auxiliary material, a light-emitting auxiliary material, an electron blocking material, a light-emitting material, an electron buffer material, a hole blocking material, an electron transport material, an electron injection material, etc., depending on their functions. In the organic EL device, holes from the anode and electrons from the cathode are injected into a light-emitting layer by the application of electric voltage, and excitons having high energy are produced by the recombination of the holes and electrons. The organic light-emitting compound moves into an excited state by the energy and emits light from the energy when the organic light-emitting compound returns to the ground state from the excited state.

Meanwhile, as set forth, the organic electroluminescent device has a multi-layer structure in order to enhance its efficiency and stability, wherein the selection of compounds contained in the hole transport layer, etc., is recognized as a means for improving device characteristics such as hole transport efficiency to light-emitting layer, luminous efficiency and lifespan.

In this regard, copper phthalocyanine (CuPc), 4,4′-bis[N-(1-naphthyl)-N-phenylamino]biphenyl (NPB), N,N′-diphenyl-N,N′-bis(3-methylphenyl)-(1,1′-biphenyl)-4,4′-diamine (TPD), 4,4′,4″-tris(3-methylphenylphenylamino)triphenylamine (MTDATA), etc., were used as a hole injection material and a hole transport material in an organic EL device. However, an organic EL device using these materials has problems of reduction in luminous efficiency and lifespan. It is because, when an organic EL device is driven under high current, thermal stress occurs between an anode and a hole injection layer, thereby such thermal stress significantly reduces the lifespan of the device. Further, since the organic material used in the hole transport zone has very high hole mobility, there has been problems in that the driving voltage is increased, the luminous efficiency is lowered, and the lifespan is reduced.

JP 2014-047197 A discloses an organic EL device comprising benzofluorenyl amine compounds such as the following structure having hole transporting characters; however, it is still necessary for improving the light-emitting efficiency and lifespan.

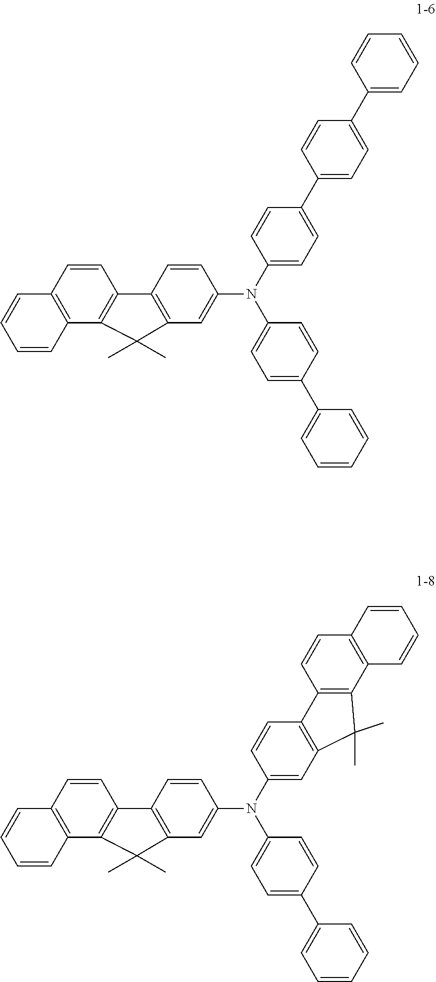 [SMILES: CC1(C)c2cc(N(c3ccc(-c4ccccc4)cc3)c3ccc(-c4ccc(-c5ccccc5)cc4)cc3)ccc2-c2ccc3ccccc3c21 ; CC1(C)c2cc(N(c3ccc(-c4ccccc4)cc3)c3ccc4c(c3)C(C)(C)c3c-4ccc4ccccc34)ccc2-c2ccc3ccccc3c21]

In this regard, development of a hole transport layer is still required for improving the durability of an organic electroluminescent device.

### DISCLOSURE OF THE INVENTION

### Problems to be Solved

The object of the present disclosure is firstly, to provide an organic electroluminescent compound being able to prepare an organic electroluminescent device having low driving voltage and/or high luminous efficiency and/or long lifespan; secondly, to provide an organic electroluminescent device comprising the organic electroluminescent compound.

### Solution to Problems

As a result of intensive studies to solve the technical problem above, the present inventors found that the aforementioned objective can be achieved by the organic electroluminescent compound represented by the following formula 1, so that the present invention was completed.

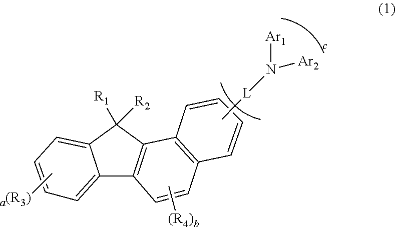

In formula 1,

R₁ and R₂ each independently represent hydrogen, deuterium, a substituted or unsubstituted (C1-C30)alkyl, a substituted or unsubstituted (C6-C30)aryl, or a substituted or unsubstituted (3- to 30-membered)heteroaryl; or may be linked to an adjacent substituent to form a substituted or unsubstituted ring;

R₃ and R₄ each independently represent hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, or a substituted or unsubstituted tri(C6-C30)arylsilyl;

L represents a single bond, a substituted or unsubstituted (C6-C30)arylene, or a substituted or unsubstituted (3- to 30-membered)heteroarylene;

Ar₁ and Ar₂ each independently represent a substituted or unsubstituted (C1-C30)alkyl, a substituted or unsubstituted (C6-C30)aryl, or a substituted or unsubstituted (3- to 30-membered)heteroaryl; or may be linked to each other to form a substituted or unsubstituted ring;

a represents an integer from 1 to 4, b represents an integer of 1 or 2, when a or b is an integer of 2 or more, each of R₃ or each of R₄ may be the same or different; and

c represents an integer of 1 or 2, when c is an integer of 2, each of Ar₁ or each of Ar₂ may be the same or different.

### Effects of the Invention

An OLED device using an organic electroluminescent compound according to the present disclosure in a hole transport layer and/or a hole auxiliary layer is significantly improved in terms of luminous efficiency and driving lifespan as compared with OLED devices using a conventional organic electroluminescent compound.

### EMBODIMENTS OF THE INVENTION

Hereinafter, the present disclosure will be described in detail. However, the following description is intended to explain the invention, and is not meant in any way to restrict the scope of the invention.

The present disclosure relates to the organic electroluminescent compound represented by formula 1 above, the organic electroluminescent material comprising the organic electroluminescent compound, and the organic electroluminescent device comprising the organic electroluminescent material.

The term “organic electroluminescent compound” in the present disclosure means a compound that may be used in an organic electroluminescent device, and may be comprised in any material layer constituting an organic electroluminescent device, as necessary.

The term “organic electroluminescent material” in the present disclosure means a material that may be used in an organic electroluminescent device, and may comprise at least one compound. The organic electroluminescent material may be comprised in any layer constituting an organic electroluminescent device, as necessary. For example, the organic electroluminescent material may be a hole injection material, a hole transport material, a hole auxiliary material, a light-emitting auxiliary material, an electron blocking material, a light-emitting material, an electron buffer material, a hole blocking material, an electron transport material, or an electron injection material, etc.

Herein, “(C1-C30)alkyl” is meant to be a linear or branched alkyl having 1 to 30 carbon atoms constituting the chain, in which the number of carbon atoms is preferably 1 to 20, and more preferably 1 to 10. The above alkyl may include methyl, ethyl, n-propyl, isopropyl, n-butyl, isobutyl, tert-butyl, etc. “(C3-C30)cycloalkyl” is a mono- or polycyclic hydrocarbon having 3 to 30 ring backbone carbon atoms, in which the number of carbon atoms is preferably 3 to 20, and more preferably 3 to 7. The above cycloalkyl may include cyclopropyl, cyclobutyl, cyclopentyl, cyclohexyl, etc. “(C6-C30)aryl(ene)” is a monocyclic or fused ring radical derived from an aromatic hydrocarbon having 6 to 30 ring backbone carbon atoms, in which the number of the ring backbone carbon atoms is preferably 6 to 20, more preferably 6 to 15, may be partially saturated, and may comprise a spiro structure. Examples of the aryl specifically include phenyl, biphenyl, terphenyl, quaterphenyl, naphthyl, binaphthyl, phenylnaphthyl, naphthylphenyl, fluorenyl, phenylfluorenyl, dimethylfluorenyl, diphenylfluorenyl, benzofluorenyl, diphenylbenzofluorenyl, dibenzofluorenyl, phenanthrenyl, benzophenanthrenyl, phenylphenanthrenyl, anthracenyl, benzanthracenyl, indenyl, triphenylenyl, pyrenyl, tetracenyl, perylenyl, chrysenyl, benzochrysenyl, naphthacenyl, fluoranthenyl, benzofluoranthenyl, toyly, xylyl, mesityl, cumenyl, spiro[fluorene-fluorene]yl, spiro[fluorene-benzofluorene]yl, azulenyl, etc. More specifically, the aryl may be o-tolyl, m-tolyl, p-tolyl, 2,3-xylyl, 3,4-xylyl, 2,5-xylyl, mesityl, o-cumenyl, m-cumenyl, p-cumenyl, p-t-butylphenyl, p-(2-phenylpropyl)phenyl, 4′-methylbiphenyl, 4″-t-butyl-p-terphenyl-4-yl, o-biphenyl, m-biphenyl, p-biphenyl, o-terphenyl, m-terphenyl-4-yl, m-terphenyl-3-yl, m-terphenyl-2-yl, p-terphenyl-4-yl, p-terphenyl-3-yl, p-terphenyl-2-yl, m-quaterphenyl, 1-naphthyl, 2-naphthyl, 1-fluorenyl, 2-fluorenyl, 3-fluorenyl, 4-fluorenyl, 9-fluorenyl, 9,9-dimethyl-1-fluorenyl, 9,9-dimethyl-2-fluorenyl, 9,9-dimethyl-3-fluorenyl, 9,9-dimethyl-4-fluorenyl, 9,9-diphenyl-1-fluorenyl, 9,9-diphenyl-2-fluorenyl, 9,9-diphenyl-3-fluorenyl, 9,9-diphenyl-4-fluorenyl, 1-anthryl, 2-anthryl, 9-anthryl, 1-phenanthryl, 2-phenanthryl, 3-phenanthryl, 4-phenanthryl, 9-phenanthryl, 1-chrysenyl, 2-chrysenyl, 3-chrysenyl, 4-chrysenyl, 5-chrysenyl, 6-chrysenyl, benzo[c]phenanthryl, benzo[g]chrysenyl, 1-triphenylenyl, 2-triphenylenyl, 3-triphenylenyl, 4-triphenylenyl, 3-fluoranthenyl, 4-fluoranthenyl, 8-fluoranthenyl, 9-fluoranthenyl, and benzofluoranthenyl.

“(3- to 30-membered)heteroaryl(ene)” is an aryl group having at least one heteroatom selected from the group consisting of B, N, O, S, Si, P, and Ge and 3 to 30 ring backbone atoms, in which the number of ring backbone atoms is preferably 5 to 25; having preferably 1 to 4 heteroatoms, and may be a monocyclic ring, or a fused ring condensed with at least one benzene ring; may be partially saturated; may be one formed by linking at least one heteroaryl or aryl group to a heteroaryl group via a single bond(s); examples of the heteroaryl specifically include a monocyclic ring-type heteroaryl including furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl, etc., and a fused ring-type heteroaryl including benzofuranyl, benzothiophenyl, isobenzofuranyl, dibenzofuranyl, dibenzothiophenyl, benzoimidazolyl, benzothiazolyl, benzoisothiazolyl, benzoisoxazolyl, benzoxazolyl, imidazopyridinyl, isoindolyl, indolyl, benzoindolyl, indazolyl, benzothiadiazolyl, quinolyl, isoquinolyl, cinnolinyl, quinazolinyl, quinoxalinyl, carbazolyl, azacarbazolyl, benzocarbazolyl, dibenzocarbazolyl, phenoxazinyl, phenanthridinyl, benzodioxolyl, indolizidinyl, acrylidinyl, silafluorenyl, germafluorenyl, etc. More specifically, the heteroaryl may be 1-pyrrolyl, 2-pyrrolyl, 3-pyrrolyl, 2-pyridinyl, 3-pyridinyl, 4-pyridinyl, 2-pyrimidinyl, 4-pyrimidinyl, 5-pyrimidinyl, 6-pyrimidinyl, 1,2,3-triazin-4-yl, 1,2,4-triazin-3-yl, 1,3,5-triazin-2-yl, 1-imidazolyl, 2-imidazolyl, 1-pyrazolyl, 1-indolizidinyl, 2-indolizidinyl, 3-indolizidinyl, 5-indolizidinyl, 6-indolizidinyl, 7-indolizidinyl, 8-indolizidinyl, 2-imidazopyridinyl, 3-imidazopyridinyl, 5-imidazopyridinyl, 6-imidazopyridinyl, 7-imidazopyridinyl, 8-imidazopyridinyl, 1-indolyl, 2-indolyl, 3-indolyl, 4-indolyl, 5-indolyl, 6-indolyl, 7-indolyl, 1-isoindolyl, 2-isoindolyl, 3-isoindolyl, 4-isoindolyl, 5-isoindolyl, 6-isoindolyl, 7-isoindolyl, 2-furyl, 3-furyl, 2-benzofuranyl, 3-benzofuranyl, 4-benzofuranyl, 5-benzofuranyl, 6-benzofuranyl, 7-benzofuranyl, 1-isobenzofuranyl, 3-isobenzofuranyl, 4-isobenzofuranyl, 5-isobenzofuranyl, 6-isobenzofuranyl, 7-isobenzofuranyl, 2-quinolyl, 3-quinolyl, 4-quinolyl, 5-quinolyl, 6-quinolyl, 7-quinolyl, 8-quinolyl, 1-isoquinolyl, 3-isoquinolyl, 4-isoquinolyl, 5-isoquinolyl, 6-isoquinolyl, 7-isoquinolyl, 8-isoquinolyl, 2-quinoxalinyl, 5-quinoxalinyl, 6-quinoxalinyl, 1-carbazolyl, 2-carbazolyl, 3-carbazolyl, 4-carbazolyl, 9-carbazolyl, azacarbazole-1-yl, azacarbazole-2-yl, azacarbazole-3-yl, azacarbazole-4-yl, azacarbazole-5-yl, azacarbazole-6-yl, azacarbazole-7-yl, azacarbazole-8-yl, azacarbazole-9-yl, 1-phenanthridinyl, 2-phenanthridinyl, 3-phenanthridinyl, 4-phenanthridinyl, 6-phenanthridinyl, 7-phenanthridinyl, 8-phenanthridinyl, 9-phenanthridinyl, 10-phenanthridinyl, 1-acrylidinyl, 2-acrylidinyl, 3-acrylidinyl, 4-acrylidinyl, 9-acrylidinyl, 2-oxazolyl, 4-oxazolyl, 5-oxazolyl, 2-oxadiazolyl, 5-oxadiazolyl, 3-furazanyl, 2-thienyl, 3-thienyl, 2-methylpyrrole-1-yl, 2-methylpyrrole-3-yl, 2-methylpyrrole-4-yl, 2-methylpyrrole-5-yl, 3-methylpyrrole-1-yl, 3-methylpyrrole-2-yl, 3-methylpyrrole-4-yl, 3-methylpyrrole-5-yl, 2-t-buthylpyrrole-4-yl, 3-(2-phenylpropyl)pyrrole-1-yl, 2-methyl-1-indolyl, 4-methyl-1-indolyl, 2-methyl-3-indolyl, 4-methyl-3-indolyl, 2-t-butyl-1-indolyl, 4-t-butyl-1-indolyl, 2-t-butyl-3-indolyl, 4-t-butyl-3-indolyl, 1-dibenzofuranyl, 2-dibenzofuranyl, 3-dibenzofuranyl, 4-dibenzofuranyl, 1-dibenzothiophenyl, 2-dibenzothiophenyl, 3-dibenzothiophenyl, 4-dibenzothiophenyl, 1-silafluorenyl, 2-silafluorenyl, 3-silafluorenyl, 4-silafluorenyl, 1-germafluorenyl, 2-germafluorenyl, 3-germafluorenyl, and 4-germafluorenyl.

“Halogen” includes F, Cl, Br, and I.

In addition, “ortho (o)”, “meta (m)”, and “para (p)” are meant to signify the substitution position of all substituents. Ortho position is a compound with substituents, which are adjacent between each other, e.g., at the 1 and 2 positions on benzene. Meta position is the next substitution position of the immediately adjacent substitution position, e.g., a compound with substituents at the 1 and 3 positions on benzene. Para position is the next substitution position of the meta position, e.g., a compound with substituents at the 1 and 4 positions on benzene.

Herein, “substituted or unsubstituted ring” is meant to be a substituted or unsubstituted, (C3-C30) mono- or polycyclic, alicyclic, aromatic ring or the combination thereof, preferably, may be a substituted or unsubstituted, (C5-C25) mono- or polycyclic, alicyclic, aromatic ring or the combination thereof, more preferably, may be (C5-C18) mono-or polycyclic, alicyclic, aromatic ring or the combination thereof.

In addition, “substituted” in the expression “substituted or unsubstituted” means that a hydrogen atom in a certain functional group is replaced with another atom or functional group, i.e., a substituent. The substituents of the substituted (C1-C30)alkyl, the substituted (C6-C30)aryl(ene), the substituted (3- to 30-membered)heteroaryl(ene), the substituted (C3-C30)cycloalkyl, the substituted (C1-C30)alkoxy, the substituted tri(C1-C30)alkylsilyl, the substituted di(C1-C30)alkyl(C6-C30)arylsilyl, the substituted (C1-C30)alkyldi(C6-C30)arylsilyl, the substituted tri(C6-C30) arylsilyl, and the substituted ring, in R₁ to R_{4,} Ar₁, Ar₂, and L each independently, are preferably at least one selected from the group consisting of deuterium, halogen, cyano, carboxyl, nitro, hydroxyl, (C1-C30)alkyl, halo(C1-C30)alkyl, (C2-C30)alkenyl, (C2-C30)alkynyl, (C1-C30)alkoxy, (C1-C30)alkylthio, (C3-C30)cycloalkyl, (C3-C30)cycloalkenyl, (3- to 7-membered) heterocycloalkyl, (C6-C30)aryloxy, (C6-C30)arylthio, (C6-C30)aryl-substituted or unsubstituted (5- to 30-membered)heteroaryl, (5- to 30-membered) heteroaryl-substituted or unsubstituted (C6-C30)aryl, tri(C1-C30)alkylsilyl, tri(C6-C30)arylsilyl, di(C1-C30)alkyl(C6-C30)arylsilyl, (C1-C30)alkyldi(C6-C30)arylsilyl, amino, mono- or di-(C1-C30)alkylamino, (C1-C30)alkyl-substituted or unsubstituted mono- or di-(C6-C30)arylamino, (C1-C30)alkyl(C6-C30)arylamino, (C1-C30)alkylcarbonyl, (C1-C30)alkoxycarbonyl, (C6-C30)arylcarbonyl, di(C6-C30)arylboronyl, di(C1-C30)alkylboronyl, (C1-C30)alkyl(C6-C30)arylboronyl, (C6-C30)ar(C1-C30)alkyl, and (C1-C30)alkyl(C6-C30)aryl, e.g., may be an unsubstituted methyl, an unsubstituted phenyl, or an unsubstituted naphthyl.

Hereinafter, the organic electroluminescent compound according to one embodiment will be described.

The organic electroluminescent compound according to one embodiment is represented by the following formula 1.

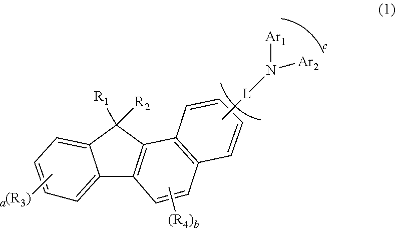

In formula 1,

R₁ and R₂ each independently represent hydrogen, deuterium, a substituted or unsubstituted (C1-C30)alkyl, a substituted or unsubstituted (C6-C30)aryl, or a substituted or unsubstituted (3- to 30-membered)heteroaryl; or may be linked to an adjacent substituent to form a substituted or unsubstituted ring;

R₃ and R₄ each independently represent hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, or a substituted or unsubstituted tri(C6-C30)arylsilyl;

L represents a single bond, a substituted or unsubstituted (C6-C30)arylene, or a substituted or unsubstituted (3- to 30-membered)heteroarylene;

Ar₁ and Ar₂ each independently represent a substituted or unsubstituted (C1-C30)alkyl, a substituted or unsubstituted (C6-C30)aryl, or a substituted or unsubstituted (3- to 30-membered)heteroaryl; or may be linked to each other to form a substituted or unsubstituted ring;

a represents an integer from 1 to 4, b represents an integer of 1 or 2, when a or b is an integer of 2 or more, each of R₃ or each of R₄ may be the same or different; and

c represents an integer of 1 or 2, when c is an integer of 2, each of Ar₁ or each of Ar₂ may be the same or different.

The organic electroluminescent compound of formula 1 according to one embodiment may be comprised in a hole transport layer and/or a hole auxiliary layer. The hole auxiliary layer may be placed between the hole transport layer and the light-emitting layer, and may be effective to promote or block the hole transport rate, thereby enabling the charge balance to be controlled. The organic electroluminescent compound of formula 1 according to one embodiment forms a resonance structure so that the flow of holes and electrons can be appropriately balanced, thereby the efficiency of the organic electroluminescent device comprising the organic electroluminescent compound can be improved. Specifically, the organic electroluminescent compound increases hole injection and hole mobility as well as the HOMO energy level by introducing an electron-rich arylamine group into a benzofluorene structure which is easy to receive holes, thereby further facilitating hole injection.

In one embodiment, the organic electroluminescent compound of formula 1 may be represented by one of the following formulae 1-1 to 1-6.

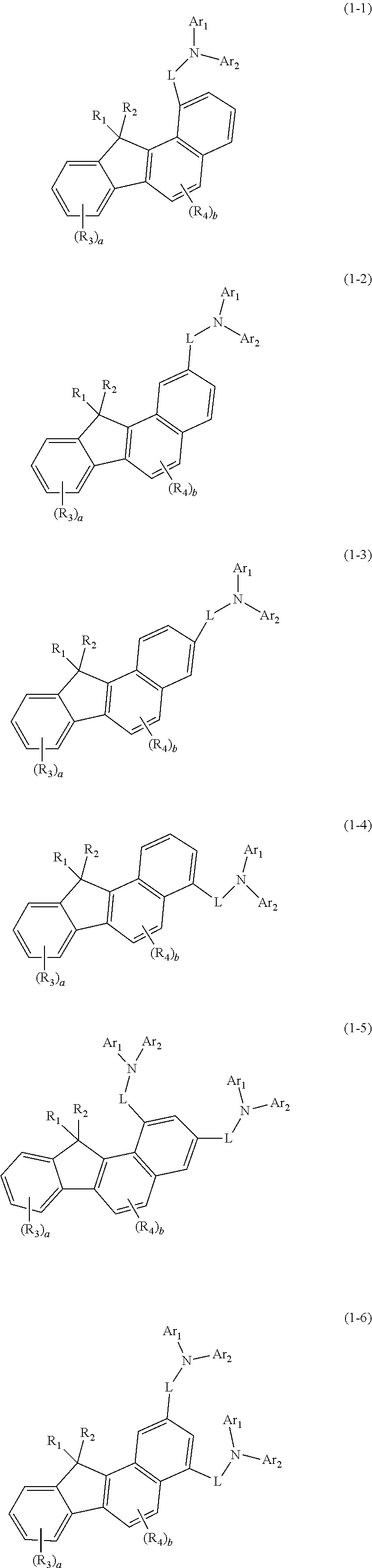

In formulae 1-1 to 1-6, R₁ to R₄, Ar₁, Ar₂, L, a, and b are as defined in formula 1 above.

In one embodiment, in formulae 1 and 1-1 to 1-6, R₁ and R₂ each independently represent hydrogen, deuterium, a substituted or unsubstituted (C1-C30)alkyl, a substituted or unsubstituted (C6-C30)aryl, or a substituted or unsubstituted (3- to 30-membered)heteroaryl; or may be linked to an adjacent substituent to form a substituted or unsubstituted ring; preferably, each independently may be hydrogen, a substituted or unsubstituted (C1-C18)alkyl, or a substituted or unsubstituted (C6-C18)aryl; more preferably, each independently may be hydrogen, a substituted or unsubstituted (C1-C4)alkyl, or a substituted or unsubstituted (C6-C12)aryl. For example, R₁ and R₂ each independently may be hydrogen, methyl, or phenyl.

In one embodiment, in formulae 1 and 1-1 to 1-6, R₃ and R₄ each independently represent hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, or a substituted or unsubstituted tri(C6-C30)arylsilyl; preferably, each independently may be hydrogen or a substituted or unsubstituted (C6-C18)aryl; more preferably, each independently may be hydrogen or a substituted or unsubstituted (C6-C12)aryl. For example, R₃ and R₄ each independently may be hydrogen or phenyl.

In one embodiment, in formulae 1 and 1-1 to 1-6, L represents a single bond, a substituted or unsubstituted (C6-C30)arylene, or a substituted or unsubstituted (3- to 30-membered)heteroarylene; preferably, may be a single bond or a substituted or unsubstituted (C6-C18)arylene; more preferably, may be a single bond or a substituted or unsubstituted (C6-C12)arylene. For example, L may be a single bond or phenylene.

In one embodiment, in formulae 1 and 1-1 to 1-6, Ar₁ and Ar₂ each independently represent a substituted or unsubstituted (C1-C30)alkyl, a substituted or unsubstituted (C6-C30)aryl, or a substituted or unsubstituted (3- to 30-membered)heteroaryl; or may be linked to each other to form a substituted or unsubstituted ring; preferably, each independently may be one of the substituents listed in the following group I.

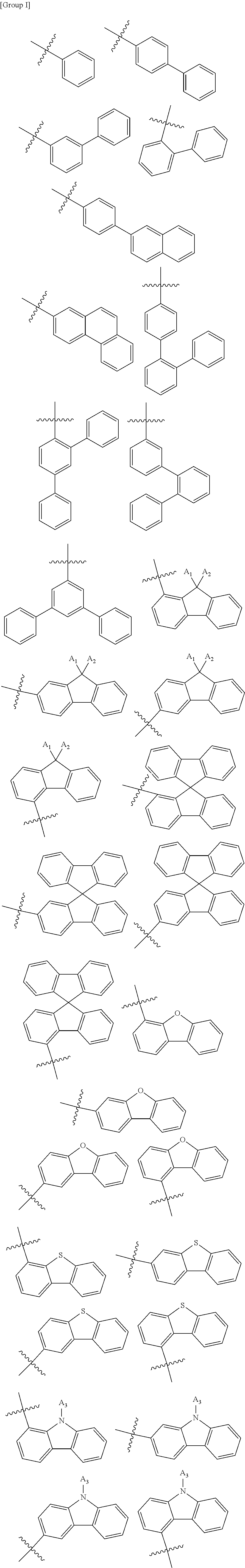

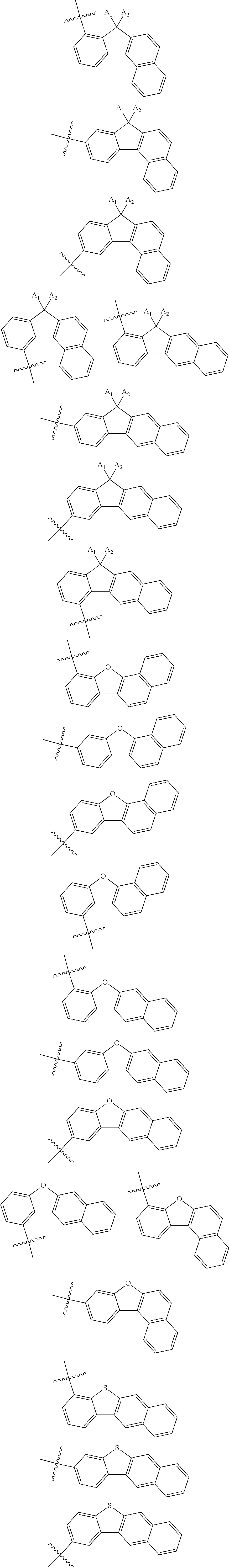

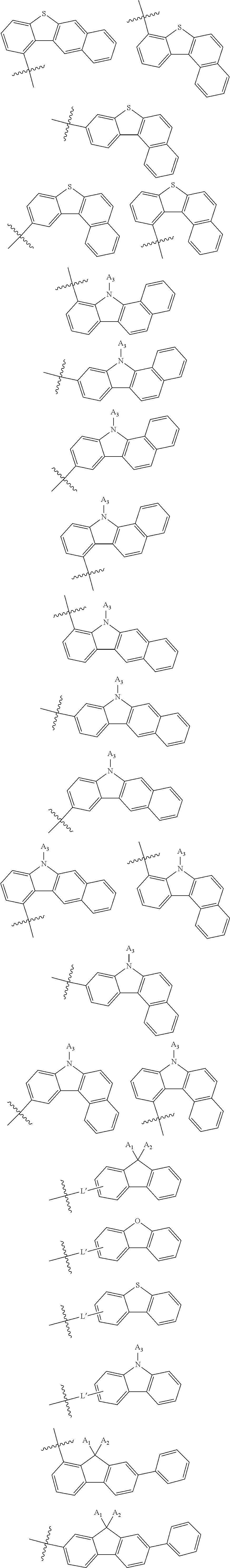

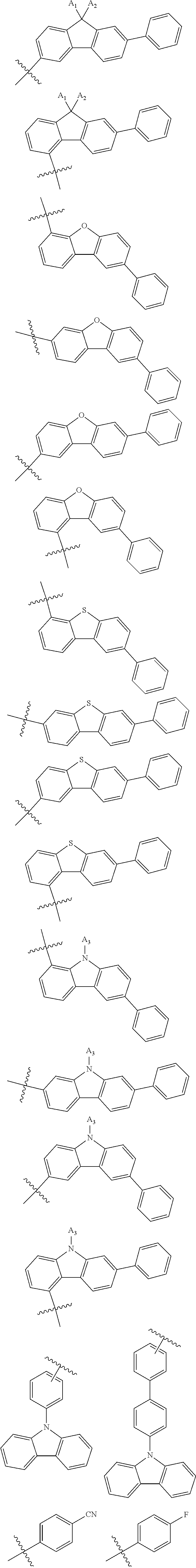

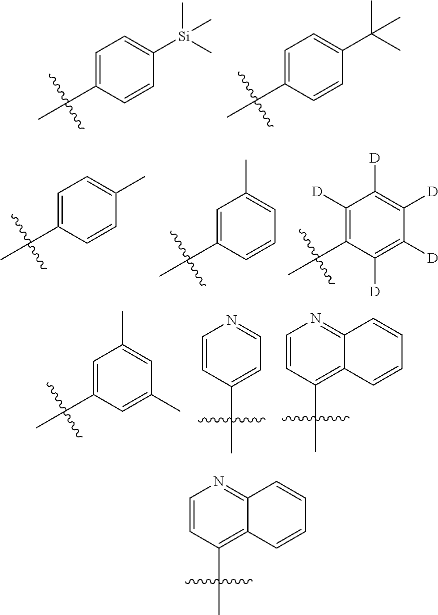

In group I, A₁ to A₃ each independently represent a substituted or unsubstituted (C1-C30)alkyl or a substituted or unsubstituted (C6-C30)aryl; preferably, each independently may be a substituted or unsubstituted (C1-C18)alkyl or a substituted or unsubstituted (C6-C18)aryl; more preferably, each independently may be a substituted or unsubstituted (C1-C4)alkyl or a substituted or unsubstituted (C6-C12)aryl. For example, A₁ to A₃ each independently may be methyl, phenyl, or naphthyl.

In group I, L′ represents a substituted or unsubstituted (C6-C30)arylene or a substituted or unsubstituted (3- to 30-membered)heteroarylene; preferably, each independently may be a substituted or unsubstituted (C6-C25)arylene or a substituted or unsubstituted (5- to 25-membered)heteroarylene; more preferably, each independently may be a substituted or unsubstituted (C6-C18)arylene or a substituted or unsubstituted (5- to 18-membered)heteroarylene.

In group I, [symbol] represents a bonding position with N.

In addition, more preferably, Ar₁ and Ar₂ each independently may be a substituted or unsubstituted (C6-C25)aryl or a substituted or unsubstituted (3- to 25-membered)heteroaryl, or may be linked to each other to form a substituted or unsubstituted (C3-C25) mono- or polycyclic aromatic ring, whose at least one carbon atom in the formed aromatic ring may be replaced with at least one heteroatom selected from nitrogen, oxygen, and sulfur; preferably, each independently may be one of the substituents listed in the following group II or may be linked to each other, so that the amine group forms a substituted or unsubstituted carbazole.

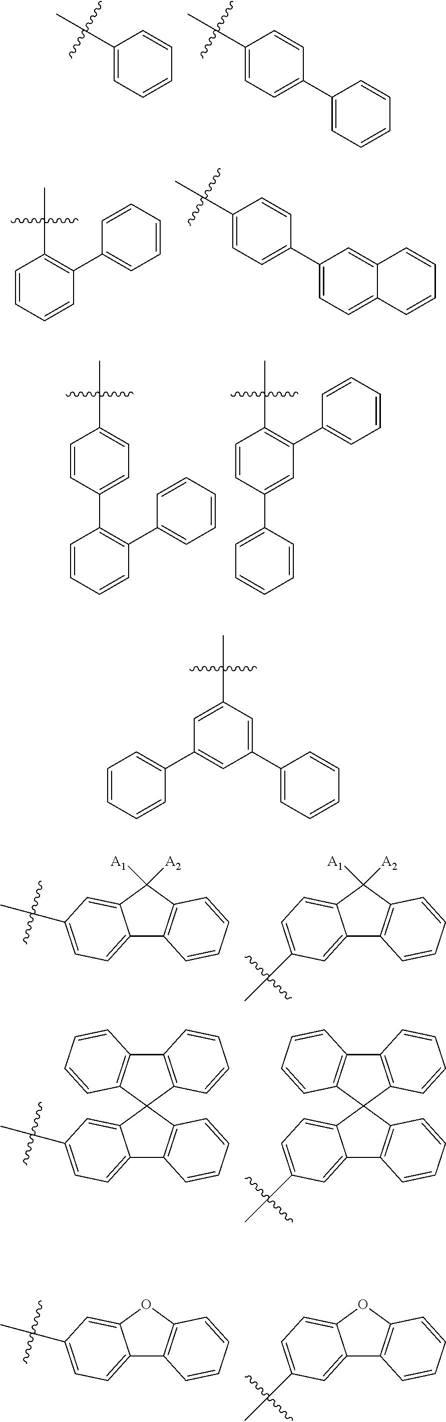

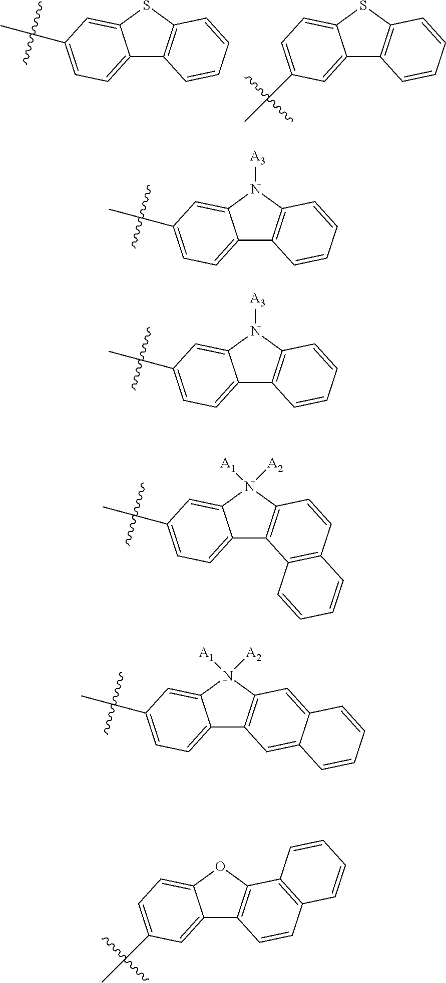

In group II, A₁ to A₃, and [symbol] are as defined in group I.

In one embodiment, the organic electroluminescent compound of formula 1 may be represented by one of the following formulae I-1 to I-4.

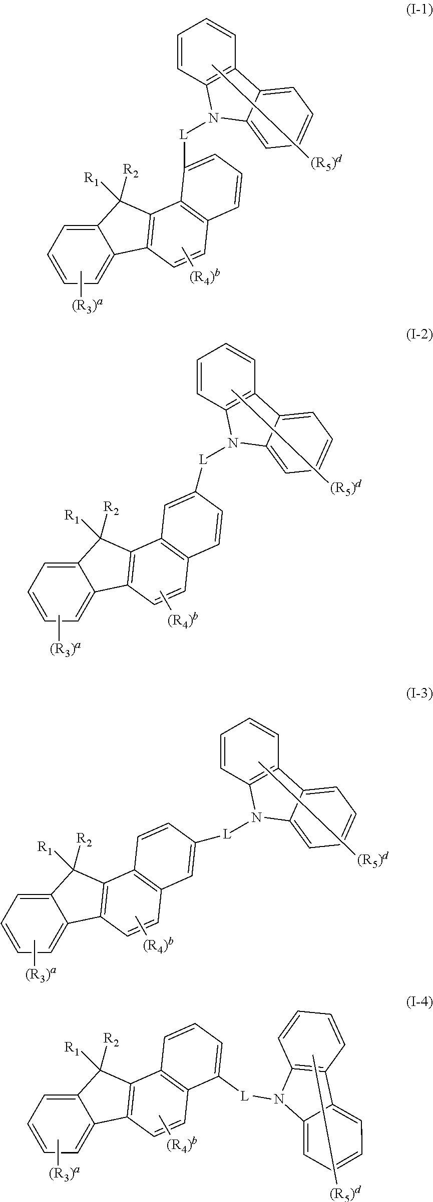

In formulae I-1 to I-4, R₁ to R₄, L, a, and b are as defined in formula 1;

R₅ represents hydrogen or —NRₓR_{y};

Rₓ and R_{y} each independently represent hydrogen, deuterium, a substituted or unsubstituted (C1-C30)alkyl, or a substituted or unsubstituted (C6-C30)aryl; and

d represents an integer of 1 or 2, when d is 2, each of R₅ may be the same or different.

In one embodiment, in formulae I-1 to I-4, R₅ represents hydrogen or —NRₓR_{y}, wherein Rₓ and R_{y} each independently may be hydrogen or a substituted or unsubstituted (C6-C30)aryl; preferably, each independently may be hydrogen or a substituted or unsubstituted (C6-C18)aryl; more preferably, each independently may be hydrogen or a substituted or unsubstituted (C6-C12)aryl. For example, in formulae I-1 to I-4, R₅ may be hydrogen or an amine substituented with phenyl.

In one embodiment, in formulae 1 and 1-1 to 1-6, a represents an integer of 1 to 4, b represents an integer of 1 or 2, when a or b represents 2 or more, each of R₃ and each of R₄ may be the same or different, c represents an integer of 1 or 2, when c is 2, each of Ar₁ or each of Ar₂ may be the same or different.

The organic electroluminescent compound according to one embodiment, in formula 1, R₁ and R₂ each independently represent hydrogen, a substituted or unsubstituted (C1-C18)alkyl, or a substituted or unsubstituted (C6-C18)aryl; R₃ and R₄ each independently represent hydrogen or a substituted or unsubstituted (C6-C18)aryl; L represents a single bond or a substituted or unsubstituted (C6-C18)arylene; Ar₁ and Ar₂ each independently represent a substituted or unsubstituted (C6-C25)aryl, or a substituted or unsubstituted (3- to 25-membered)heteroaryl, or may be linked to each other to form a substituted or unsubstituted (C3-C25) mono- or polycyclic, aromatic ring.

According to another embodiment, in formula 1, R₁ and R₂ each independently represent hydrogen, methyl, or phenyl; R₃ and R₄ each independently represent hydrogen or phenyl; L represents a single bond or phenylene; Ar₁ and Ar₂ each independently represent one of the substituents listed in the group II or may be linked to each other, so that the amine group forms a substituted or unsubstituted carbazole.

According to one embodiment, the organic electroluminescent compound of formula 1 may be more specifically illustrated by the following compounds, but are not limited thereto:

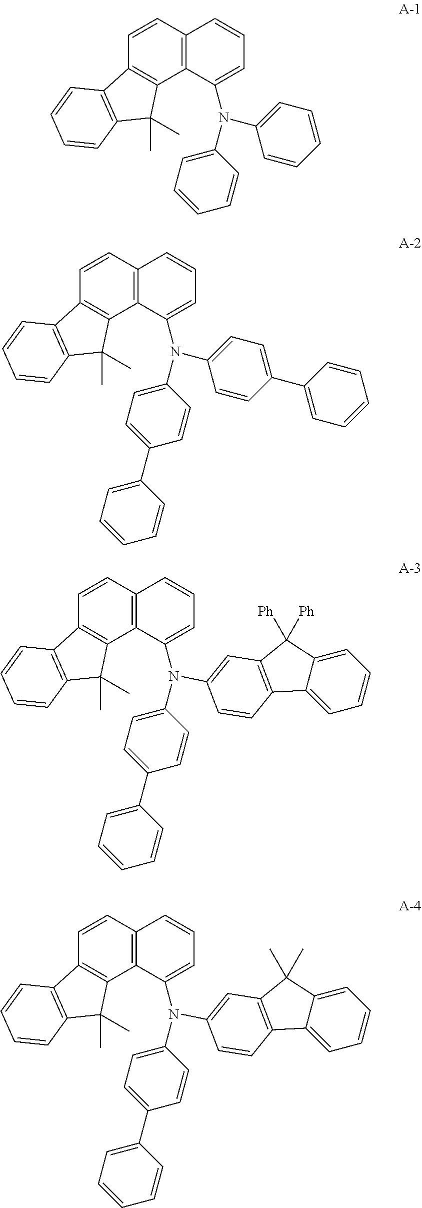

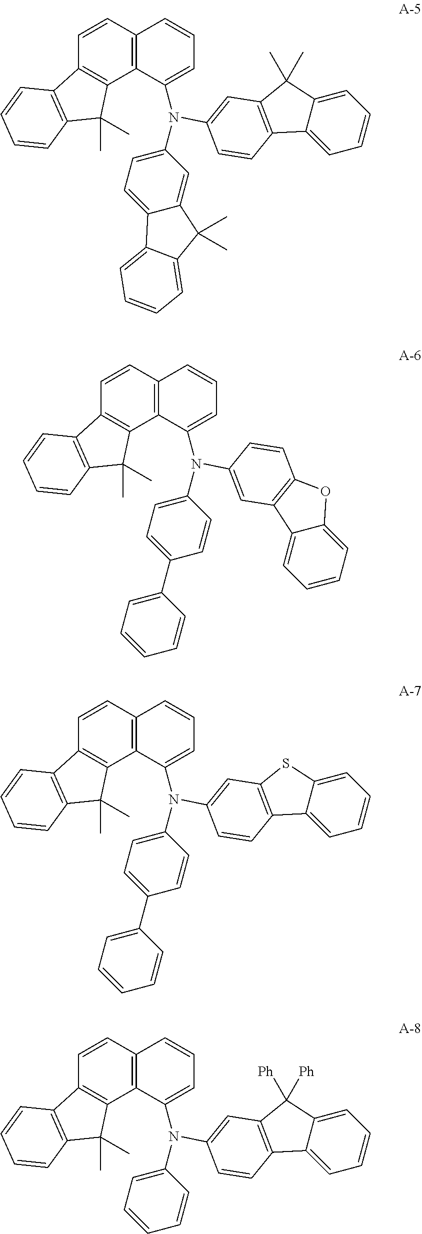 [SMILES: CC1(C)c2ccccc2-c2ccc(N(c3ccc4c(c3)C(C)(C)c3ccccc3-4)c3cccc4ccc5c(c34)C(C)(C)c3ccccc3-5)cc21 ; CC1(C)c2ccccc2-c2ccc3cccc(N(c4ccc(-c5ccccc5)cc4)c4ccc5oc6ccccc6c5c4)c3c21 ; CC1(C)c2ccccc2-c2ccc3cccc(N(c4ccc(-c5ccccc5)cc4)c4ccc5c(c4)sc4ccccc45)c3c21 ; CC1(C)c2ccccc2-c2ccc3cccc(N(c4ccccc4)c4ccc5c(c4)C(c4ccccc4)(c4ccccc4)c4ccccc4-5)c3c21]

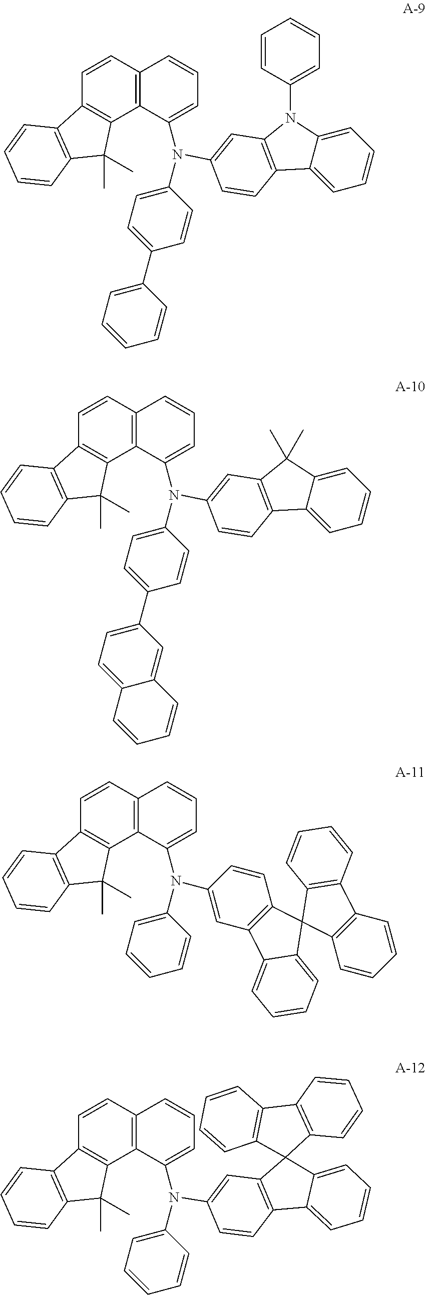

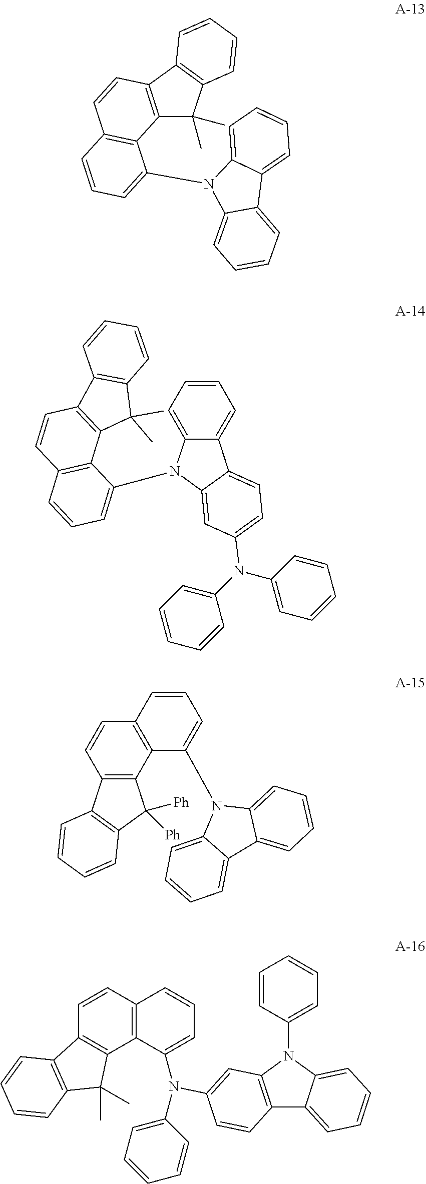

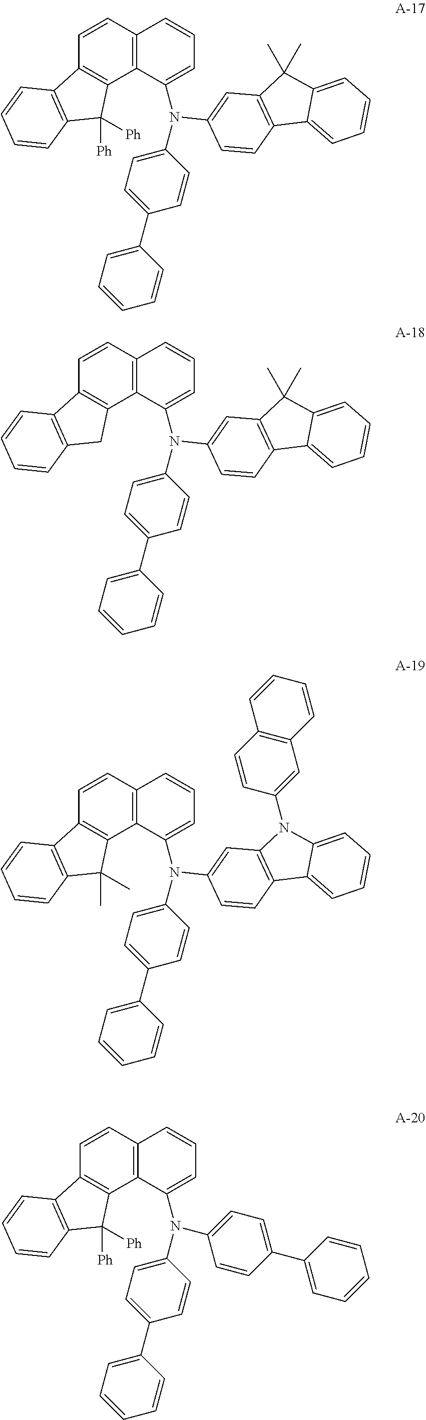

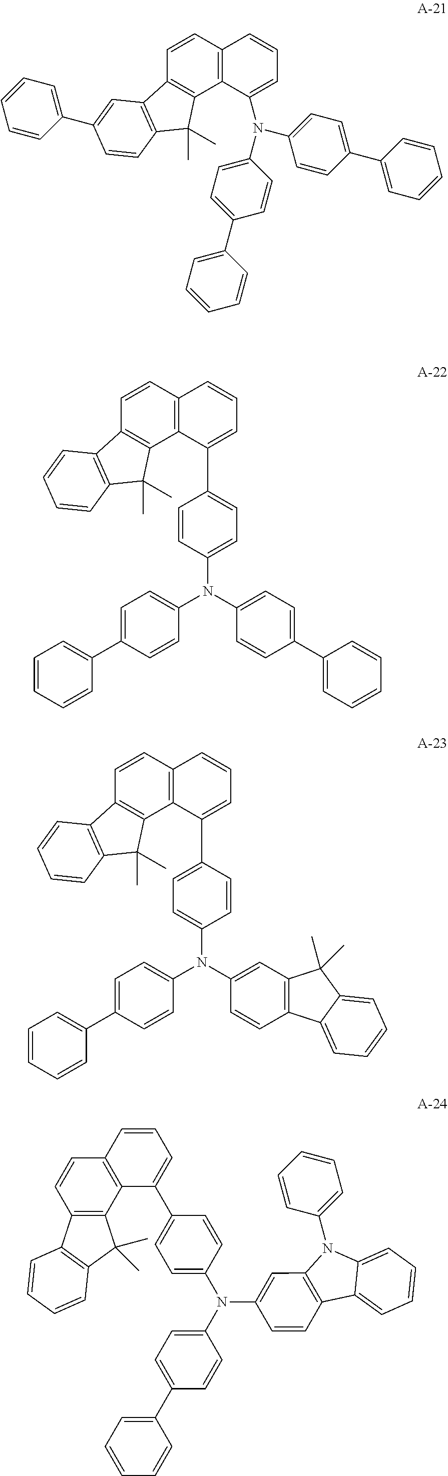 [SMILES: CC1(C)c2ccc(-c3ccccc3)cc2-c2ccc3cccc(N(c4ccc(-c5ccccc5)cc4)c4ccc(-c5ccccc5)cc4)c3c21 ; CC1(C)c2ccccc2-c2ccc3cccc(-c4ccc(N(c5ccc(-c6ccccc6)cc5)c5ccc(-c6ccccc6)cc5)cc4)c3c21 ; CC1(C)c2ccccc2-c2ccc(N(c3ccc(-c4ccccc4)cc3)c3ccc(-c4cccc5ccc6c(c45)C(C)(C)c4ccccc4-6)cc3)cc21 ; CC1(C)c2ccccc2-c2ccc3cccc(-c4ccc(N(c5ccc(-c6ccccc6)cc5)c5ccc6c7ccccc7n(-c7ccccc7)c6c5)cc4)c3c21]

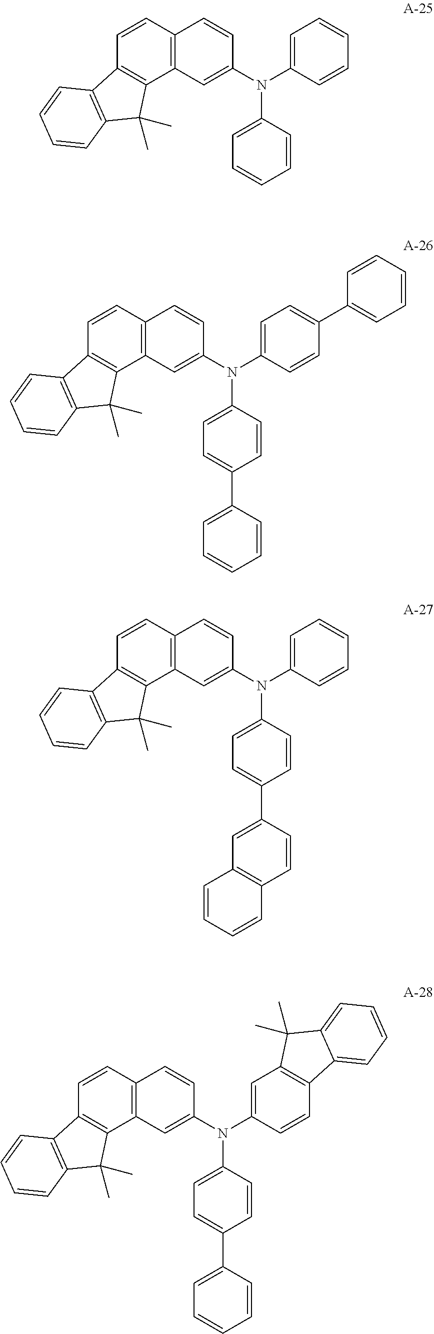 [SMILES: CC1(C)c2ccccc2-c2ccc3ccc(N(c4ccccc4)c4ccccc4)cc3c21 ; CC1(C)c2ccccc2-c2ccc3ccc(N(c4ccc(-c5ccccc5)cc4)c4ccc(-c5ccccc5)cc4)cc3c21 ; CC1(C)c2ccccc2-c2ccc3ccc(N(c4ccccc4)c4ccc(-c5ccc6ccccc6c5)cc4)cc3c21 ; CC1(C)c2ccccc2-c2ccc(N(c3ccc(-c4ccccc4)cc3)c3ccc4ccc5c(c4c3)C(C)(C)c3ccccc3-5)cc21]

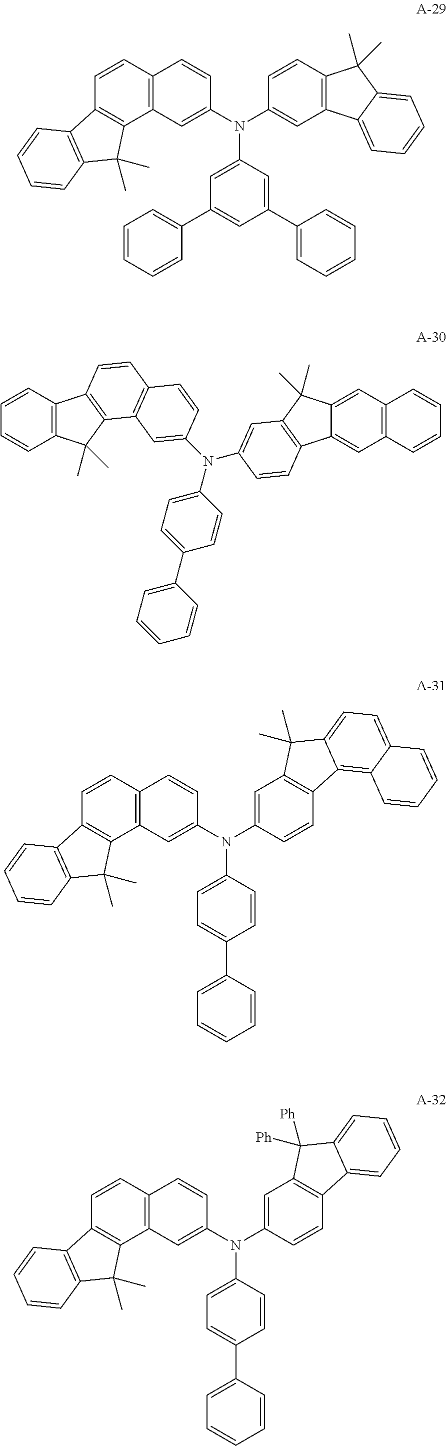 [SMILES: CC1(C)c2ccccc2-c2cc(N(c3cc(-c4ccccc4)cc(-c4ccccc4)c3)c3ccc4ccc5c(c4c3)C(C)(C)c3ccccc3-5)ccc21 ; CC1(C)c2cc(N(c3ccc(-c4ccccc4)cc3)c3ccc4ccc5c(c4c3)C(C)(C)c3ccccc3-5)ccc2-c2cc3ccccc3cc21 ; CC1(C)c2cc(N(c3ccc(-c4ccccc4)cc3)c3ccc4ccc5c(c4c3)C(C)(C)c3ccccc3-5)ccc2-c2c1ccc1ccccc21 ; CC1(C)c2ccccc2-c2ccc3ccc(N(c4ccc(-c5ccccc5)cc4)c4ccc5c(c4)C(c4ccccc4)(c4ccccc4)c4ccccc4-5)cc3c21]

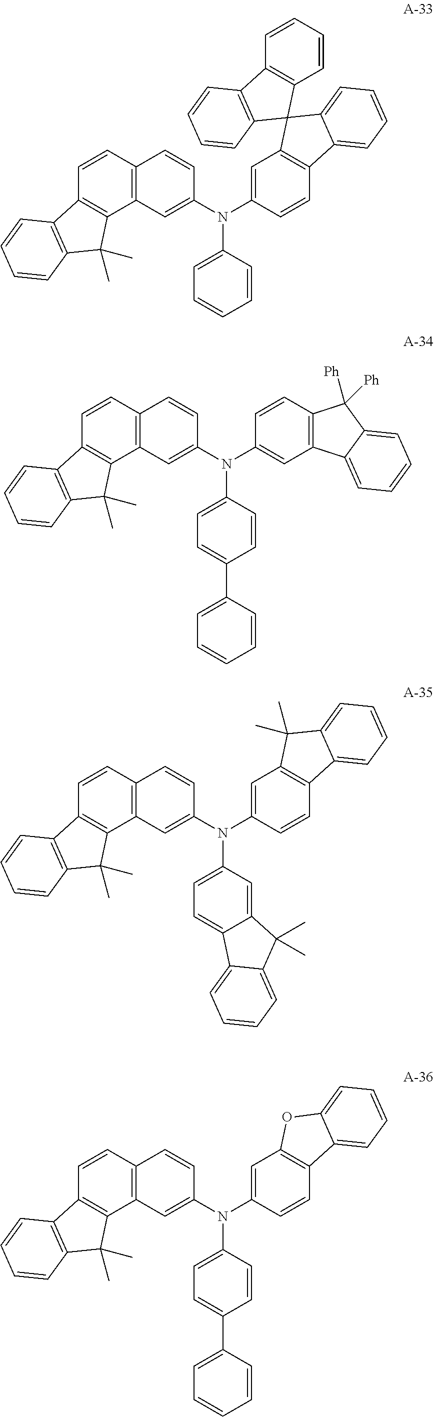 [SMILES: CC1(C)c2ccccc2-c2ccc3ccc(N(c4ccccc4)c4ccc5c(c4)C4(c6ccccc6-c6ccccc64)c4ccccc4-5)cc3c21 ; CC1(C)c2ccccc2-c2ccc3ccc(N(c4ccc(-c5ccccc5)cc4)c4ccc5c(c4)-c4ccccc4C5(c4ccccc4)c4ccccc4)cc3c21 ; CC1(C)c2ccccc2-c2ccc(N(c3ccc4c(c3)C(C)(C)c3ccccc3-4)c3ccc4ccc5c(c4c3)C(C)(C)c3ccccc3-5)cc21 ; CC1(C)c2ccccc2-c2ccc3ccc(N(c4ccc(-c5ccccc5)cc4)c4ccc5c(c4)oc4ccccc45)cc3c21]

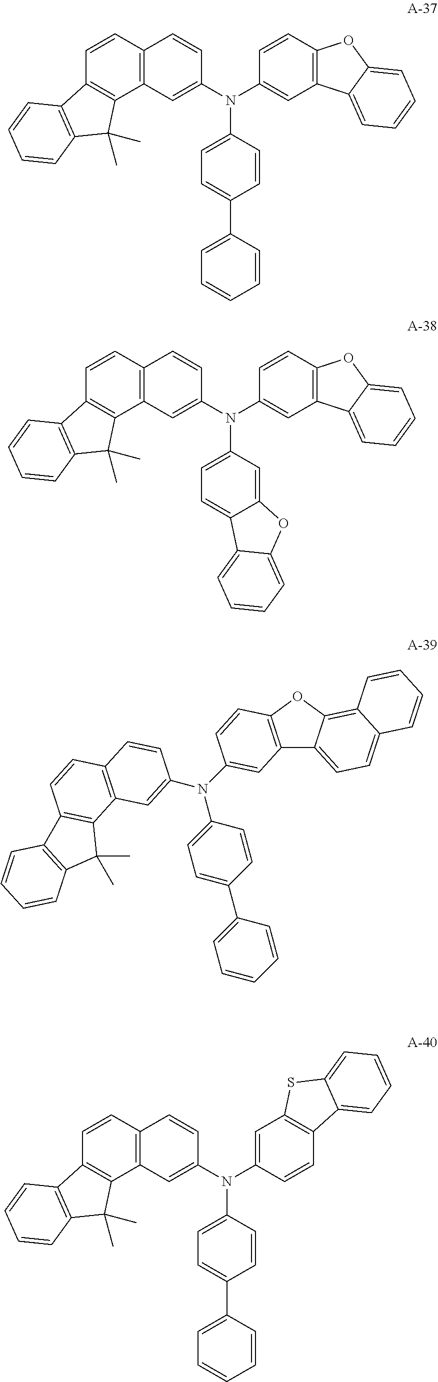 [SMILES: CC1(C)c2ccccc2-c2ccc3ccc(N(c4ccc(-c5ccccc5)cc4)c4ccc5oc6ccccc6c5c4)cc3c21 ; CC1(C)c2ccccc2-c2ccc3ccc(N(c4ccc5c(c4)oc4ccccc45)c4ccc5oc6ccccc6c5c4)cc3c21 ; CC1(C)c2ccccc2-c2ccc3ccc(N(c4ccc(-c5ccccc5)cc4)c4ccc5oc6c7ccccc7ccc6c5c4)cc3c21 ; CC1(C)c2ccccc2-c2ccc3ccc(N(c4ccc(-c5ccccc5)cc4)c4ccc5c(c4)sc4ccccc45)cc3c21]

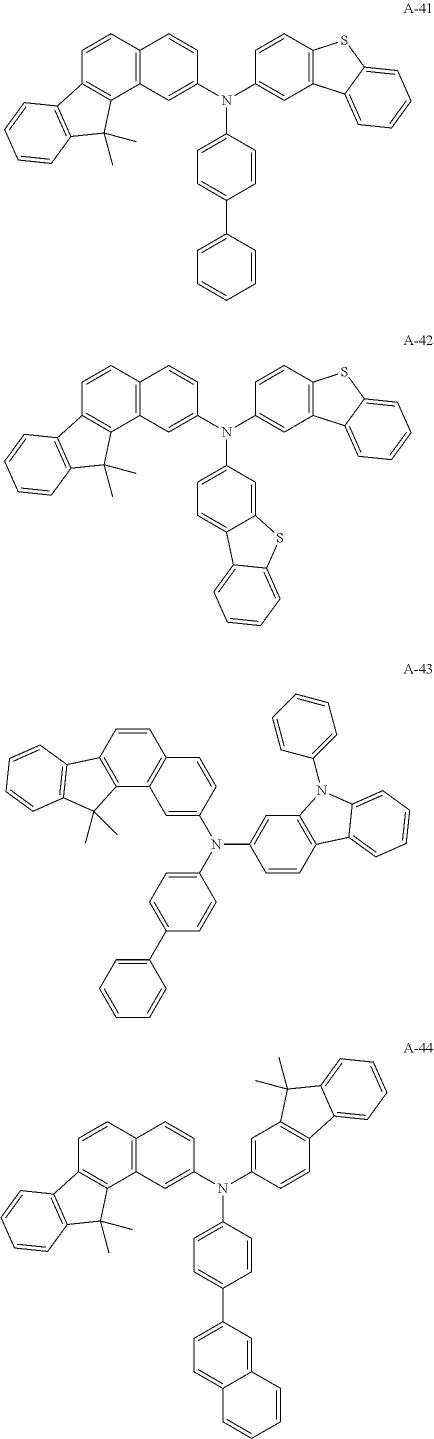 [SMILES: CC1(C)c2ccccc2-c2ccc3ccc(N(c4ccc(-c5ccccc5)cc4)c4ccc5sc6ccccc6c5c4)cc3c21 ; CC1(C)c2ccccc2-c2ccc3ccc(N(c4ccc5c(c4)sc4ccccc45)c4ccc5sc6ccccc6c5c4)cc3c21 ; CC1(C)c2ccccc2-c2ccc3ccc(N(c4ccc(-c5ccccc5)cc4)c4ccc5c6ccccc6n(-c6ccccc6)c5c4)cc3c21 ; CC1(C)c2ccccc2-c2ccc(N(c3ccc(-c4ccc5ccccc5c4)cc3)c3ccc4ccc5c(c4c3)C(C)(C)c3ccccc3-5)cc21]

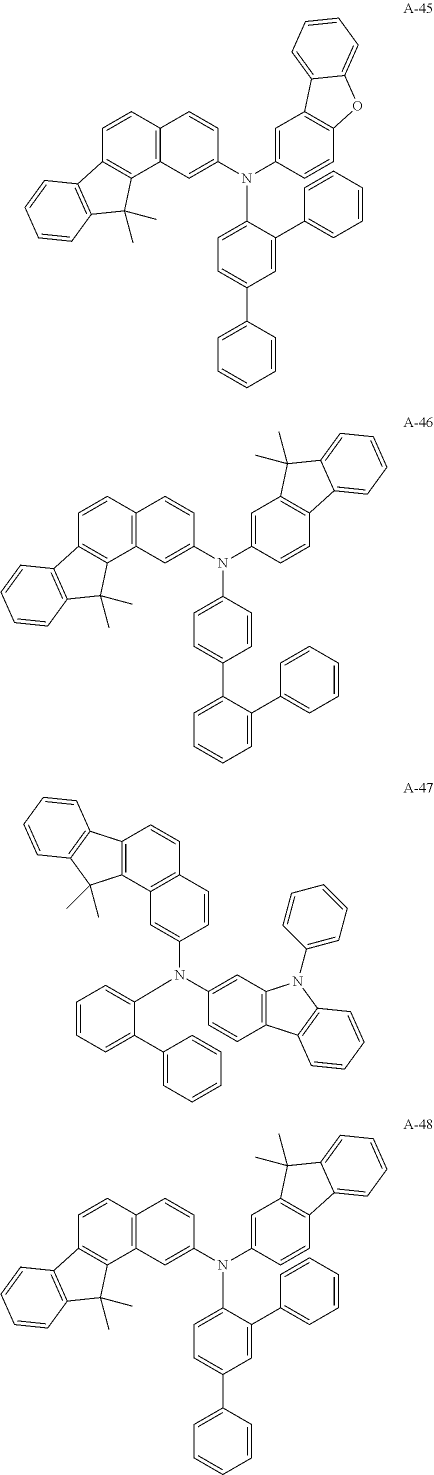 [SMILES: CC1(C)c2ccccc2-c2ccc3ccc(N(c4ccc5oc6ccccc6c5c4)c4ccc(-c5ccccc5)cc4-c4ccccc4)cc3c21 ; CC1(C)c2ccccc2-c2ccc(N(c3ccc(-c4ccccc4-c4ccccc4)cc3)c3ccc4ccc5c(c4c3)C(C)(C)c3ccccc3-5)cc21 ; CC1(C)c2ccccc2-c2ccc3ccc(N(c4ccc5c6ccccc6n(-c6ccccc6)c5c4)c4ccccc4-c4ccccc4)cc3c21 ; CC1(C)c2ccccc2-c2ccc(N(c3ccc4ccc5c(c4c3)C(C)(C)c3ccccc3-5)c3ccc(-c4ccccc4)cc3-c3ccccc3)cc21]

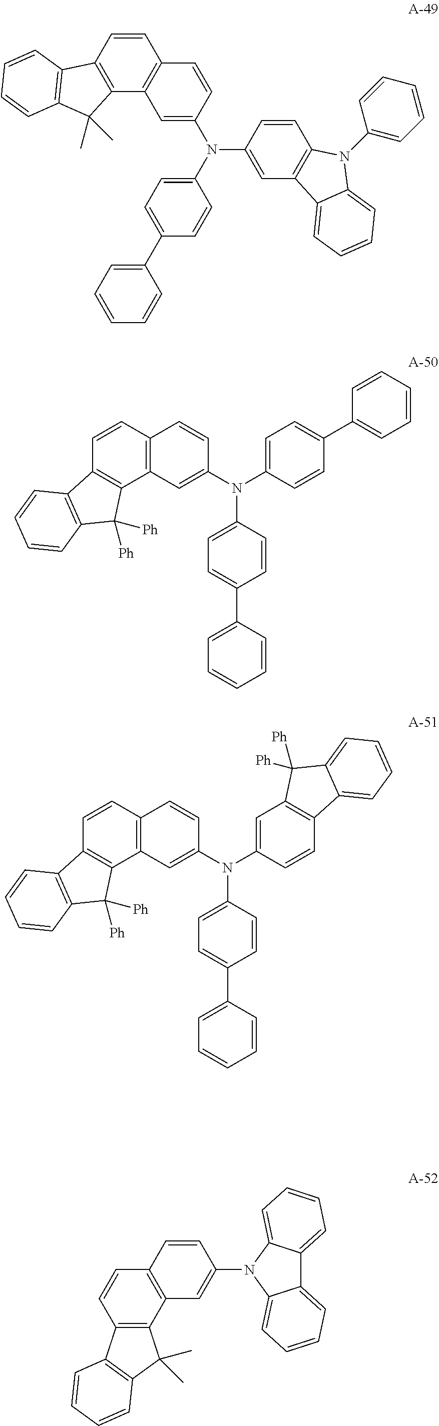 [SMILES: CC1(C)c2ccccc2-c2ccc3ccc(N(c4ccc(-c5ccccc5)cc4)c4ccc5c(c4)c4ccccc4n5-c4ccccc4)cc3c21 ; c1ccc(-c2ccc(N(c3ccc(-c4ccccc4)cc3)c3ccc4ccc5c(c4c3)C(c3ccccc3)(c3ccccc3)c3ccccc3-5)cc2)cc1 ; c1ccc(-c2ccc(N(c3ccc4c(c3)C(c3ccccc3)(c3ccccc3)c3ccccc3-4)c3ccc4ccc5c(c4c3)C(c3ccccc3)(c3ccccc3)c3ccccc3-5)cc2)cc1 ; CC1(C)c2ccccc2-c2ccc3ccc(-n4c5ccccc5c5ccccc54)cc3c21]

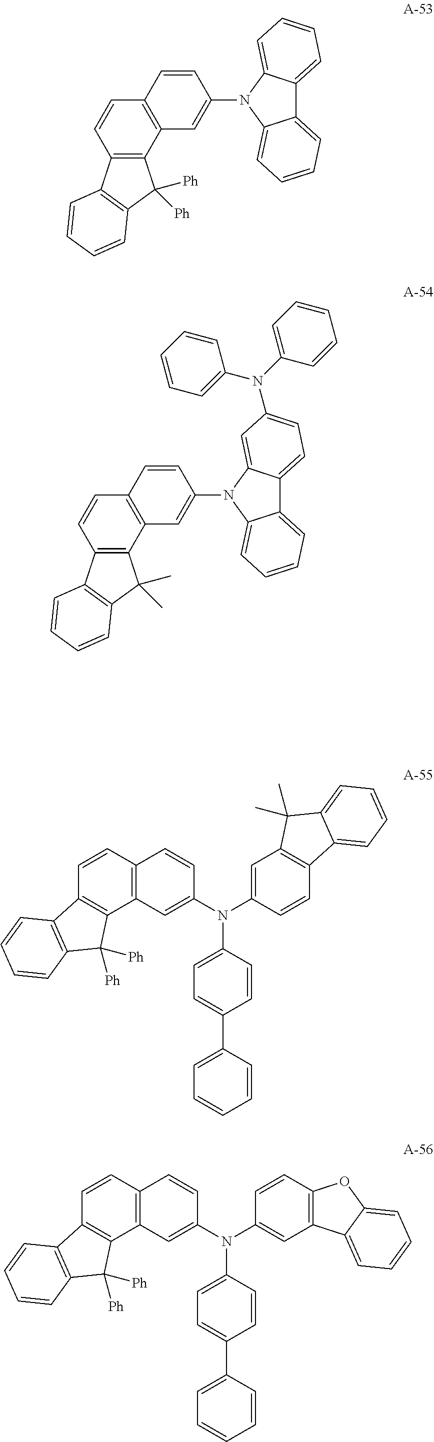 [SMILES: c1ccc(C2(c3ccccc3)c3ccccc3-c3ccc4ccc(-n5c6ccccc6c6ccccc65)cc4c32)cc1 ; CC1(C)c2ccccc2-c2ccc3ccc(-n4c5ccccc5c5ccc(N(c6ccccc6)c6ccccc6)cc54)cc3c21 ; CC1(C)c2ccccc2-c2ccc(N(c3ccc(-c4ccccc4)cc3)c3ccc4ccc5c(c4c3)C(c3ccccc3)(c3ccccc3)c3ccccc3-5)cc21 ; c1ccc(-c2ccc(N(c3ccc4ccc5c(c4c3)C(c3ccccc3)(c3ccccc3)c3ccccc3-5)c3ccc4oc5ccccc5c4c3)cc2)cc1]

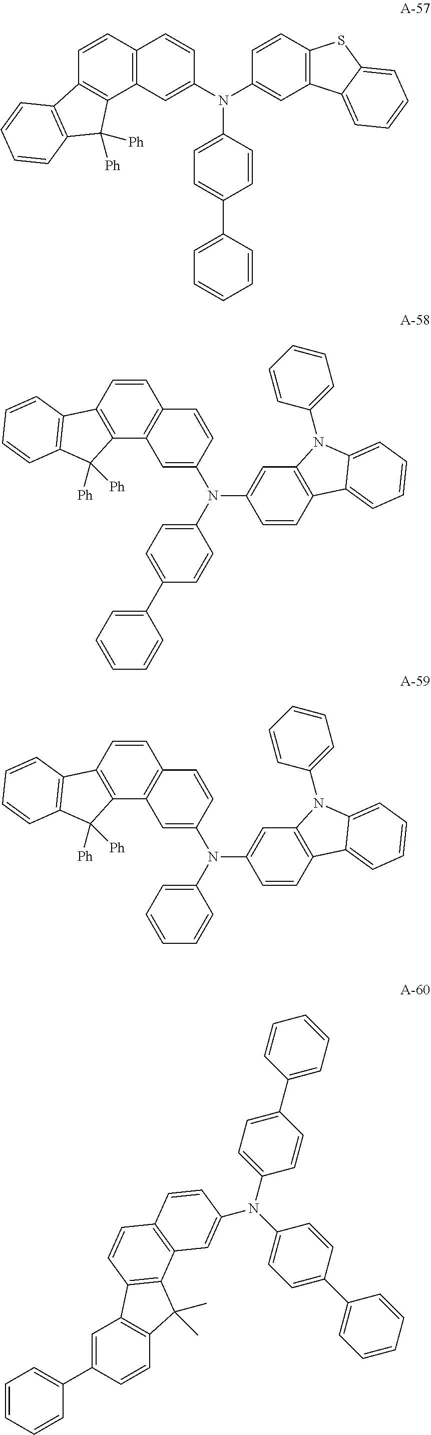 [SMILES: c1ccc(-c2ccc(N(c3ccc4ccc5c(c4c3)C(c3ccccc3)(c3ccccc3)c3ccccc3-5)c3ccc4sc5ccccc5c4c3)cc2)cc1 ; c1ccc(-c2ccc(N(c3ccc4ccc5c(c4c3)C(c3ccccc3)(c3ccccc3)c3ccccc3-5)c3ccc4c5ccccc5n(-c5ccccc5)c4c3)cc2)cc1 ; c1ccc(N(c2ccc3ccc4c(c3c2)C(c2ccccc2)(c2ccccc2)c2ccccc2-4)c2ccc3c4ccccc4n(-c4ccccc4)c3c2)cc1 ; CC1(C)c2ccc(-c3ccccc3)cc2-c2ccc3ccc(N(c4ccc(-c5ccccc5)cc4)c4ccc(-c5ccccc5)cc4)cc3c21]

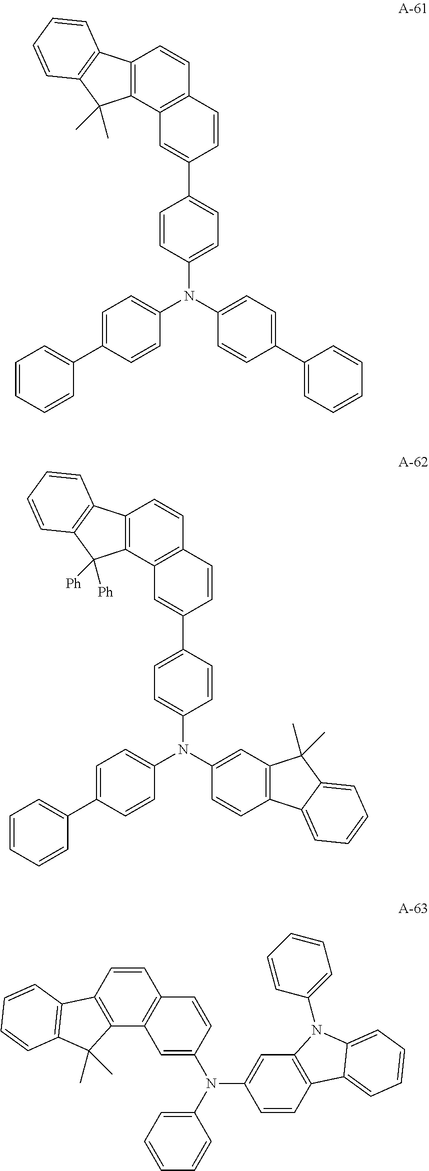 [SMILES: CC1(C)c2ccccc2-c2ccc3ccc(-c4ccc(N(c5ccc(-c6ccccc6)cc5)c5ccc(-c6ccccc6)cc5)cc4)cc3c21 ; CC1(C)c2ccccc2-c2ccc(N(c3ccc(-c4ccccc4)cc3)c3ccc(-c4ccc5ccc6c(c5c4)C(c4ccccc4)(c4ccccc4)c4ccccc4-6)cc3)cc21 ; CC1(C)c2ccccc2-c2ccc3ccc(N(c4ccccc4)c4ccc5c6ccccc6n(-c6ccccc6)c5c4)cc3c21]

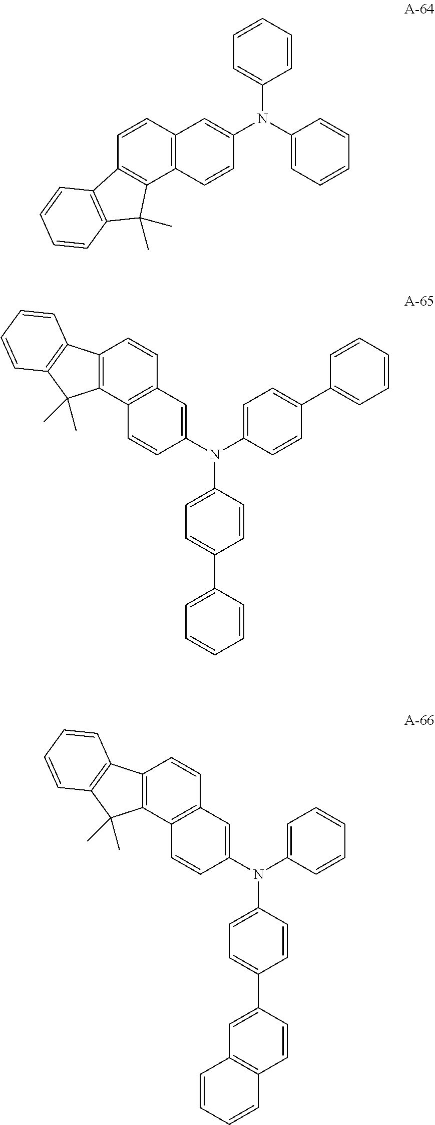 [SMILES: CC1(C)c2ccccc2-c2ccc3cc(N(c4ccccc4)c4ccccc4)ccc3c21 ; CC1(C)c2ccccc2-c2ccc3cc(N(c4ccc(-c5ccccc5)cc4)c4ccc(-c5ccccc5)cc4)ccc3c21 ; CC1(C)c2ccccc2-c2ccc3cc(N(c4ccccc4)c4ccc(-c5ccc6ccccc6c5)cc4)ccc3c21]

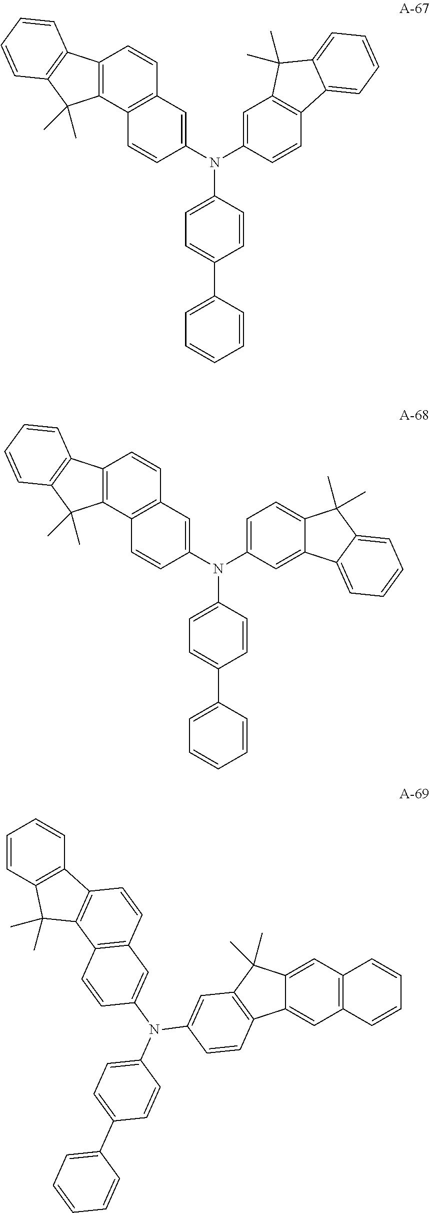 [SMILES: CC1(C)c2ccccc2-c2ccc(N(c3ccc(-c4ccccc4)cc3)c3ccc4c5c(ccc4c3)-c3ccccc3C5(C)C)cc21 ; CC1(C)c2ccccc2-c2cc(N(c3ccc(-c4ccccc4)cc3)c3ccc4c5c(ccc4c3)-c3ccccc3C5(C)C)ccc21 ; CC1(C)c2cc(N(c3ccc(-c4ccccc4)cc3)c3ccc4c5c(ccc4c3)-c3ccccc3C5(C)C)ccc2-c2cc3ccccc3cc21]

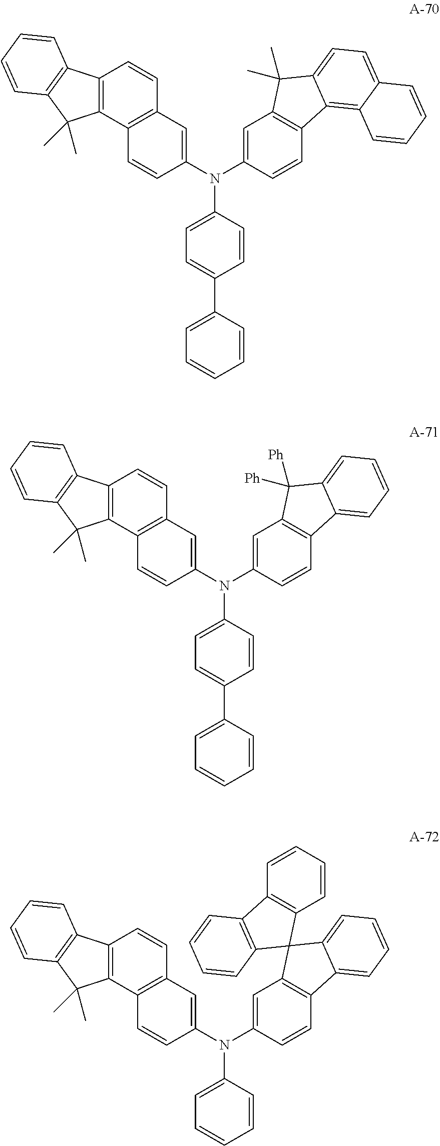 [SMILES: CC1(C)c2cc(N(c3ccc(-c4ccccc4)cc3)c3ccc4c5c(ccc4c3)-c3ccccc3C5(C)C)ccc2-c2c1ccc1ccccc21 ; CC1(C)c2ccccc2-c2ccc3cc(N(c4ccc(-c5ccccc5)cc4)c4ccc5c(c4)C(c4ccccc4)(c4ccccc4)c4ccccc4-5)ccc3c21 ; CC1(C)c2ccccc2-c2ccc3cc(N(c4ccccc4)c4ccc5c(c4)C4(c6ccccc6-c6ccccc64)c4ccccc4-5)ccc3c21]

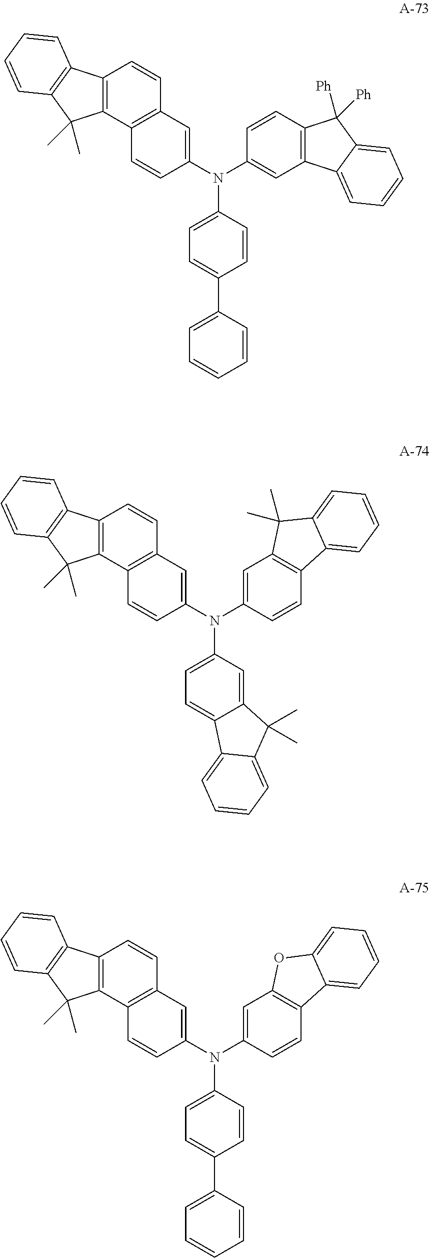 [SMILES: CC1(C)c2ccccc2-c2ccc3cc(N(c4ccc(-c5ccccc5)cc4)c4ccc5c(c4)-c4ccccc4C5(c4ccccc4)c4ccccc4)ccc3c21 ; CC1(C)c2ccccc2-c2ccc(N(c3ccc4c(c3)C(C)(C)c3ccccc3-4)c3ccc4c5c(ccc4c3)-c3ccccc3C5(C)C)cc21 ; CC1(C)c2ccccc2-c2ccc3cc(N(c4ccc(-c5ccccc5)cc4)c4ccc5c(c4)oc4ccccc45)ccc3c21]

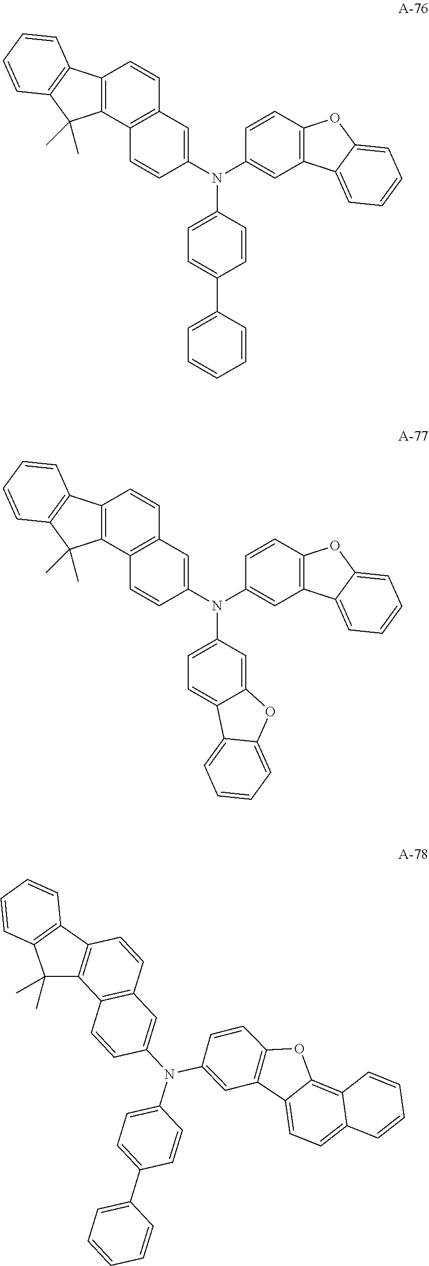 [SMILES: CC1(C)c2ccccc2-c2ccc3cc(N(c4ccc(-c5ccccc5)cc4)c4ccc5oc6ccccc6c5c4)ccc3c21 ; CC1(C)c2ccccc2-c2ccc3cc(N(c4ccc5c(c4)oc4ccccc45)c4ccc5oc6ccccc6c5c4)ccc3c21 ; CC1(C)c2ccccc2-c2ccc3cc(N(c4ccc(-c5ccccc5)cc4)c4ccc5oc6c7ccccc7ccc6c5c4)ccc3c21]

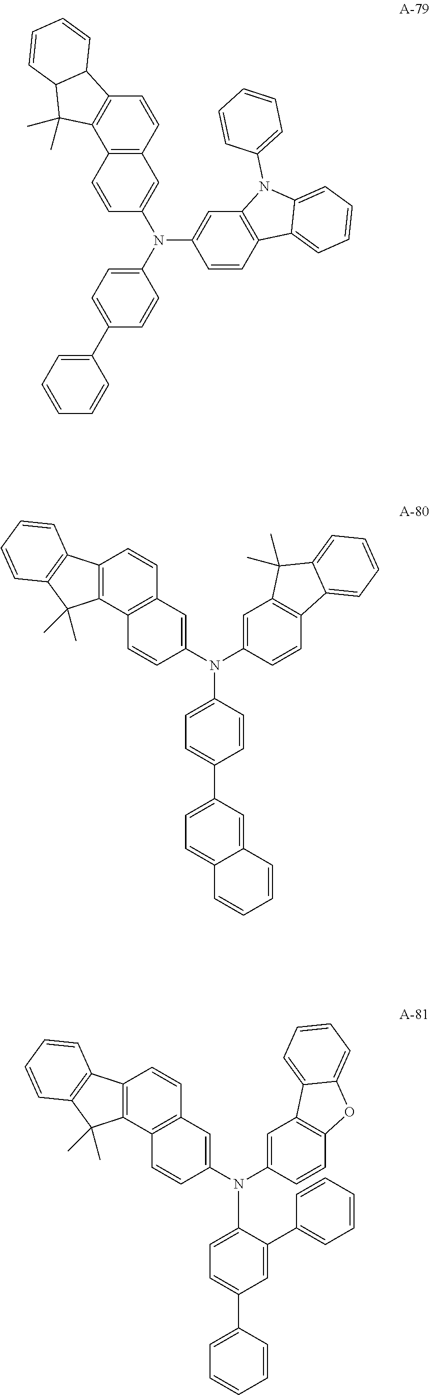 [SMILES: CC1(C)c2c(ccc3cc(N(c4ccc(-c5ccccc5)cc4)c4ccc5c6ccccc6n(-c6ccccc6)c5c4)ccc23)C2C=CC=CC21 ; CC1(C)c2ccccc2-c2ccc(N(c3ccc(-c4ccc5ccccc5c4)cc3)c3ccc4c5c(ccc4c3)-c3ccccc3C5(C)C)cc21 ; CC1(C)c2ccccc2-c2ccc3cc(N(c4ccc5oc6ccccc6c5c4)c4ccc(-c5ccccc5)cc4-c4ccccc4)ccc3c21]

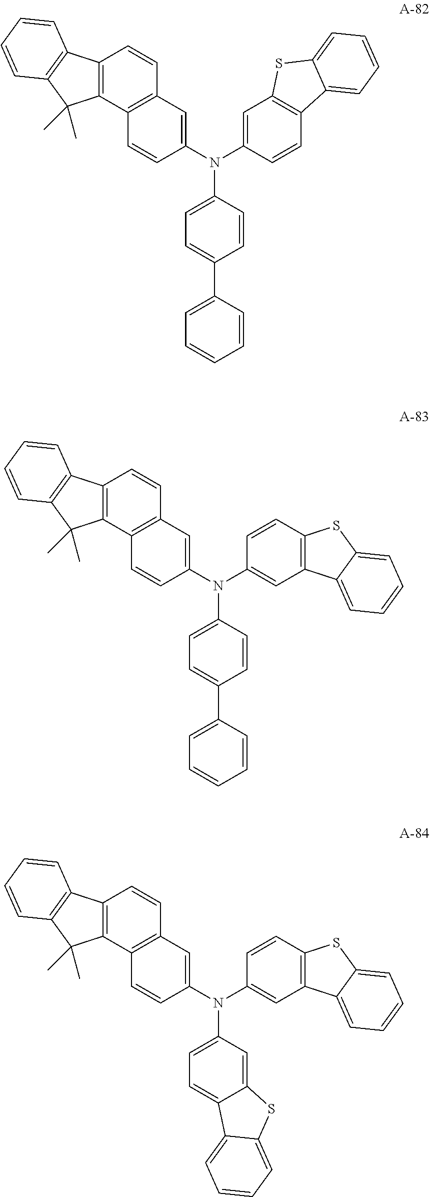 [SMILES: CC1(C)c2ccccc2-c2ccc3cc(N(c4ccc(-c5ccccc5)cc4)c4ccc5c(c4)sc4ccccc45)ccc3c21 ; CC1(C)c2ccccc2-c2ccc3cc(N(c4ccc(-c5ccccc5)cc4)c4ccc5sc6ccccc6c5c4)ccc3c21 ; CC1(C)c2ccccc2-c2ccc3cc(N(c4ccc5c(c4)sc4ccccc45)c4ccc5sc6ccccc6c5c4)ccc3c21]

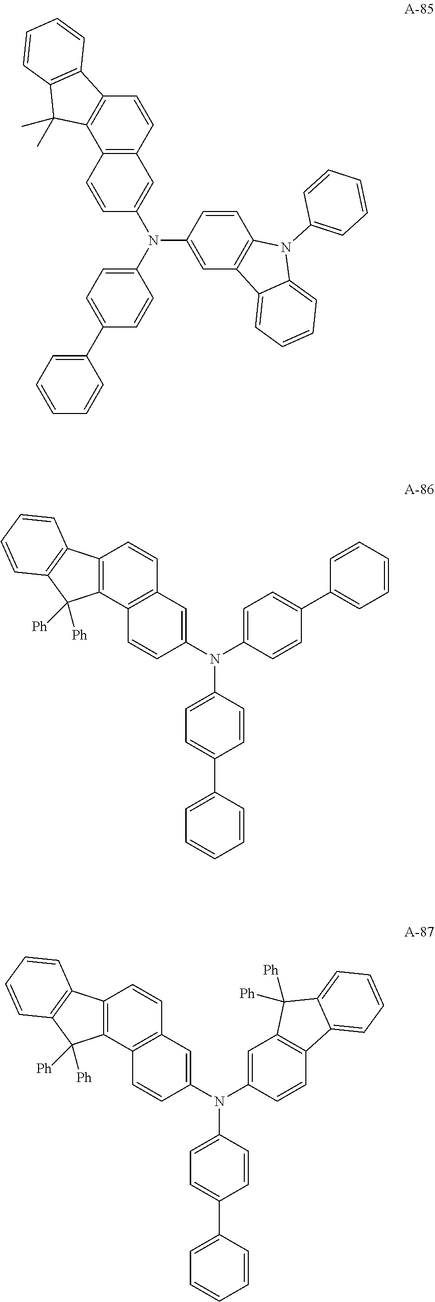 [SMILES: CC1(C)c2ccccc2-c2ccc3cc(N(c4ccc(-c5ccccc5)cc4)c4ccc5c(c4)c4ccccc4n5-c4ccccc4)ccc3c21 ; c1ccc(-c2ccc(N(c3ccc(-c4ccccc4)cc3)c3ccc4c5c(ccc4c3)-c3ccccc3C5(c3ccccc3)c3ccccc3)cc2)cc1 ; c1ccc(-c2ccc(N(c3ccc4c(c3)C(c3ccccc3)(c3ccccc3)c3ccccc3-4)c3ccc4c5c(ccc4c3)-c3ccccc3C5(c3ccccc3)c3ccccc3)cc2)cc1]

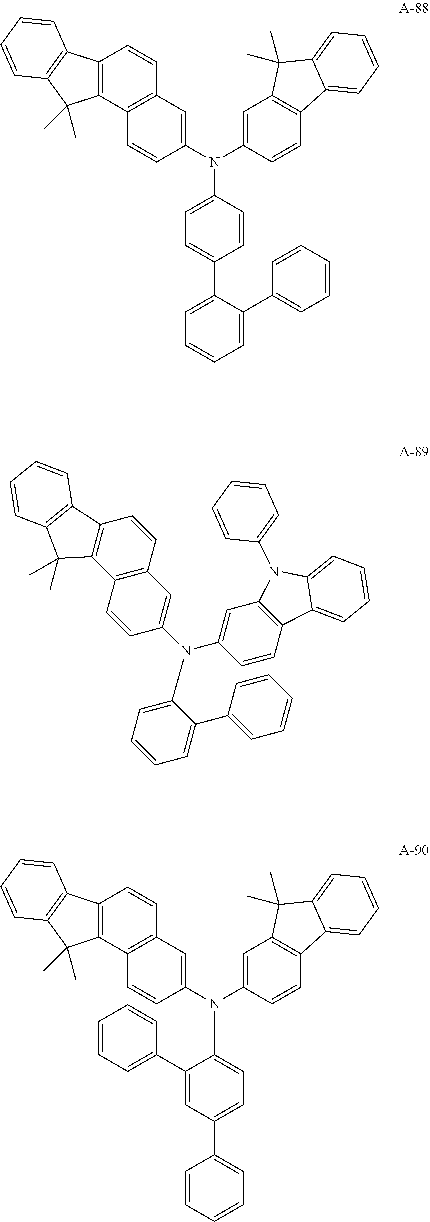 [SMILES: CC1(C)c2ccccc2-c2ccc(N(c3ccc(-c4ccccc4-c4ccccc4)cc3)c3ccc4c5c(ccc4c3)-c3ccccc3C5(C)C)cc21 ; CC1(C)c2ccccc2-c2ccc3cc(N(c4ccc5c6ccccc6n(-c6ccccc6)c5c4)c4ccccc4-c4ccccc4)ccc3c21 ; CC1(C)c2ccccc2-c2ccc(N(c3ccc4c5c(ccc4c3)-c3ccccc3C5(C)C)c3ccc(-c4ccccc4)cc3-c3ccccc3)cc21]

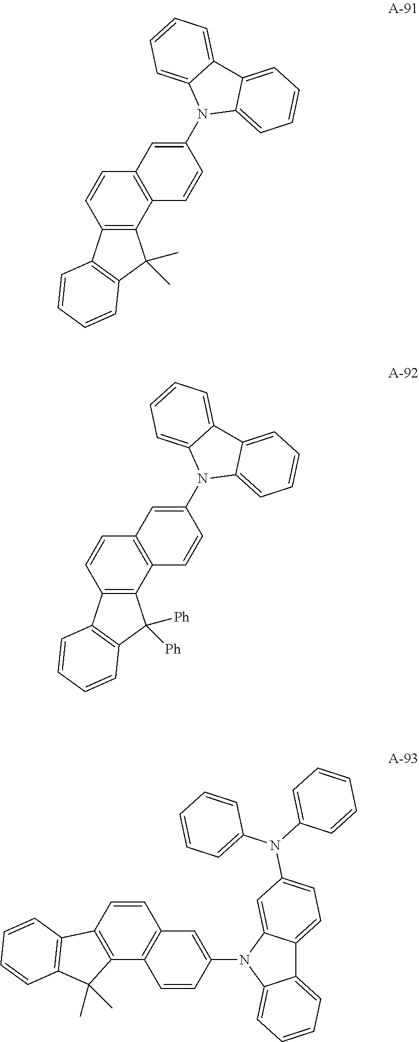 [SMILES: CC1(C)c2ccccc2-c2ccc3cc(-n4c5ccccc5c5ccccc54)ccc3c21 ; c1ccc(C2(c3ccccc3)c3ccccc3-c3ccc4cc(-n5c6ccccc6c6ccccc65)ccc4c32)cc1 ; CC1(C)c2ccccc2-c2ccc3cc(-n4c5ccccc5c5ccc(N(c6ccccc6)c6ccccc6)cc54)ccc3c21]

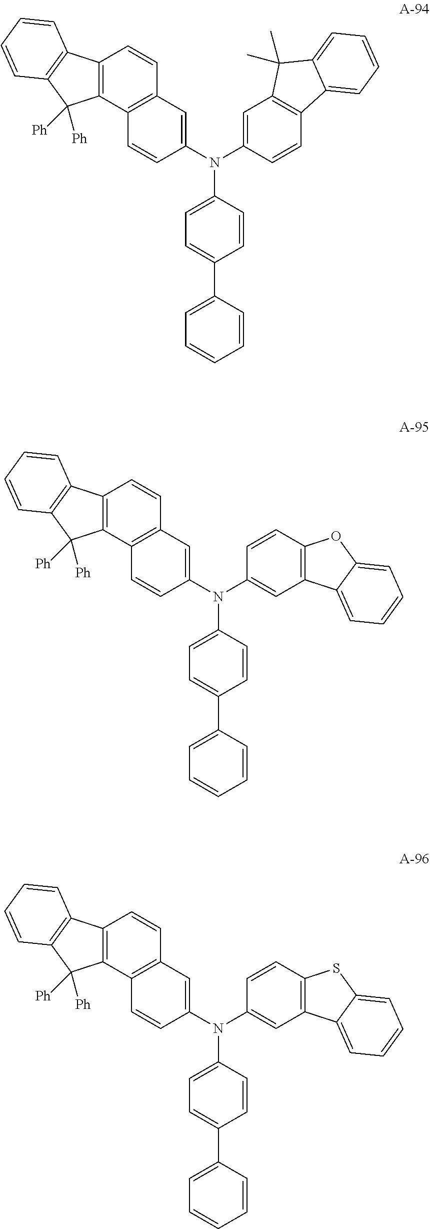 [SMILES: CC1(C)c2ccccc2-c2ccc(N(c3ccc(-c4ccccc4)cc3)c3ccc4c5c(ccc4c3)-c3ccccc3C5(c3ccccc3)c3ccccc3)cc21 ; c1ccc(-c2ccc(N(c3ccc4c5c(ccc4c3)-c3ccccc3C5(c3ccccc3)c3ccccc3)c3ccc4oc5ccccc5c4c3)cc2)cc1 ; c1ccc(-c2ccc(N(c3ccc4c5c(ccc4c3)-c3ccccc3C5(c3ccccc3)c3ccccc3)c3ccc4sc5ccccc5c4c3)cc2)cc1]

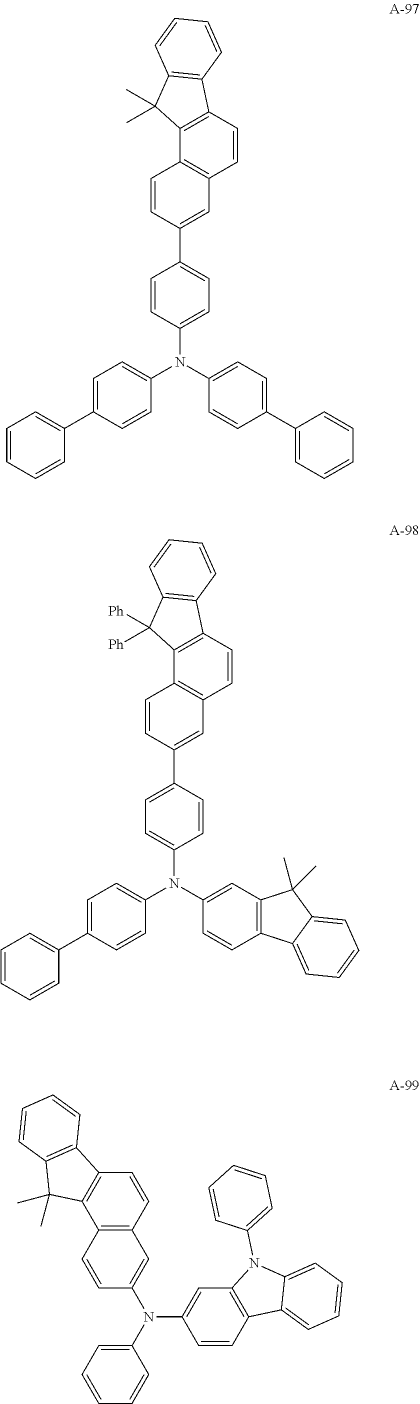 [SMILES: CC1(C)c2ccccc2-c2ccc3cc(-c4ccc(N(c5ccc(-c6ccccc6)cc5)c5ccc(-c6ccccc6)cc5)cc4)ccc3c21 ; CC1(C)c2ccccc2-c2ccc(N(c3ccc(-c4ccccc4)cc3)c3ccc(-c4ccc5c6c(ccc5c4)-c4ccccc4C6(c4ccccc4)c4ccccc4)cc3)cc21 ; CC1(C)c2ccccc2-c2ccc3cc(N(c4ccccc4)c4ccc5c6ccccc6n(-c6ccccc6)c5c4)ccc3c21]

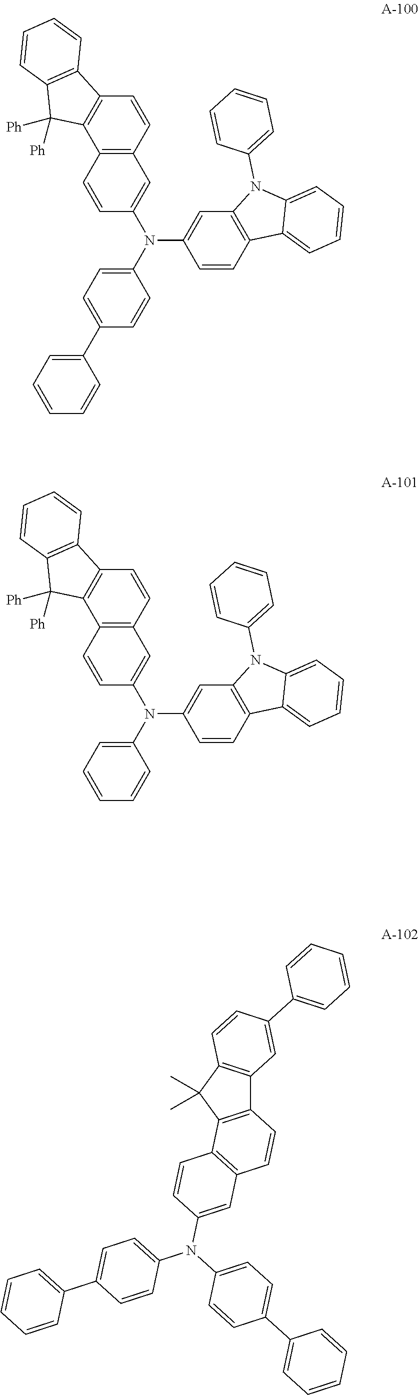 [SMILES: c1ccc(-c2ccc(N(c3ccc4c5c(ccc4c3)-c3ccccc3C5(c3ccccc3)c3ccccc3)c3ccc4c5ccccc5n(-c5ccccc5)c4c3)cc2)cc1 ; c1ccc(N(c2ccc3c4c(ccc3c2)-c2ccccc2C4(c2ccccc2)c2ccccc2)c2ccc3c4ccccc4n(-c4ccccc4)c3c2)cc1 ; CC1(C)c2ccc(-c3ccccc3)cc2-c2ccc3cc(N(c4ccc(-c5ccccc5)cc4)c4ccc(-c5ccccc5)cc4)ccc3c21]

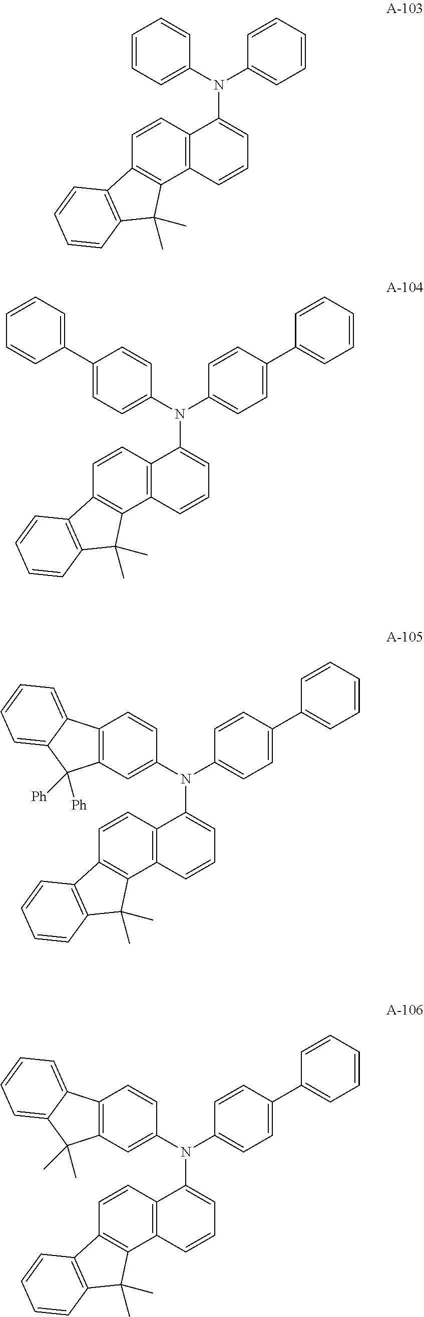 [SMILES: CC1(C)c2ccccc2-c2ccc3c(N(c4ccccc4)c4ccccc4)cccc3c21 ; CC1(C)c2ccccc2-c2ccc3c(N(c4ccc(-c5ccccc5)cc4)c4ccc(-c5ccccc5)cc4)cccc3c21 ; CC1(C)c2ccccc2-c2ccc3c(N(c4ccc(-c5ccccc5)cc4)c4ccc5c(c4)C(c4ccccc4)(c4ccccc4)c4ccccc4-5)cccc3c21 ; CC1(C)c2ccccc2-c2ccc(N(c3ccc(-c4ccccc4)cc3)c3cccc4c5c(ccc34)-c3ccccc3C5(C)C)cc21]

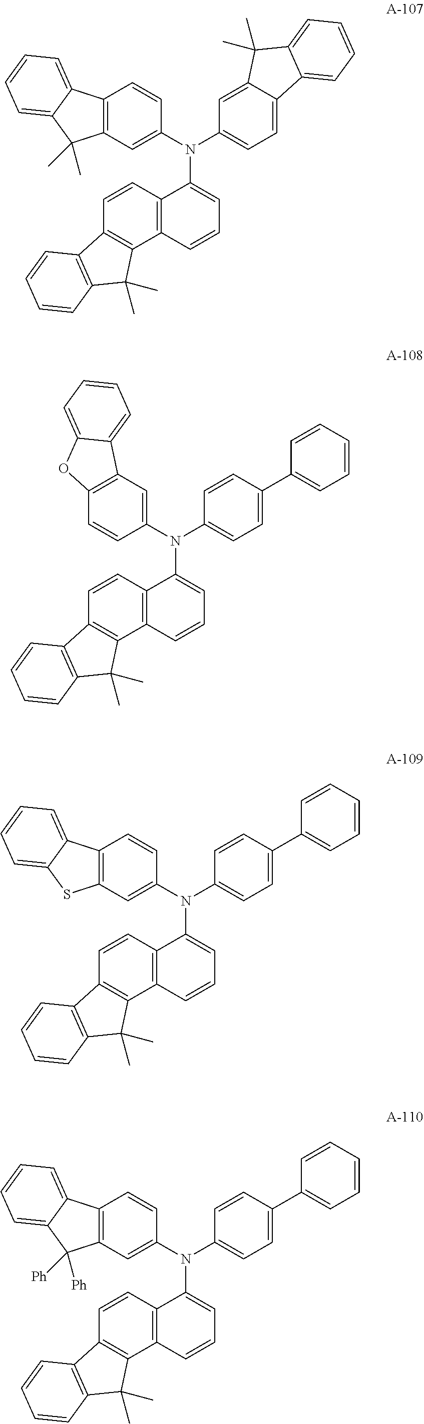 [SMILES: CC1(C)c2ccccc2-c2ccc(N(c3ccc4c(c3)C(C)(C)c3ccccc3-4)c3cccc4c5c(ccc34)-c3ccccc3C5(C)C)cc21 ; CC1(C)c2ccccc2-c2ccc3c(N(c4ccc(-c5ccccc5)cc4)c4ccc5oc6ccccc6c5c4)cccc3c21 ; CC1(C)c2ccccc2-c2ccc3c(N(c4ccc(-c5ccccc5)cc4)c4ccc5c(c4)sc4ccccc45)cccc3c21 ; CC1(C)c2ccccc2-c2ccc3c(N(c4ccc(-c5ccccc5)cc4)c4ccc5c(c4)C(c4ccccc4)(c4ccccc4)c4ccccc4-5)cccc3c21]

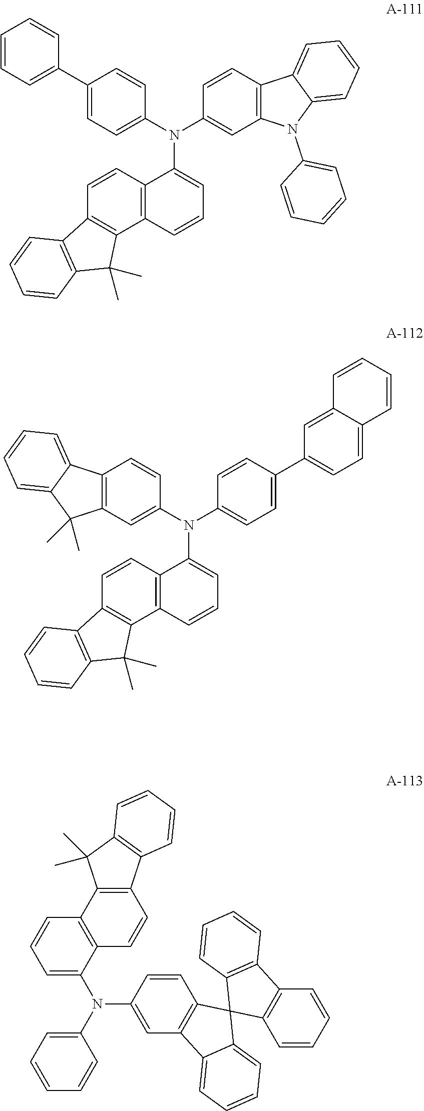 [SMILES: CC1(C)c2ccccc2-c2ccc3c(N(c4ccc(-c5ccccc5)cc4)c4ccc5c6ccccc6n(-c6ccccc6)c5c4)cccc3c21 ; CC1(C)c2ccccc2-c2ccc(N(c3ccc(-c4ccc5ccccc5c4)cc3)c3cccc4c5c(ccc34)-c3ccccc3C5(C)C)cc21 ; CC1(C)c2ccccc2-c2ccc3c(N(c4ccccc4)c4ccc5c(c4)-c4ccccc4C54c5ccccc5-c5ccccc54)cccc3c21]

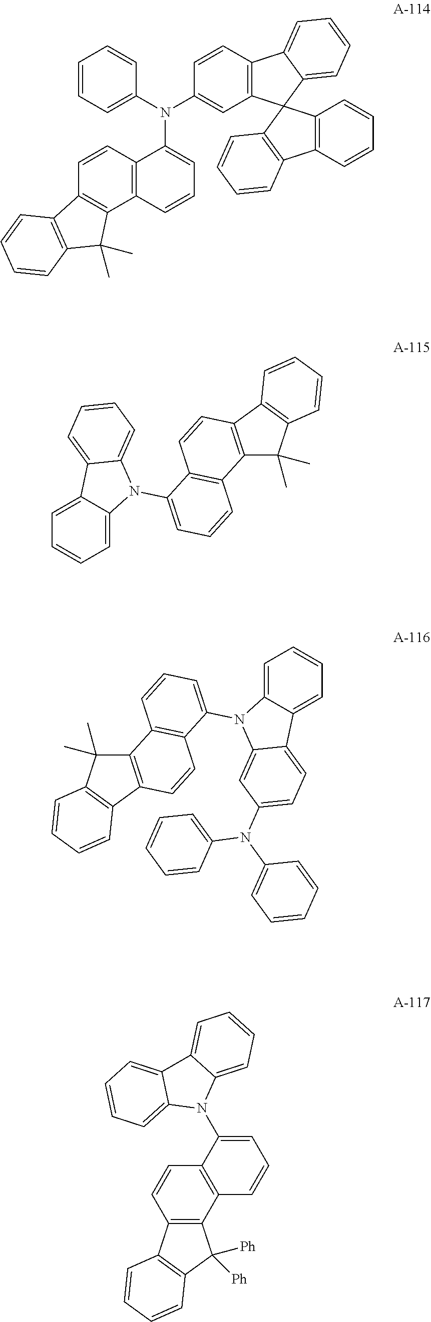 [SMILES: CC1(C)c2ccccc2-c2ccc3c(N(c4ccccc4)c4ccc5c(c4)C4(c6ccccc6-c6ccccc64)c4ccccc4-5)cccc3c21 ; CC1(C)c2ccccc2-c2ccc3c(-n4c5ccccc5c5ccccc54)cccc3c21 ; CC1(C)c2ccccc2-c2ccc3c(-n4c5ccccc5c5ccc(N(c6ccccc6)c6ccccc6)cc54)cccc3c21 ; c1ccc(C2(c3ccccc3)c3ccccc3-c3ccc4c(-n5c6ccccc6c6ccccc65)cccc4c32)cc1]

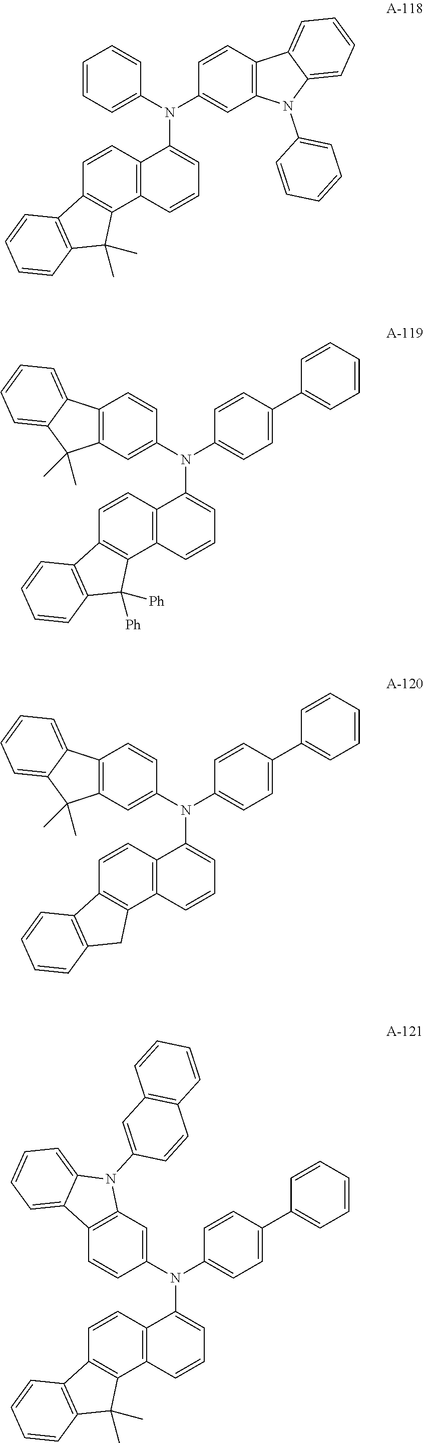 [SMILES: CC1(C)c2ccccc2-c2ccc3c(N(c4ccccc4)c4ccc5c6ccccc6n(-c6ccccc6)c5c4)cccc3c21 ; CC1(C)c2ccccc2-c2ccc(N(c3ccc(-c4ccccc4)cc3)c3cccc4c5c(ccc34)-c3ccccc3C5(c3ccccc3)c3ccccc3)cc21 ; CC1(C)c2ccccc2-c2ccc(N(c3ccc(-c4ccccc4)cc3)c3cccc4c5c(ccc34)-c3ccccc3C5)cc21 ; CC1(C)c2ccccc2-c2ccc3c(N(c4ccc(-c5ccccc5)cc4)c4ccc5c6ccccc6n(-c6ccc7ccccc7c6)c5c4)cccc3c21]

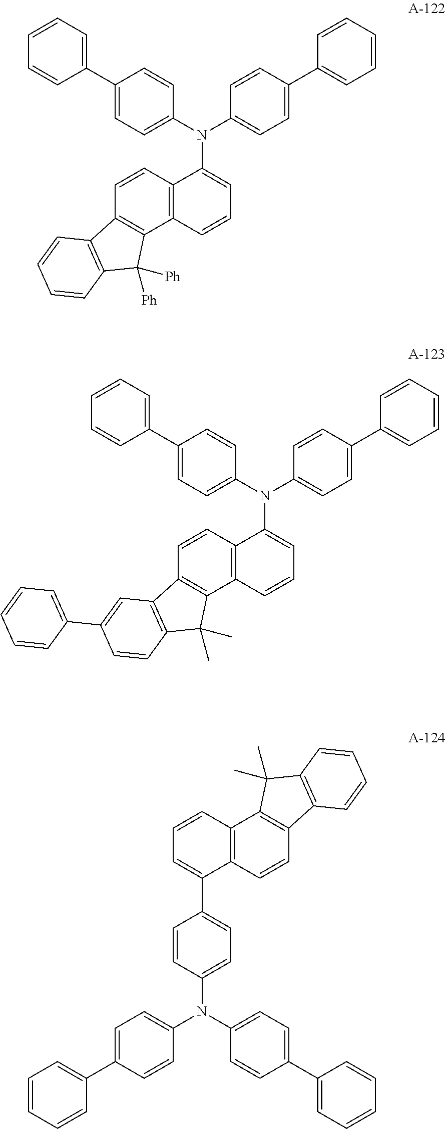 [SMILES: c1ccc(-c2ccc(N(c3ccc(-c4ccccc4)cc3)c3cccc4c5c(ccc34)-c3ccccc3C5(c3ccccc3)c3ccccc3)cc2)cc1 ; CC1(C)c2ccc(-c3ccccc3)cc2-c2ccc3c(N(c4ccc(-c5ccccc5)cc4)c4ccc(-c5ccccc5)cc4)cccc3c21 ; CC1(C)c2ccccc2-c2ccc3c(-c4ccc(N(c5ccc(-c6ccccc6)cc5)c5ccc(-c6ccccc6)cc5)cc4)cccc3c21]

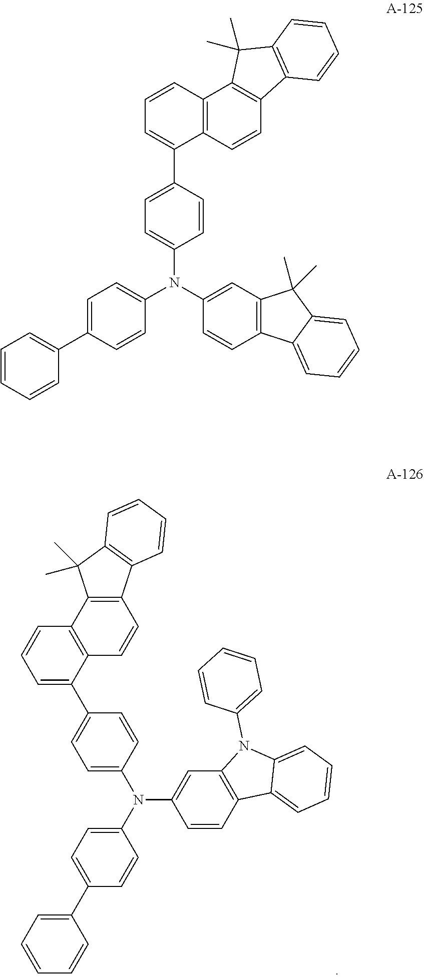 [SMILES: CC1(C)c2ccccc2-c2ccc(N(c3ccc(-c4ccccc4)cc3)c3ccc(-c4cccc5c6c(ccc45)-c4ccccc4C6(C)C)cc3)cc21 ; CC1(C)c2ccccc2-c2ccc3c(-c4ccc(N(c5ccc(-c6ccccc6)cc5)c5ccc6c7ccccc7n(-c7ccccc7)c6c5)cc4)cccc3c21]

The compound of formula 1 according to the present disclosure may be produced by a synthetic method known to a person skilled in the art, and for example referring to the following reaction schemes 1 to 3, but is not limited thereto:

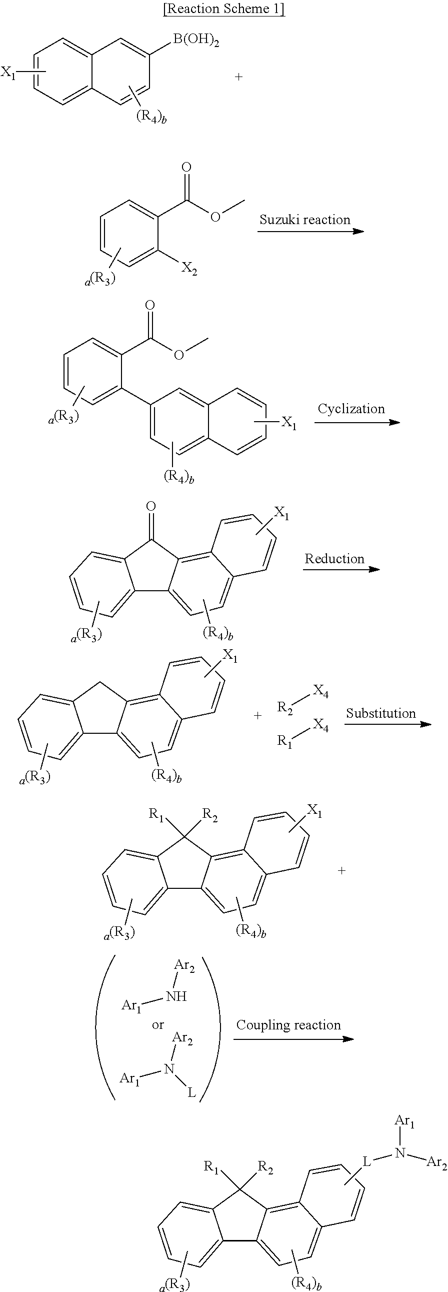

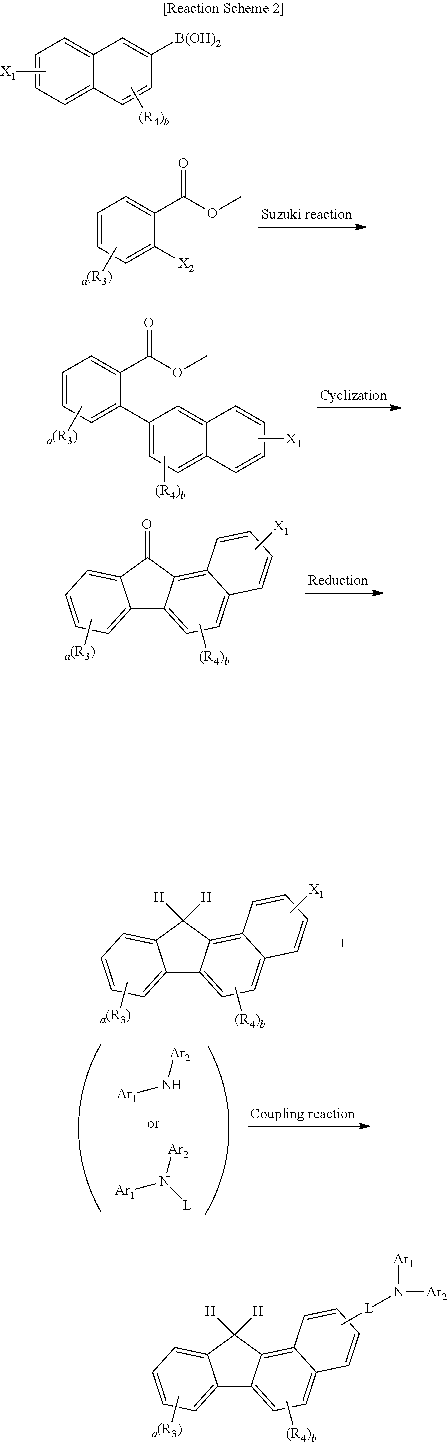

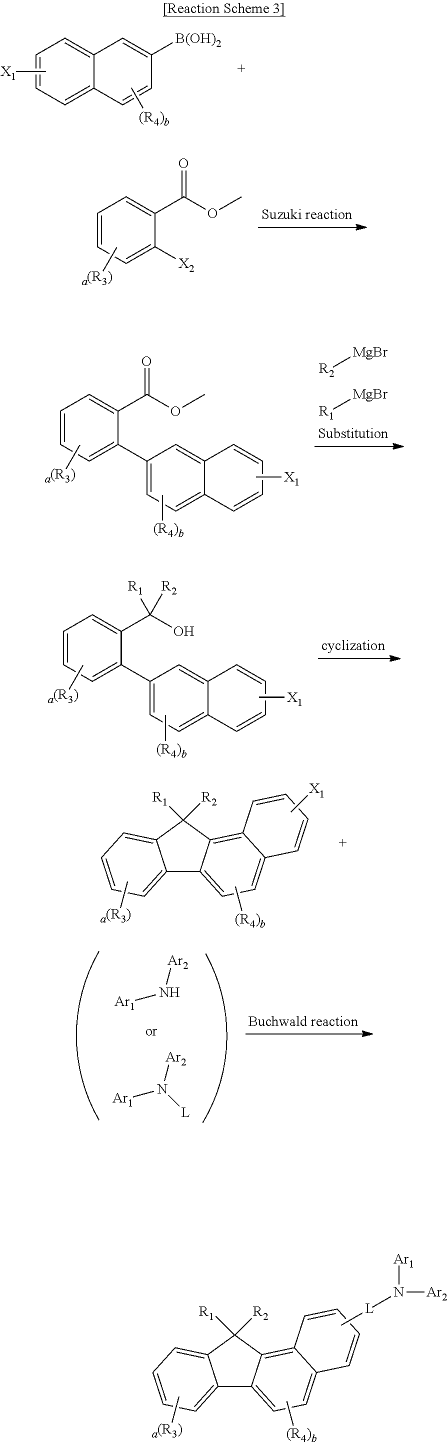

In reaction schemes 1 to 3, R₁ to R₄, Ar₁, Ar₂, a, and b are as defined in formula 1, and X₁, X₂, and X₄ each independently represent Cl, Br, or I.

The present disclosure may provide an organic electroluminescent material comprising the organic electroluminescent compound of formula 1, and an organic electroluminescent device comprising the organic electroluminescent material.

The organic electroluminescent material may consist of the organic electroluminescent compound of the present disclosure as a sole compound, or may further comprise conventional materials generally used in organic electroluminescent materials. Preferably, the organic electroluminescent compound of formula 1 may be included as hole transport layer (HTL) materials in the organic electroluminescent device.

The organic electroluminescent material of the present disclosure may contain at least one host compound in addition to the organic electroluminescent compound of formula 1. A host compound according to one embodiment can use any of the known phosphorescent hosts. In terms of luminous efficiency, the host material may be particularly preferably selected from the group consisting of the compounds represented by the following formula 2 or 3, but is not limited thereto.

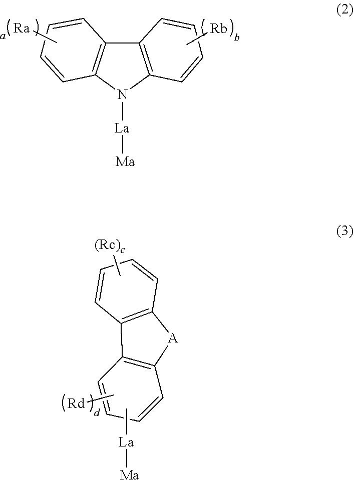

In formulae 2 and 3,

Ma represents a substituted or unsubstituted (C6-C30)aryl, a substituted or unsubstituted mono- or di-(C6-C30)arylamino, or a substituted or unsubstituted (3- to 30-membered)heteroaryl;

La represents a single bond, a substituted or unsubstituted (C6-C30)arylene, or a substituted or unsubstituted (3- to 30-membered)heteroarylene;

A represents S, O, NR₇ or CR₈ R₉;

Ra to Rd each independently represent hydrogen, deuterium, halogen, cyano, a substituted or unsubstituted (C1-C30)alkyl, a substituted or unsubstituted (C2-C30)alkenyl, a substituted or unsubstituted (C2-C30)alkynyl, a substituted or unsubstituted (C3-C30)cycloalkyl, a substituted or unsubstituted (C6-C30)aryl, a substituted or unsubstituted (3- to 30-membered)heteroaryl, a substituted or unsubstituted tri(C1-C30)alkylsilyl, a substituted or unsubstituted tri(C6-C30)arylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted (C1-C30)alkyl(C6-C30)arylamino, or a substituted or unsubstituted mono- or di-(C6-C30)arylamino; or may be linked to an adjacent substituent to form a substituted or unsubstituted, mono- or polycyclic, (3- to 30-membered) alicyclic, aromatic ring, or the combination thereof, whose carbon atom(s) may be replaced with at least one heteroatom selected from nitrogen, oxygen, and sulfur;

R₇ to R₉ each independently represent hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C6-C30)arylamino, or a substituted or unsubstituted (C1-C30)alkyl(C6-C30)arylamino; R₈ and R₉ may be linked each other to form a substituted or unsubstituted, mono- or polycyclic, (3- to 30-membered) alicyclic, aromatic ring, or a combination thereof, whose carbon atom(s) may be replaced with at least one heteroatom selected from nitrogen, oxygen, and sulfur;

a to c each independently represent an integer of 1 to 4, d represents an integer 1 to 3; and

the heteroaryl(ene) contains at least one heteroatom selected from B, N, O, S, Si, and P.

The compounds represented by one of formulae 2 and 3 may be illustrated by the following compounds, but are not limited thereto:

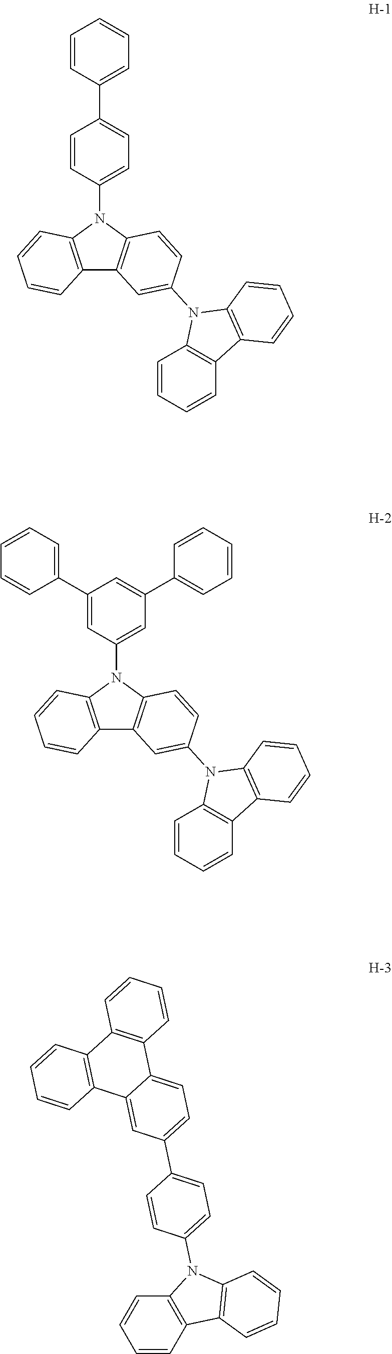 [SMILES: c1ccc(-c2ccc(-n3c4ccccc4c4cc(-n5c6ccccc6c6ccccc65)ccc43)cc2)cc1 ; c1ccc(-c2cc(-c3ccccc3)cc(-n3c4ccccc4c4cc(-n5c6ccccc6c6ccccc65)ccc43)c2)cc1 ; c1ccc2c(c1)c1ccccc1c1cc(-c3ccc(-n4c5ccccc5c5ccccc54)cc3)ccc21]

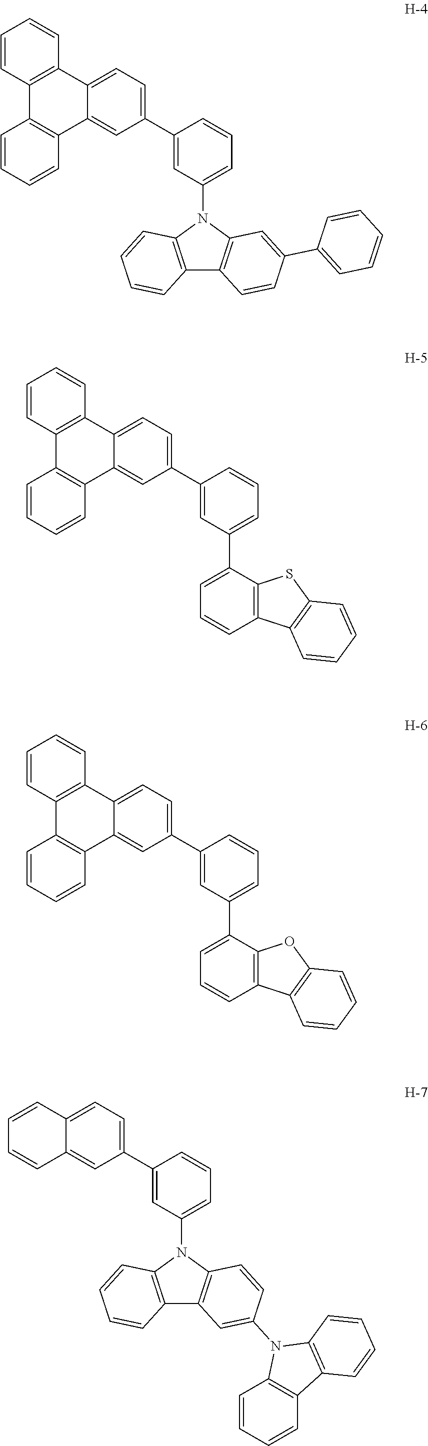 [SMILES: c1ccc(-c2ccc3c4ccccc4n(-c4cccc(-c5ccc6c7ccccc7c7ccccc7c6c5)c4)c3c2)cc1 ; c1cc(-c2ccc3c4ccccc4c4ccccc4c3c2)cc(-c2cccc3c2sc2ccccc23)c1 ; c1cc(-c2ccc3c4ccccc4c4ccccc4c3c2)cc(-c2cccc3c2oc2ccccc23)c1 ; c1cc(-c2ccc3ccccc3c2)cc(-n2c3ccccc3c3cc(-n4c5ccccc5c5ccccc54)ccc32)c1]

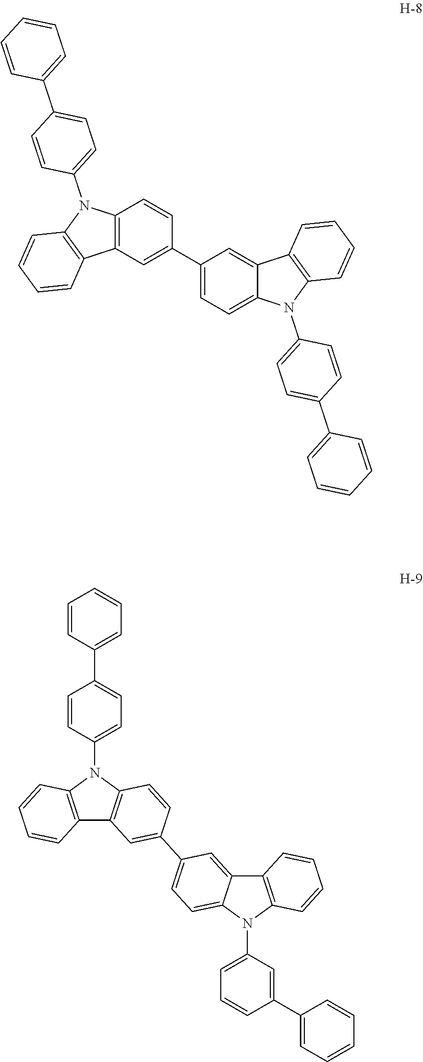 [SMILES: c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2ccc(-n3c4ccccc4c4cc(-c5ccc6c(c5)c5ccccc5n6-c5cccc(-c6ccccc6)c5)ccc43)cc2)cc1]

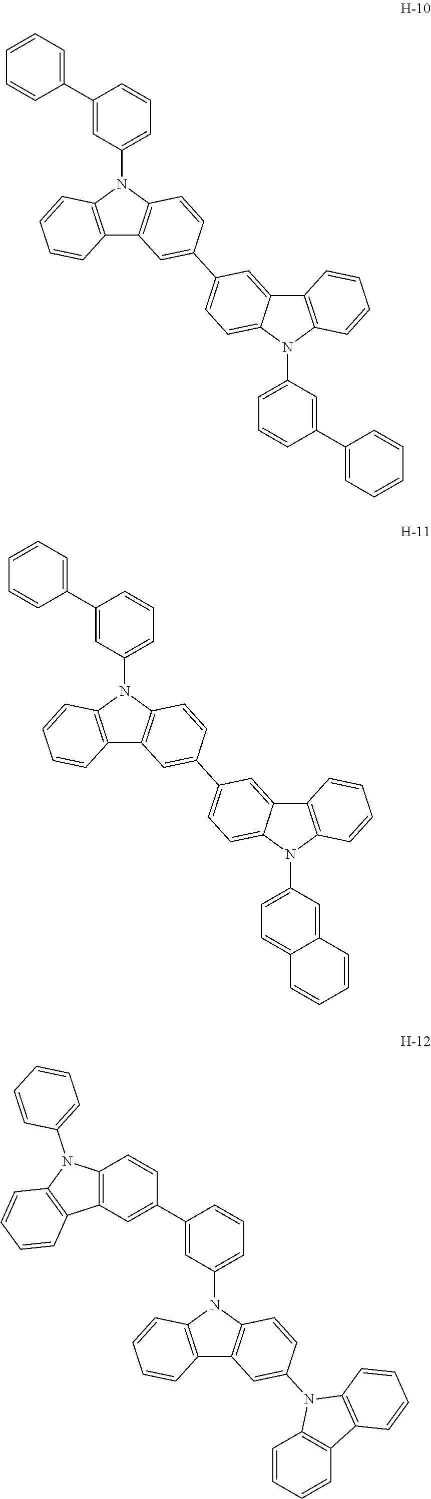 [SMILES: c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2cccc(-n3c4ccccc4c4cc(-c5ccc6c(c5)c5ccccc5n6-c5ccc6ccccc6c5)ccc43)c2)cc1 ; c1ccc(-n2c3ccccc3c3cc(-c4cccc(-n5c6ccccc6c6cc(-n7c8ccccc8c8ccccc87)ccc65)c4)ccc32)cc1]

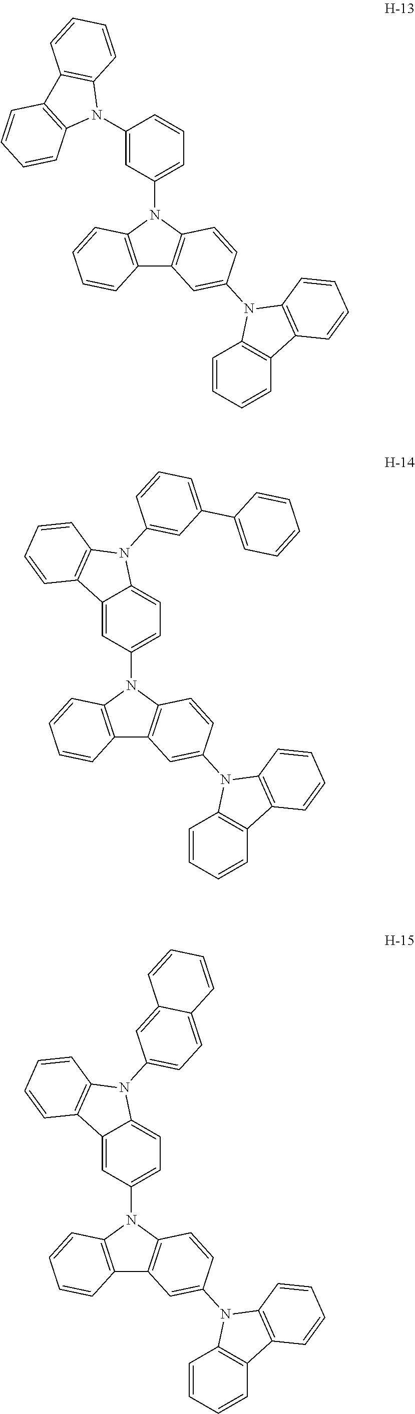 [SMILES: c1cc(-n2c3ccccc3c3ccccc32)cc(-n2c3ccccc3c3cc(-n4c5ccccc5c5ccccc54)ccc32)c1 ; c1ccc(-c2cccc(-n3c4ccccc4c4cc(-n5c6ccccc6c6cc(-n7c8ccccc8c8ccccc87)ccc65)ccc43)c2)cc1 ; c1ccc2cc(-n3c4ccccc4c4cc(-n5c6ccccc6c6cc(-n7c8ccccc8c8ccccc87)ccc65)ccc43)ccc2c1]

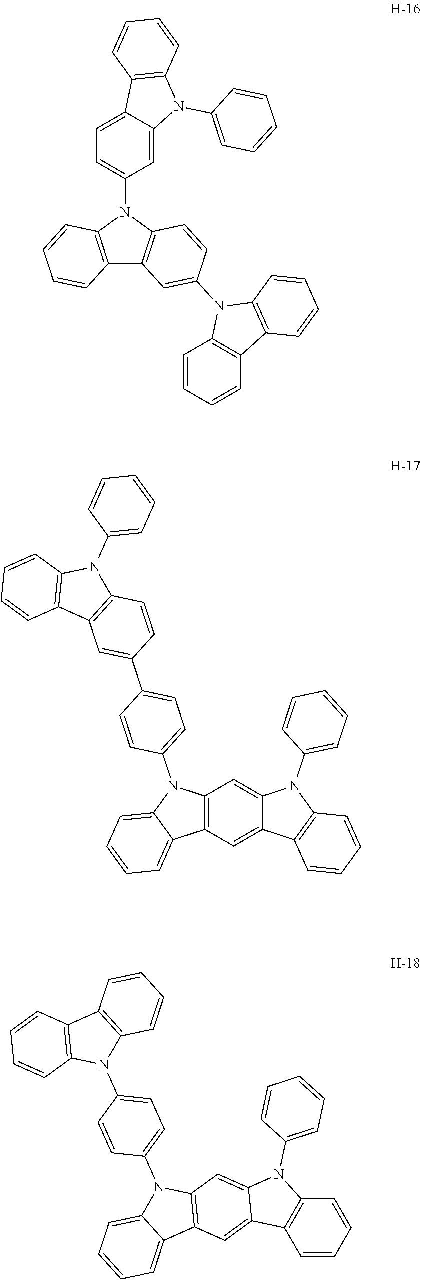 [SMILES: c1ccc(-n2c3ccccc3c3ccc(-n4c5ccccc5c5cc(-n6c7ccccc7c7ccccc76)ccc54)cc32)cc1 ; c1ccc(-n2c3ccccc3c3cc(-c4ccc(-n5c6ccccc6c6cc7c8ccccc8n(-c8ccccc8)c7cc65)cc4)ccc32)cc1 ; c1ccc(-n2c3ccccc3c3cc4c5ccccc5n(-c5ccc(-n6c7ccccc7c7ccccc76)cc5)c4cc32)cc1]

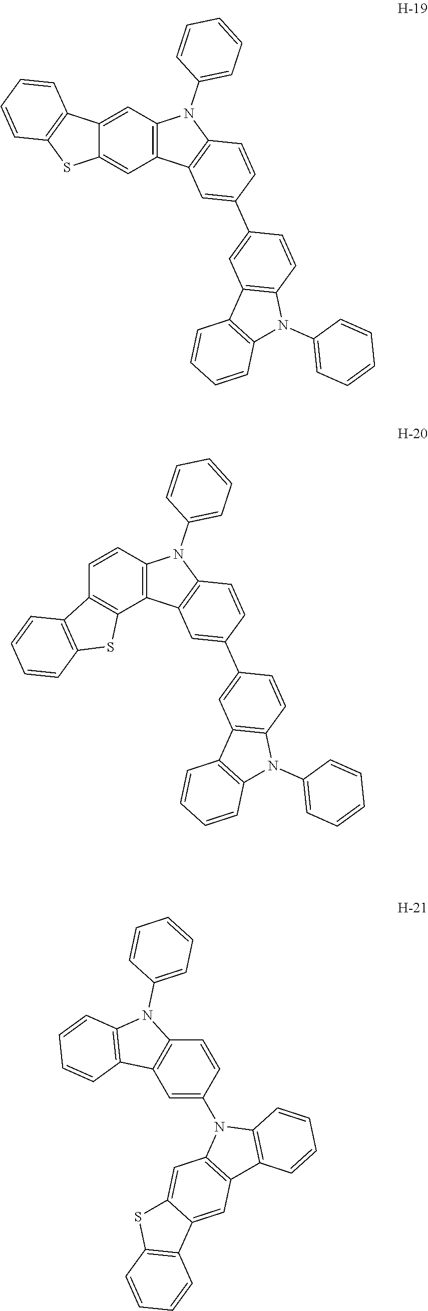 [SMILES: c1ccc(-n2c3ccccc3c3cc(-c4ccc5c(c4)c4cc6sc7ccccc7c6cc4n5-c4ccccc4)ccc32)cc1 ; c1ccc(-n2c3ccccc3c3cc(-c4ccc5c(c4)c4c6sc7ccccc7c6ccc4n5-c4ccccc4)ccc32)cc1 ; c1ccc(-n2c3ccccc3c3cc(-n4c5ccccc5c5cc6c(cc54)sc4ccccc46)ccc32)cc1]

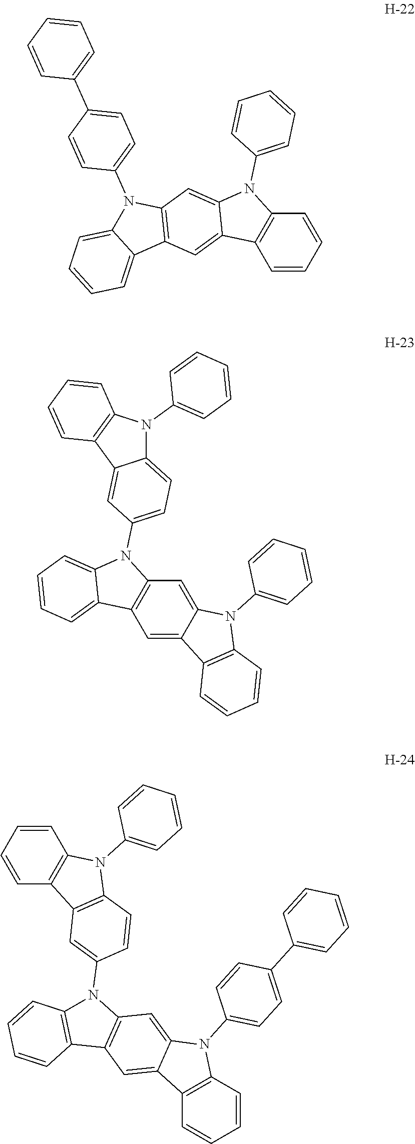 [SMILES: c1ccc(-c2ccc(-n3c4ccccc4c4cc5c6ccccc6n(-c6ccccc6)c5cc43)cc2)cc1 ; c1ccc(-n2c3ccccc3c3cc(-n4c5ccccc5c5cc6c7ccccc7n(-c7ccccc7)c6cc54)ccc32)cc1 ; c1ccc(-c2ccc(-n3c4ccccc4c4cc5c6ccccc6n(-c6ccc7c(c6)c6ccccc6n7-c6ccccc6)c5cc43)cc2)cc1]

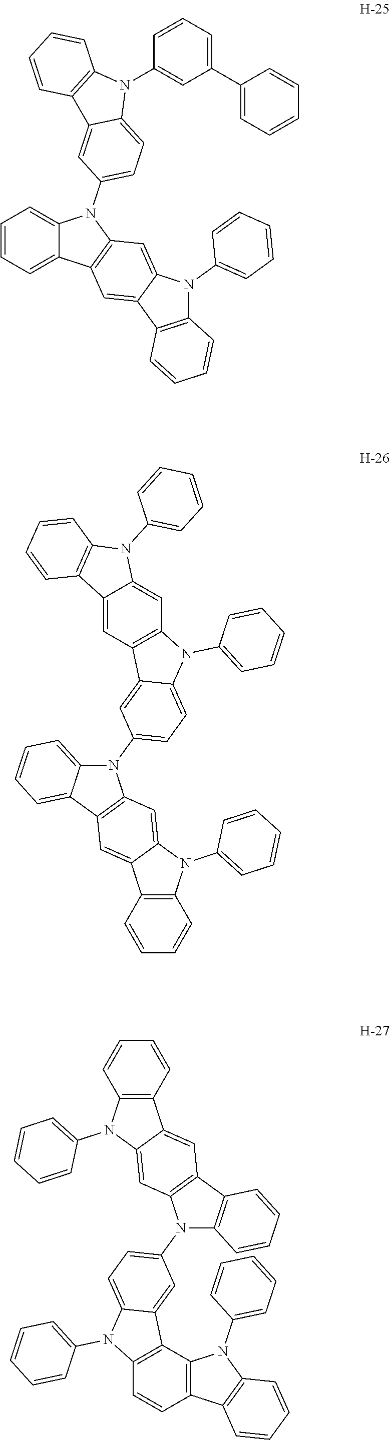 [SMILES: c1ccc(-c2cccc(-n3c4ccccc4c4cc(-n5c6ccccc6c6cc7c8ccccc8n(-c8ccccc8)c7cc65)ccc43)c2)cc1 ; c1ccc(-n2c3ccccc3c3cc4c5ccccc5n(-c5ccc6c(c5)c5cc7c8ccccc8n(-c8ccccc8)c7cc5n6-c5ccccc5)c4cc32)cc1 ; c1ccc(-n2c3ccccc3c3cc4c5ccccc5n(-c5ccc6c(c5)c5c(ccc7c8ccccc8n(-c8ccccc8)c75)n6-c5ccccc5)c4cc32)cc1]

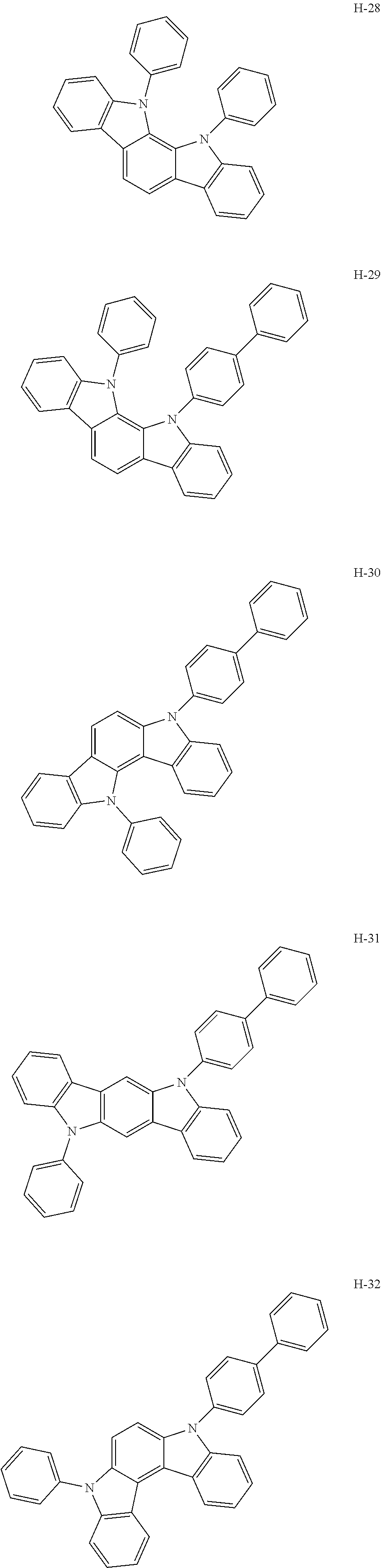 [SMILES: c1ccc(-n2c3ccccc3c3ccc4c5ccccc5n(-c5ccccc5)c4c32)cc1 ; c1ccc(-c2ccc(-n3c4ccccc4c4ccc5c6ccccc6n(-c6ccccc6)c5c43)cc2)cc1 ; c1ccc(-c2ccc(-n3c4ccccc4c4c3ccc3c5ccccc5n(-c5ccccc5)c34)cc2)cc1 ; c1ccc(-c2ccc(-n3c4ccccc4c4cc5c(cc43)c3ccccc3n5-c3ccccc3)cc2)cc1 ; c1ccc(-c2ccc(-n3c4ccccc4c4c5c6ccccc6n(-c6ccccc6)c5ccc43)cc2)cc1]

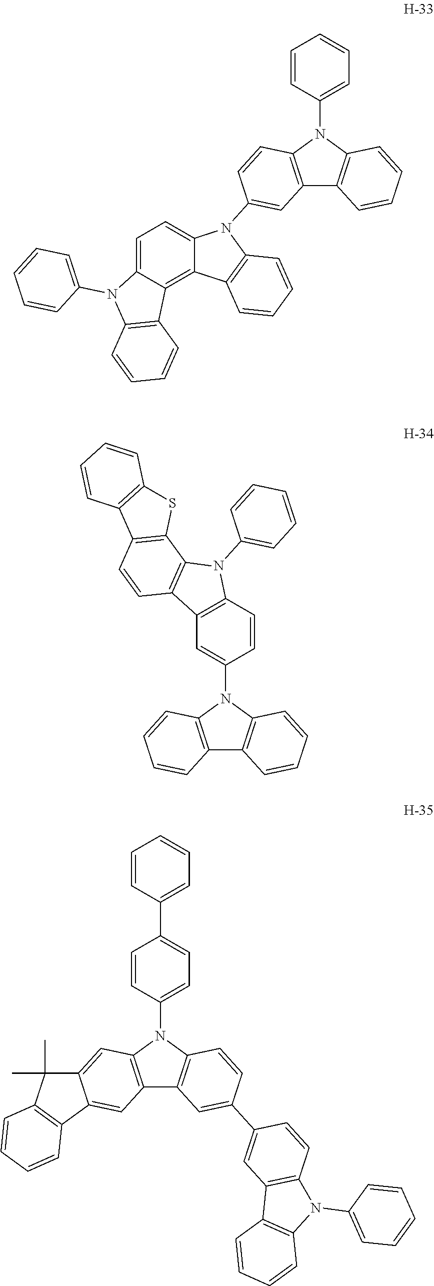 [SMILES: c1ccc(-n2c3ccccc3c3cc(-n4c5ccccc5c5c6c7ccccc7n(-c7ccccc7)c6ccc54)ccc32)cc1 ; c1ccc(-n2c3ccc(-n4c5ccccc5c5ccccc54)cc3c3ccc4c5ccccc5sc4c32)cc1 ; CC1(C)c2ccccc2-c2cc3c4cc(-c5ccc6c(c5)c5ccccc5n6-c5ccccc5)ccc4n(-c4ccc(-c5ccccc5)cc4)c3cc21]

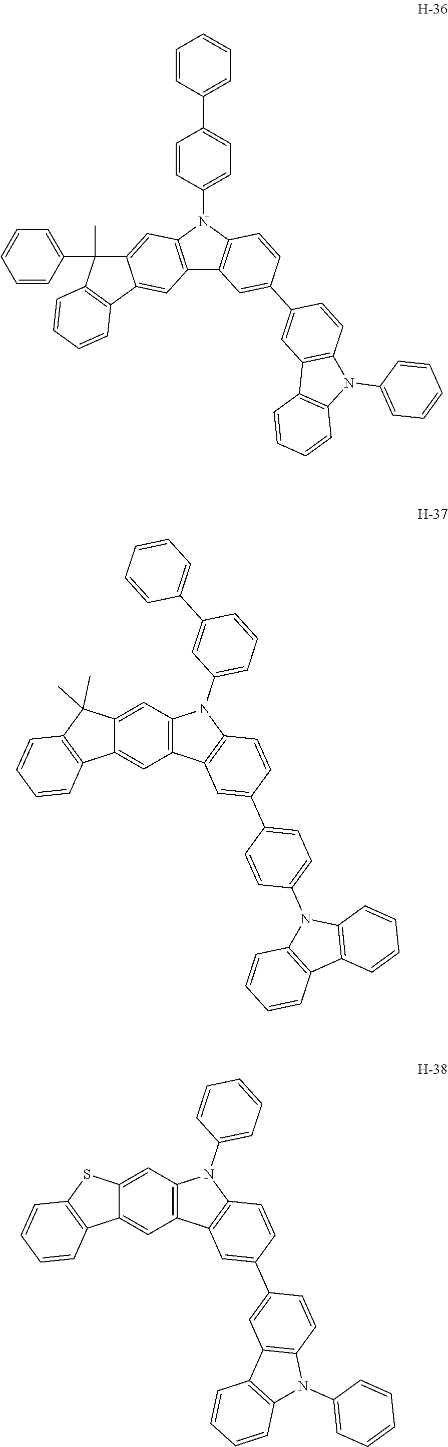 [SMILES: CC1(c2ccccc2)c2ccccc2-c2cc3c4cc(-c5ccc6c(c5)c5ccccc5n6-c5ccccc5)ccc4n(-c4ccc(-c5ccccc5)cc4)c3cc21 ; CC1(C)c2ccccc2-c2cc3c4cc(-c5ccc(-n6c7ccccc7c7ccccc76)cc5)ccc4n(-c4cccc(-c5ccccc5)c4)c3cc21 ; c1ccc(-n2c3ccccc3c3cc(-c4ccc5c(c4)c4cc6c(cc4n5-c4ccccc4)sc4ccccc46)ccc32)cc1]

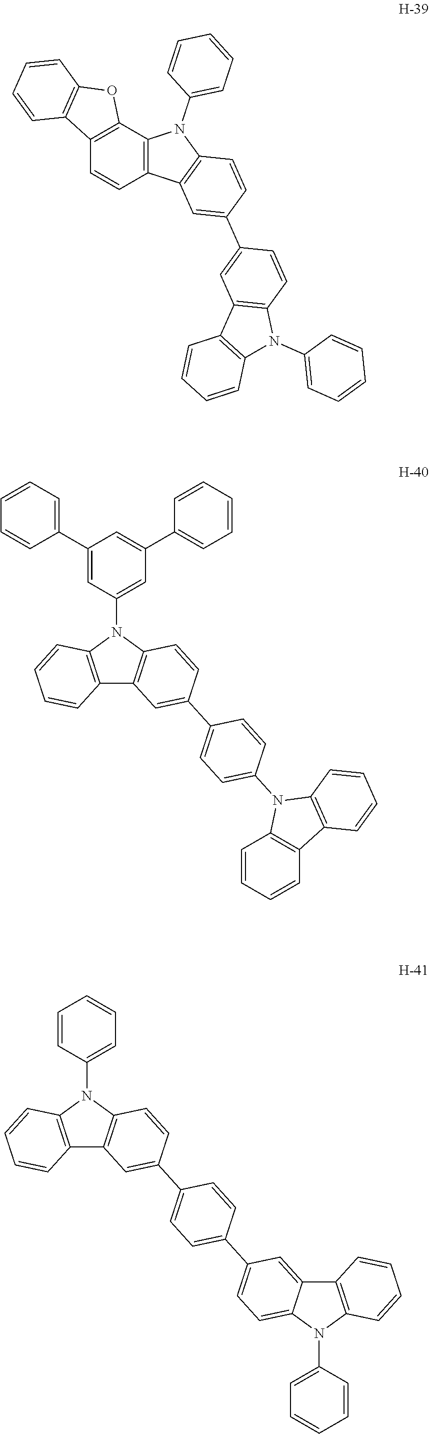 [SMILES: c1ccc(-n2c3ccccc3c3cc(-c4ccc5c(c4)c4ccc6c7ccccc7oc6c4n5-c4ccccc4)ccc32)cc1 ; c1ccc(-c2cc(-c3ccccc3)cc(-n3c4ccccc4c4cc(-c5ccc(-n6c7ccccc7c7ccccc76)cc5)ccc43)c2)cc1 ; c1ccc(-n2c3ccccc3c3cc(-c4ccc(-c5ccc6c(c5)c5ccccc5n6-c5ccccc5)cc4)ccc32)cc1]

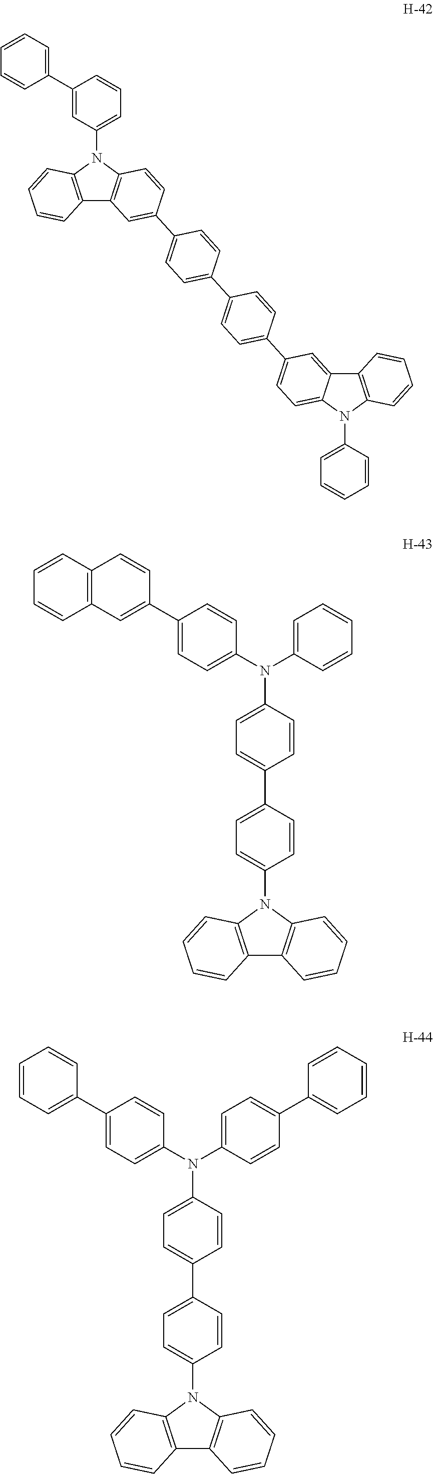 [SMILES: c1ccc(-c2cccc(-n3c4ccccc4c4cc(-c5ccc(-c6ccc(-c7ccc8c(c7)c7ccccc7n8-c7ccccc7)cc6)cc5)ccc43)c2)cc1 ; c1ccc(N(c2ccc(-c3ccc(-n4c5ccccc5c5ccccc54)cc3)cc2)c2ccc(-c3ccc4ccccc4c3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

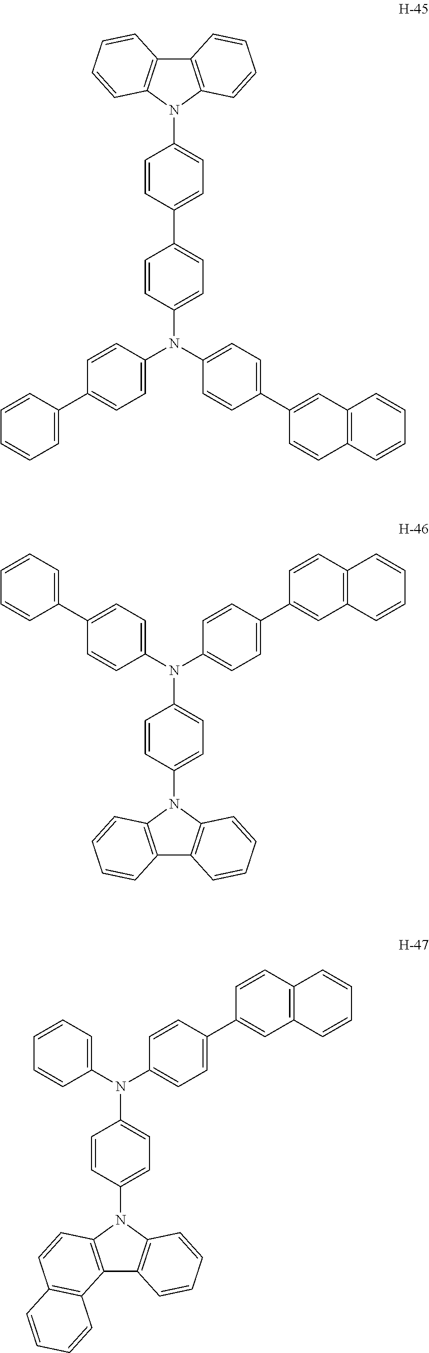 [SMILES: c1ccc(-c2ccc(N(c3ccc(-c4ccc(-n5c6ccccc6c6ccccc65)cc4)cc3)c3ccc(-c4ccc5ccccc5c4)cc3)cc2)cc1 ; c1ccc(-c2ccc(N(c3ccc(-c4ccc5ccccc5c4)cc3)c3ccc(-n4c5ccccc5c5ccccc54)cc3)cc2)cc1 ; c1ccc(N(c2ccc(-c3ccc4ccccc4c3)cc2)c2ccc(-n3c4ccccc4c4c5ccccc5ccc43)cc2)cc1]

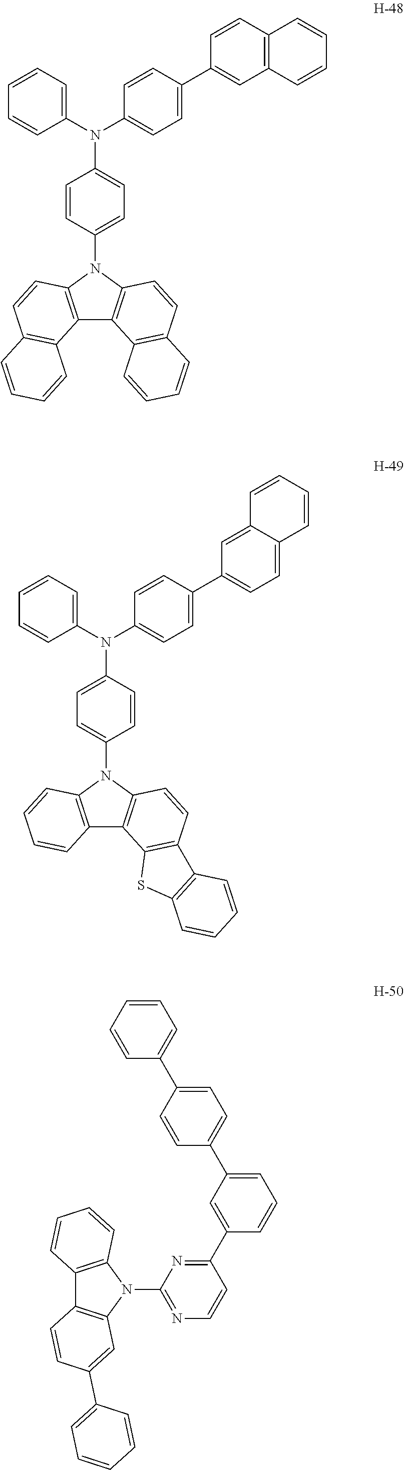 [SMILES: c1ccc(N(c2ccc(-c3ccc4ccccc4c3)cc2)c2ccc(-n3c4ccc5ccccc5c4c4c5ccccc5ccc43)cc2)cc1 ; c1ccc(N(c2ccc(-c3ccc4ccccc4c3)cc2)c2ccc(-n3c4ccccc4c4c5sc6ccccc6c5ccc43)cc2)cc1 ; c1ccc(-c2ccc(-c3cccc(-c4ccnc(-n5c6ccccc6c6ccc(-c7ccccc7)cc65)n4)c3)cc2)cc1]

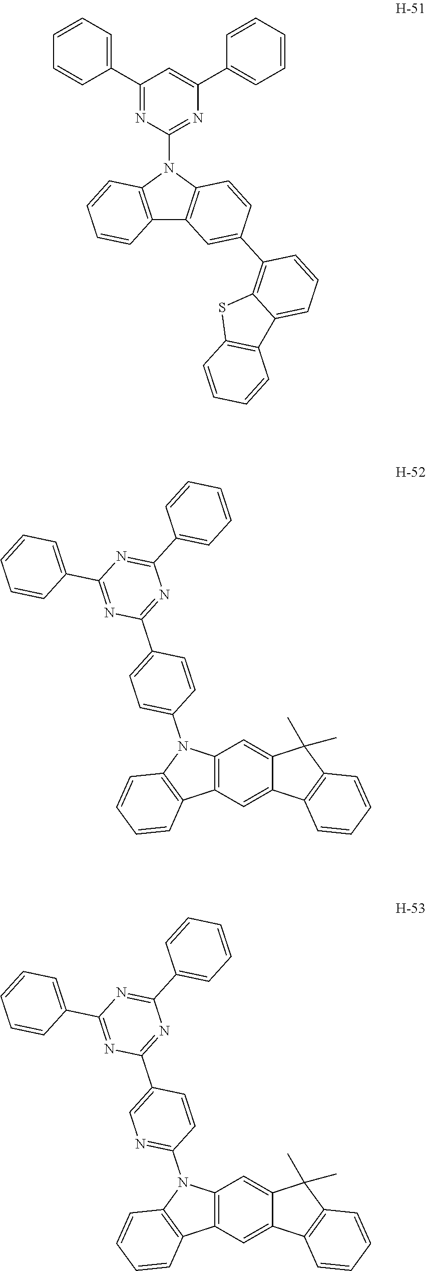 [SMILES: c1ccc(-c2cc(-c3ccccc3)nc(-n3c4ccccc4c4cc(-c5cccc6c5sc5ccccc56)ccc43)n2)cc1 ; CC1(C)c2ccccc2-c2cc3c4ccccc4n(-c4ccc(-c5nc(-c6ccccc6)nc(-c6ccccc6)n5)cc4)c3cc21 ; CC1(C)c2ccccc2-c2cc3c4ccccc4n(-c4ccc(-c5nc(-c6ccccc6)nc(-c6ccccc6)n5)cn4)c3cc21]

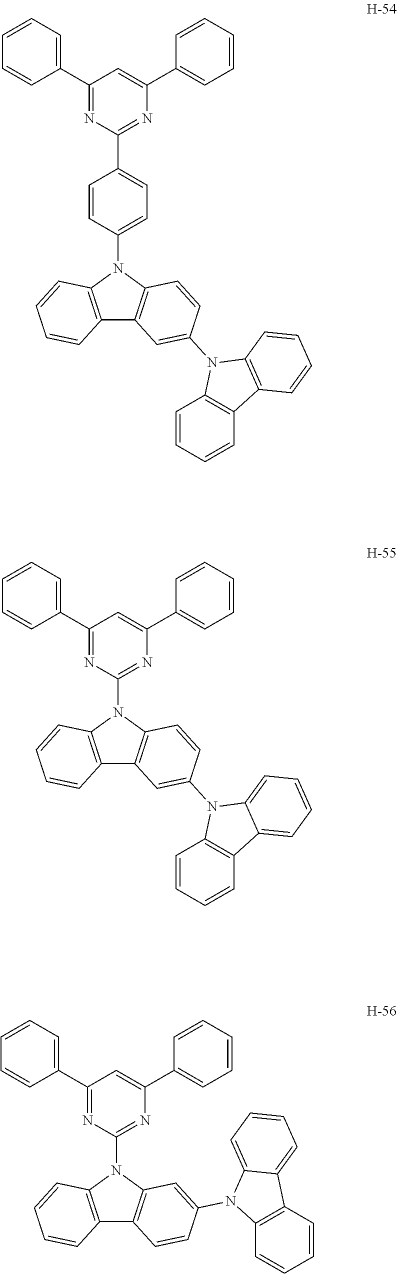 [SMILES: c1ccc(-c2cc(-c3ccccc3)nc(-c3ccc(-n4c5ccccc5c5cc(-n6c7ccccc7c7ccccc76)ccc54)cc3)n2)cc1 ; c1ccc(-c2cc(-c3ccccc3)nc(-n3c4ccccc4c4cc(-n5c6ccccc6c6ccccc65)ccc43)n2)cc1 ; c1ccc(-c2cc(-c3ccccc3)nc(-n3c4ccccc4c4ccc(-n5c6ccccc6c6ccccc65)cc43)n2)cc1]

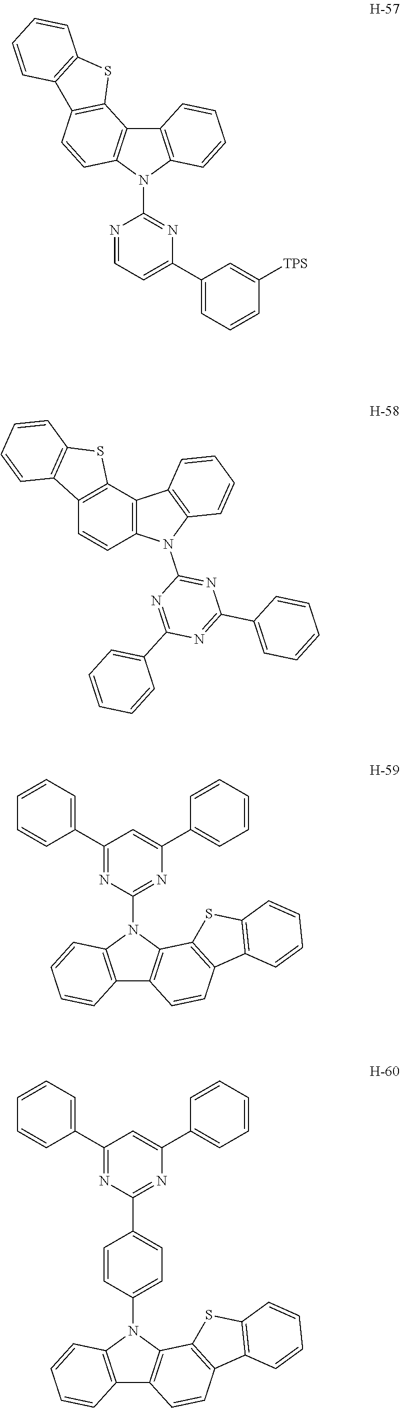

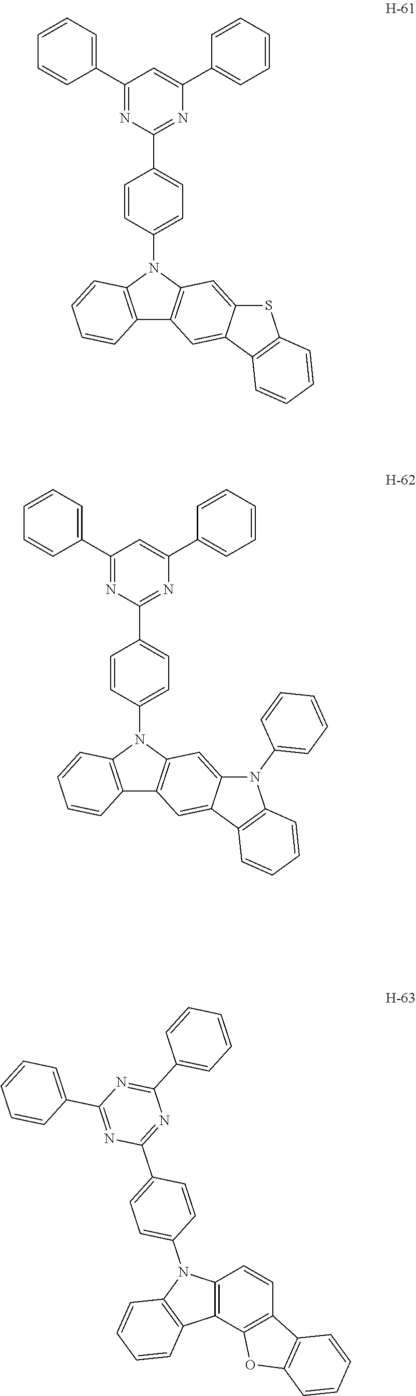 [SMILES: c1ccc(-c2cc(-c3ccccc3)nc(-c3ccc(-n4c5ccccc5c5cc6c(cc54)sc4ccccc46)cc3)n2)cc1 ; c1ccc(-c2cc(-c3ccccc3)nc(-c3ccc(-n4c5ccccc5c5cc6c7ccccc7n(-c7ccccc7)c6cc54)cc3)n2)cc1 ; c1ccc(-c2nc(-c3ccccc3)nc(-c3ccc(-n4c5ccccc5c5c6oc7ccccc7c6ccc54)cc3)n2)cc1]

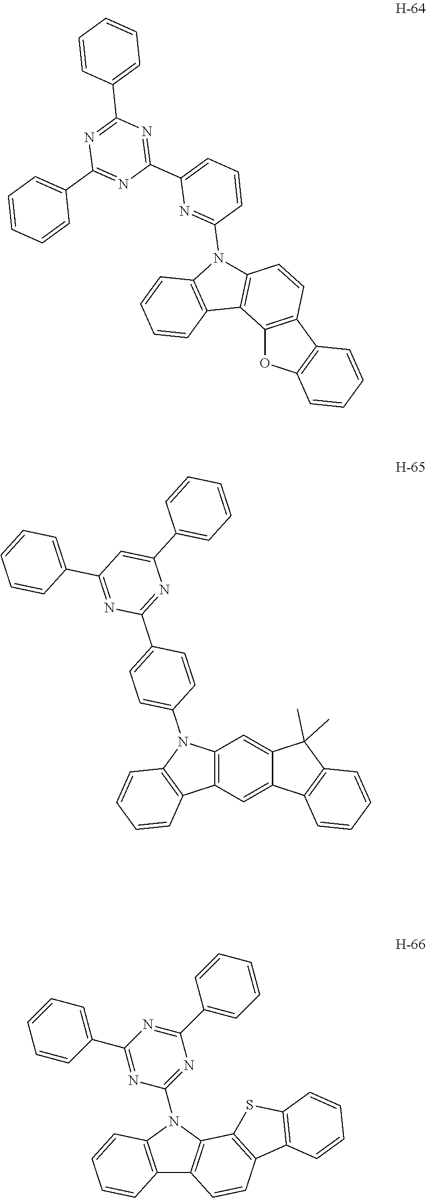 [SMILES: c1ccc(-c2nc(-c3ccccc3)nc(-c3cccc(-n4c5ccccc5c5c6oc7ccccc7c6ccc54)n3)n2)cc1 ; CC1(C)c2ccccc2-c2cc3c4ccccc4n(-c4ccc(-c5nc(-c6ccccc6)cc(-c6ccccc6)n5)cc4)c3cc21 ; c1ccc(-c2nc(-c3ccccc3)nc(-n3c4ccccc4c4ccc5c6ccccc6sc5c43)n2)cc1]

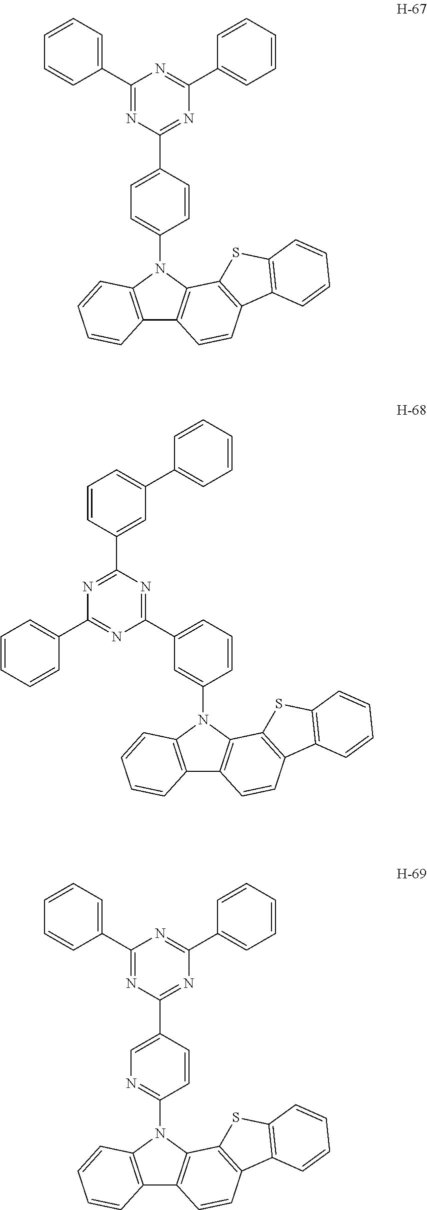 [SMILES: c1ccc(-c2nc(-c3ccccc3)nc(-c3ccc(-n4c5ccccc5c5ccc6c7ccccc7sc6c54)cc3)n2)cc1 ; c1ccc(-c2cccc(-c3nc(-c4ccccc4)nc(-c4cccc(-n5c6ccccc6c6ccc7c8ccccc8sc7c65)c4)n3)c2)cc1 ; c1ccc(-c2nc(-c3ccccc3)nc(-c3ccc(-n4c5ccccc5c5ccc6c7ccccc7sc6c54)nc3)n2)cc1]

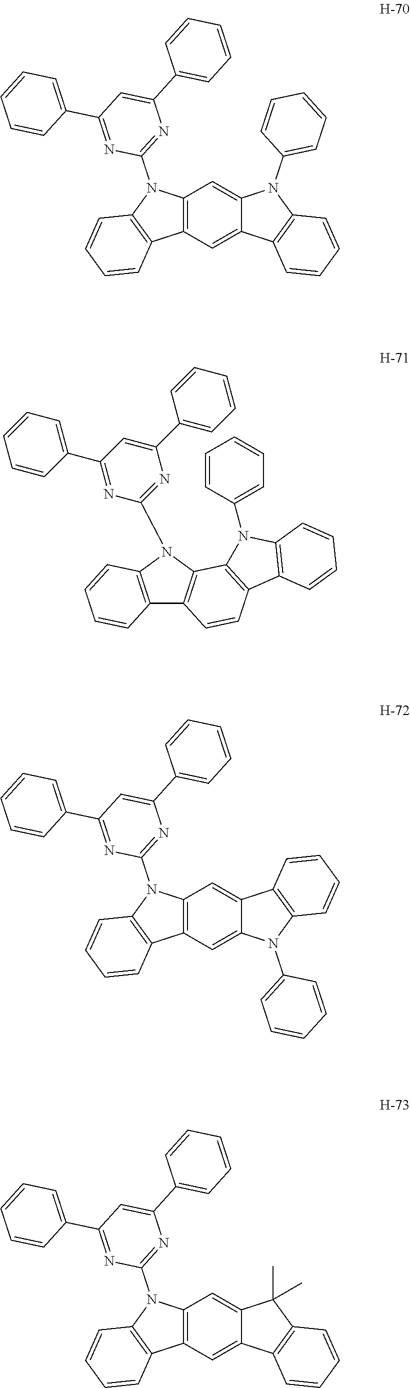 [SMILES: c1ccc(-c2cc(-c3ccccc3)nc(-n3c4ccccc4c4cc5c6ccccc6n(-c6ccccc6)c5cc43)n2)cc1 ; c1ccc(-c2cc(-c3ccccc3)nc(-n3c4ccccc4c4ccc5c6ccccc6n(-c6ccccc6)c5c43)n2)cc1 ; c1ccc(-c2cc(-c3ccccc3)nc(-n3c4ccccc4c4cc5c(cc43)c3ccccc3n5-c3ccccc3)n2)cc1 ; CC1(C)c2ccccc2-c2cc3c4ccccc4n(-c4nc(-c5ccccc5)cc(-c5ccccc5)n4)c3cc21]

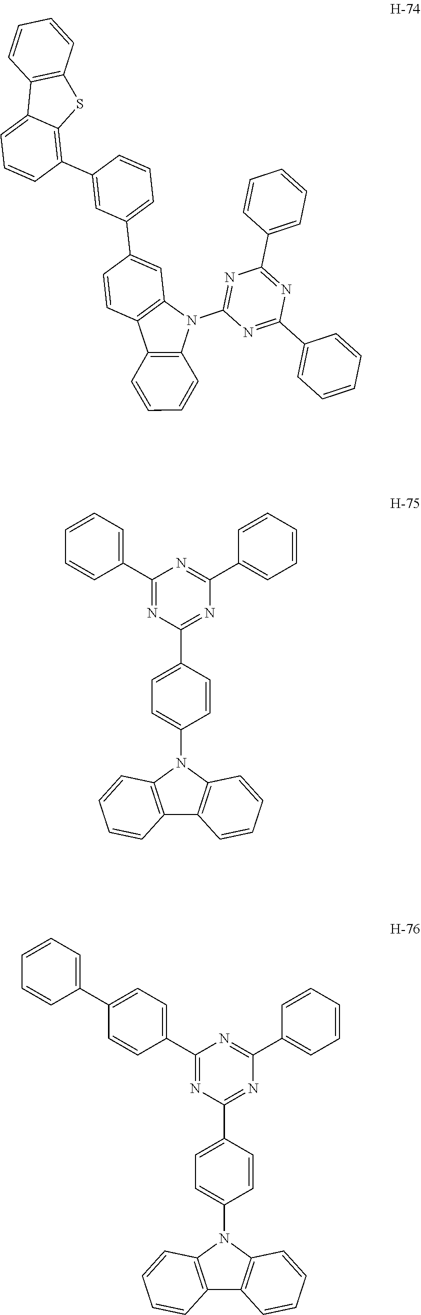 [SMILES: c1ccc(-c2nc(-c3ccccc3)nc(-n3c4ccccc4c4ccc(-c5cccc(-c6cccc7c6sc6ccccc67)c5)cc43)n2)cc1 ; c1ccc(-c2nc(-c3ccccc3)nc(-c3ccc(-n4c5ccccc5c5ccccc54)cc3)n2)cc1 ; c1ccc(-c2ccc(-c3nc(-c4ccccc4)nc(-c4ccc(-n5c6ccccc6c6ccccc65)cc4)n3)cc2)cc1]

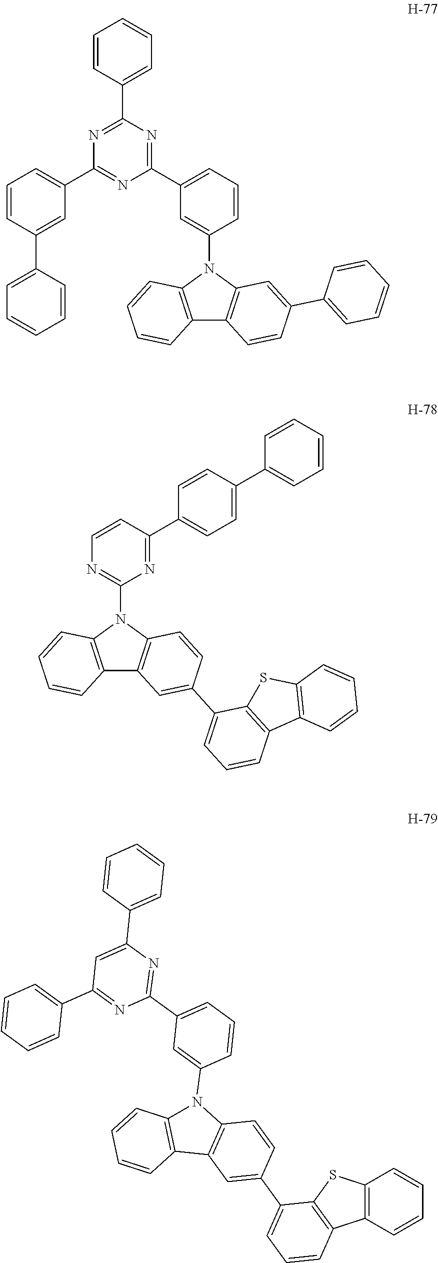 [SMILES: c1ccc(-c2cccc(-c3nc(-c4ccccc4)nc(-c4cccc(-n5c6ccccc6c6ccc(-c7ccccc7)cc65)c4)n3)c2)cc1 ; c1ccc(-c2ccc(-c3ccnc(-n4c5ccccc5c5cc(-c6cccc7c6sc6ccccc67)ccc54)n3)cc2)cc1 ; c1ccc(-c2cc(-c3ccccc3)nc(-c3cccc(-n4c5ccccc5c5cc(-c6cccc7c6sc6ccccc67)ccc54)c3)n2)cc1]

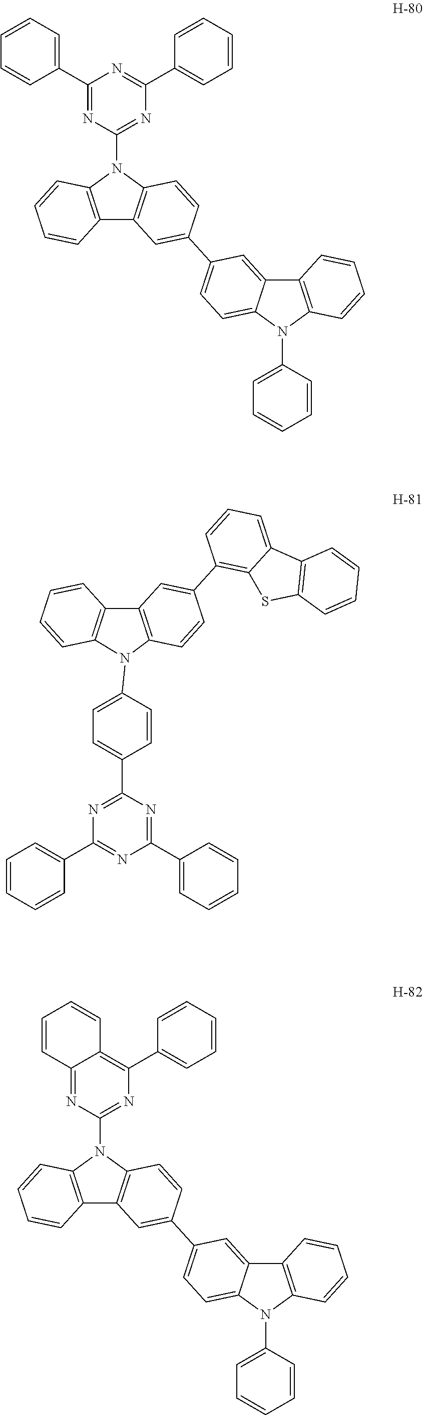 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-c3ccc(-n4c5ccccc5c5cc(-c6cccc7c6sc6ccccc67)ccc54)cc3)n2)cc1 ; c1ccc(-c2nc(-n3c4ccccc4c4cc(-c5ccc6c(c5)c5ccccc5n6-c5ccccc5)ccc43)nc3ccccc23)cc1]

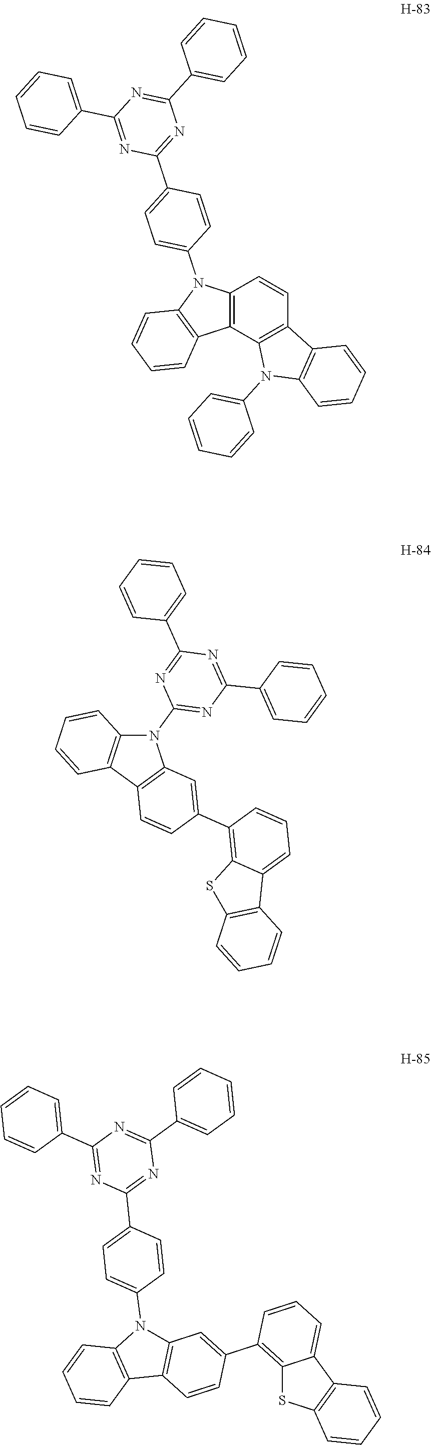 [SMILES: c1ccc(-c2nc(-c3ccccc3)nc(-c3ccc(-n4c5ccccc5c5c4ccc4c6ccccc6n(-c6ccccc6)c45)cc3)n2)cc1 ; c1ccc(-c2nc(-c3ccccc3)nc(-n3c4ccccc4c4ccc(-c5cccc6c5sc5ccccc56)cc43)n2)cc1 ; c1ccc(-c2nc(-c3ccccc3)nc(-c3ccc(-n4c5ccccc5c5ccc(-c6cccc7c6sc6ccccc67)cc54)cc3)n2)cc1]

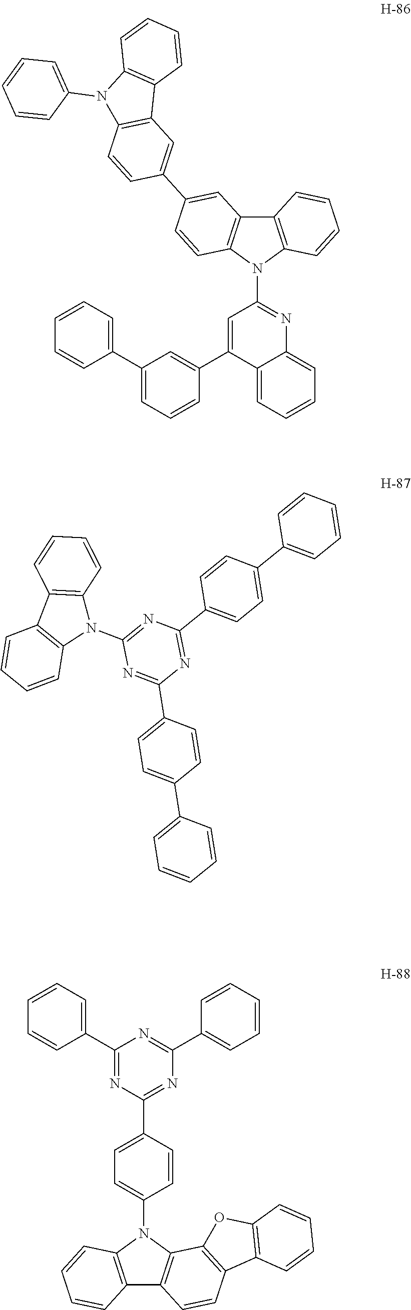 [SMILES: c1ccc(-c2cccc(-c3cc(-n4c5ccccc5c5cc(-c6ccc7c(c6)c6ccccc6n7-c6ccccc6)ccc54)nc4ccccc34)c2)cc1 ; c1ccc(-c2ccc(-c3nc(-c4ccc(-c5ccccc5)cc4)nc(-n4c5ccccc5c5ccccc54)n3)cc2)cc1 ; c1ccc(-c2nc(-c3ccccc3)nc(-c3ccc(-n4c5ccccc5c5ccc6c7ccccc7oc6c54)cc3)n2)cc1]

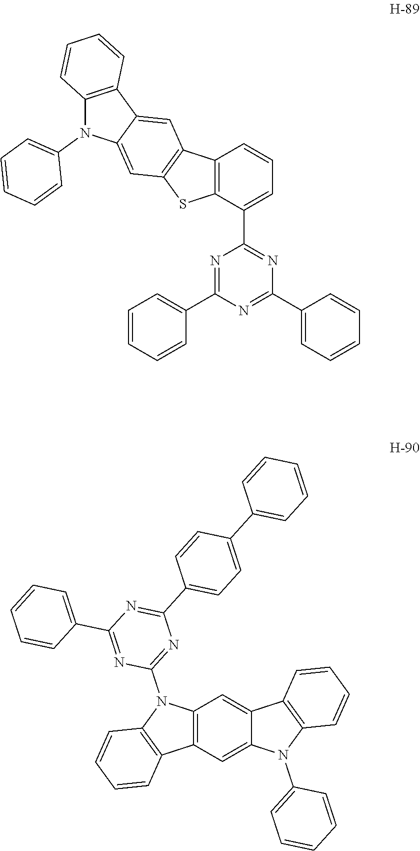 [SMILES: c1ccc(-c2nc(-c3ccccc3)nc(-c3cccc4c3sc3cc5c(cc34)c3ccccc3n5-c3ccccc3)n2)cc1 ; c1ccc(-c2ccc(-c3nc(-c4ccccc4)nc(-n4c5ccccc5c5cc6c(cc54)c4ccccc4n6-c4ccccc4)n3)cc2)cc1]

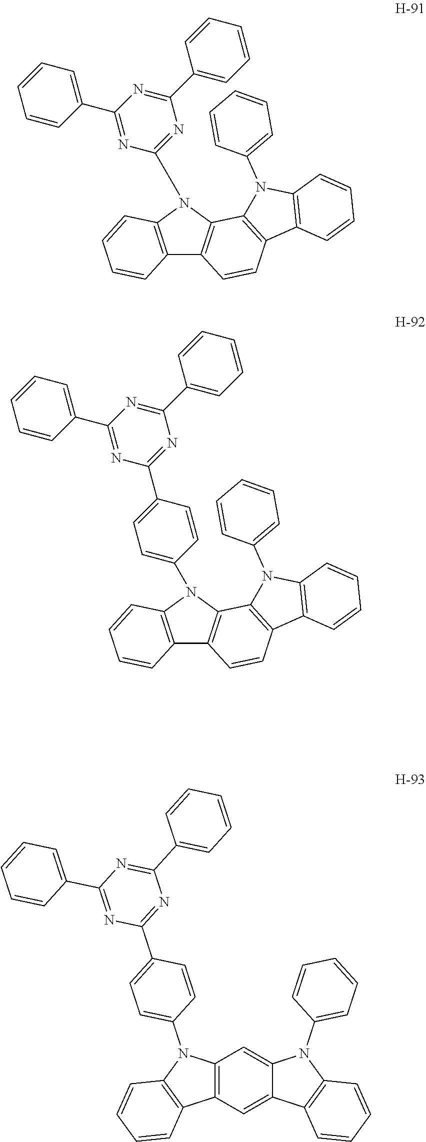 [SMILES: c1ccc(-c2nc(-c3ccccc3)nc(-n3c4ccccc4c4ccc5c6ccccc6n(-c6ccccc6)c5c43)n2)cc1 ; c1ccc(-c2nc(-c3ccccc3)nc(-c3ccc(-n4c5ccccc5c5ccc6c7ccccc7n(-c7ccccc7)c6c54)cc3)n2)cc1 ; c1ccc(-c2nc(-c3ccccc3)nc(-c3ccc(-n4c5ccccc5c5cc6c7ccccc7n(-c7ccccc7)c6cc54)cc3)n2)cc1]

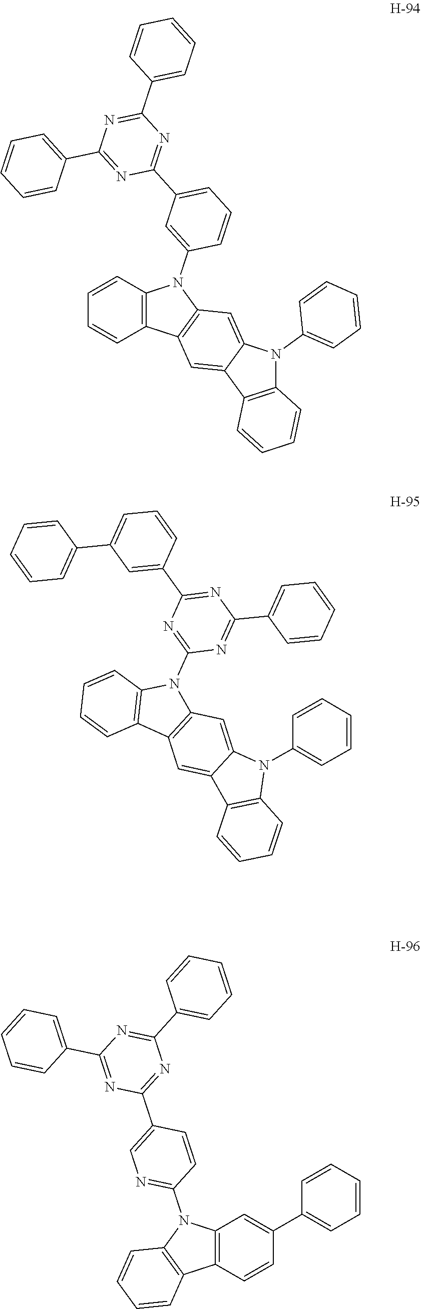 [SMILES: c1ccc(-c2nc(-c3ccccc3)nc(-c3cccc(-n4c5ccccc5c5cc6c7ccccc7n(-c7ccccc7)c6cc54)c3)n2)cc1 ; c1ccc(-c2cccc(-c3nc(-c4ccccc4)nc(-n4c5ccccc5c5cc6c7ccccc7n(-c7ccccc7)c6cc54)n3)c2)cc1 ; c1ccc(-c2ccc3c4ccccc4n(-c4ccc(-c5nc(-c6ccccc6)nc(-c6ccccc6)n5)cn4)c3c2)cc1]

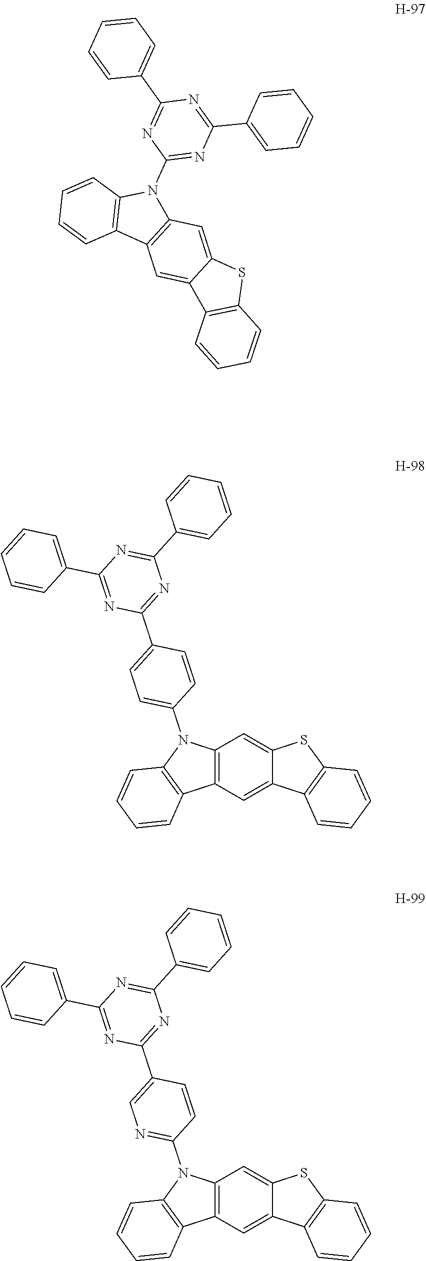 [SMILES: c1ccc(-c2nc(-c3ccccc3)nc(-n3c4ccccc4c4cc5c(cc43)sc3ccccc35)n2)cc1 ; c1ccc(-c2nc(-c3ccccc3)nc(-c3ccc(-n4c5ccccc5c5cc6c(cc54)sc4ccccc46)cc3)n2)cc1 ; c1ccc(-c2nc(-c3ccccc3)nc(-c3ccc(-n4c5ccccc5c5cc6c(cc54)sc4ccccc46)nc3)n2)cc1]

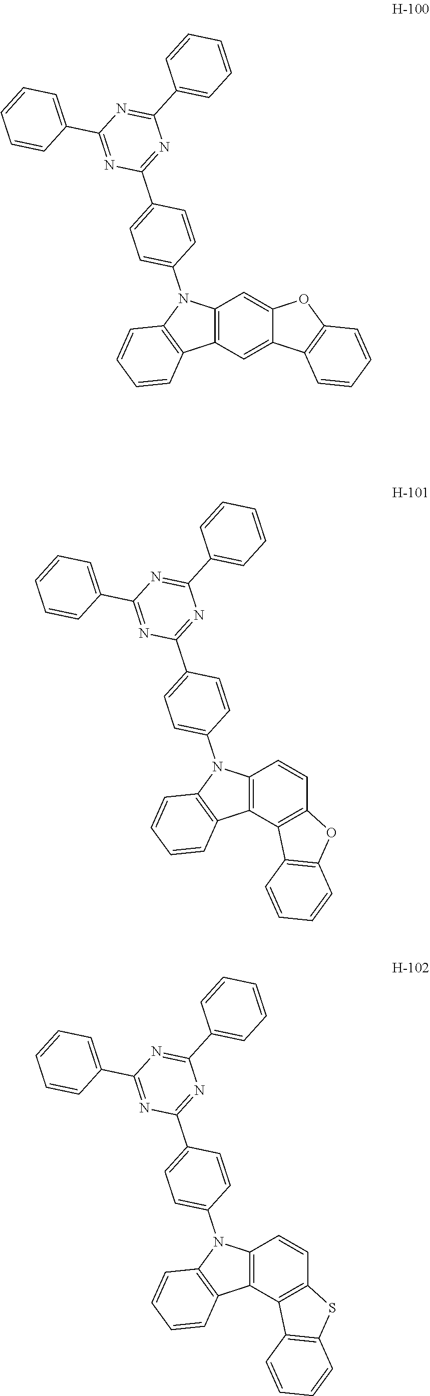 [SMILES: c1ccc(-c2nc(-c3ccccc3)nc(-c3ccc(-n4c5ccccc5c5cc6c(cc54)oc4ccccc46)cc3)n2)cc1 ; c1ccc(-c2nc(-c3ccccc3)nc(-c3ccc(-n4c5ccccc5c5c6c(ccc54)oc4ccccc46)cc3)n2)cc1 ; c1ccc(-c2nc(-c3ccccc3)nc(-c3ccc(-n4c5ccccc5c5c6c(ccc54)sc4ccccc46)cc3)n2)cc1]

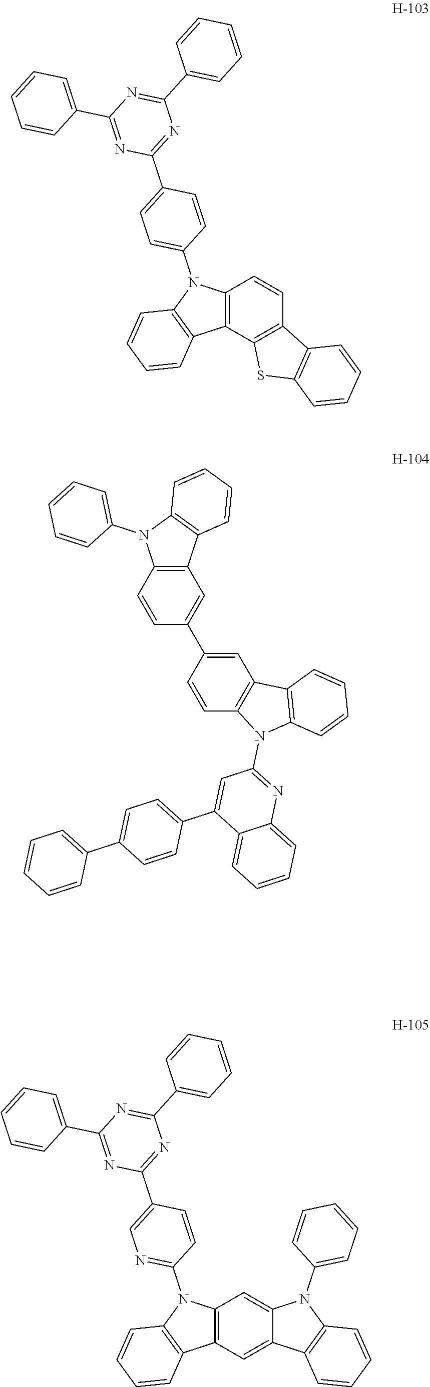 [SMILES: c1ccc(-c2nc(-c3ccccc3)nc(-c3ccc(-n4c5ccccc5c5c6sc7ccccc7c6ccc54)cc3)n2)cc1 ; c1ccc(-c2ccc(-c3cc(-n4c5ccccc5c5cc(-c6ccc7c(c6)c6ccccc6n7-c6ccccc6)ccc54)nc4ccccc34)cc2)cc1 ; c1ccc(-c2nc(-c3ccccc3)nc(-c3ccc(-n4c5ccccc5c5cc6c7ccccc7n(-c7ccccc7)c6cc54)nc3)n2)cc1]

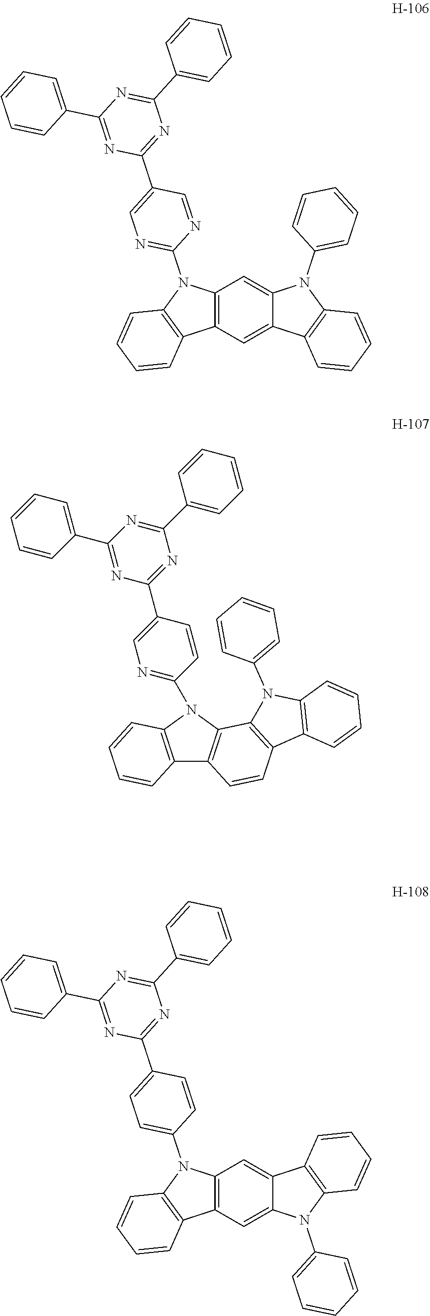 [SMILES: c1ccc(-c2nc(-c3ccccc3)nc(-c3cnc(-n4c5ccccc5c5cc6c7ccccc7n(-c7ccccc7)c6cc54)nc3)n2)cc1 ; c1ccc(-c2nc(-c3ccccc3)nc(-c3ccc(-n4c5ccccc5c5ccc6c7ccccc7n(-c7ccccc7)c6c54)nc3)n2)cc1 ; c1ccc(-c2nc(-c3ccccc3)nc(-c3ccc(-n4c5ccccc5c5cc6c(cc54)c4ccccc4n6-c4ccccc4)cc3)n2)cc1]

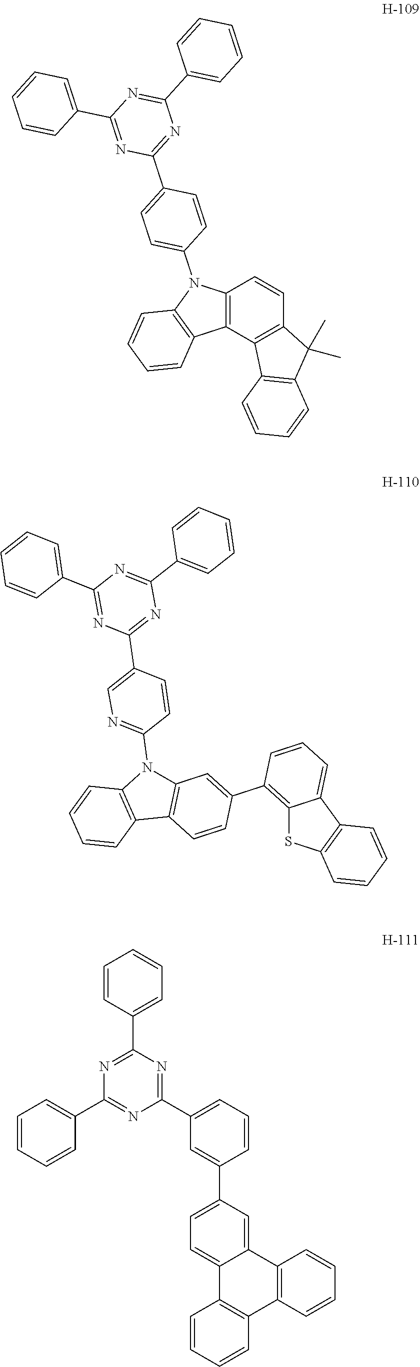 [SMILES: CC1(C)c2ccccc2-c2c1ccc1c2c2ccccc2n1-c1ccc(-c2nc(-c3ccccc3)nc(-c3ccccc3)n2)cc1 ; c1ccc(-c2nc(-c3ccccc3)nc(-c3ccc(-n4c5ccccc5c5ccc(-c6cccc7c6sc6ccccc67)cc54)nc3)n2)cc1 ; c1ccc(-c2nc(-c3ccccc3)nc(-c3cccc(-c4ccc5c6ccccc6c6ccccc6c5c4)c3)n2)cc1]

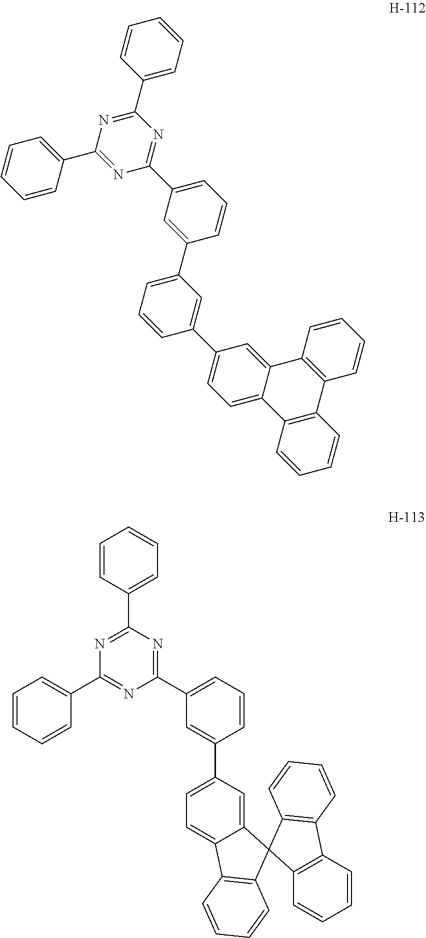 [SMILES: c1ccc(-c2nc(-c3ccccc3)nc(-c3cccc(-c4cccc(-c5ccc6c7ccccc7c7ccccc7c6c5)c4)c3)n2)cc1 ; c1ccc(-c2nc(-c3ccccc3)nc(-c3cccc(-c4ccc5c(c4)C4(c6ccccc6-c6ccccc64)c4ccccc4-5)c3)n2)cc1]

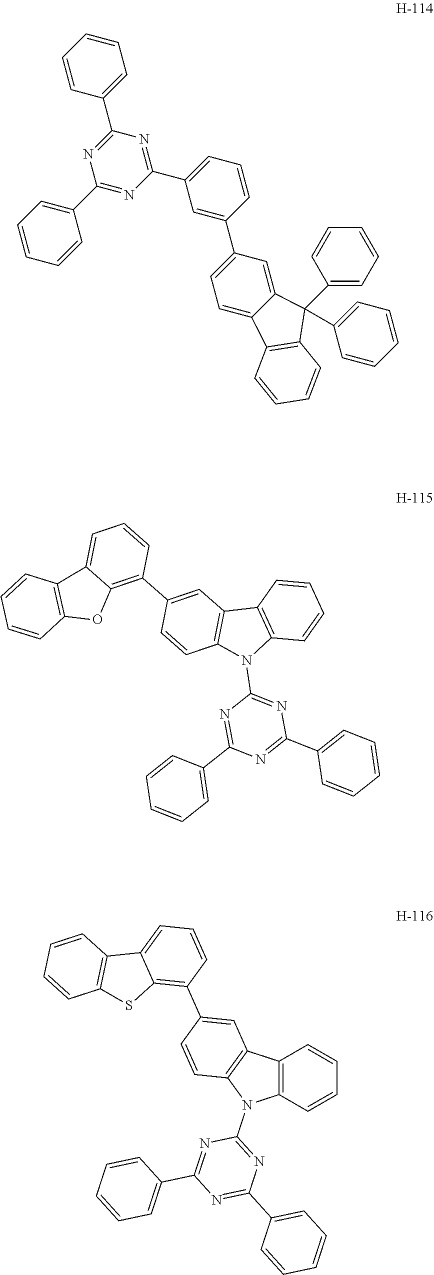 [SMILES: c1ccc(-c2nc(-c3ccccc3)nc(-c3cccc(-c4ccc5c(c4)C(c4ccccc4)(c4ccccc4)c4ccccc4-5)c3)n2)cc1 ; c1ccc(-c2nc(-c3ccccc3)nc(-n3c4ccccc4c4cc(-c5cccc6c5oc5ccccc56)ccc43)n2)cc1 ; c1ccc(-c2nc(-c3ccccc3)nc(-n3c4ccccc4c4cc(-c5cccc6c5sc5ccccc56)ccc43)n2)cc1]

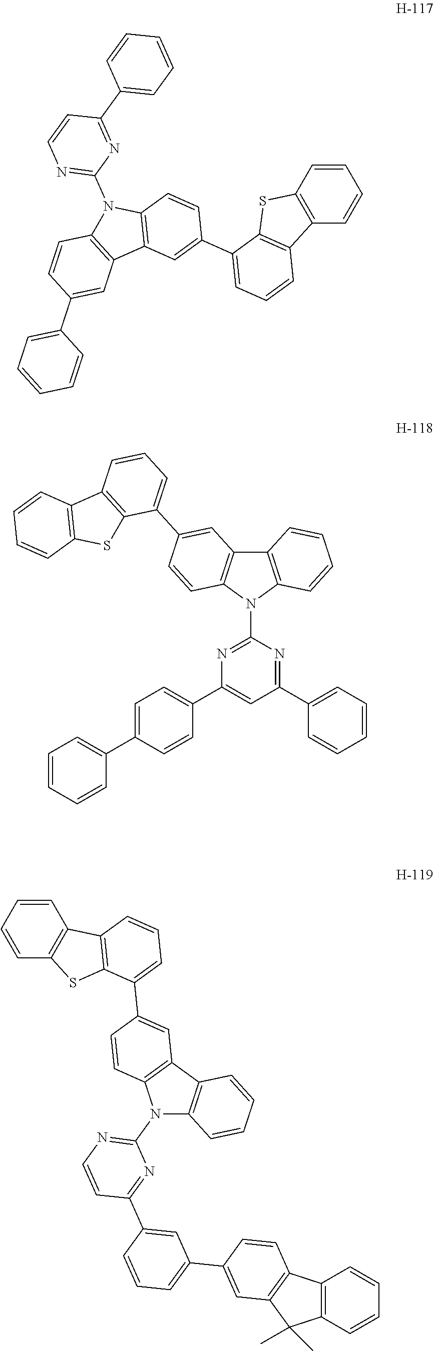 [SMILES: c1ccc(-c2ccc3c(c2)c2cc(-c4cccc5c4sc4ccccc45)ccc2n3-c2nccc(-c3ccccc3)n2)cc1 ; c1ccc(-c2ccc(-c3cc(-c4ccccc4)nc(-n4c5ccccc5c5cc(-c6cccc7c6sc6ccccc67)ccc54)n3)cc2)cc1 ; CC1(C)c2ccccc2-c2ccc(-c3cccc(-c4ccnc(-n5c6ccccc6c6cc(-c7cccc8c7sc7ccccc78)ccc65)n4)c3)cc21]

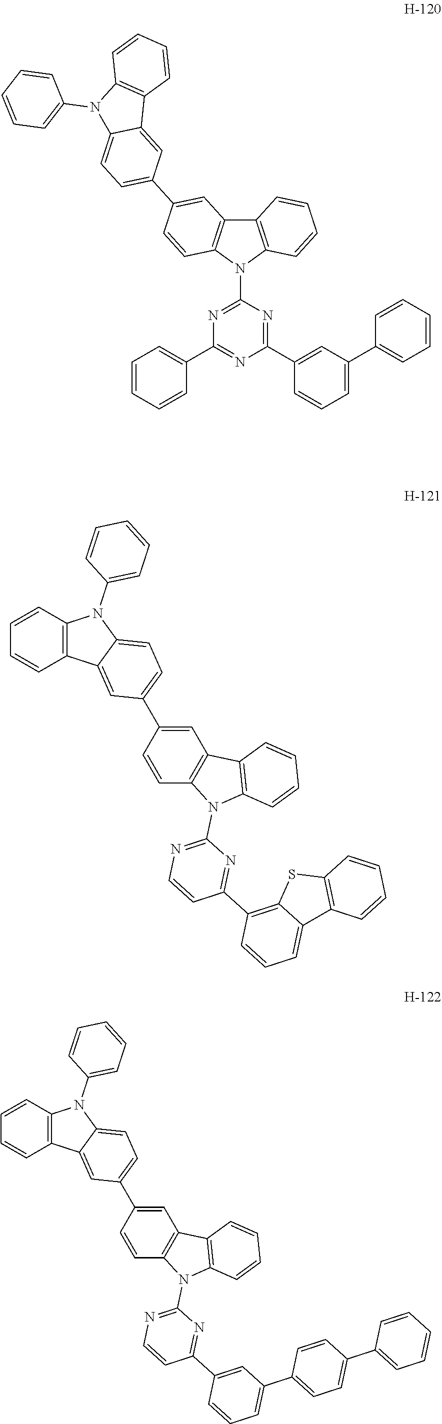 [SMILES: c1ccc(-c2cccc(-c3nc(-c4ccccc4)nc(-n4c5ccccc5c5cc(-c6ccc7c(c6)c6ccccc6n7-c6ccccc6)ccc54)n3)c2)cc1 ; c1ccc(-n2c3ccccc3c3cc(-c4ccc5c(c4)c4ccccc4n5-c4nccc(-c5cccc6c5sc5ccccc56)n4)ccc32)cc1 ; c1ccc(-c2ccc(-c3cccc(-c4ccnc(-n5c6ccccc6c6cc(-c7ccc8c(c7)c7ccccc7n8-c7ccccc7)ccc65)n4)c3)cc2)cc1]

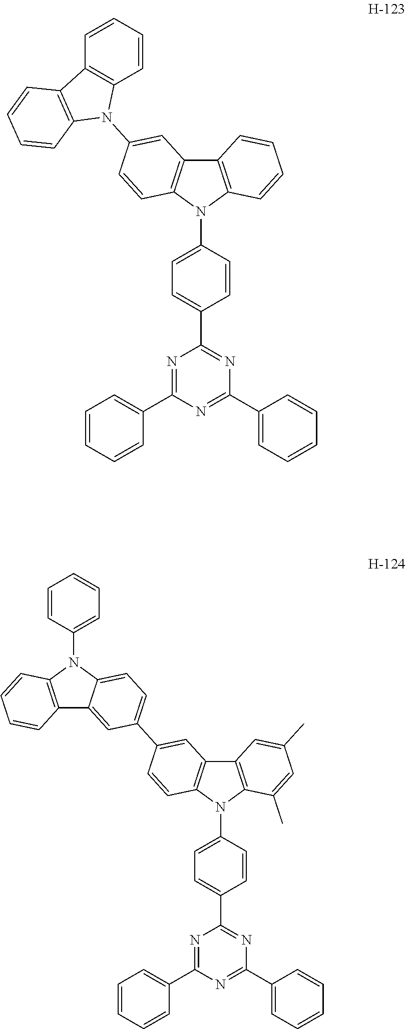 [SMILES: c1ccc(-c2nc(-c3ccccc3)nc(-c3ccc(-n4c5ccccc5c5cc(-n6c7ccccc7c7ccccc76)ccc54)cc3)n2)cc1 ; Cc1cc(C)c2c(c1)c1cc(-c3ccc4c(c3)c3ccccc3n4-c3ccccc3)ccc1n2-c1ccc(-c2nc(-c3ccccc3)nc(-c3ccccc3)n2)cc1]

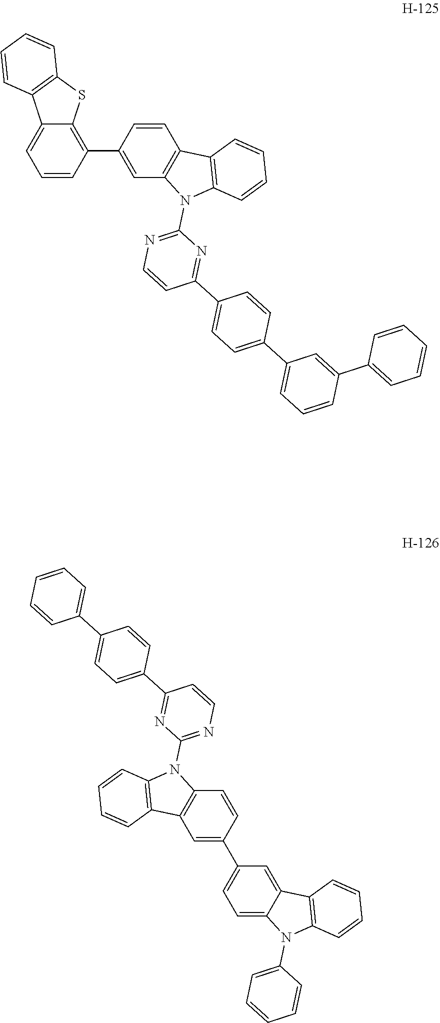 [SMILES: c1ccc(-c2cccc(-c3ccc(-c4ccnc(-n5c6ccccc6c6ccc(-c7cccc8c7sc7ccccc78)cc65)n4)cc3)c2)cc1 ; c1ccc(-c2ccc(-c3ccnc(-n4c5ccccc5c5cc(-c6ccc7c(c6)c6ccccc6n7-c6ccccc6)ccc54)n3)cc2)cc1]

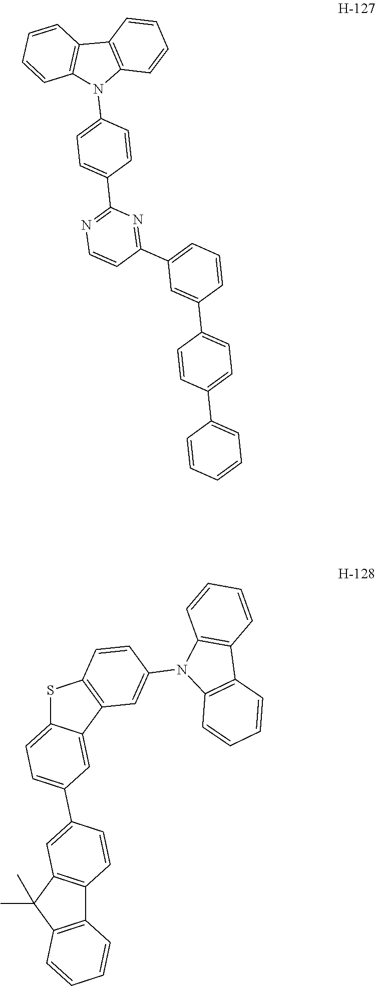 [SMILES: c1ccc(-c2ccc(-c3cccc(-c4ccnc(-c5ccc(-n6c7ccccc7c7ccccc76)cc5)n4)c3)cc2)cc1 ; CC1(C)c2ccccc2-c2ccc(-c3ccc4sc5ccc(-n6c7ccccc7c7ccccc76)cc5c4c3)cc21]

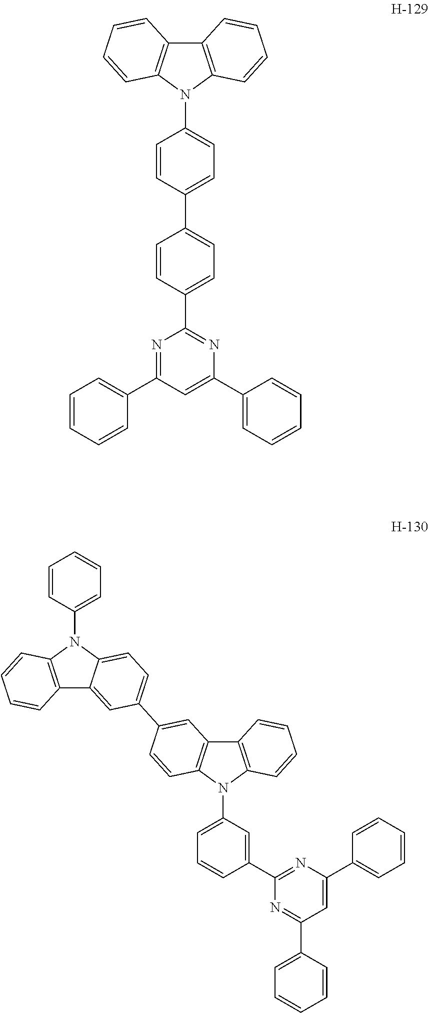 [SMILES: c1ccc(-c2cc(-c3ccccc3)nc(-c3ccc(-c4ccc(-n5c6ccccc6c6ccccc65)cc4)cc3)n2)cc1 ; c1ccc(-c2cc(-c3ccccc3)nc(-c3cccc(-n4c5ccccc5c5cc(-c6ccc7c(c6)c6ccccc6n7-c6ccccc6)ccc54)c3)n2)cc1]

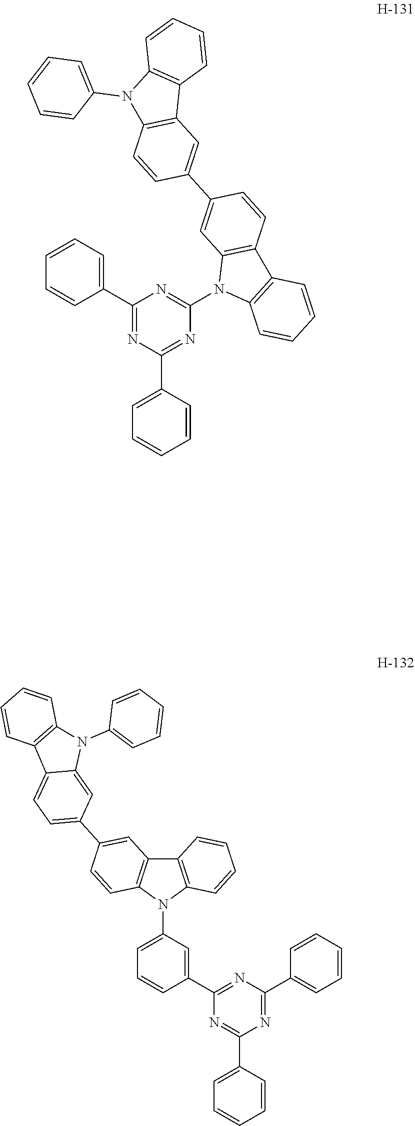 [SMILES: c1ccc(-c2nc(-c3ccccc3)nc(-n3c4ccccc4c4ccc(-c5ccc6c(c5)c5ccccc5n6-c5ccccc5)cc43)n2)cc1 ; c1ccc(-c2nc(-c3ccccc3)nc(-c3cccc(-n4c5ccccc5c5cc(-c6ccc7c8ccccc8n(-c8ccccc8)c7c6)ccc54)c3)n2)cc1]

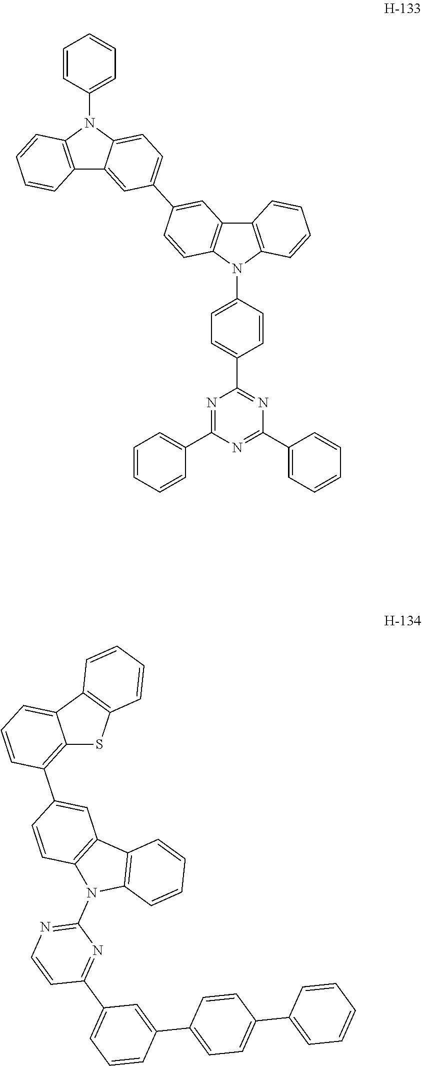 [SMILES: c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2ccc(-c3cccc(-c4ccnc(-n5c6ccccc6c6cc(-c7cccc8c7sc7ccccc78)ccc65)n4)c3)cc2)cc1]

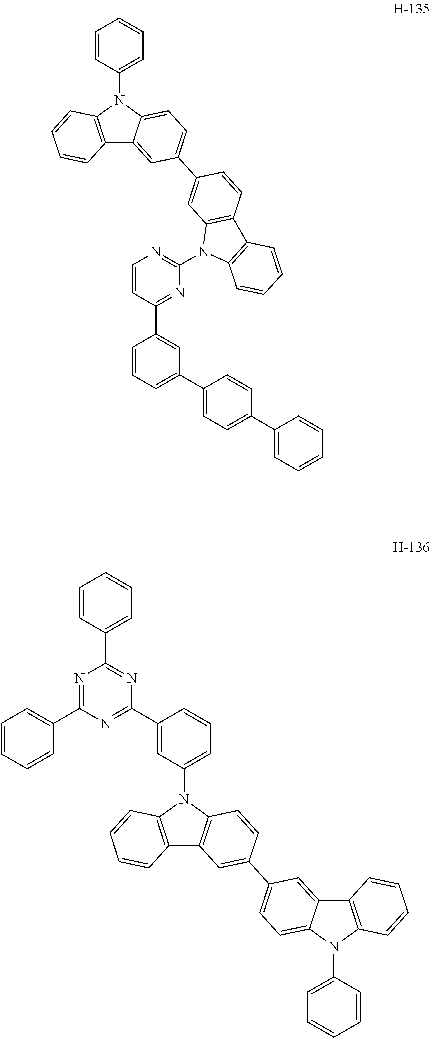 [SMILES: c1ccc(-c2ccc(-c3cccc(-c4ccnc(-n5c6ccccc6c6ccc(-c7ccc8c(c7)c7ccccc7n8-c7ccccc7)cc65)n4)c3)cc2)cc1 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1]

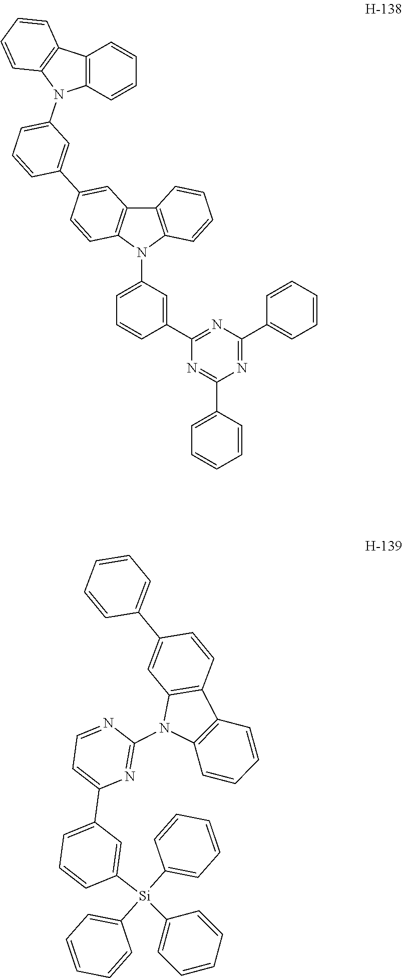 [SMILES: c1ccc(-c2nc(-c3ccccc3)nc(-c3cccc(-n4c5ccccc5c5cc(-c6cccc(-n7c8ccccc8c8ccccc87)c6)ccc54)c3)n2)cc1 ; c1ccc(-c2ccc3c4ccccc4n(-c4nccc(-c5cccc([Si](c6ccccc6)(c6ccccc6)c6ccccc6)c5)n4)c3c2)cc1]

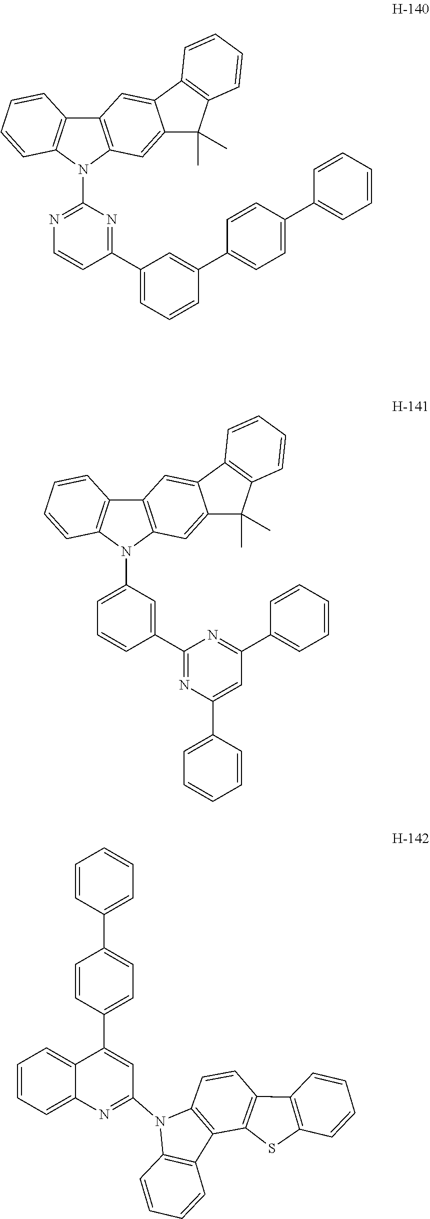 [SMILES: CC1(C)c2ccccc2-c2cc3c4ccccc4n(-c4nccc(-c5cccc(-c6ccc(-c7ccccc7)cc6)c5)n4)c3cc21 ; CC1(C)c2ccccc2-c2cc3c4ccccc4n(-c4cccc(-c5nc(-c6ccccc6)cc(-c6ccccc6)n5)c4)c3cc21 ; c1ccc(-c2ccc(-c3cc(-n4c5ccccc5c5c6sc7ccccc7c6ccc54)nc4ccccc34)cc2)cc1]

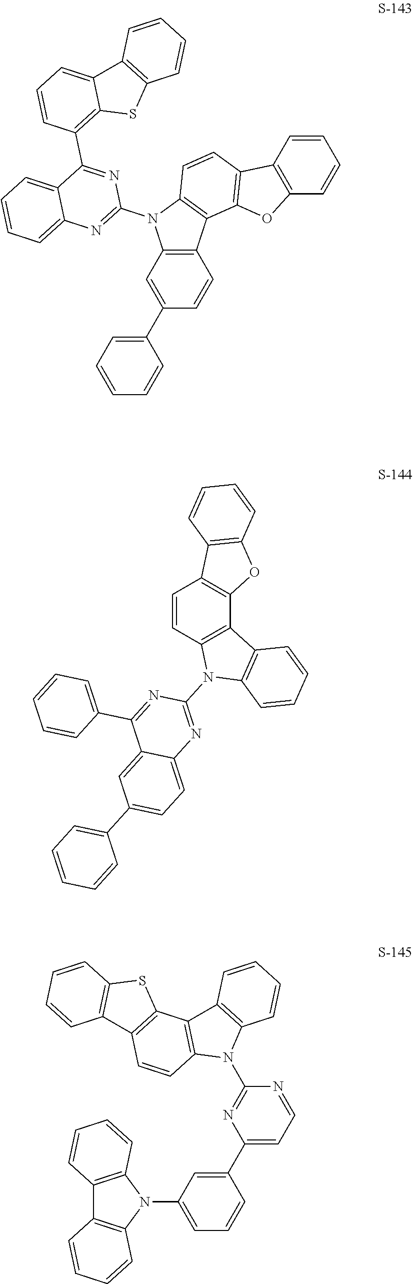 [SMILES: c1ccc(-c2ccc3c4c5oc6ccccc6c5ccc4n(-c4nc(-c5cccc6c5sc5ccccc56)c5ccccc5n4)c3c2)cc1 ; c1ccc(-c2ccc3nc(-n4c5ccccc5c5c6oc7ccccc7c6ccc54)nc(-c4ccccc4)c3c2)cc1 ; c1cc(-c2ccnc(-n3c4ccccc4c4c5sc6ccccc6c5ccc43)n2)cc(-n2c3ccccc3c3ccccc32)c1]

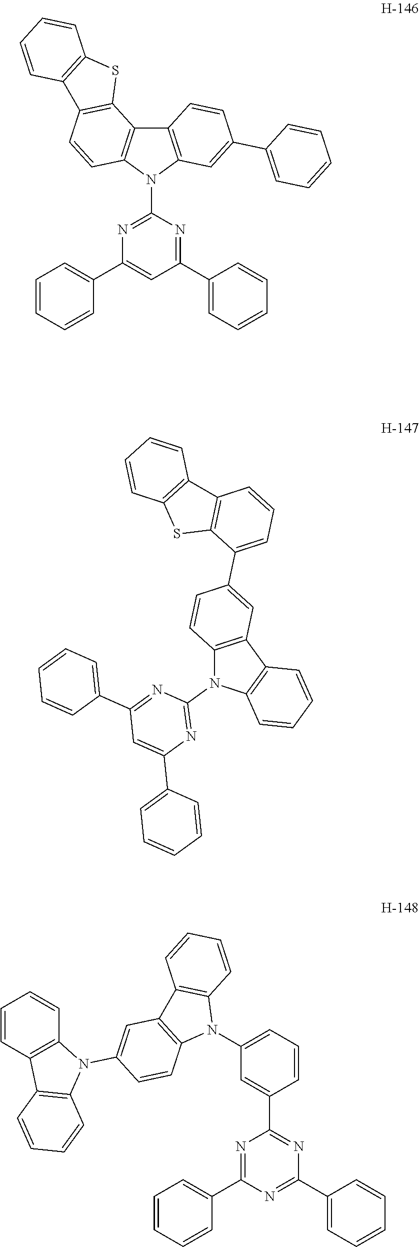 [SMILES: c1ccc(-c2ccc3c4c5sc6ccccc6c5ccc4n(-c4nc(-c5ccccc5)cc(-c5ccccc5)n4)c3c2)cc1 ; c1ccc(-c2cc(-c3ccccc3)nc(-n3c4ccccc4c4cc(-c5cccc6c5sc5ccccc56)ccc43)n2)cc1 ; c1ccc(-c2nc(-c3ccccc3)nc(-c3cccc(-n4c5ccccc5c5cc(-n6c7ccccc7c7ccccc76)ccc54)c3)n2)cc1]

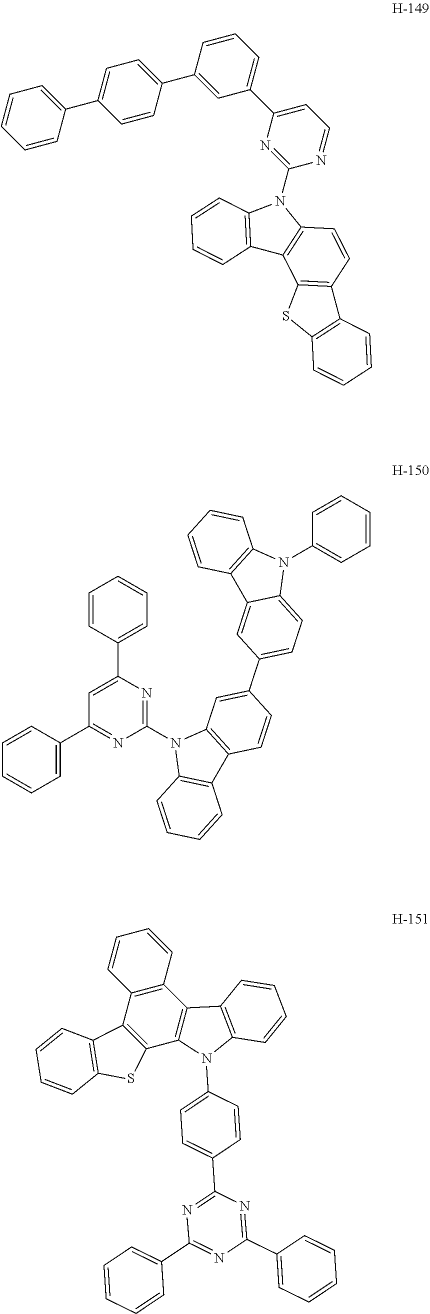 [SMILES: c1ccc(-c2ccc(-c3cccc(-c4ccnc(-n5c6ccccc6c6c7sc8ccccc8c7ccc65)n4)c3)cc2)cc1 ; c1ccc(-c2cc(-c3ccccc3)nc(-n3c4ccccc4c4ccc(-c5ccc6c(c5)c5ccccc5n6-c5ccccc5)cc43)n2)cc1 ; c1ccc(-c2nc(-c3ccccc3)nc(-c3ccc(-n4c5ccccc5c5c6ccccc6c6c7ccccc7sc6c54)cc3)n2)cc1]

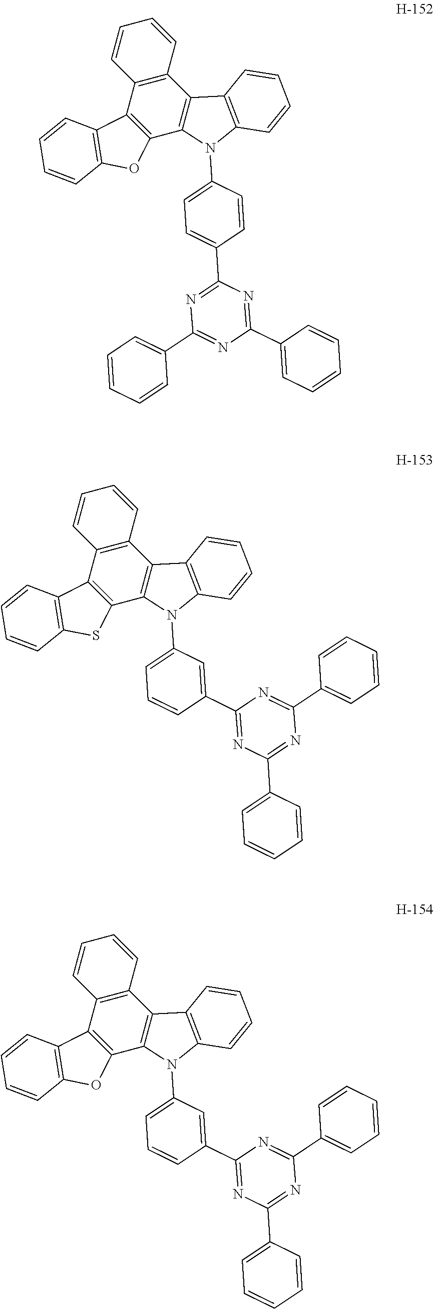 [SMILES: c1ccc(-c2nc(-c3ccccc3)nc(-c3ccc(-n4c5ccccc5c5c6ccccc6c6c7ccccc7oc6c54)cc3)n2)cc1 ; c1ccc(-c2nc(-c3ccccc3)nc(-c3cccc(-n4c5ccccc5c5c6ccccc6c6c7ccccc7sc6c54)c3)n2)cc1 ; c1ccc(-c2nc(-c3ccccc3)nc(-c3cccc(-n4c5ccccc5c5c6ccccc6c6c7ccccc7oc6c54)c3)n2)cc1]

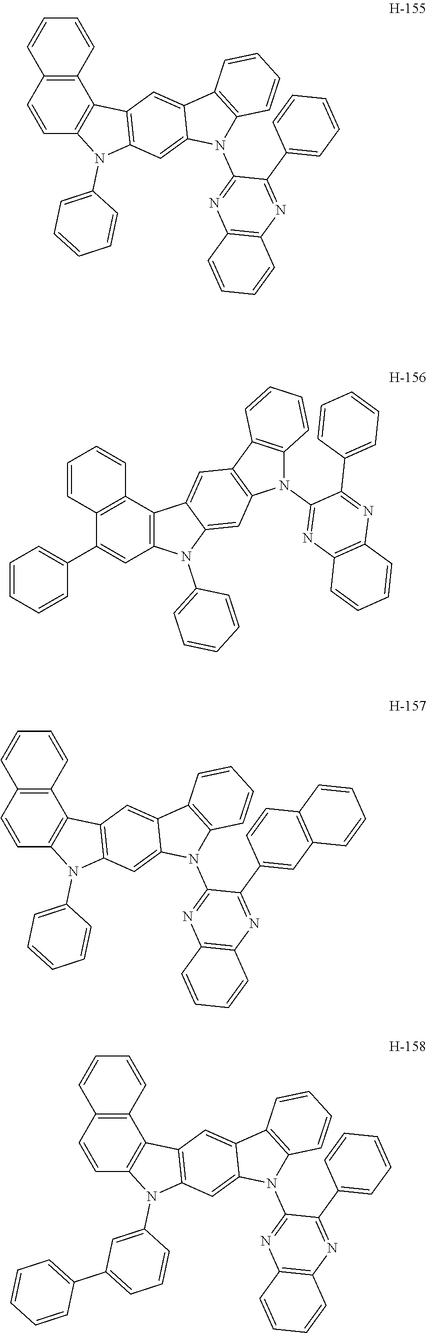 [SMILES: c1ccc(-c2nc3ccccc3nc2-n2c3ccccc3c3cc4c5c6ccccc6ccc5n(-c5ccccc5)c4cc32)cc1 ; c1ccc(-c2nc3ccccc3nc2-n2c3ccccc3c3cc4c5c6ccccc6c(-c6ccccc6)cc5n(-c5ccccc5)c4cc32)cc1 ; c1ccc(-n2c3cc4c(cc3c3c5ccccc5ccc32)c2ccccc2n4-c2nc3ccccc3nc2-c2ccc3ccccc3c2)cc1 ; c1ccc(-c2cccc(-n3c4cc5c(cc4c4c6ccccc6ccc43)c3ccccc3n5-c3nc4ccccc4nc3-c3ccccc3)c2)cc1]

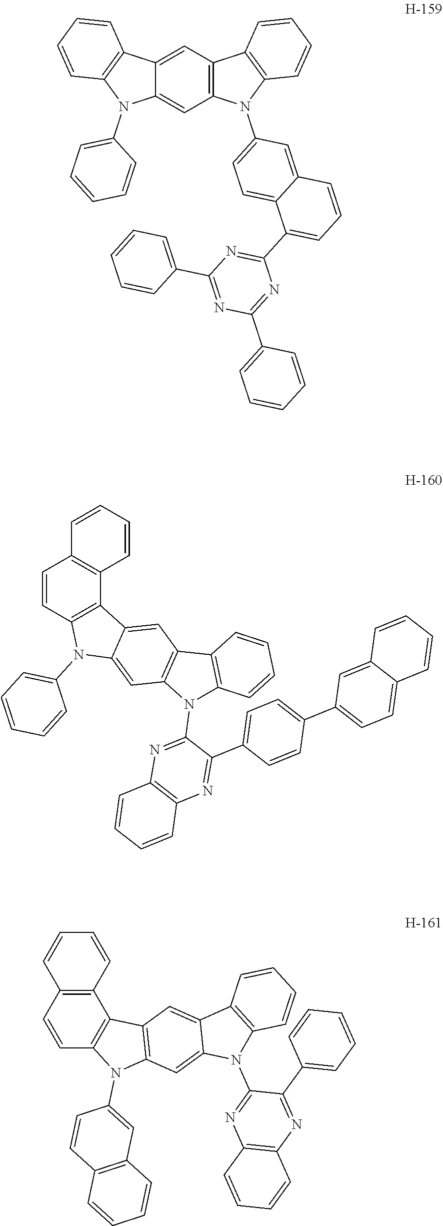 [SMILES: c1ccc(-c2nc(-c3ccccc3)nc(-c3cccc4cc(-n5c6ccccc6c6cc7c8ccccc8n(-c8ccccc8)c7cc65)ccc34)n2)cc1 ; c1ccc(-n2c3cc4c(cc3c3c5ccccc5ccc32)c2ccccc2n4-c2nc3ccccc3nc2-c2ccc(-c3ccc4ccccc4c3)cc2)cc1 ; c1ccc(-c2nc3ccccc3nc2-n2c3ccccc3c3cc4c5c6ccccc6ccc5n(-c5ccc6ccccc6c5)c4cc32)cc1]

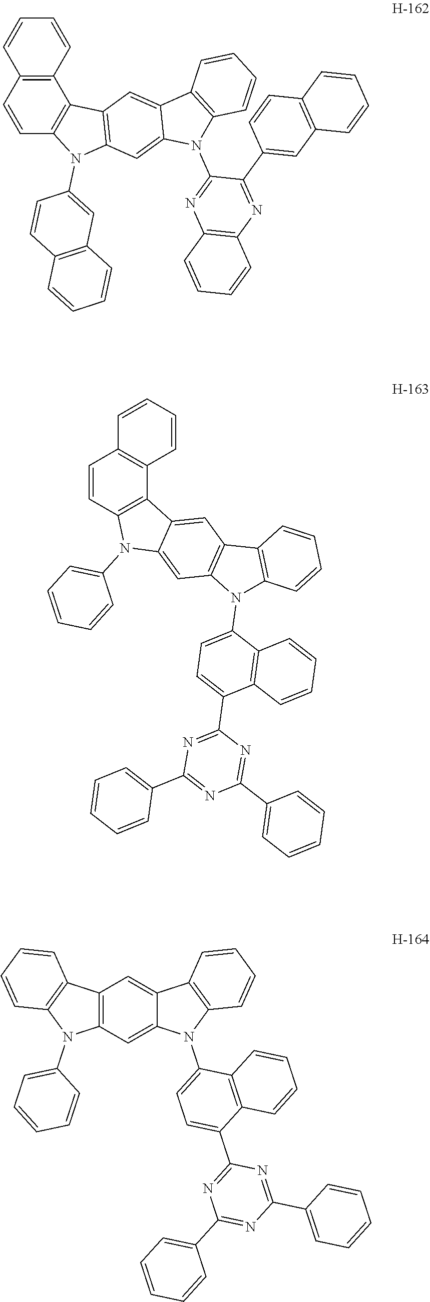 [SMILES: c1ccc2cc(-c3nc4ccccc4nc3-n3c4ccccc4c4cc5c6c7ccccc7ccc6n(-c6ccc7ccccc7c6)c5cc43)ccc2c1 ; c1ccc(-c2nc(-c3ccccc3)nc(-c3ccc(-n4c5ccccc5c5cc6c7c8ccccc8ccc7n(-c7ccccc7)c6cc54)c4ccccc34)n2)cc1 ; c1ccc(-c2nc(-c3ccccc3)nc(-c3ccc(-n4c5ccccc5c5cc6c7ccccc7n(-c7ccccc7)c6cc54)c4ccccc34)n2)cc1]

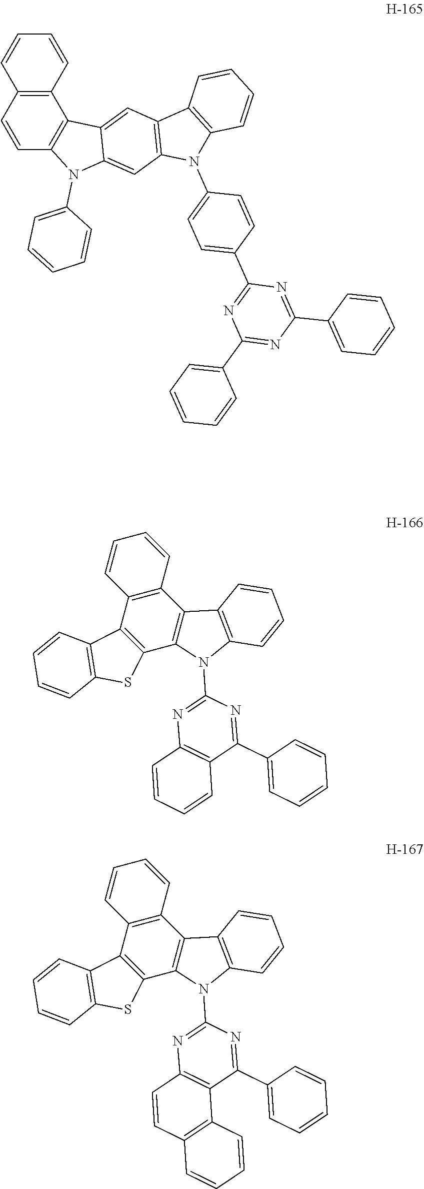 [SMILES: c1ccc(-c2nc(-c3ccccc3)nc(-c3ccc(-n4c5ccccc5c5cc6c7c8ccccc8ccc7n(-c7ccccc7)c6cc54)cc3)n2)cc1 ; c1ccc(-c2nc(-n3c4ccccc4c4c5ccccc5c5c6ccccc6sc5c43)nc3ccccc23)cc1 ; c1ccc(-c2nc(-n3c4ccccc4c4c5ccccc5c5c6ccccc6sc5c43)nc3ccc4ccccc4c23)cc1]

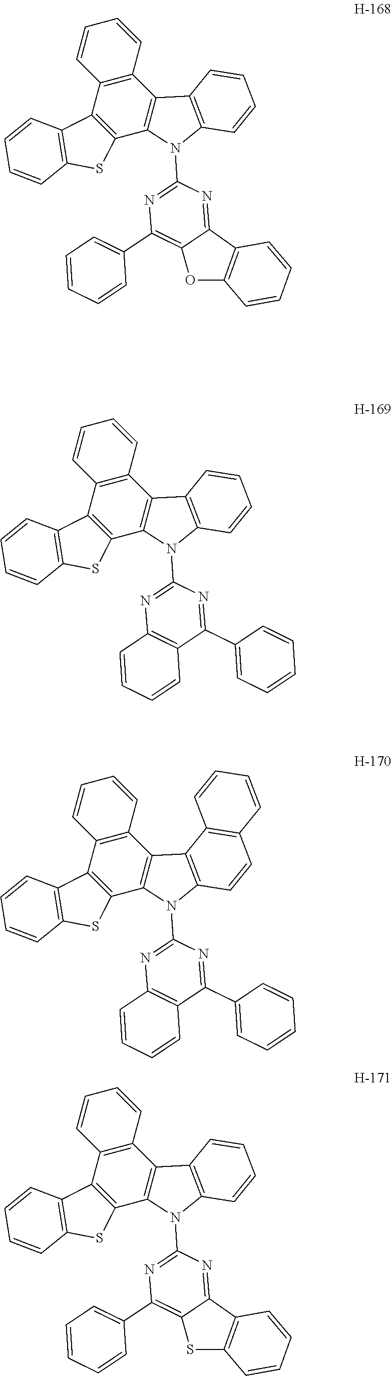

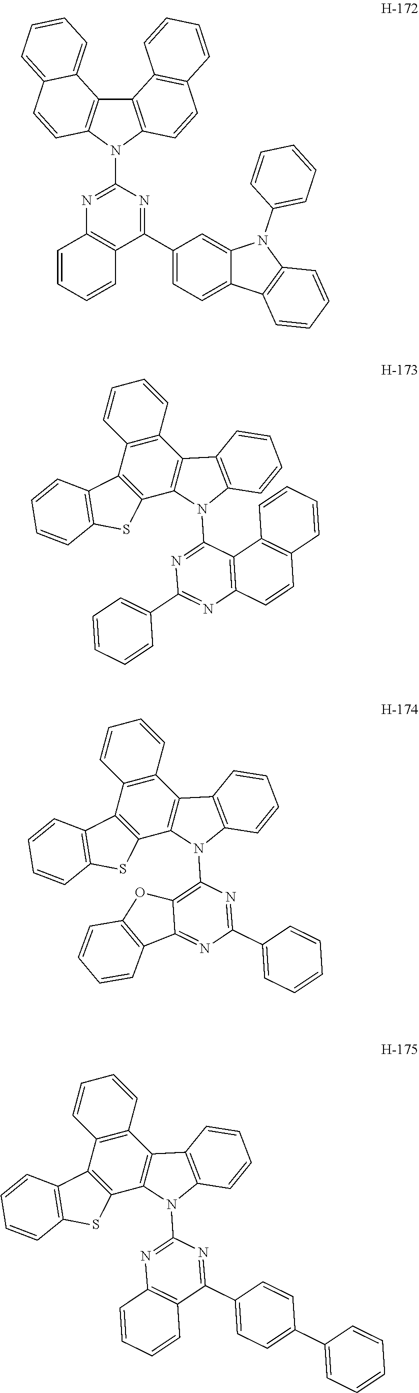 [SMILES: c1ccc(-n2c3ccccc3c3ccc(-c4nc(-n5c6ccc7ccccc7c6c6c7ccccc7ccc65)nc5ccccc45)cc32)cc1 ; c1ccc(-c2nc(-n3c4ccccc4c4c5ccccc5c5c6ccccc6sc5c43)c3c(ccc4ccccc43)n2)cc1 ; c1ccc(-c2nc(-n3c4ccccc4c4c5ccccc5c5c6ccccc6sc5c43)c3oc4ccccc4c3n2)cc1 ; c1ccc(-c2ccc(-c3nc(-n4c5ccccc5c5c6ccccc6c6c7ccccc7sc6c54)nc4ccccc34)cc2)cc1]

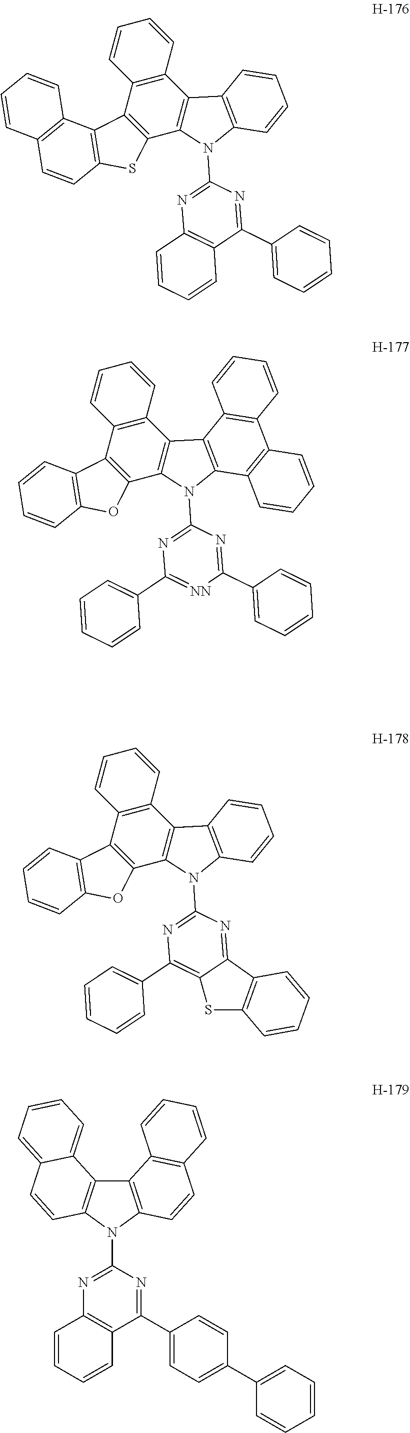

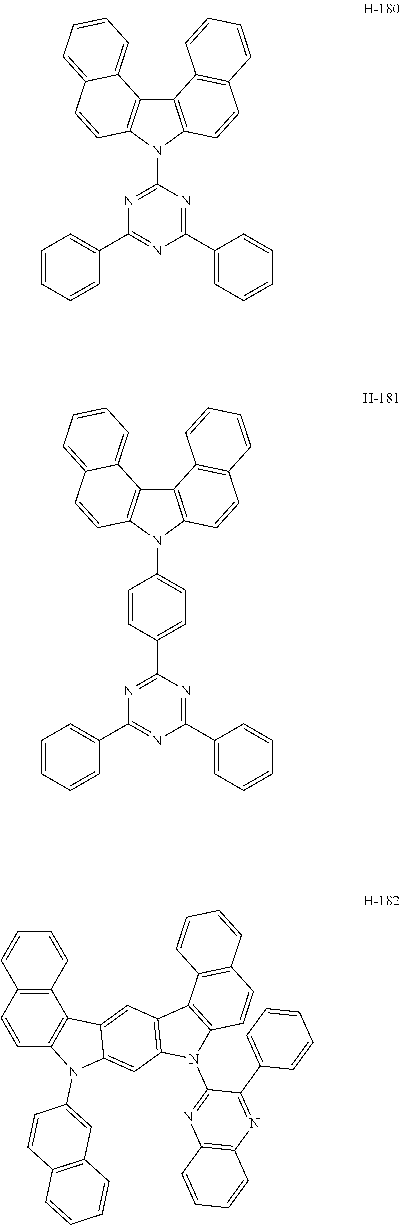 [SMILES: c1ccc(-c2nc(-c3ccccc3)nc(-n3c4ccc5ccccc5c4c4c5ccccc5ccc43)n2)cc1 ; c1ccc(-c2nc(-c3ccccc3)nc(-c3ccc(-n4c5ccc6ccccc6c5c5c6ccccc6ccc54)cc3)n2)cc1 ; c1ccc(-c2nc3ccccc3nc2-n2c3cc4c(cc3c3c5ccccc5ccc32)c2c3ccccc3ccc2n4-c2ccc3ccccc3c2)cc1]

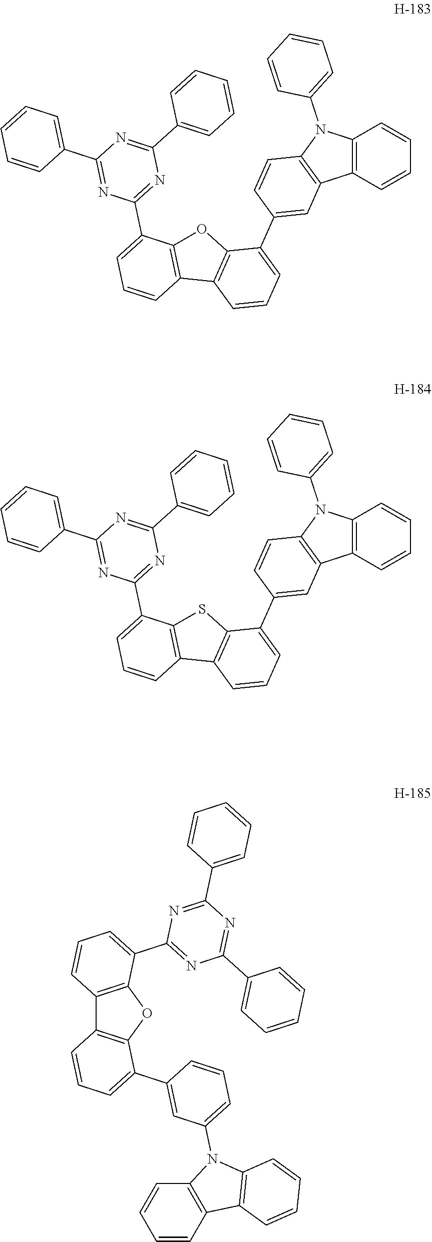 [SMILES: c1ccc(-c2nc(-c3ccccc3)nc(-c3cccc4c3oc3c(-c5ccc6c(c5)c5ccccc5n6-c5ccccc5)cccc34)n2)cc1 ; c1ccc(-c2nc(-c3ccccc3)nc(-c3cccc4c3sc3c(-c5ccc6c(c5)c5ccccc5n6-c5ccccc5)cccc34)n2)cc1 ; c1ccc(-c2nc(-c3ccccc3)nc(-c3cccc4c3oc3c(-c5cccc(-n6c7ccccc7c7ccccc76)c5)cccc34)n2)cc1]

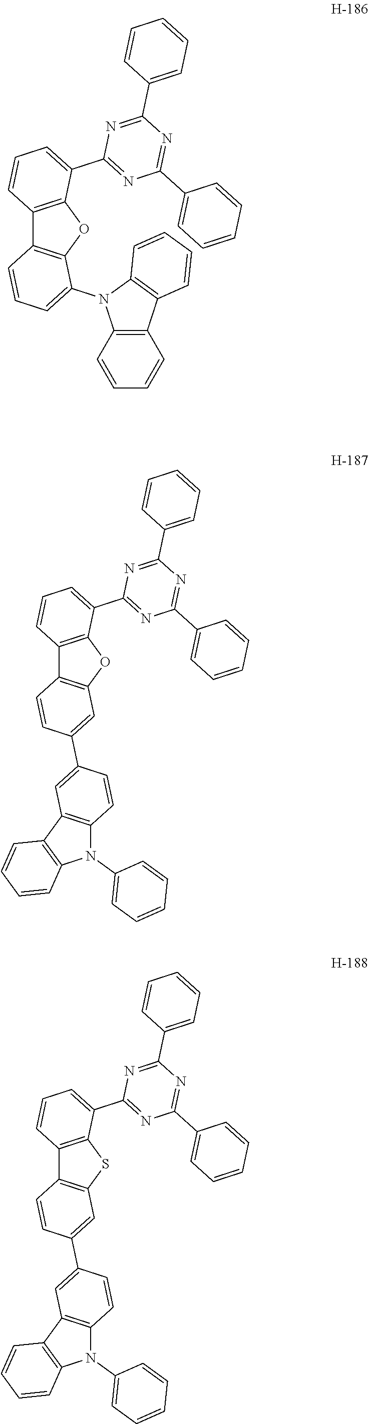 [SMILES: c1ccc(-c2nc(-c3ccccc3)nc(-c3cccc4c3oc3c(-n5c6ccccc6c6ccccc65)cccc34)n2)cc1 ; c1ccc(-c2nc(-c3ccccc3)nc(-c3cccc4c3oc3cc(-c5ccc6c(c5)c5ccccc5n6-c5ccccc5)ccc34)n2)cc1 ; c1ccc(-c2nc(-c3ccccc3)nc(-c3cccc4c3sc3cc(-c5ccc6c(c5)c5ccccc5n6-c5ccccc5)ccc34)n2)cc1]

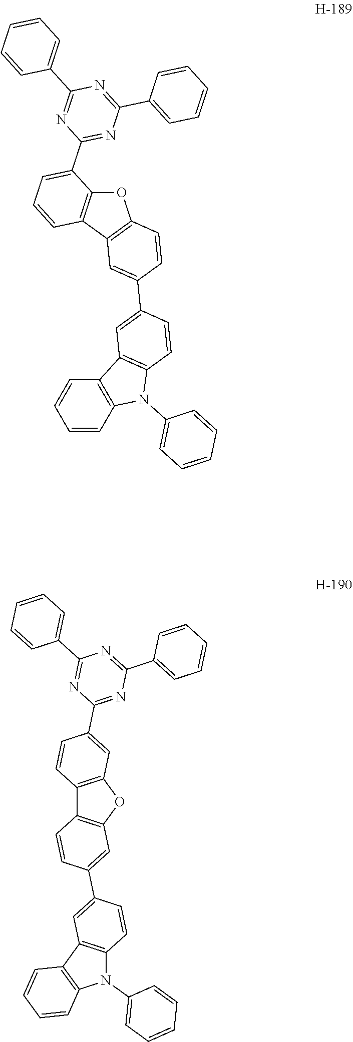 [SMILES: c1ccc(-c2nc(-c3ccccc3)nc(-c3cccc4c3oc3ccc(-c5ccc6c(c5)c5ccccc5n6-c5ccccc5)cc34)n2)cc1 ; c1ccc(-c2nc(-c3ccccc3)nc(-c3ccc4c(c3)oc3cc(-c5ccc6c(c5)c5ccccc5n6-c5ccccc5)ccc34)n2)cc1]

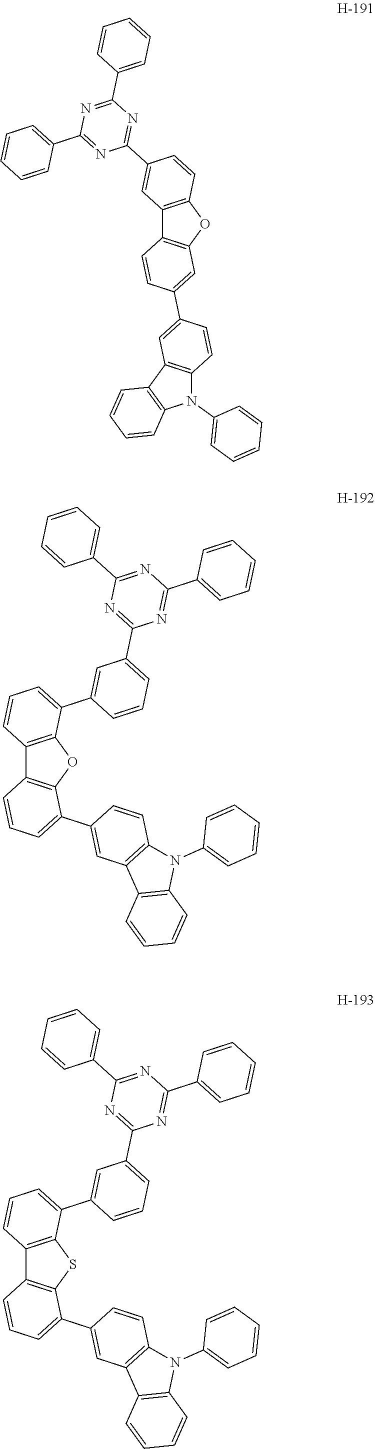 [SMILES: c1ccc(-c2nc(-c3ccccc3)nc(-c3ccc4oc5cc(-c6ccc7c(c6)c6ccccc6n7-c6ccccc6)ccc5c4c3)n2)cc1 ; c1ccc(-c2nc(-c3ccccc3)nc(-c3cccc(-c4cccc5c4oc4c(-c6ccc7c(c6)c6ccccc6n7-c6ccccc6)cccc45)c3)n2)cc1 ; c1ccc(-c2nc(-c3ccccc3)nc(-c3cccc(-c4cccc5c4sc4c(-c6ccc7c(c6)c6ccccc6n7-c6ccccc6)cccc45)c3)n2)cc1]

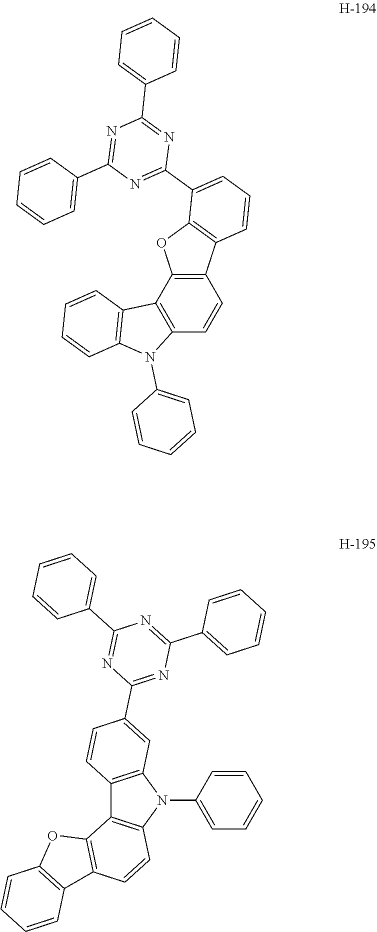 [SMILES: c1ccc(-c2nc(-c3ccccc3)nc(-c3cccc4c3oc3c4ccc4c3c3ccccc3n4-c3ccccc3)n2)cc1 ; c1ccc(-c2nc(-c3ccccc3)nc(-c3ccc4c5c6oc7ccccc7c6ccc5n(-c5ccccc5)c4c3)n2)cc1]

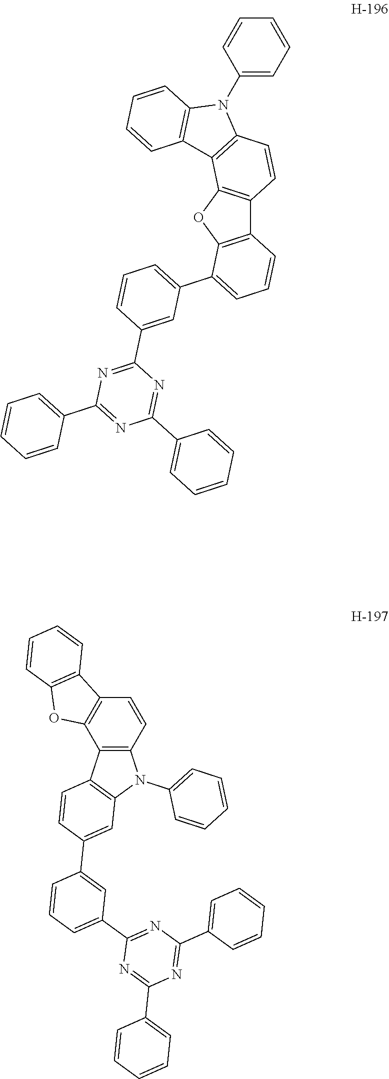 [SMILES: c1ccc(-c2nc(-c3ccccc3)nc(-c3cccc(-c4cccc5c4oc4c5ccc5c4c4ccccc4n5-c4ccccc4)c3)n2)cc1 ; c1ccc(-c2nc(-c3ccccc3)nc(-c3cccc(-c4ccc5c6c7oc8ccccc8c7ccc6n(-c6ccccc6)c5c4)c3)n2)cc1]

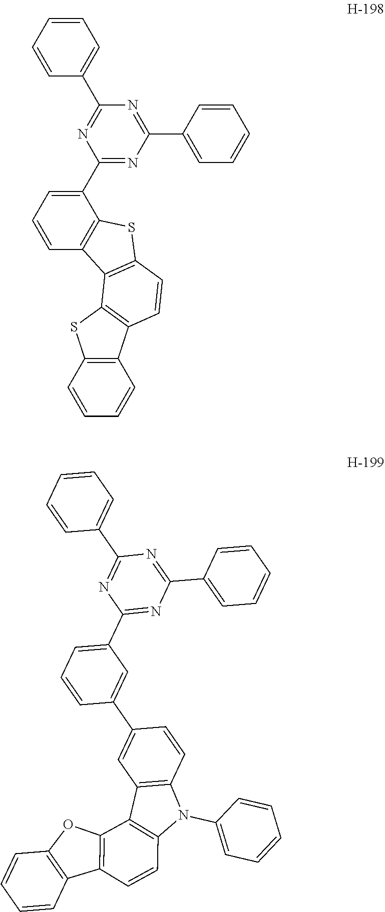 [SMILES: c1ccc(-c2nc(-c3ccccc3)nc(-c3cccc4c3sc3ccc5c6ccccc6sc5c34)n2)cc1 ; c1ccc(-c2nc(-c3ccccc3)nc(-c3cccc(-c4ccc5c(c4)c4c6oc7ccccc7c6ccc4n5-c4ccccc4)c3)n2)cc1]

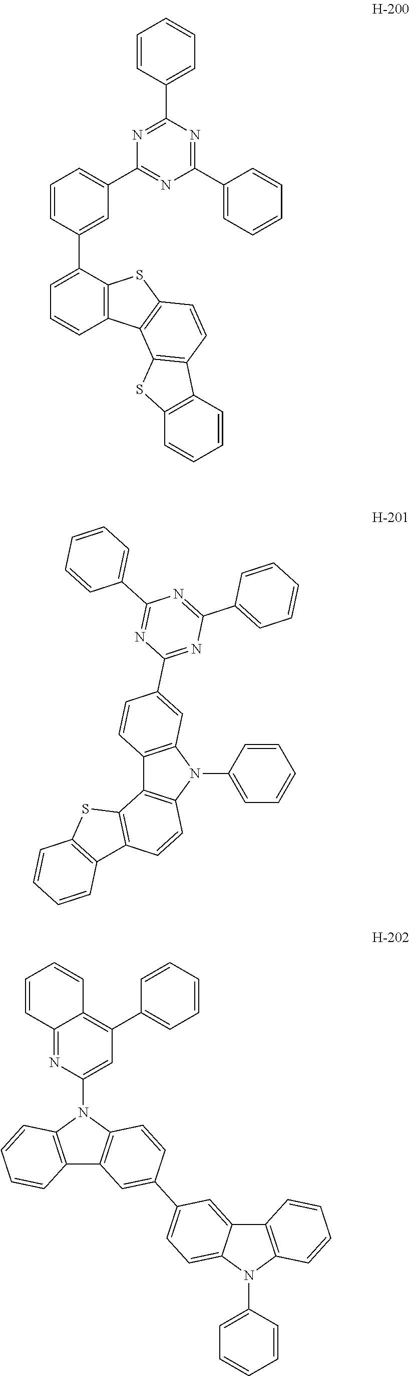 [SMILES: c1ccc(-c2nc(-c3ccccc3)nc(-c3cccc(-c4cccc5c4sc4ccc6c7ccccc7sc6c45)c3)n2)cc1 ; c1ccc(-c2nc(-c3ccccc3)nc(-c3ccc4c5c6sc7ccccc7c6ccc5n(-c5ccccc5)c4c3)n2)cc1 ; c1ccc(-c2cc(-n3c4ccccc4c4cc(-c5ccc6c(c5)c5ccccc5n6-c5ccccc5)ccc43)nc3ccccc23)cc1]

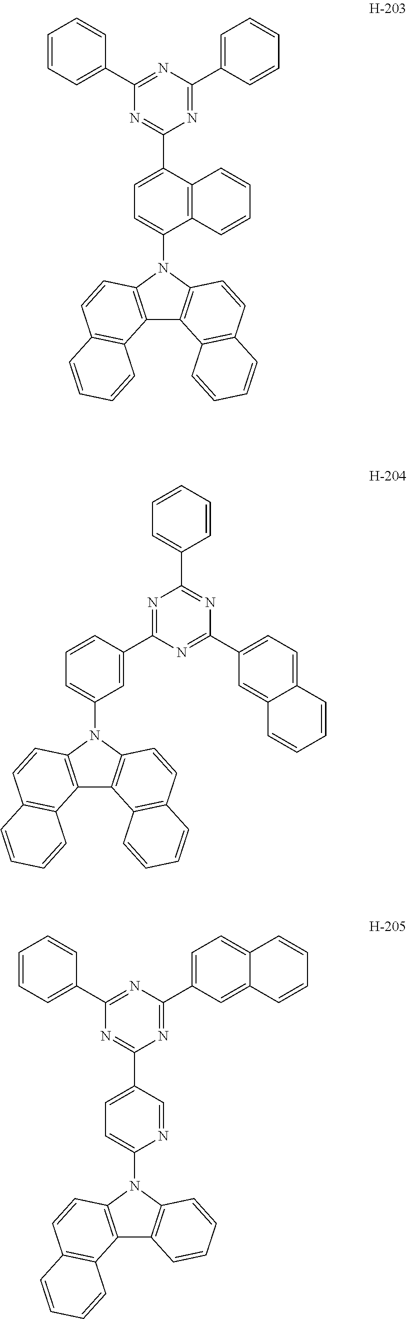 [SMILES: c1ccc(-c2nc(-c3ccccc3)nc(-c3ccc(-n4c5ccc6ccccc6c5c5c6ccccc6ccc54)c4ccccc34)n2)cc1 ; c1ccc(-c2nc(-c3cccc(-n4c5ccc6ccccc6c5c5c6ccccc6ccc54)c3)nc(-c3ccc4ccccc4c3)n2)cc1 ; c1ccc(-c2nc(-c3ccc(-n4c5ccccc5c5c6ccccc6ccc54)nc3)nc(-c3ccc4ccccc4c3)n2)cc1]

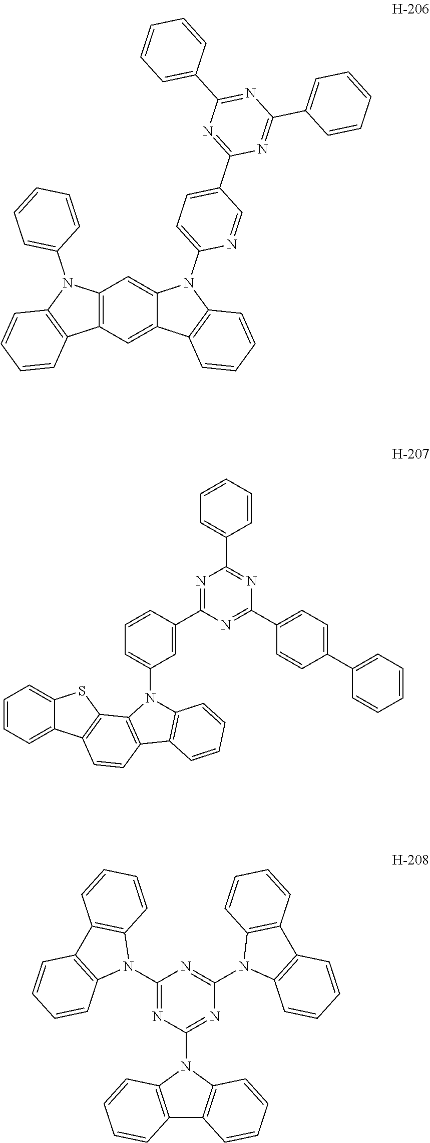 [SMILES: c1ccc(-c2nc(-c3ccccc3)nc(-c3ccc(-n4c5ccccc5c5cc6c7ccccc7n(-c7ccccc7)c6cc54)nc3)n2)cc1 ; c1ccc(-c2ccc(-c3nc(-c4ccccc4)nc(-c4cccc(-n5c6ccccc6c6ccc7c8ccccc8sc7c65)c4)n3)cc2)cc1 ; c1ccc2c(c1)c1ccccc1n2-c1nc(-n2c3ccccc3c3ccccc32)nc(-n2c3ccccc3c3ccccc32)n1]

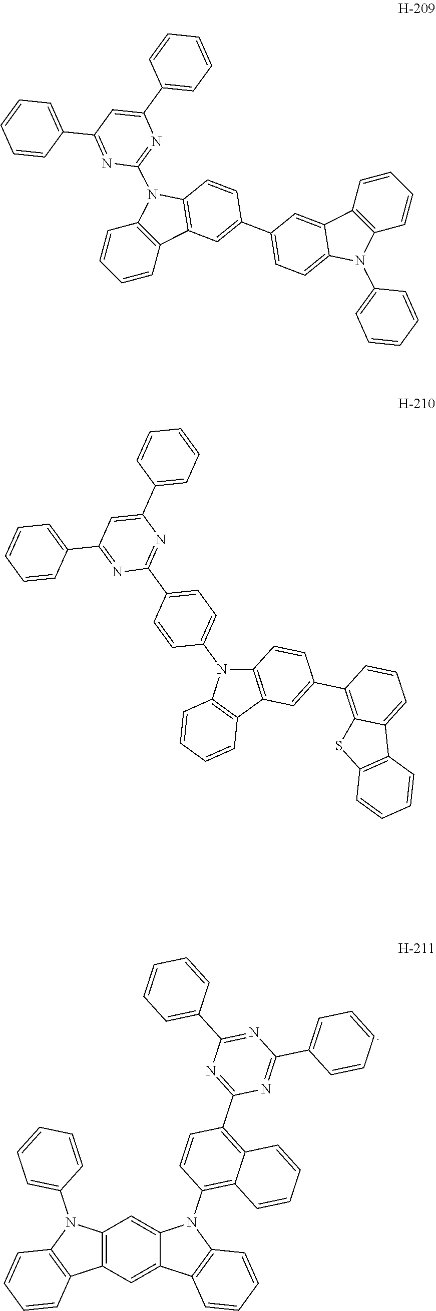 [SMILES: c1ccc(-c2cc(-c3ccccc3)nc(-n3c4ccccc4c4cc(-c5ccc6c(c5)c5ccccc5n6-c5ccccc5)ccc43)n2)cc1 ; c1ccc(-c2cc(-c3ccccc3)nc(-c3ccc(-n4c5ccccc5c5cc(-c6cccc7c6sc6ccccc67)ccc54)cc3)n2)cc1 ; c1ccc(-c2nc(-c3ccccc3)nc(-c3ccc(-n4c5ccccc5c5cc6c7ccccc7n(-c7ccccc7)c6cc54)c4ccccc34)n2)cc1]

### [Wherein, TPS Represents a Triphenylsilyl Group]

The organic electroluminescent material may further comprise at least one dopant. The dopant comprised in the organic electroluminescent material of the present disclosure may be at least one phosphorescent or fluorescence dopant, preferably phosphorescent dopant. The phosphorescent dopant material applied to the organic electroluminescent device of the present disclosure is not particularly limited, but may be preferably a metallated complex compound(s) of a metal atom(s) selected from iridium (Ir), osmium (Os), copper (Cu), and platinum (Pt), more preferably an ortho-metallated complex compound(s) of a metal atom(s) selected from iridium (Ir), osmium (Os), copper (Cu), and platinum (Pt), and even more preferably ortho-metallated iridium complex compound(s).

The compound represented by the following formula 101 may be used as the dopant, but is not limited thereto:

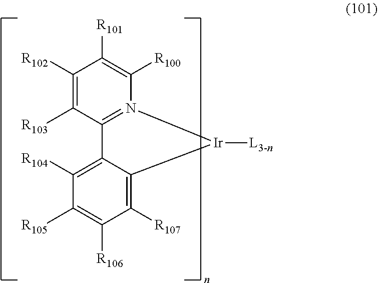

In formula 101,

wherein, L is selected from the following structure 1 or 2:

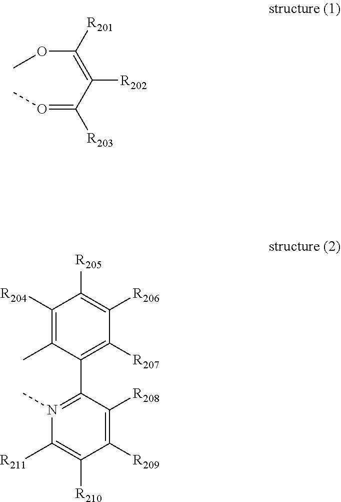

R₁₀₀ to R₁₀₃ each independently represent hydrogen, deuterium, halogen, halogen-substituted or unsubstituted (C1-C30)alkyl, a substituted or unsubstituted (C3-C30)cycloalkyl, a substituted or unsubstituted (C6-C30)aryl, cyano, a substituted or unsubstituted (3- to 30-membered)heteroaryl, or a substituted or unsubstituted (C1-C30)alkoxy; or R₁₀₀ to R₁₀₃ may be linked to an adjacent substituent(s) to form a substituted or unsubstituted fused ring, e.g., a substituted or unsubstituted quinoline, a substituted or unsubstituted benzofuropyridine, a substituted or unsubstituted benzothienopyridine, a substituted or unsubstituted indenopyridine, a substituted or unsubstituted benzofuroquinoline, a substituted or unsubstituted benzothienoquinoline, or a substituted or unsubstituted indenoquinoline;

R₁₀₄ to R₁₀₇ each independently represent hydrogen, deuterium, halogen, halogen-substituted or unsubstituted (C1-C30)alkyl, a substituted or unsubstituted (C3-C30)cycloalkyl, a substituted or unsubstituted (C6-C30)aryl, a substituted or unsubstituted (3- to 30-membered)heteroaryl, cyano, or a substituted or unsubstituted (C1-C30)alkoxy; or R₁₀₄ to R₁₀₇ may be linked to an adjacent substituent(s) to form a substituted or unsubstituted fused ring, e.g., a substituted or unsubstituted naphthyl, a substituted or unsubstituted fluorene, a substituted or unsubstituted dibenzothiophene, a substituted or unsubstituted dibenzofuran, a substituted or unsubstituted indenopyridine, a substituted or unsubstituted benzofuropyridine, or a substituted or unsubstituted benzothienopyridine;

R₂₀₁ to R₂₁₁ each independently represent hydrogen, deuterium, halogen, halogen-substituted or unsubstituted (C1-C30)alkyl, a substituted or unsubstituted (C3-C30)cycloalkyl, or a substituted or unsubstituted (C6-C30)aryl; R₂₀₁ to R₂₁₁ may be linked to an adjacent substituent(s) to form a substituted or unsubstituted fused ring; and

n represents an integer of 1 to 3.

The specific examples of the dopant compound include the following, but are not limited thereto:

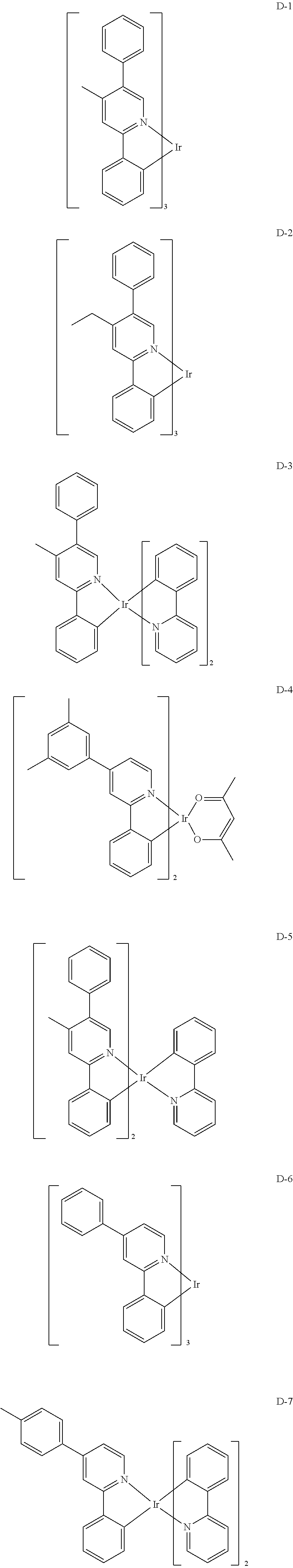

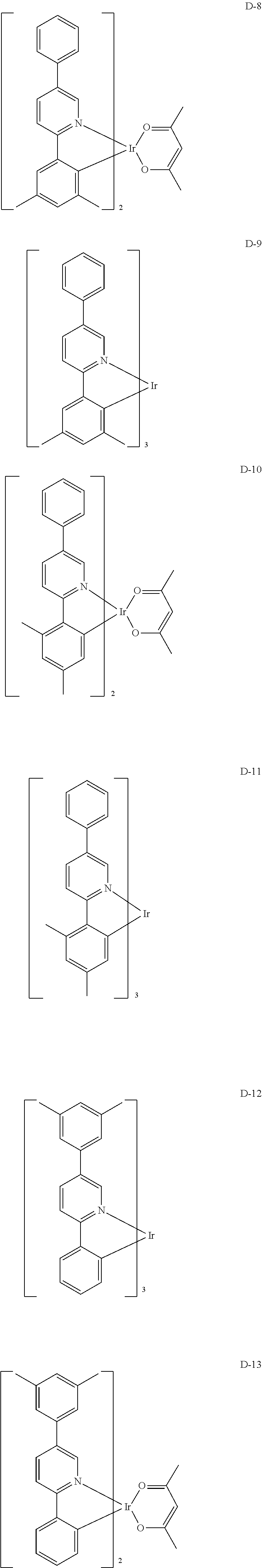

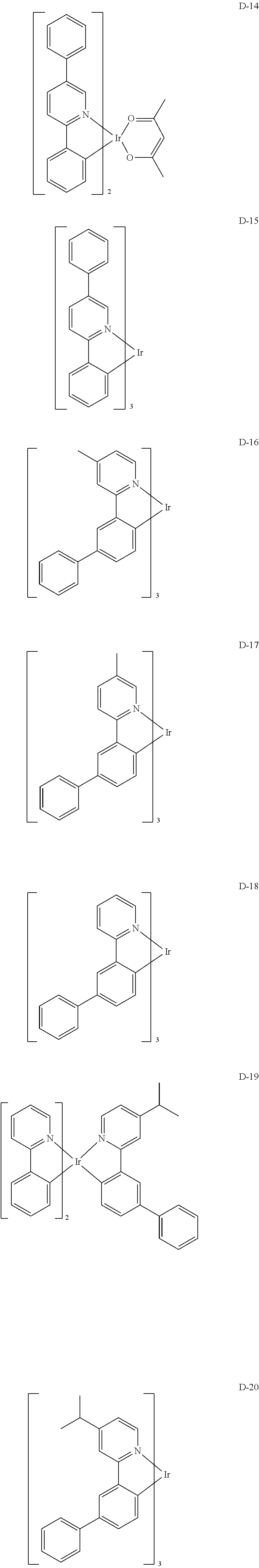

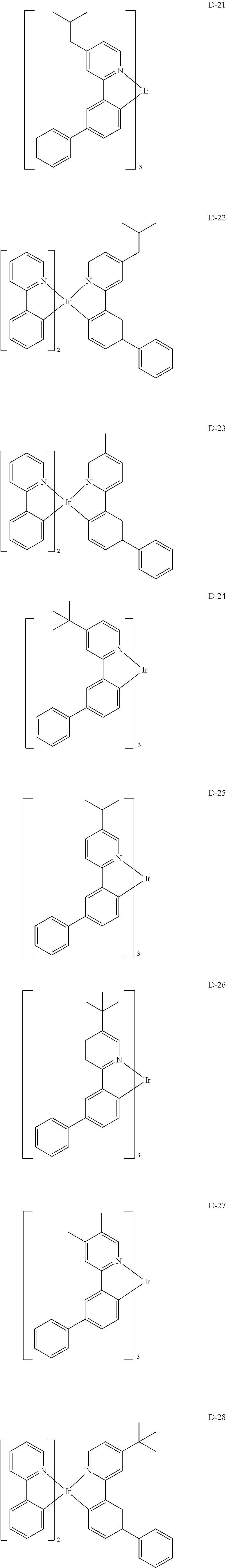

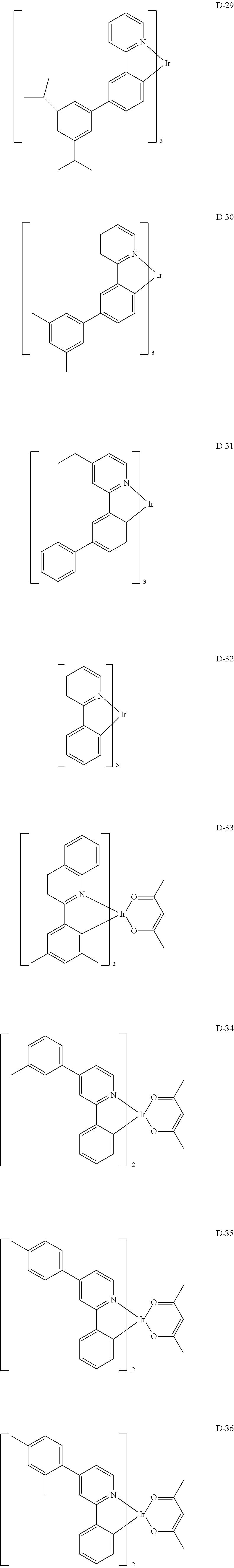

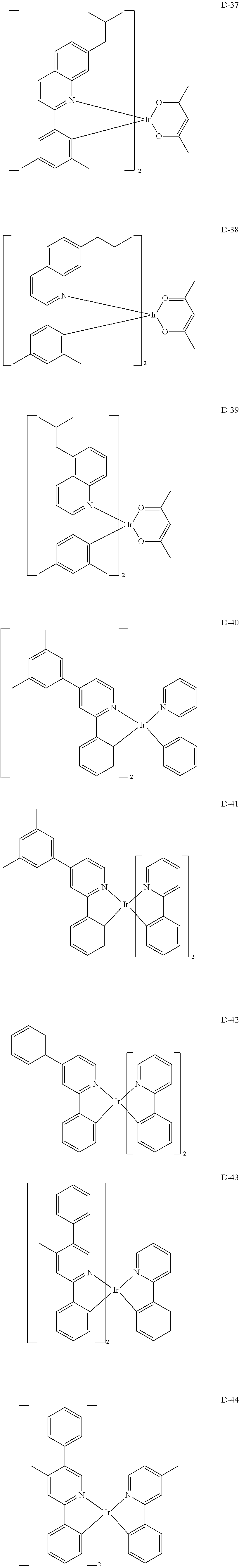

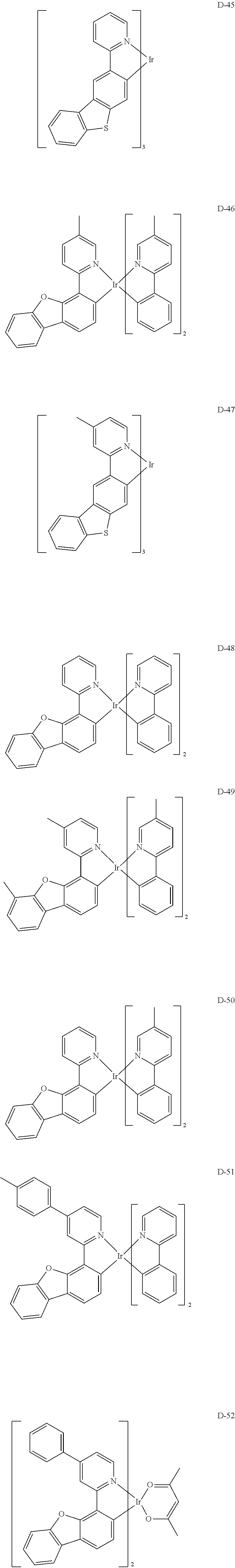

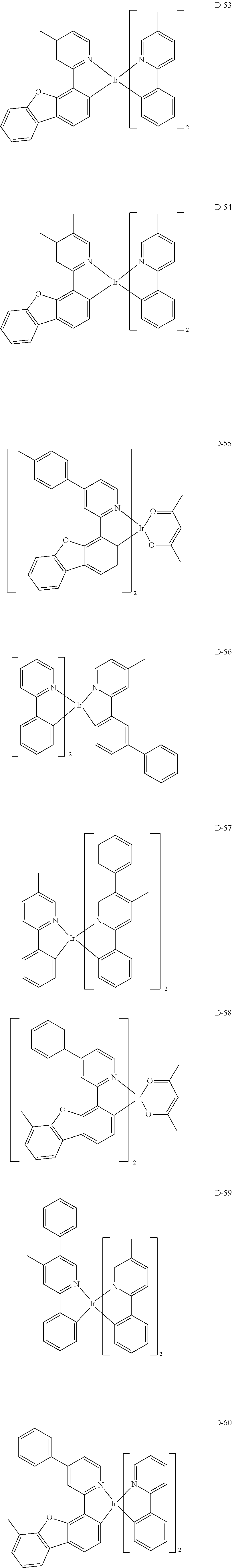

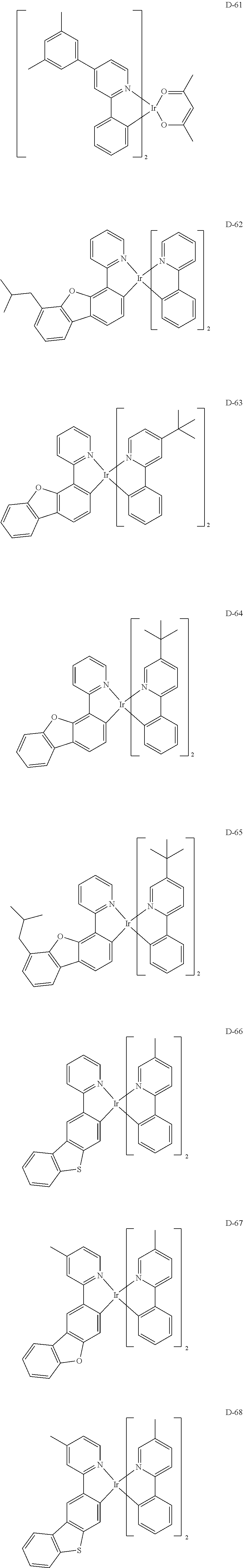

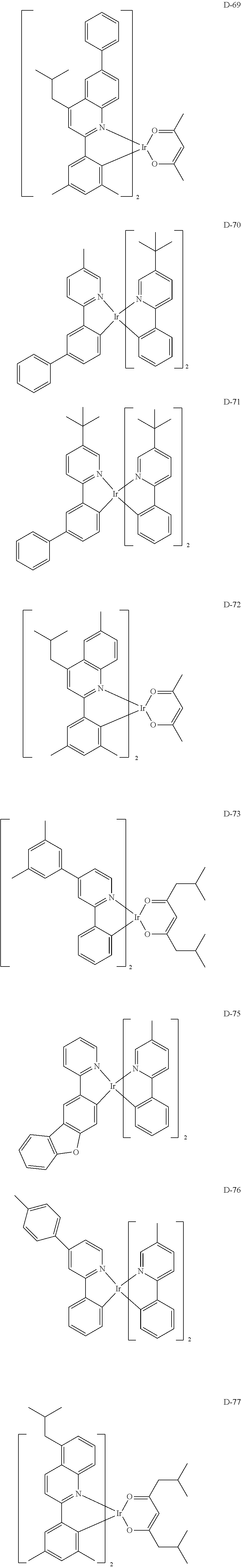

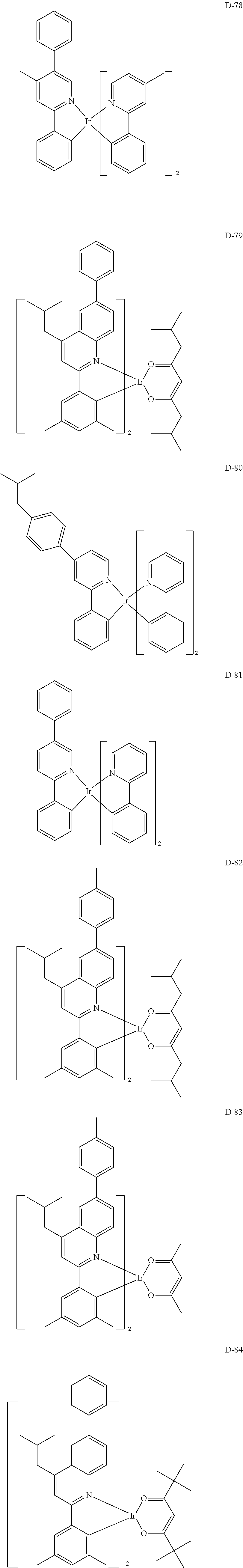

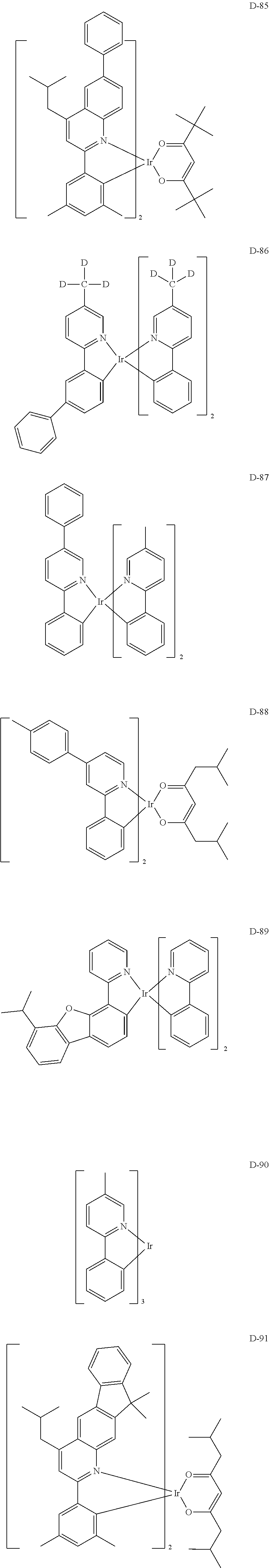

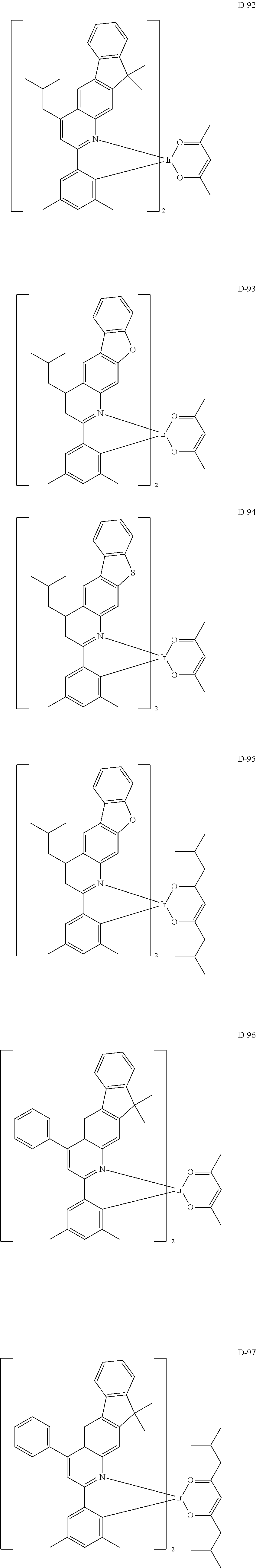

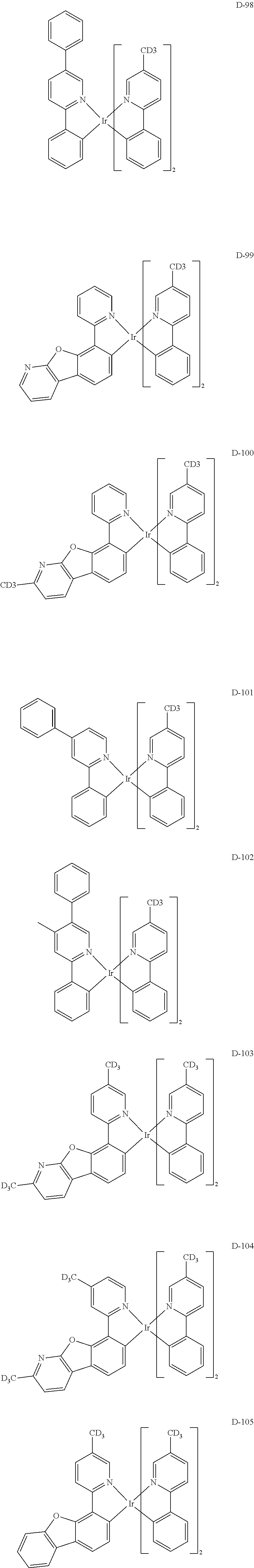

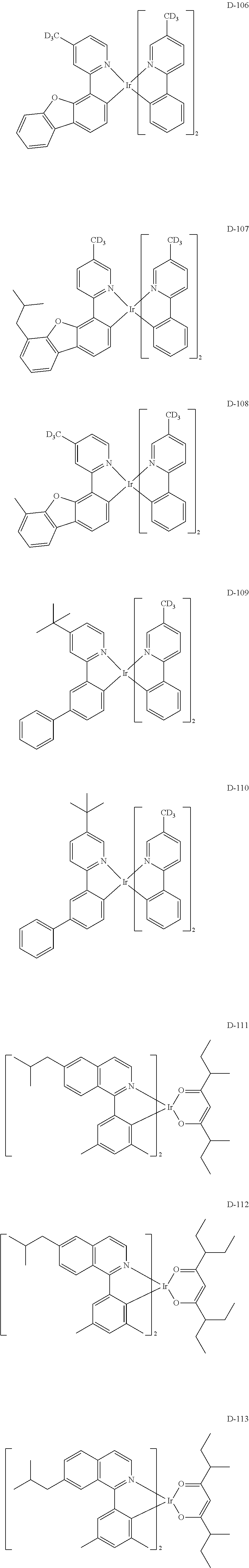

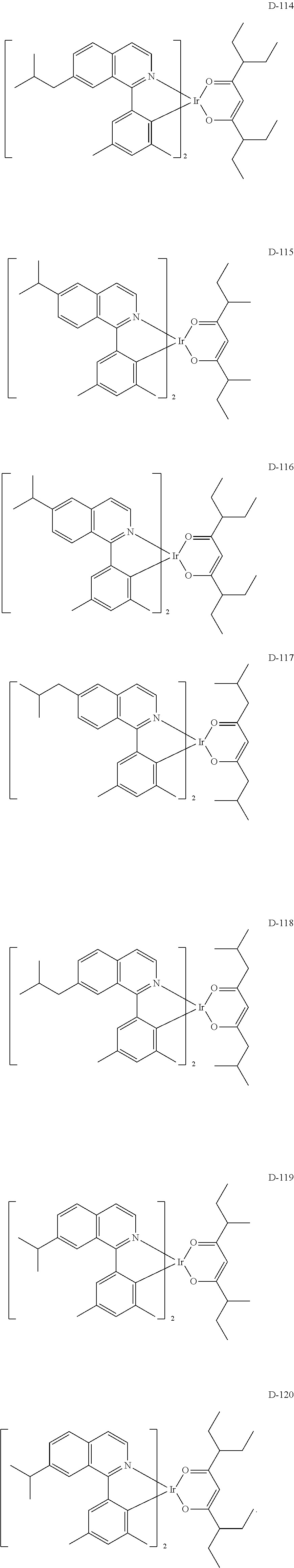

Hereinafter, an organic electroluminescent device to which the aforementioned organic electroluminescent compound or the organic electroluminescent material is applied will be explained.

The organic electroluminescent device according to the present disclosure includes a first electrode; a second electrode; and at least one organic layer interposed between the first electrode and the second electrode.

The organic electroluminescent compound of formula 1 of the present disclosure may be comprised in at least one layer constituting the organic electroluminescent device. According to one embodiment, the organic layer may comprise a hole transport layer and/or a hole auxiliary layer comprising the organic electroluminescent compound of formula 1. The hole transport layer and/or the hole auxiliary layer may be comprised solely of the organic electroluminescent compound of the present disclosure, or may be comprised of at least two species of the organic electroluminescent compounds; and may be further comprised of conventional materials included in the organic electroluminescent material.

The organic layer may comprise a hole transport layer and a hole auxiliary layer, and may further comprise at least one layer selected from a hole injection layer, a light-emitting layer, a light-emitting auxiliary layer, an electron transport layer, an electron injection layer, an interlayer, a hole blocking layer, an electron blocking layer, and an electron buffer layer, wherein each layer may be constituted of multi-layers. The organic layer may further comprise at least one compound selected from the group consisting of an arylamine-based compound and a styrylarylamine-based compound. Also, the organic layer may further comprise at least one metal selected from the group consisting of metals of Group 1, metals of Group 2, transition metals of the 4th period, transition metals of the 5th period, lanthanides, and organic metals of the d-transition elements of the Periodic Table, or at least one complex compound comprising such a metal.

An organic electroluminescent material according to one embodiment may be used as light-emitting materials for a white organic light-emitting device. The white organic light-emitting device has suggested various structures such as a parallel side-by-side arrangement method, a stacking arrangement method, or CCM (color conversion material) method, etc., according to the arrangement of R (Red), G (Green), B (blue), or YG (yellowish green) light-emitting units. In addition, the organic electroluminescent material according to one embodiment may be also applied to the organic electroluminescent device comprising QD (quantum dot).

One of the first electrode and the second electrode may be an anode and the other may be a cathode. Wherein, the first electrode and the second electrode may each be formed as a transmissive conductive material, a transflective conductive material, or a reflective conductive material. The organic electroluminescent device may be a top emission type, a bottom emission type, or a both-sides emission type according to the kinds of the material forming the first electrode and the second electrode.

A hole injection layer, a hole transport layer, an electron blocking layer, or a combination thereof can be used between the anode and the light-emitting layer. The hole injection layer may be multi-layers in order to lower the hole injection barrier (or hole injection voltage) from the anode to the hole transport layer or the electron blocking layer, wherein each of the multi-layers may use two compounds simultaneously. Further, the hole injection layer may be doped as p-dopant. Also, the electron blocking layer may be placed between the hole transport layer (or hole injection layer) and the light-emitting layer, and can confine the excitons within the light-emitting layer by blocking the overflow of electrons from the light-emitting layer to prevent a light-emitting leakage. The hole transport layer or the electron blocking layer may be multi-layers, wherein each layer may use a plurality of compounds.

An electron buffer layer, a hole blocking layer, an electron transport layer, an electron injection layer, or a combination thereof can be used between the light-emitting layer and the cathode. The electron buffer layer may be multi-layers in order to control the injection of the electron and improve the interfacial properties between the light-emitting layer and the electron injection layer, wherein each of the multi-layers may use two compounds simultaneously. The hole blocking layer or the electron transport layer may also be multi-layers, wherein each layer may use a plurality of compounds. Also, the electron injection layer may be doped as n-dopant.

The light-emitting auxiliary layer may be placed between the anode and the light-emitting layer, or between the cathode and the light-emitting layer. When the light-emitting auxiliary layer is placed between the anode and the light-emitting layer, it can be used for promoting the hole injection and/or the hole transport, or for preventing the overflow of electrons. When the light-emitting auxiliary layer is placed between the cathode and the light-emitting layer, it can be used for promoting the electron injection and/or the electron transport, or for preventing the overflow of holes. In addition, the hole auxiliary layer may be placed between the hole transport layer (or hole injection layer) and the light-emitting layer, and may be effective to promote or block the hole transport rate (or the hole injection rate), thereby enabling the charge balance to be controlled. When an organic electroluminescent device includes two or more hole transport layers, the hole transport layer, which is further included, may be used as the hole auxiliary layer or the electron blocking layer. The light-emitting auxiliary layer, the hole auxiliary layer, or the electron blocking layer may have an effect of improving the efficiency and/or the lifespan of the organic electroluminescent device.

In the organic electroluminescent device of the present disclosure, preferably, at least one layer (hereinafter, “a surface layer”) selected from a chalcogenide layer, a halogenated metal layer, and a metal oxide layer may be placed on an inner surface(s) of one or both electrode(s). Specifically, a chalcogenide (including oxides) layer of silicon and aluminum is preferably placed on an anode surface of an electroluminescent medium layer, and a halogenated metal layer or a metal oxide layer is preferably placed on a cathode surface of an electroluminescent medium layer. The operation stability for the organic electroluminescent device may be obtained by the surface layer. Preferably, the chalcogenide includes SiOₓ(1≤X≤2), AlOₓ(1≤X≤1.5), SiON, SiAION, etc.; the halogenated metal includes LiF, MgF₂, CaF₂, a rare earth metal fluoride, etc.; and the metal oxide includes Cs₂O, Li₂O, MgO, SrO, BaO, CaO, etc.

In addition, in the organic electroluminescent device of the present disclosure, a mixed region of an electron transport compound and a reductive dopant, or a mixed region of a hole transport compound and an oxidative dopant may be placed on at least one surface of a pair of electrodes. In this case, the electron transport compound is reduced to an anion, and thus it becomes easier to inject and transport electrons from the mixed region to an electroluminescent medium. Furthermore, the hole transport compound is oxidized to a cation, and thus it becomes easier to inject and transport holes from the mixed region to the electroluminescent medium. Preferably, the oxidative dopant includes various Lewis acids and acceptor compounds, and the reductive dopant includes alkali metals, alkali metal compounds, alkaline earth metals, rare-earth metals, and mixtures thereof. Also, a reductive dopant layer may be employed as a charge generating layer to produce an organic electroluminescent device having two or more light-emitting layers and emitting white light.

In order to form each layer of the organic electroluminescent device of the present disclosure, dry film-forming methods such as vacuum evaporation, sputtering, plasma, ion plating methods, etc., or wet film-forming methods such as ink jet printing, nozzle printing, slot coating, spin coating, dip coating, flow coating methods, etc., can be used.

When using a wet film-forming method, a thin film may be formed by dissolving or diffusing materials forming each layer into any suitable solvent such as ethanol, chloroform, tetrahydrofuran, dioxane, etc. The solvent may be any solvent where the materials forming each layer can be dissolved or diffused, and where there are no problems in film-formation capability.

Hereinafter, the preparation method of compounds according to the present disclosure will be explained with reference to the representative compound or the intermediate compound of the present disclosure in order to understand the present disclosure in detail.

### Example 1

### Preparation of Compound A-28

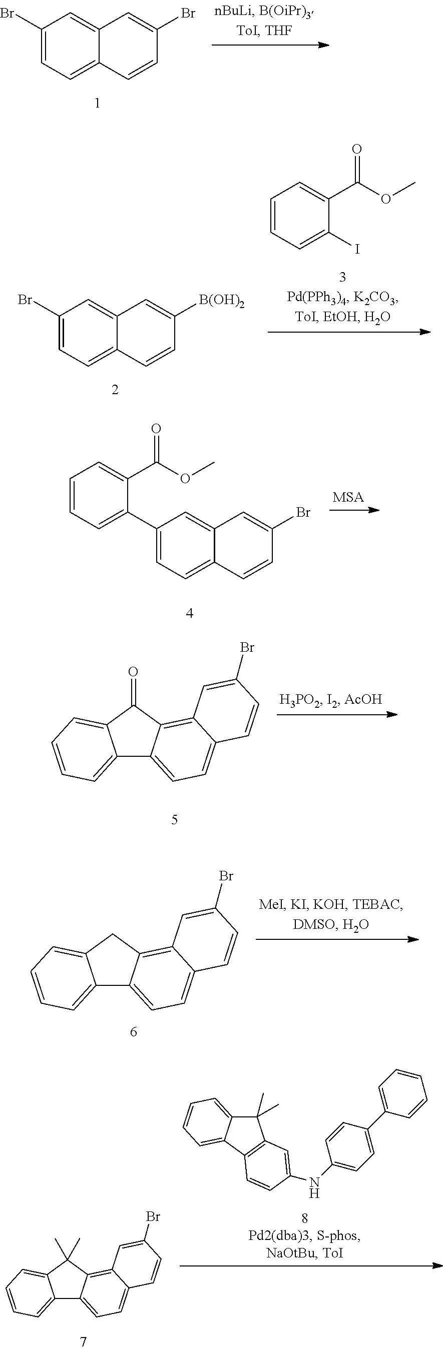

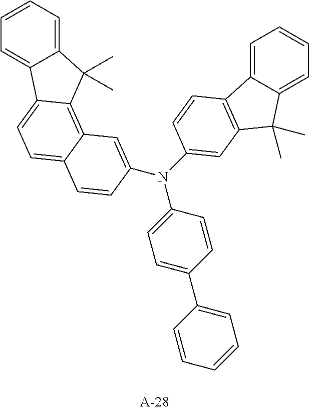 [SMILES: CC1(C)c2ccccc2-c2ccc(N(c3ccc(-c4ccccc4)cc3)c3ccc4ccc5c(c4c3)C(C)(C)c3ccccc3-5)cc21 ; "A-28"]

Preparation of Compound 2

Compound 1 (48.8 g, 170.7 mmol) was dissolved in toluene (640 mL) and tetrahydrofuran (THF) (210 mL) in a flask. Thereafter, triisopropyl borate (B(OiPr)₃) (99 mL, 426.8 mmol) was added to the flask, and then n-butyllithium (nBuLi) (102.0 mL, 256.0 mmol) was slowly added dropwise at −78° C. under a nitrogen atmosphere. After 12 hours, distilled water was added to terminate the reaction followed by extraction with EA/H₂O to obtain compound 2 (21.6 g, yield: 50%).

### Preparation of Compound 4

Compound 2 (21.6 g, 84.1 mmol), compound 3 (12.9 mL, 84.1 mmol), tetrakis(triphenylphosphine)palladium(0) (Pd(PPh₃)₄) (4.9 g, 4.3 mmol), potassium carbonate (K₂CO₃) (29.8 g, 215.3 mmol), 315 mL of THF, and 105 mL of H₂O were added to a flask and dissolved, and the mixture was refluxed and stirred for 3 hours. After completion of the reaction, the mixture was extracted with EA/H₂O, and thereafter purified by column chromatography to obtain compound 4 (29.4 g, yield: 100%).

### Preparation of Compound 5

Compound 4 (16.6 g, 48.7 mmol) and 150 mL of methane sulfonic acid (MSA) were added to a flask, and stirred for 18 hours at 70° C. After completion of the reaction, followed by adding the mixture dropwise to H₂O and filtration, compound 5 was obtained (12.8 g, yield: 85%).

### Preparation of Compound 6

Phosphoric acid (H₃PO₂) (7.2 mL, 66.2 mmol), iodine (I₂) (5.3 g, 20.7 mmol), and 207 mL of acetic acid (AcOH) were added to a flask, and refluxed and stirred for 1 hour, and then compound 5 (12.8 g, 41.4 mmol) was added to the flask and refluxed and stirred for 4 hours.

After completion of the reaction, the mixture was extracted with EA/H₂O, and thereafter purified by column chromatography to obtain compound 6 (11.9 g, yield: 97%).

### Preparation of Compound 7

Compound 6 (9.9 g, 33.5 mmol), potassium iodide (KI) (556 mg, 3.4 mmol), potassium hydroxide (KOH) (9.4 g, 167.5 mmol), benzyltriethyl ammoniumchloride (TEBAC) (382 mg, 1.7 mmol), 168 mL of dimethyl sulfonic acid (DMSO), and 17 mL of H₂O were added in a flask and stirred for 30 minutes at room temperature, and then methyl iodide (MeI) (5.2 mL, 83.8 mmol) was added to the flask and stirred for 22 hours at room temperature. After completion of the reaction, the mixture was extracted with EA/H₂O, and thereafter purified by column chromatography to obtain compound 7 (5.6 g, yield: 52%).

### Preparation of Compound A-28

Compound 7 (5.6 g, 17.3 mmol), compound 8 (6.9 g, 19.1 mmol), tris (dibenzylideneacetone)dipalladium(0) (Pd₂(dba)₃) (792 mg, 0.87 mmol), 2-dicyclohexylphosphino-2′,6′-dimethoxybiphenyl (S-phos) (710 mg, 1.7 mmol), sodium-tert-butoxide (NaOtBu) (4.2 g, 43.3 mmol), and 87 mL of toluene were added to a flask and refluxed and stirred for 30 minutes. After completion of the reaction, the mixture was extracted with EA/H₂O, and thereafter purified by column chromatography to obtain compound A-28 (4.5 g, yield: 43%).

| | MW | M.P. |
|---|---|---|
| A-28 | 603.81 | 147° C. |

### Example 2

### Preparation of Compound A-29

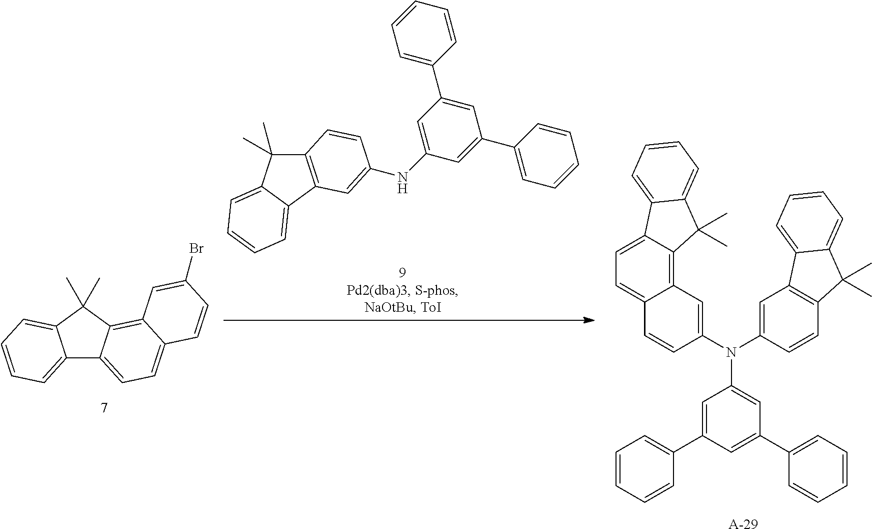

Compound 7 (4.0 g, 12.4 mmol), compound 9 (6.0 g, 13.6 mmol), Pd₂(dba)₃ (568 mg, 0.62 mmol), S-phos (509 mg, 1.24 mmol), NaOtBu (3.0 g, 31.0 mmol), and 62 mL of toluene were added to a flask and stirred for 30 minutes at room temperature. After completion of the reaction, the mixture was extracted with EA/H₂O, and thereafter purified by column chromatography to obtain compound A-29 (5.9 g, yield: 70%).

| | MW | M.P. |
|---|---|---|
| A-29 | 679.89 | 175° C. |

### Example 3

### Preparation of Compound A-27

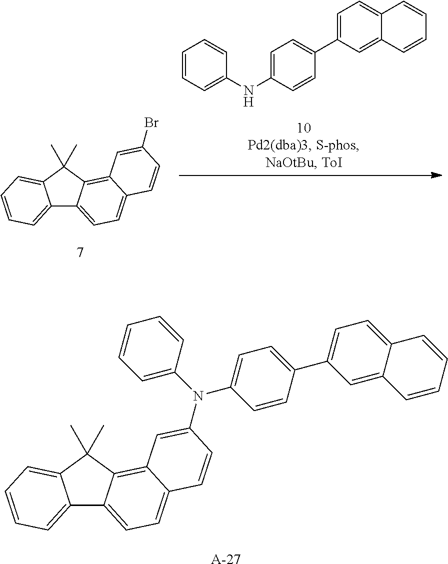 [SMILES: c1ccc(Nc2ccc(-c3ccc4ccccc4c3)cc2)cc1 ; CC1(C)c2ccccc2-c2ccc3ccc(Br)cc3c21 ; CC1(C)c2ccccc2-c2ccc3ccc(N(c4ccccc4)c4ccc(-c5ccc6ccccc6c5)cc4)cc3c21 ; "A-27"]

### Preparation of Compound A-27

Compound 7 (4.0 g, 12.4 mmol), compound 10 (4.0 g, 13.6 mmol), Pd₂(dba)₃ (568 mg, 0.62 mmol), S-phos (509 mg, 1.24 mmol), NaOtBu (2.4 g, 24.8 mmol), and 62 mL of toluene were added to a flask and stirred for 30 minutes at room temperature. After completion of the reaction, the mixture was extracted with EA/H₂O, and thereafter purified by column chromatography to obtain compound A-27 (5.0 g, yield: 75%).

| | MW | M.P. |
|---|---|---|
| A-27 | 537.69 | 205° C. |

### Example 4

### Preparation of Compound A-67

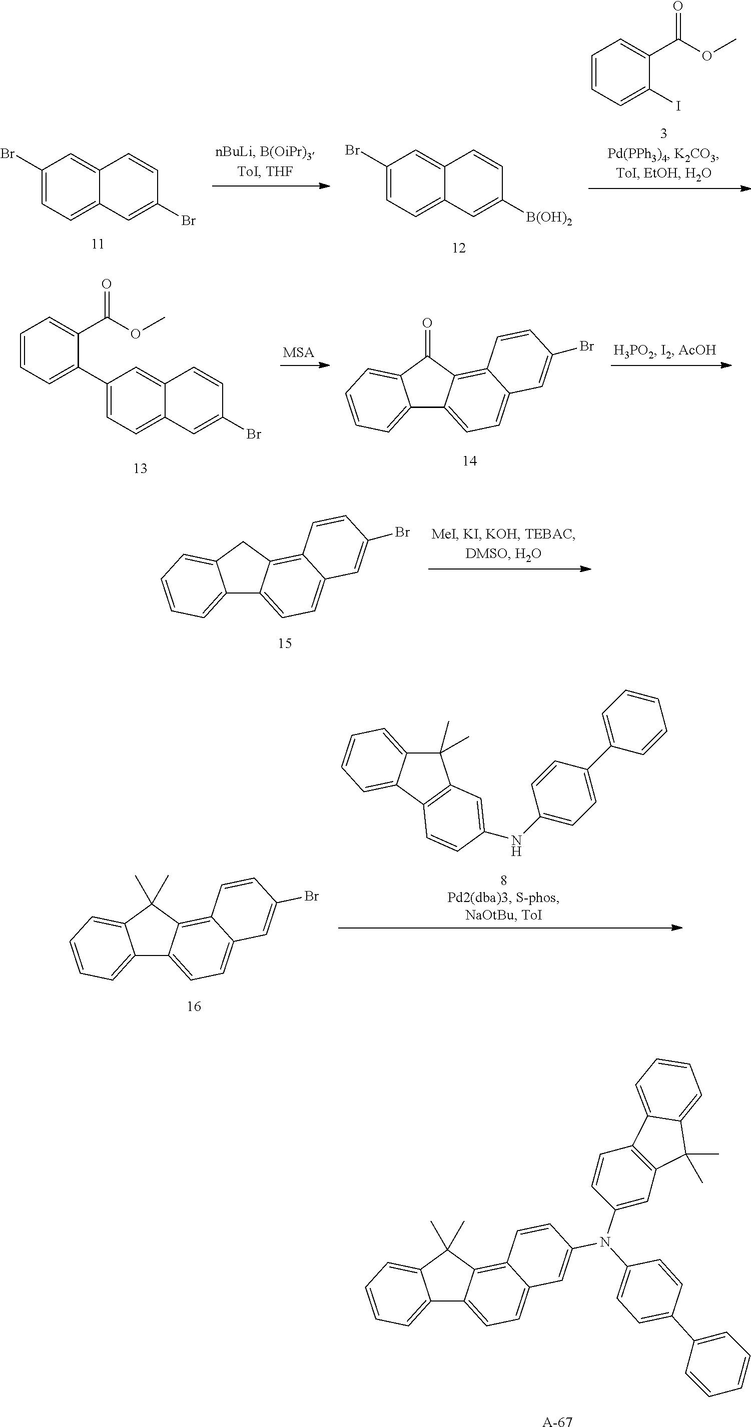

### Preparation of Compound 12

Compound 11 (50.0 g, 174.8 mmol) was dissolved in toluene (650 mL) and THF (220 mL) in a flask. Thereafter, B(OiPr)₃ (100 mL, 437.0 mmol) was added dropwise to the flask, and then n-BuLi (100.0 mL, 262.3 mmol) was slowly added dropwise at −78° C. under a nitrogen atmosphere. After 12 hours, distilled water was added to terminate the reaction followed by extraction with EA/H₂O to obtain compound 12 (28.5 g, yield: 65%).

### Preparation of Compound 13

Compound 12 (28.5 g, 84.1 mmol), compound 3 (16.6 mL, 113.6 mmol), Pd(PPh₃)₄ (6.6 g, 5.7 mmol), K₂CO₃ (39.3 g, 284.0 mmol), 570 mL of THF, and 140 mL of H₂O were added to a flask and dissolved, and the mixture was refluxed and stirred for 6 hours. After completion of the reaction, the mixture was extracted with EA/H₂O, and thereafter purified by column chromatography to obtain compound 13 (14.5 g, yield: 37%).

### Preparation of Compound 14

Compound 13 (14.5 g, 42.5 mmol) and 170 mL of MSA were added to a flask and stirred for 18 hours at 70° C. After completion of the reaction, followed by adding the mixture dropwise to H₂O and filtration, compound 14 was obtained (12.4 g, yield: 92%).

### Preparation of Compound 15

H₃PO₂ (7.0 mL, 64.2 mmol), I₂ (5.3 g, 20.7 mmol), and 200 mL of AcOH were added in a flask, and refluxed and stirred for 1 hour, and then compound 14 (12.4 g, 40.1 mmol) was added to the flask, and refluxed and stirred for 18 hours. After completion of the reaction, the mixture was extracted with EA/H₂O, and thereafter purified by column chromatography to obtain compound 15 (10.3 g, yield: 87%).

### Preparation of Compound 16

Compound 15 (10.3 g, 14.9 mmol), KI (579 mg, 3.5 mmol), KOH (9.8 g, 174.5 mmol), TEBAC (397 mg, 1.8 mmol), 175 mL of DMSO, and 17 mL of H₂O were added to a flask and stirred for 30 minutes at room temperature, and then MeI (5.4 mL, 87.2 mmol) was added to the flask and stirred for 19 hours at room temperature. After completion of the reaction, the mixture was extracted with EA/H₂O, and thereafter purified by column chromatography to obtain compound 16 (8.8 g, yield: 78%).

### Preparation of Compound A-67

Compound 16 (3.5 g, 10.8 mmol), compound 8 (4.3 g, 11.9 mmol), Pd ₂(dba)₃ (494 mg, 0.54 mmol), S-phos (443 mg, 1.08 mmol), NaOtBu (2.6 g, 27.0 mmol), and 54 mL of toluene were added to a flask and refluxed and stirred for 35 minutes. After completion of the reaction, the mixture was extracted with EA/H₂O, and thereafter purified by column chromatography to obtain compound A-67 (6.0 g, yield: 92%).

| | MW | M.P |
|---|---|---|
| A-67 | 603.81 | 159° C. |

### Example 5

### Preparation of Compound A-66

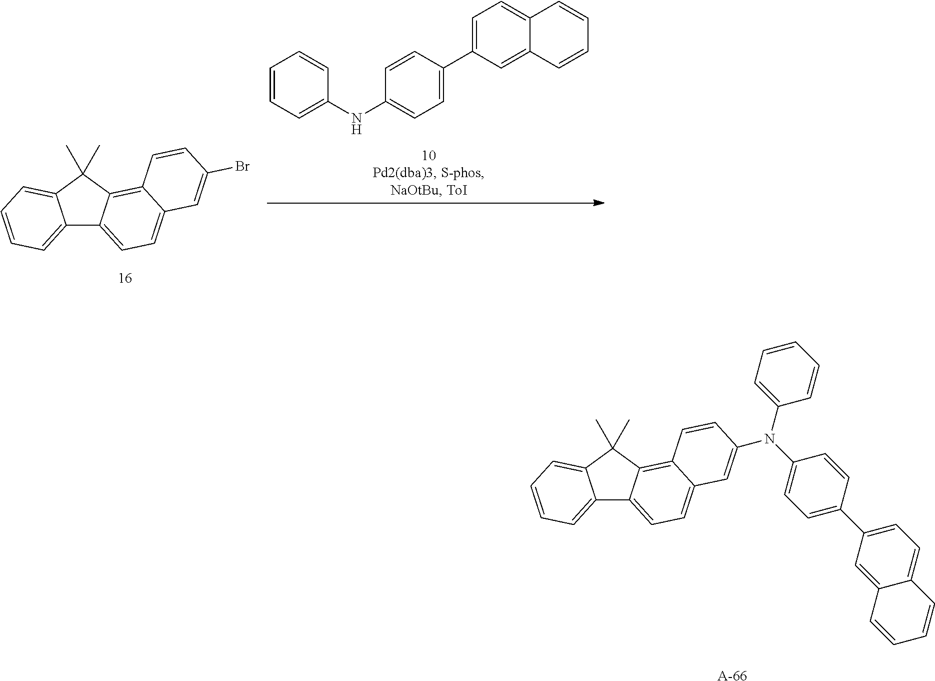 [SMILES: c1ccc(Nc2ccc(-c3ccc4ccccc4c3)cc2)cc1 ; CC1(C)c2ccccc2-c2ccc3cc(Br)ccc3c21 ; CC1(C)c2ccccc2-c2ccc3cc(N(c4ccccc4)c4ccc(-c5ccc6ccccc6c5)cc4)ccc3c21 ; "A-66"]

### Preparation of Compound A-66

Compound 16 (3.7 g, 11.4 mmol), compound 10 (3.7 g, 12.6 mmol), Pd₂(dba)₃ (522 mg, 0.57 mmol), S-phos (468 mg, 1.14 mmol), NaOtBu (2.7 g, 28.5 mmol), and 57 mL of toluene were added to a flask and refluxed and stirred for 1 hour. After completion of the reaction, the mixture was extracted with EA/H₂O, and thereafter purified by column chromatography to obtain compound A-66 (3.5 g, yield: 57%).

| | MW | M.P |
|---|---|---|
| A-66 | 537.69 | 119° C. |

### Example 6

### Preparation of Compound A-44

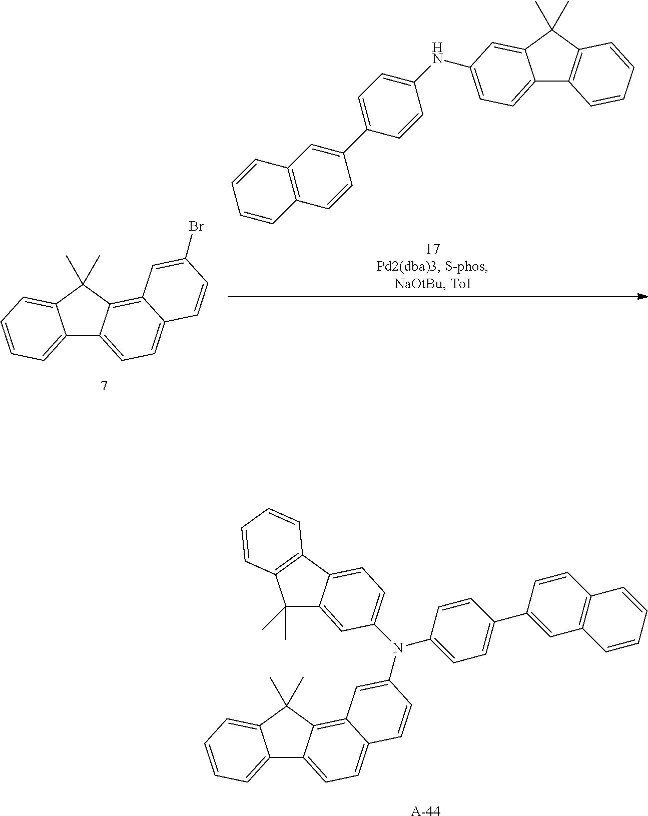 [SMILES: CC1(C)c2ccccc2-c2ccc(Nc3ccc(-c4ccc5ccccc5c4)cc3)cc21 ; CC1(C)c2ccccc2-c2ccc3ccc(Br)cc3c21 ; CC1(C)c2ccccc2-c2ccc(N(c3ccc(-c4ccc5ccccc5c4)cc3)c3ccc4ccc5c(c4c3)C(C)(C)c3ccccc3-5)cc21 ; "A-44"]

### Preparation of Compound A-44

Compound 7 (4.3 g, 13.3 mmol), compound 17 (5.5 g, 13.3 mmol), Pd₂(dba)₃ (609 mg, 0.67 mmol), S-phos (546 mg, 1.33 mmol), NaOtBu (3.2 g, 33.3 mmol), and 100 mL of toluene were added to a flask and stirred for 30 minutes at room temperature. After completion of the reaction, the mixture was extracted with EA/H₂O, and thereafter purified by column chromatography to obtain compound A-44 (6.7 g, yield: 77%).

| | MW | M.P |
|---|---|---|
| A-44 | 653.87 | 234° C. |

### Example 7

### Preparation of Compound A-68

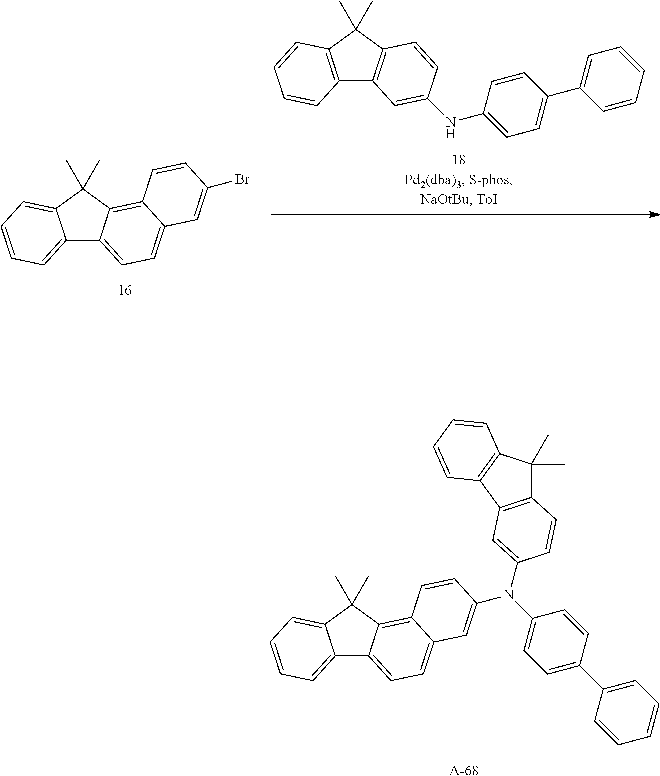 [SMILES: CC1(C)c2ccccc2-c2cc(Nc3ccc(-c4ccccc4)cc3)ccc21 ; CC1(C)c2ccccc2-c2ccc3cc(Br)ccc3c21 ; CC1(C)c2ccccc2-c2cc(N(c3ccc(-c4ccccc4)cc3)c3ccc4c5c(ccc4c3)-c3ccccc3C5(C)C)ccc21 ; "A-68"]

### Preparation of Compound A-68

Compound 16 (3.0 g, 9.28 mmol), compound 18 (3.5 g, 9.75 mmol), Pd₂(dba)₃ (425 mg, 0.46 mmol), S-phos (381 mg, 0.93 mmol), NaOtBu (2.2 g, 23.2 mmol), and 50 mL of toluene were added and stirred for 30 minutes at room temperature. After completion of the reaction, the mixture was extracted with EA/H₂O, thereafter purified by column chromatography to obtain compound A-68 (4.2 g, yield: 75%).

| | MW | M.P |
|---|---|---|
| A-68 | 603.81 | 230° C. |

Hereinafter, the luminescent characteristics of the organic electroluminescent device comprising the organic electroluminescent compound of the present disclosure will be described in order to understand the present disclosure in detail.

### Device Example 1

### Producing a Red Light-Emitting Organic Electroluminescent Device According to the Present Disclosure

An OLED device was produced by using the organic electroluminescent compound of the present disclosure. First, a transparent electrode indium tin oxide (ITO) thin film (10 Ω/sq) on a glass substrate for an OLED device (GEOMATEC CO., LTD., Japan) was subjected to an ultrasonic washing with acetone and isopropanol, sequentially, and then was stored in isopropanol. The ITO substrate was then mounted on a substrate holder of a vacuum vapor deposition apparatus. Compound HI-1 was introduced into a cell of the vacuum vapor deposition apparatus, and then the pressure in the chamber of the apparatus was controlled to 10⁻⁶ torr. Thereafter, an electric current was applied to the cell to evaporate the above-introduced material, thereby forming a first hole injection layer having a thickness of 90 nm on the ITO substrate. Next, compound HI-2 was introduced into another cell of the vacuum vapor deposition apparatus, and was evaporated by applying an electric current to the cell, thereby forming a second hole injection layer having a thickness of 5 nm on the first hole injection layer. Compound HT-1 was then introduced into another cell of the vacuum vapor deposition apparatus, and was evaporated by applying an electric current to the cell, thereby forming a first hole transport layer having a thickness of 10 nm on the second hole injection layer. Compound A-28 was then introduced into another cell of the vacuum vapor deposition apparatus, and was evaporated by applying an electric current to the cell, thereby forming a second hole transport layer (a hole auxiliary layer) having a thickness of 60 nm on the first hole transport layer. After forming the hole injection layers and the hole transport layers, a light-emitting layer was formed thereon as follows: Compound H-211 was introduced into one cell of the vacuum vapor depositing apparatus as a host, and compound D-39 was introduced into another cell as a dopant. The two materials were evaporated to form a light-emitting layer having a thickness of 40 nm on the second hole transport layer by doping a dopant in an amount of 2 wt % based on the total amount of the host and dopant. Next, compounds ET-1 and EI-1 were evaporated at a rate of 1:1, and were deposited to form an electron transport layer having a thickness of 35 nm on the light-emitting layer. After depositing compound EI-1 as an electron injection layer having a thickness of 2 nm on the electron transport layer, an AI cathode having a thickness of 1,500 nm was deposited on the electron injection layer by another vacuum vapor deposition apparatus. Thus, an OLED device was produced.

### Device Examples 2 and 3

### Producing a Red Light-Emitting Organic Electroluminescent Device According to the Present Disclosure

OLED devices of Device Examples 2 and 3 were produced in the same manner as in Device Example 1, except that compounds A-44 and A-68 were used as the second hole transport material, respectively.

### Comparative Example 1

### Producing a Red Light-Emitting Organic Electroluminescent Device not According to the Present Disclosure

An OLED device was produced in the same manner as in Device Example 1, except that compound Ref-1 was used as the second hole transport material.

The compounds used in Device Examples 1 to 3 and Comparative Example 1, are shown in Table 1 below.

TABLE 1

| | | |
|---|---|---|
| Hole Injection Layer/Hole Transport Layer | 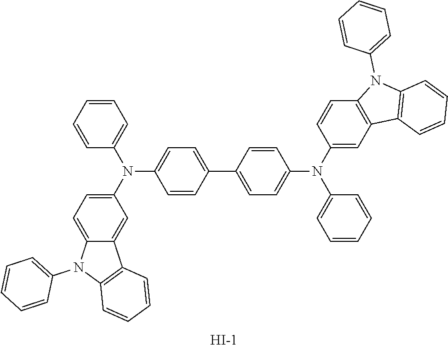 | 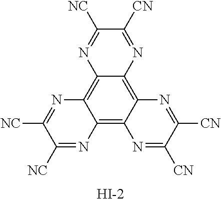 |
| | 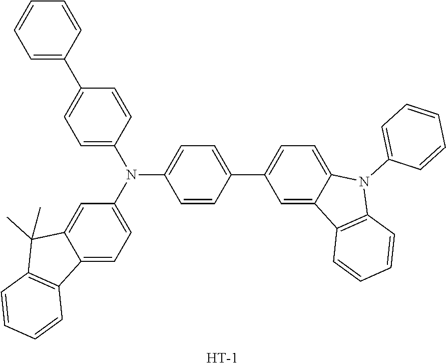 | |
| | 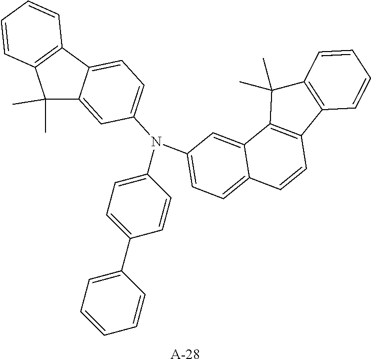 | 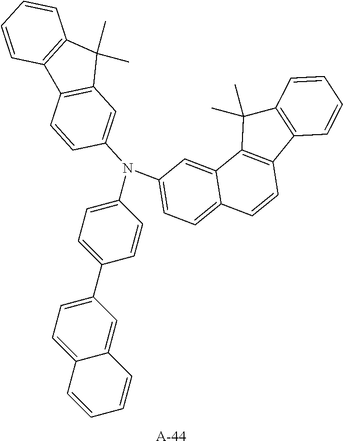 |
| | 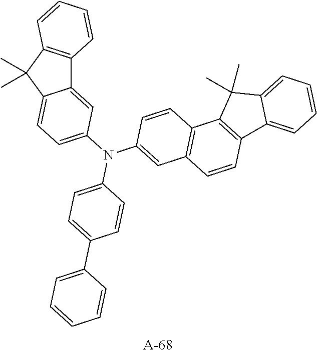 | 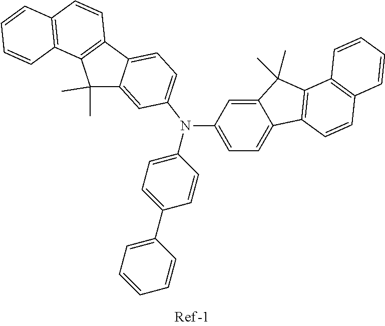 |
| Light- Emitting Layer | 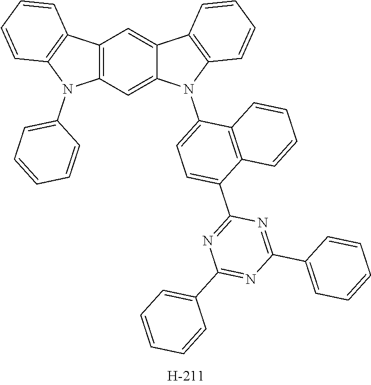 | 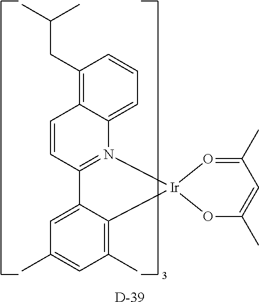 |
| Electron Transport Layer/ Electron Injection Layer | 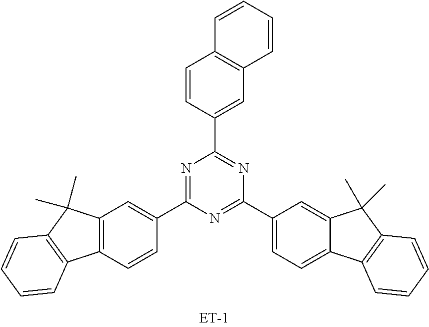 | 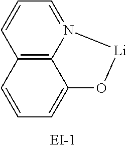 |

The results of the driving voltage, the luminous efficiency, and the CIE color coordinates at a luminance of 1,000 nits, and the time taken to reduce the initial luminance to a luminance of 98% at a constant current in a luminance of 5,000 nits, of the organic electroluminescent device of Device Examples 1 to 3 and Comparative Example 1 produced as described above, are shown in the following Table 2.

TABLE 2

| | Second | | | | Color | | |
|---|---|---|---|---|---|---|---|
| | Hole | | Driving | Luminous | Coordinates | | Lifespan |
| | Transport | Host | Voltage | Efficiency | CIE (x, y) | | T98 |
| | Material | Material | (V) | (cd/A) | x | y | (Hr) |
| Device | A-28 | H-211 | 2.8 | 22.3 | 0.669 | 0.330 | 70 |
| Example 1 | | | | | | | |
| Device | A-44 | | 2.8 | 21.4 | 0.669 | 0.330 | 75 |
| Example 2 | | | | | | | |
| Device | A-68 | | 2.8 | 21.8 | 0.668 | 0.332 | 44 |
| Example 3 | | | | | | | |
| Comparative | Ref-1 | | 3.2 | 11.2 | 0.663 | 0.335 | 37 |
| Example 1 | | | | | | | |

Referring to Table 2 above, OLED of Device Examples 1 to 3 using the organic electroluminescent compound of the present disclosure exhibits far superior effects on the driving voltage, the luminous efficiency, and the lifespan as compared with the OLED of Comparative Example 1, so that the characteristics being able to overcome the conventional problems can be confirmed in that the lifespan is lowered with an increase of efficiency.

That is, when an organic electroluminescent compound according to the present disclosure is used as material(s) in a hole transport layer and/or a hole auxiliary layer, it is possible to have advantages in increasing the light-emitting efficiency and lifespan as well as lowering the voltage used to emit light of the same luminance.

1. An organic electroluminescent compound represented by the following formula 1: 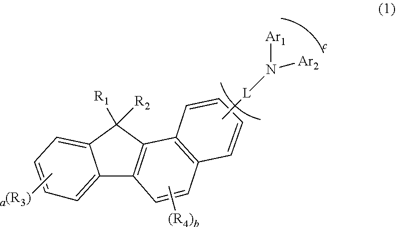
wherein,
R₁ and R₂ each independently represent hydrogen, deuterium, a substituted or unsubstituted (C1-C30)alkyl, a substituted or unsubstituted (C6-C30)aryl, or a substituted or unsubstituted (3- to 30-membered)heteroaryl; or may be linked to an adjacent substituent to form a substituted or unsubstituted ring;
R₃ and R₄ each independently represent hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, or a substituted or unsubstituted tri(C6-C30)arylsilyl;
L represents a single bond, a substituted or unsubstituted (C6-C30)arylene, or a substituted or unsubstituted (3- to 30-membered)heteroarylene;
Ar₁ and Ar₂ each independently represent a substituted or unsubstituted (C1-C30)alkyl, a substituted or unsubstituted (C6-C30)aryl, or a substituted or unsubstituted (3- to 30-membered)heteroaryl; or may be linked to each other to form a substituted or unsubstituted ring;
a represent an integer from 1 to 4, b represents an integer 1 or 2, when a or b is an integer of 2 or more, each of R₃ or each of R₄ may be the same or different; and
c represents an integer 1 or 2, when c is an integer 2, each of Ar₁ or each of Ar₂ may be the same or different.

2. The organic electroluminescent compound according to claim 1, wherein the formula 1 is represented by any one of the following formulae 1-1 to 1-6: 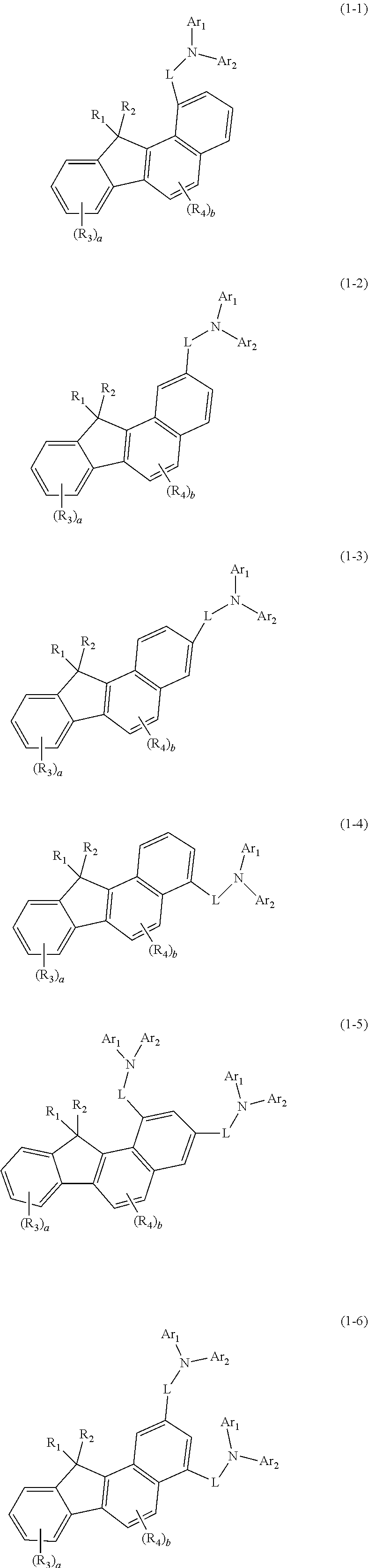
wherein, R₁ to R₄, Ar₁, Ar₂, L, a, and b are as defined in claim 1.

3. The organic electroluminescent compound according to claim 1, wherein Ar₁ and Ar₂ each independently represent any one of the the substituents selected from the following group I: 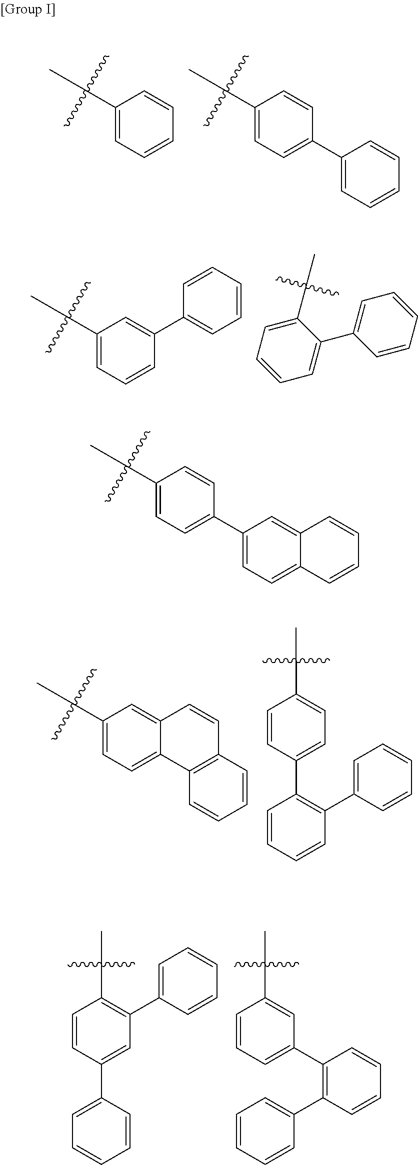 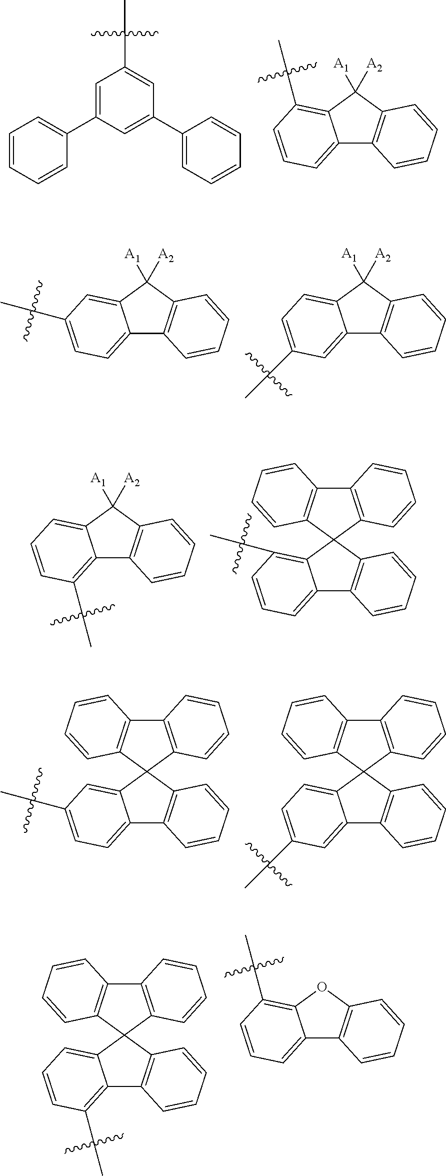 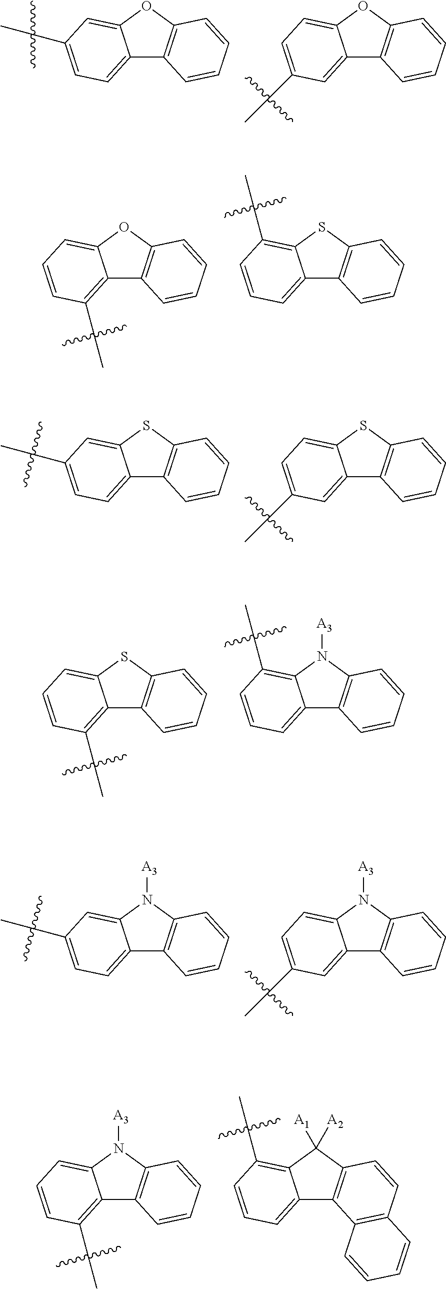 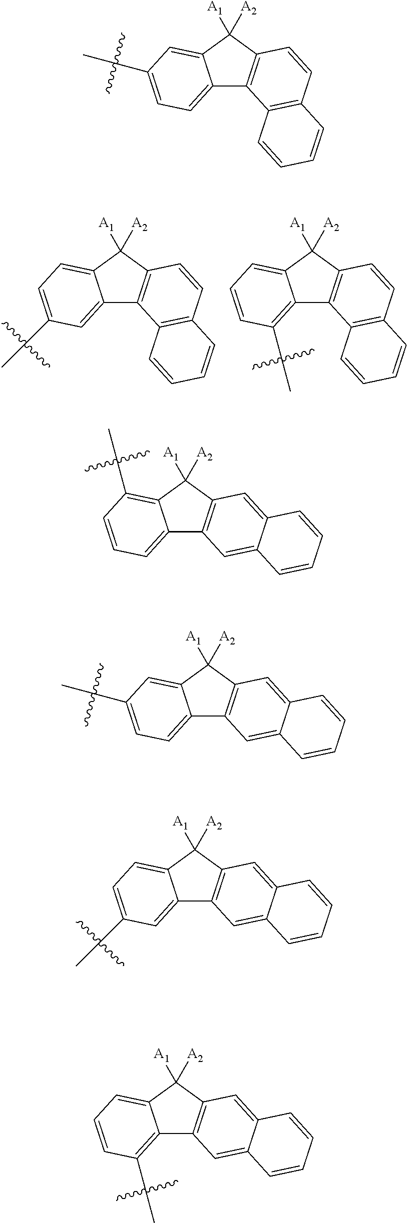 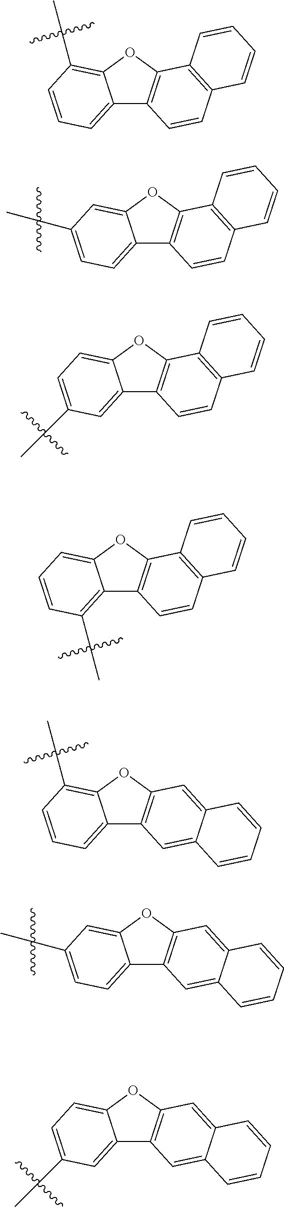 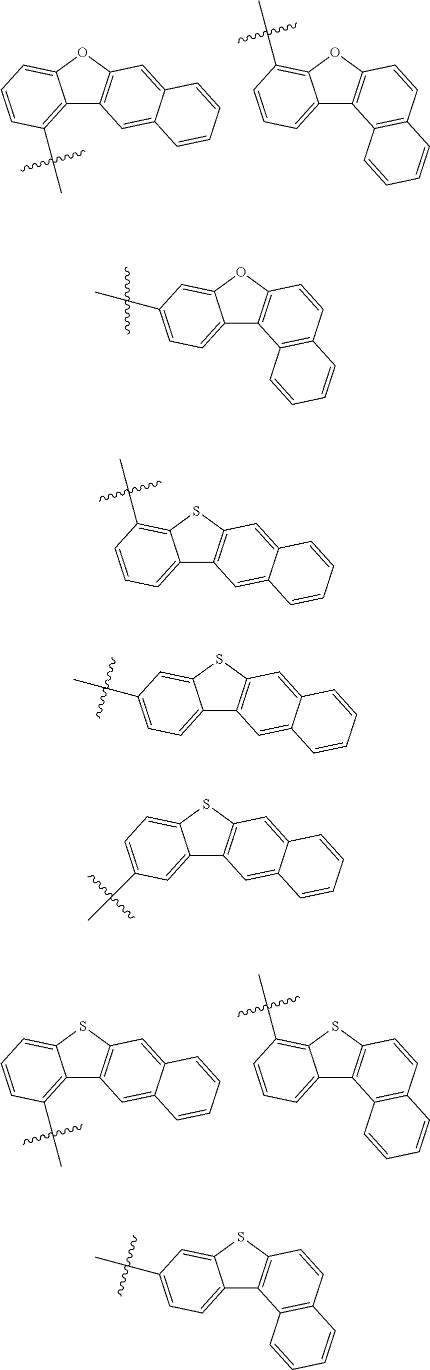 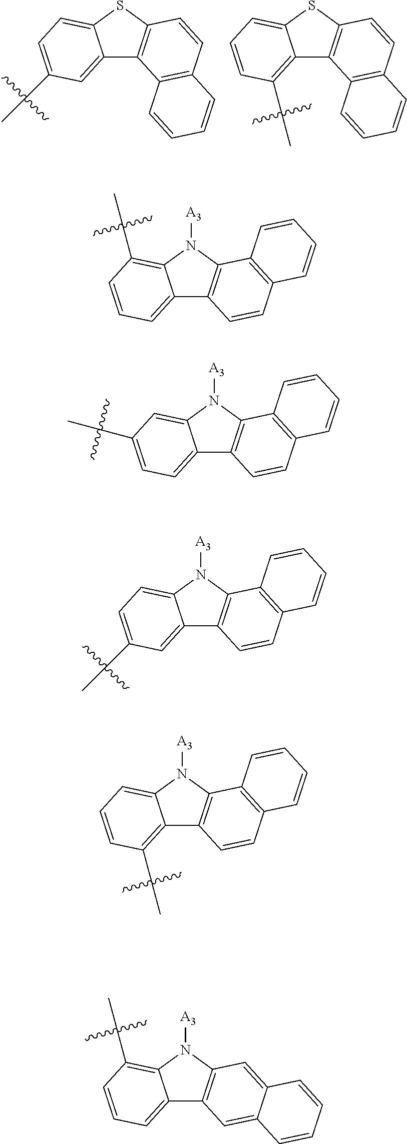 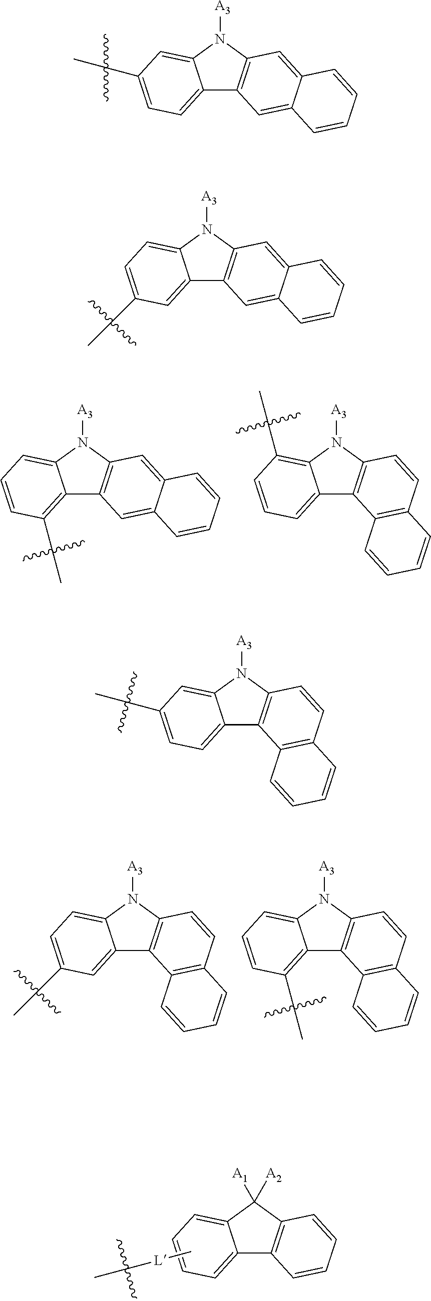 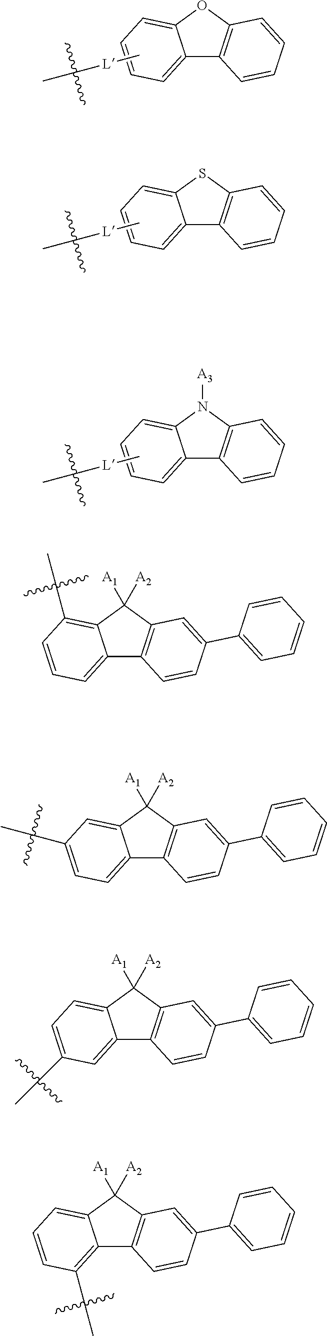 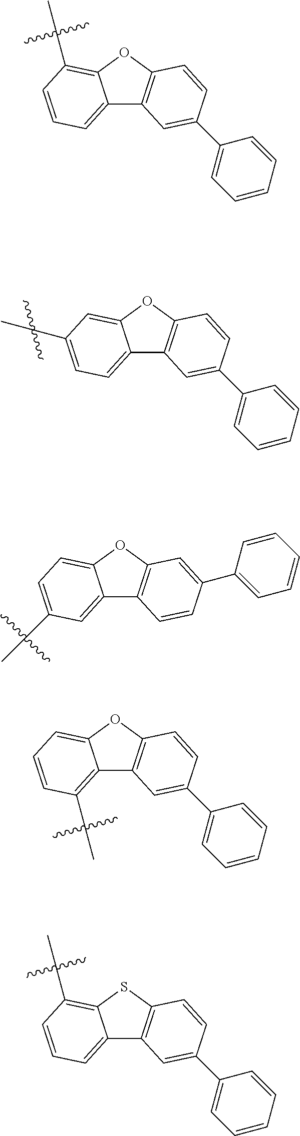 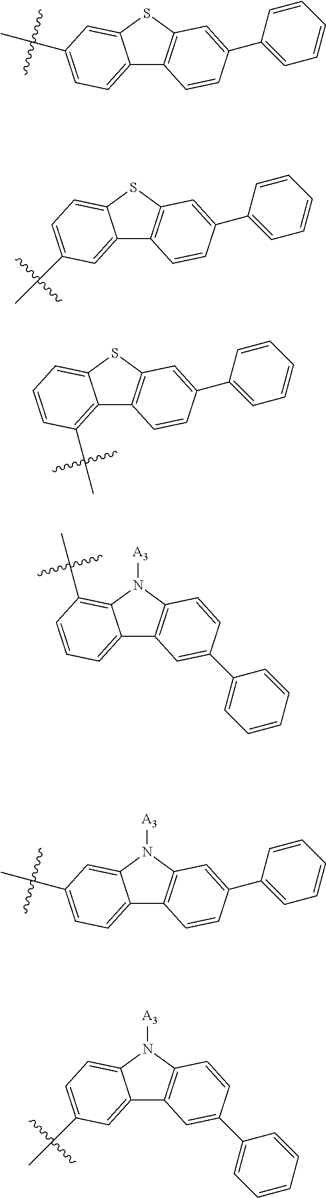 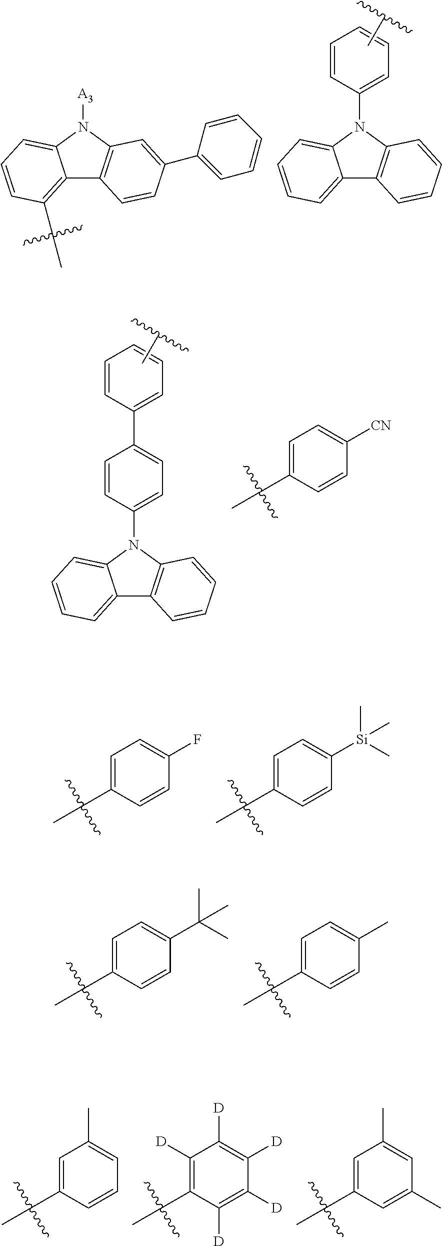 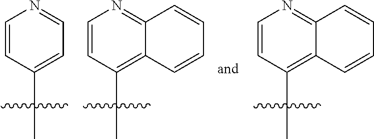
wherein, A₁ to A3 each independently represent a substituted or unsubstituted (C1-C30)alkyl or a substituted or unsubstituted (C6-C30)aryl;
L′ represents a substituted or unsubstituted (C6-C30)arylene or a substituted or unsubstituted (3- to 30-membered)heteroarylene; and [symbol]
represents bonding position with N.

4. The organic electroluminescent compound according to claim 1, wherein, R₁ and R₂ each independently represent hydrogen, a substituted or unsubstituted (C1-C18)alkyl, or a substituted or unsubstituted (C6-C18)aryl,
R₃ and R₄ each independently represent hydrogen or a substituted or unsubstituted (C6-C18)aryl,
L represent a single bond or a substituted or unsubstituted (C6-C18)arylene, and
Ar₁ and Ar₂ each independently represent one of the substituents listed in group I of claim 3 or are linked each other, so that the amine group forms a substituted or unsubstituted carbazole.

5. The organic electroluminescent compound according to claim 1, wherein the formula 1 is represented by any one of the following formulae I-1 to I-4: 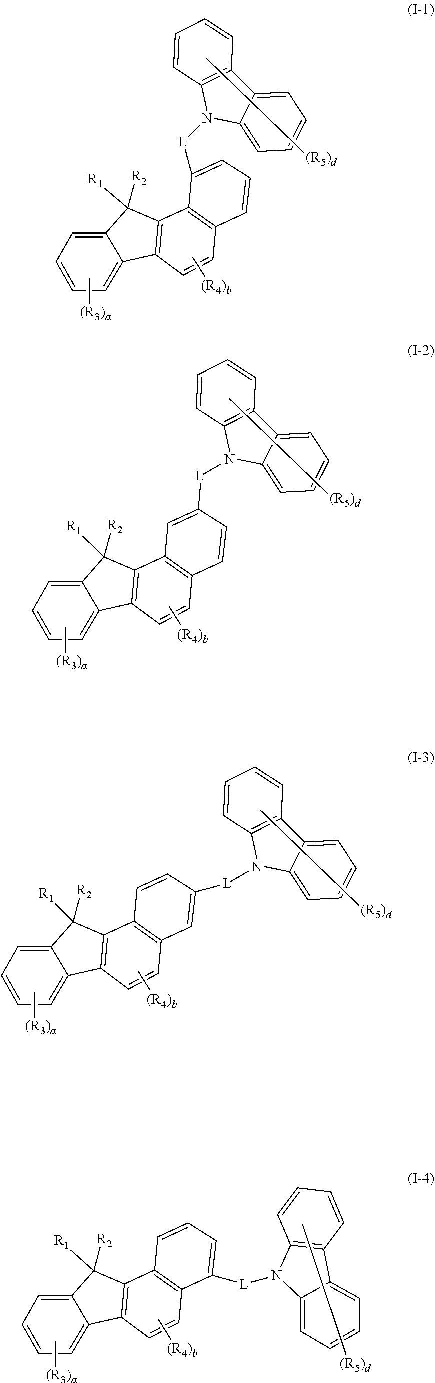
wherein, R₁ to R₄, L, a, and b are as defined in claim 1;
R₅ represents hydrogen or —NRₓR_{y};
Rₓ and R_{y} each independently represent hydrogen, deuterium, a substituted or unsubstituted (C1-C30)alkyl, or a substituted or unsubstituted (C6-C30)aryl; and
d represents an integer of 1 or 2, when d is 2, each of R₅ may be the same or different.

6. The organic electroluminescent compound according to claim 1, wherein the substituents of the substituted (C1-C30)alkyl, the substituted (C6-C30)aryl(ene), the substituted (3- to 30-membered)heteroaryl(ene), the substituted (C3-C30)cycloalkyl, the substituted (C1-C30)alkoxy, the substituted tri(C1-C30)alkylsilyl, the substituted di(C1-C30)alkyl(C6-C30)arylsilyl, the substituted (C1-C30)alkyldi(C6-C30)arylsilyl, the substituted tri(C6-C30)arylsilyl, and the substituted ring, in R₁ to R₄, Ar₁, Ar₂, and L, each independently, are at least one selected from the group consisting of deuterium, halogen, cyano, carboxyl, nitro, hydroxyl, (C1-C30)alkyl, halo(C1-C30)alkyl, (C2-C30)alkenyl, (C2-C30)alkynyl, (C1-C30)alkoxy, (C1-C30)alkylthio, (C3-C30)cycloalkyl, (C3-C30)cycloalkenyl, (3- to 7-membered) heterocycloalkyl, (C6-C30)aryloxy, (C6-C30)arylthio, (C6-C30)aryl-substituted or unsubstituted (5- to 30-membered)heteroaryl, (5- to 30-membered)heteroaryl-substituted or unsubstituted (C6-C30)aryl, tri(C1-C30)alkylsilyl, tri(C6-C30)arylsilyl, di(C1-C30)alkyl(C6-C30)arylsilyl, (C1-C30)alkyldi(C6-C30)arylsilyl, amino, mono- or di-(C1-C30)alkylamino, (C1-C30)alkyl-substituted or unsubstituted mono- or di-(C6-C30)arylamino, (C1-C30)alkyl(C6-C30)arylamino, (C1-C30)alkylcarbonyl, (C1-C30)alkoxycarbonyl, (C6-C30)arylcarbonyl, di(C6-C30)arylboronyl, di(C1-C30)alkylboronyl, (C1-C30)alkyl(C6-C30)arylboronyl, (C6-C30)ar(C1-C30)alkyl, and (C1-C30)alkyl(C6-C30)aryl.

7. The organic electroluminescent compound according to claim 1, wherein the compound represented by formula 1 is selected from the group consisting of:

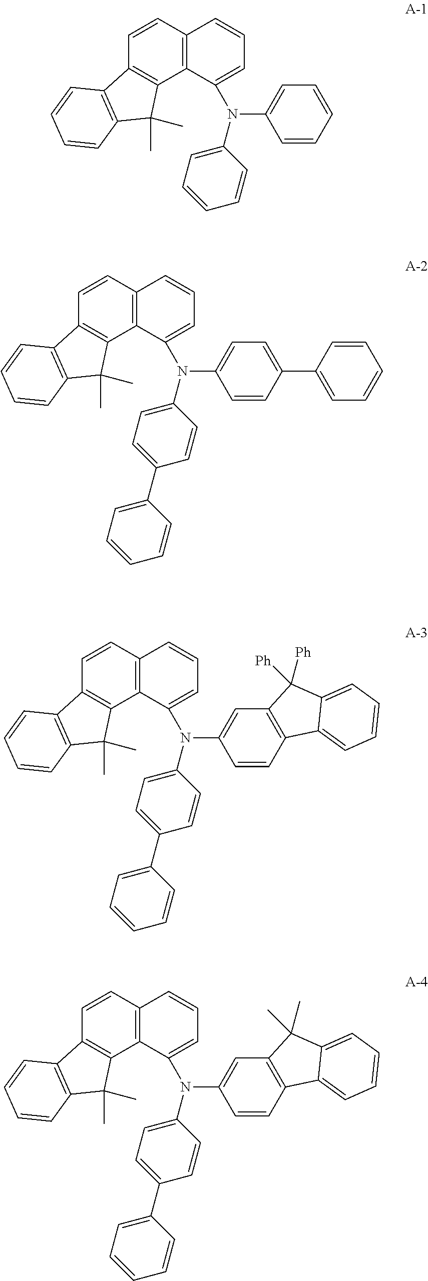 [SMILES: CC1(C)c2ccccc2-c2ccc3cccc(N(c4ccccc4)c4ccccc4)c3c21 ; CC1(C)c2ccccc2-c2ccc3cccc(N(c4ccc(-c5ccccc5)cc4)c4ccc(-c5ccccc5)cc4)c3c21 ; CC1(C)c2ccccc2-c2ccc3cccc(N(c4ccc(-c5ccccc5)cc4)c4ccc5c(c4)C(c4ccccc4)(c4ccccc4)c4ccccc4-5)c3c21 ; CC1(C)c2ccccc2-c2ccc(N(c3ccc(-c4ccccc4)cc3)c3cccc4ccc5c(c34)C(C)(C)c3ccccc3-5)cc21]

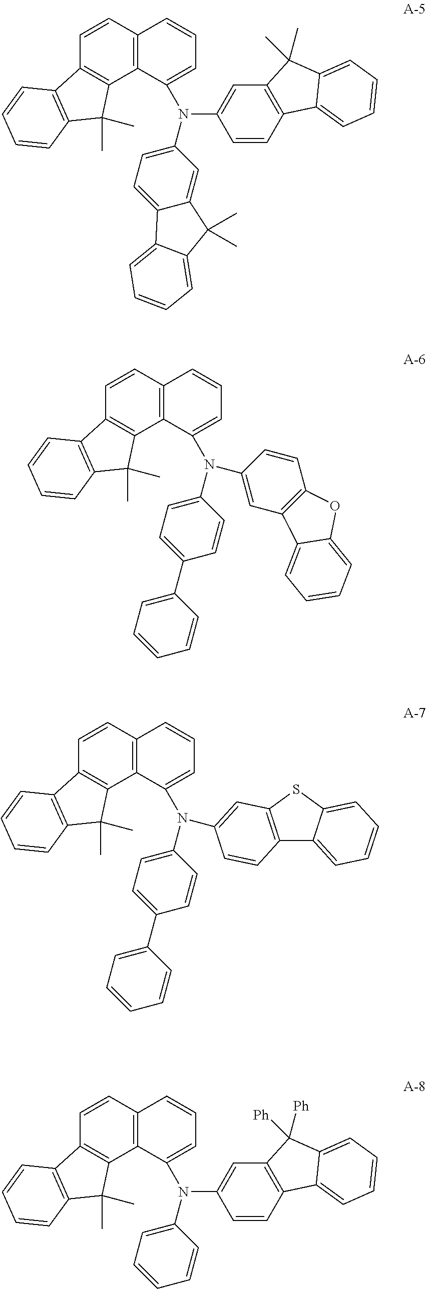 [SMILES: CC1(C)c2ccccc2-c2ccc(N(c3ccc4c(c3)C(C)(C)c3ccccc3-4)c3cccc4ccc5c(c34)C(C)(C)c3ccccc3-5)cc21 ; CC1(C)c2ccccc2-c2ccc3cccc(N(c4ccc(-c5ccccc5)cc4)c4ccc5oc6ccccc6c5c4)c3c21 ; CC1(C)c2ccccc2-c2ccc3cccc(N(c4ccc(-c5ccccc5)cc4)c4ccc5c(c4)sc4ccccc45)c3c21 ; CC1(C)c2ccccc2-c2ccc3cccc(N(c4ccccc4)c4ccc5c(c4)C(c4ccccc4)(c4ccccc4)c4ccccc4-5)c3c21]

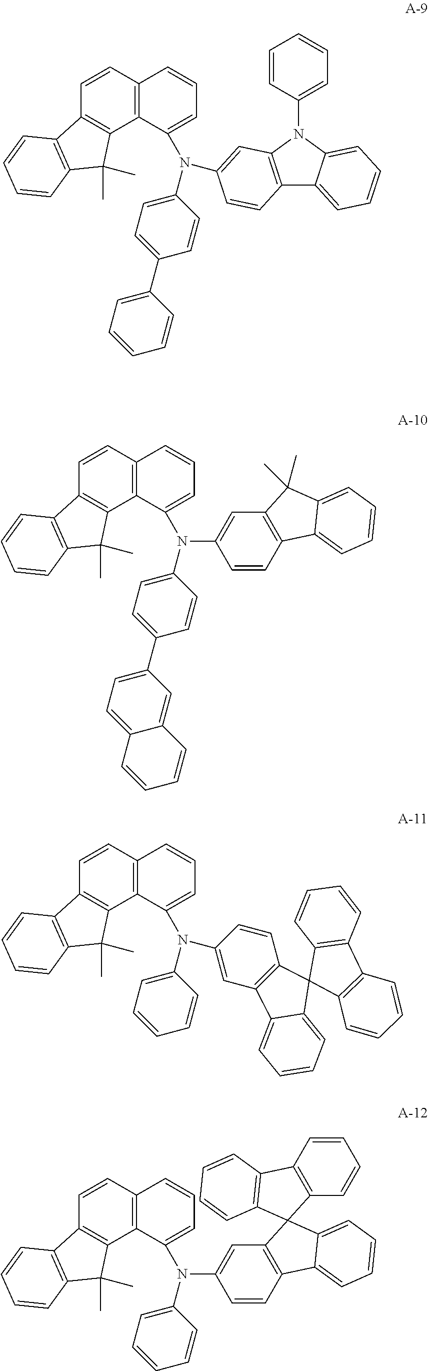 [SMILES: CC1(C)c2ccccc2-c2ccc3cccc(N(c4ccc(-c5ccccc5)cc4)c4ccc5c6ccccc6n(-c6ccccc6)c5c4)c3c21 ; CC1(C)c2ccccc2-c2ccc(N(c3ccc(-c4ccc5ccccc5c4)cc3)c3cccc4ccc5c(c34)C(C)(C)c3ccccc3-5)cc21 ; CC1(C)c2ccccc2-c2ccc3cccc(N(c4ccccc4)c4ccc5c(c4)-c4ccccc4C54c5ccccc5-c5ccccc54)c3c21 ; CC1(C)c2ccccc2-c2ccc3cccc(N(c4ccccc4)c4ccc5c(c4)C4(c6ccccc6-c6ccccc64)c4ccccc4-5)c3c21]

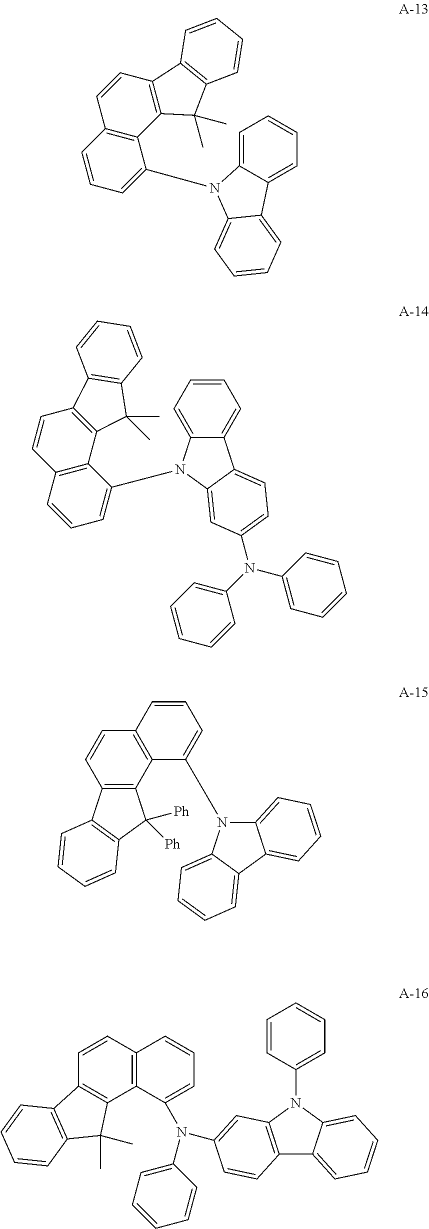 [SMILES: CC1(C)c2ccccc2-c2ccc3cccc(-n4c5ccccc5c5ccccc54)c3c21 ; CC1(C)c2ccccc2-c2ccc3cccc(-n4c5ccccc5c5ccc(N(c6ccccc6)c6ccccc6)cc54)c3c21 ; c1ccc(C2(c3ccccc3)c3ccccc3-c3ccc4cccc(-n5c6ccccc6c6ccccc65)c4c32)cc1 ; CC1(C)c2ccccc2-c2ccc3cccc(N(c4ccccc4)c4ccc5c6ccccc6n(-c6ccccc6)c5c4)c3c21]

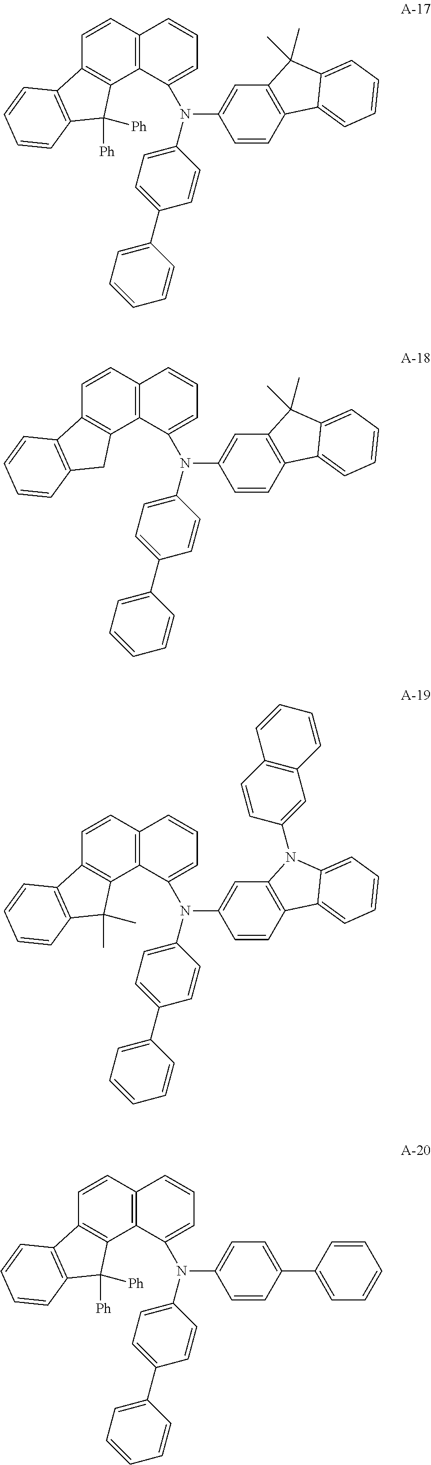 [SMILES: CC1(C)c2ccccc2-c2ccc(N(c3ccc(-c4ccccc4)cc3)c3cccc4ccc5c(c34)C(c3ccccc3)(c3ccccc3)c3ccccc3-5)cc21 ; CC1(C)c2ccccc2-c2ccc(N(c3ccc(-c4ccccc4)cc3)c3cccc4ccc5c(c34)Cc3ccccc3-5)cc21 ; CC1(C)c2ccccc2-c2ccc3cccc(N(c4ccc(-c5ccccc5)cc4)c4ccc5c6ccccc6n(-c6ccc7ccccc7c6)c5c4)c3c21 ; c1ccc(-c2ccc(N(c3ccc(-c4ccccc4)cc3)c3cccc4ccc5c(c34)C(c3ccccc3)(c3ccccc3)c3ccccc3-5)cc2)cc1]

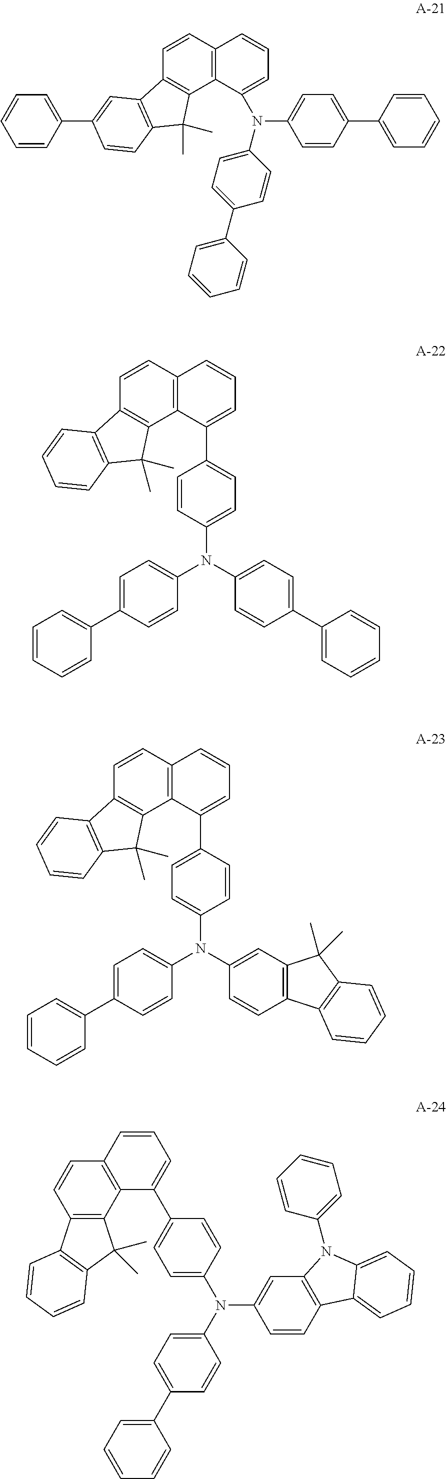 [SMILES: CC1(C)c2ccc(-c3ccccc3)cc2-c2ccc3cccc(N(c4ccc(-c5ccccc5)cc4)c4ccc(-c5ccccc5)cc4)c3c21 ; CC1(C)c2ccccc2-c2ccc3cccc(-c4ccc(N(c5ccc(-c6ccccc6)cc5)c5ccc(-c6ccccc6)cc5)cc4)c3c21 ; CC1(C)c2ccccc2-c2ccc(N(c3ccc(-c4ccccc4)cc3)c3ccc(-c4cccc5ccc6c(c45)C(C)(C)c4ccccc4-6)cc3)cc21 ; CC1(C)c2ccccc2-c2ccc3cccc(-c4ccc(N(c5ccc(-c6ccccc6)cc5)c5ccc6c7ccccc7n(-c7ccccc7)c6c5)cc4)c3c21]

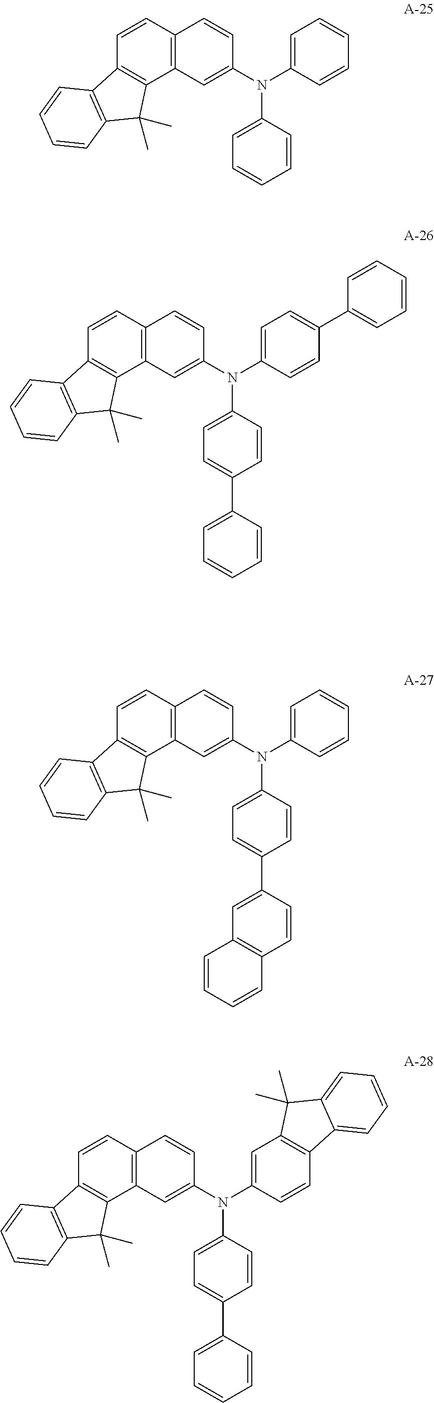 [SMILES: CC1(C)c2ccccc2-c2ccc3ccc(N(c4ccccc4)c4ccccc4)cc3c21 ; CC1(C)c2ccccc2-c2ccc3ccc(N(c4ccc(-c5ccccc5)cc4)c4ccc(-c5ccccc5)cc4)cc3c21 ; CC1(C)c2ccccc2-c2ccc3ccc(N(c4ccccc4)c4ccc(-c5ccc6ccccc6c5)cc4)cc3c21 ; CC1(C)c2ccccc2-c2ccc(N(c3ccc(-c4ccccc4)cc3)c3ccc4ccc5c(c4c3)C(C)(C)c3ccccc3-5)cc21]

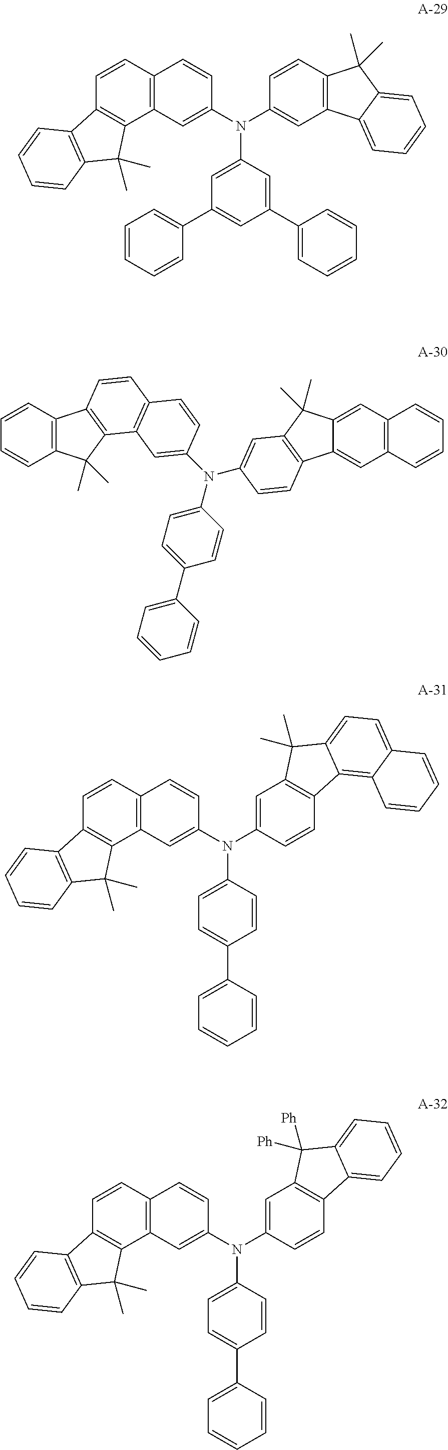 [SMILES: CC1(C)c2ccccc2-c2cc(N(c3cc(-c4ccccc4)cc(-c4ccccc4)c3)c3ccc4ccc5c(c4c3)C(C)(C)c3ccccc3-5)ccc21 ; CC1(C)c2cc(N(c3ccc(-c4ccccc4)cc3)c3ccc4ccc5c(c4c3)C(C)(C)c3ccccc3-5)ccc2-c2cc3ccccc3cc21 ; CC1(C)c2cc(N(c3ccc(-c4ccccc4)cc3)c3ccc4ccc5c(c4c3)C(C)(C)c3ccccc3-5)ccc2-c2c1ccc1ccccc21 ; CC1(C)c2ccccc2-c2ccc3ccc(N(c4ccc(-c5ccccc5)cc4)c4ccc5c(c4)C(c4ccccc4)(c4ccccc4)c4ccccc4-5)cc3c21]

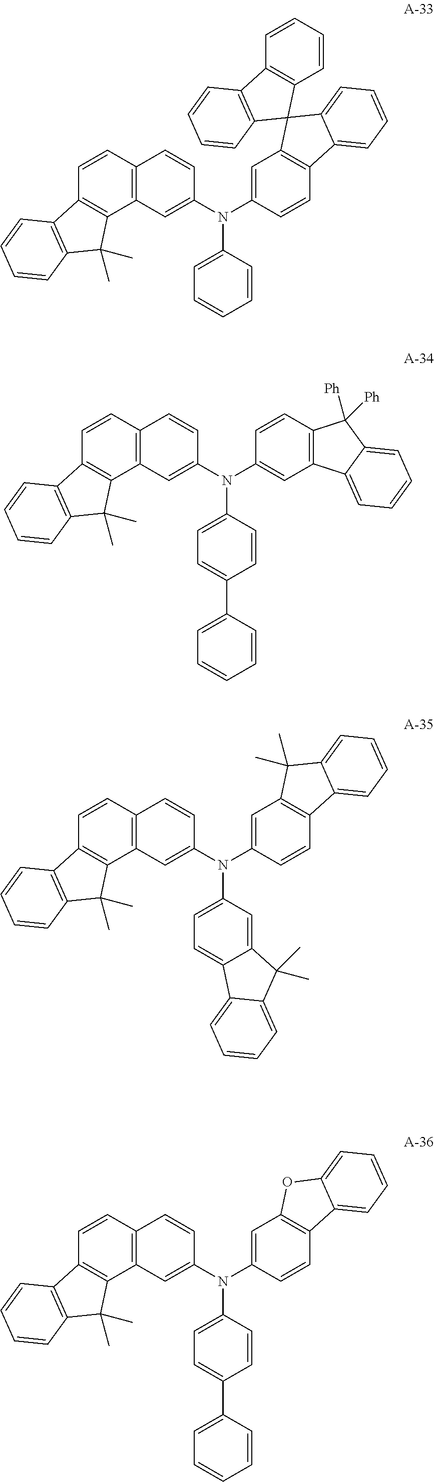 [SMILES: CC1(C)c2ccccc2-c2ccc3ccc(N(c4ccccc4)c4ccc5c(c4)C4(c6ccccc6-c6ccccc64)c4ccccc4-5)cc3c21 ; CC1(C)c2ccccc2-c2ccc3ccc(N(c4ccc(-c5ccccc5)cc4)c4ccc5c(c4)-c4ccccc4C5(c4ccccc4)c4ccccc4)cc3c21 ; CC1(C)c2ccccc2-c2ccc(N(c3ccc4c(c3)C(C)(C)c3ccccc3-4)c3ccc4ccc5c(c4c3)C(C)(C)c3ccccc3-5)cc21 ; CC1(C)c2ccccc2-c2ccc3ccc(N(c4ccc(-c5ccccc5)cc4)c4ccc5c(c4)oc4ccccc45)cc3c21]

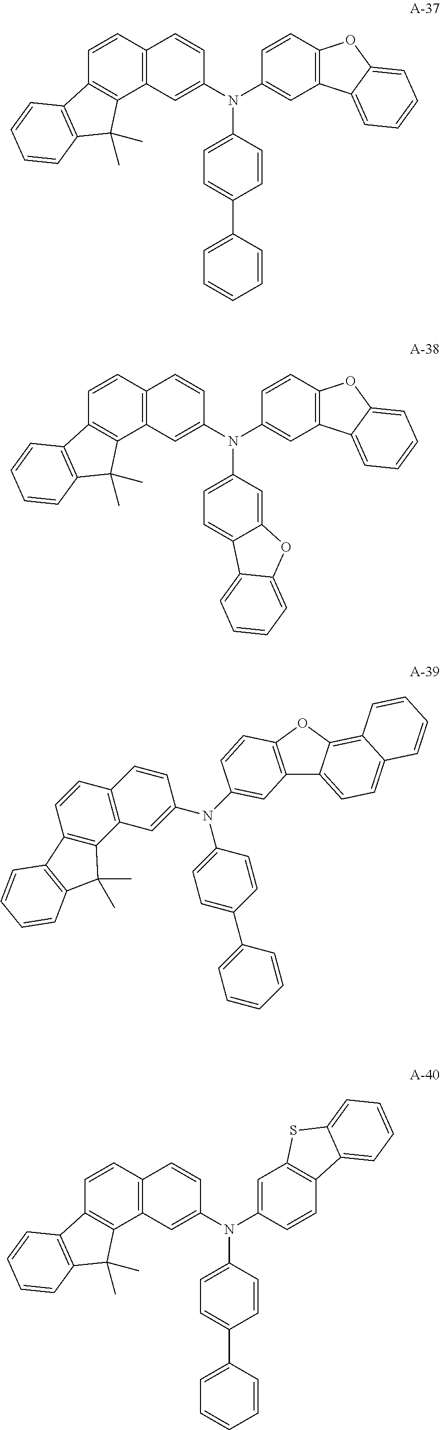 [SMILES: CC1(C)c2ccccc2-c2ccc3ccc(N(c4ccc(-c5ccccc5)cc4)c4ccc5oc6ccccc6c5c4)cc3c21 ; CC1(C)c2ccccc2-c2ccc3ccc(N(c4ccc5c(c4)oc4ccccc45)c4ccc5oc6ccccc6c5c4)cc3c21 ; CC1(C)c2ccccc2-c2ccc3ccc(N(c4ccc(-c5ccccc5)cc4)c4ccc5oc6c7ccccc7ccc6c5c4)cc3c21 ; CC1(C)c2ccccc2-c2ccc3ccc(N(c4ccc(-c5ccccc5)cc4)c4ccc5c(c4)sc4ccccc45)cc3c21]

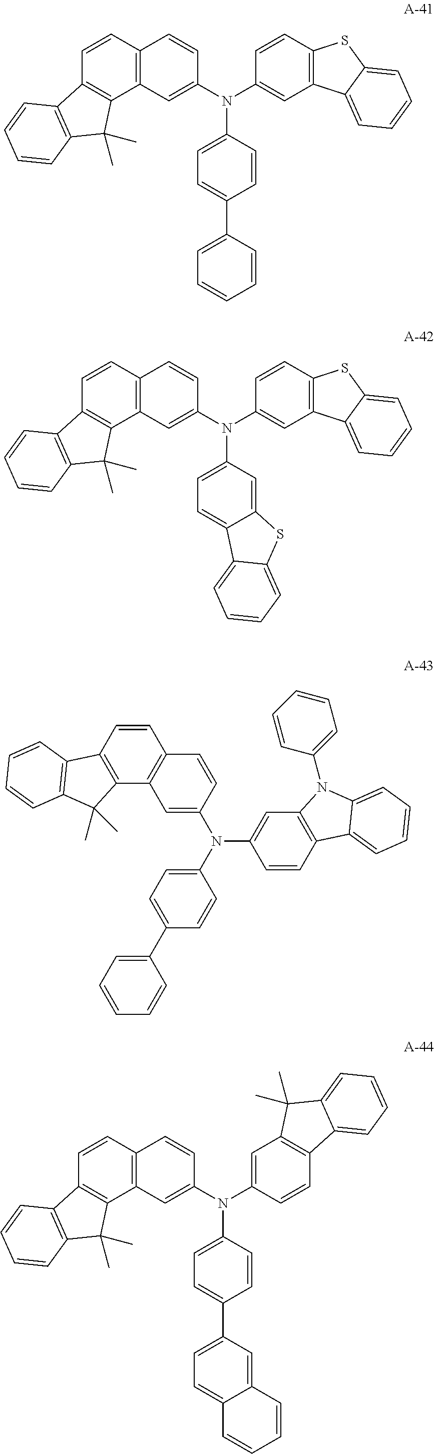 [SMILES: CC1(C)c2ccccc2-c2ccc3ccc(N(c4ccc(-c5ccccc5)cc4)c4ccc5sc6ccccc6c5c4)cc3c21 ; CC1(C)c2ccccc2-c2ccc3ccc(N(c4ccc5c(c4)sc4ccccc45)c4ccc5sc6ccccc6c5c4)cc3c21 ; CC1(C)c2ccccc2-c2ccc3ccc(N(c4ccc(-c5ccccc5)cc4)c4ccc5c6ccccc6n(-c6ccccc6)c5c4)cc3c21 ; CC1(C)c2ccccc2-c2ccc(N(c3ccc(-c4ccc5ccccc5c4)cc3)c3ccc4ccc5c(c4c3)C(C)(C)c3ccccc3-5)cc21]

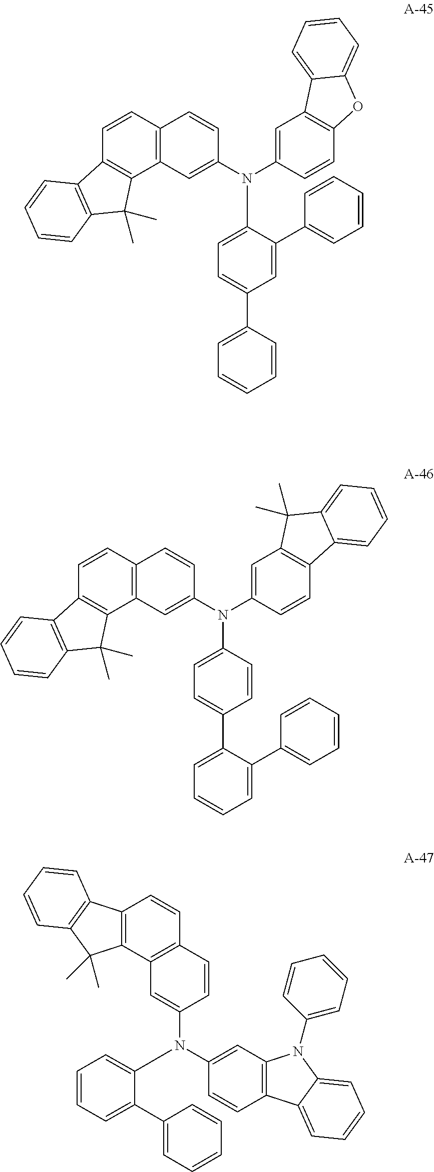 [SMILES: CC1(C)c2ccccc2-c2ccc3ccc(N(c4ccc5oc6ccccc6c5c4)c4ccc(-c5ccccc5)cc4-c4ccccc4)cc3c21 ; CC1(C)c2ccccc2-c2ccc(N(c3ccc(-c4ccccc4-c4ccccc4)cc3)c3ccc4ccc5c(c4c3)C(C)(C)c3ccccc3-5)cc21 ; CC1(C)c2ccccc2-c2ccc3ccc(N(c4ccc5c6ccccc6n(-c6ccccc6)c5c4)c4ccccc4-c4ccccc4)cc3c21]

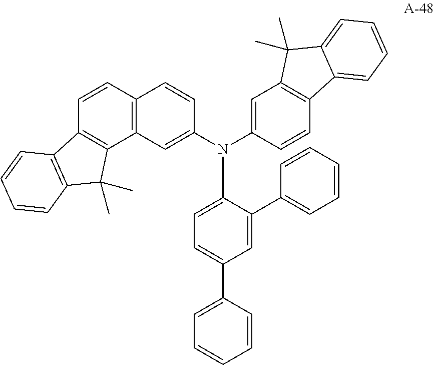 [SMILES: CC1(C)c2ccccc2-c2ccc(N(c3ccc4ccc5c(c4c3)C(C)(C)c3ccccc3-5)c3ccc(-c4ccccc4)cc3-c3ccccc3)cc21]

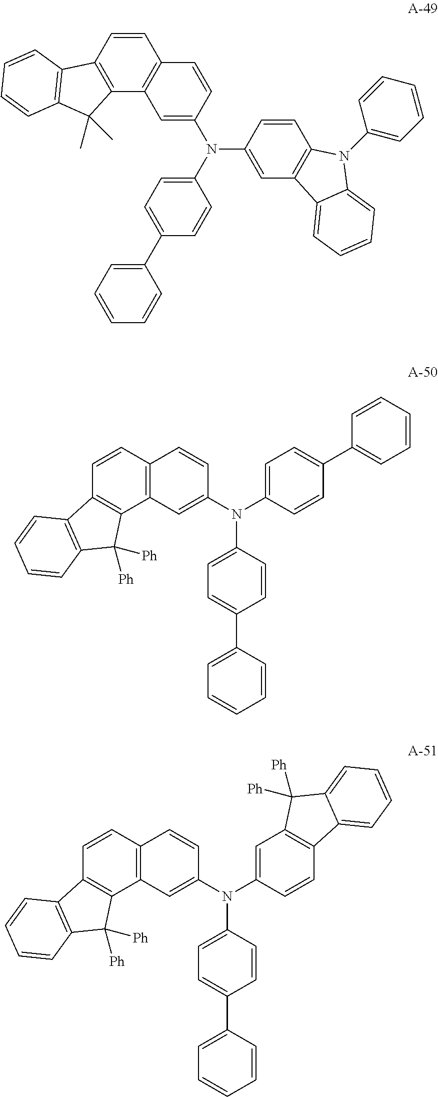 [SMILES: CC1(C)c2ccccc2-c2ccc3ccc(N(c4ccc(-c5ccccc5)cc4)c4ccc5c(c4)c4ccccc4n5-c4ccccc4)cc3c21 ; c1ccc(-c2ccc(N(c3ccc(-c4ccccc4)cc3)c3ccc4ccc5c(c4c3)C(c3ccccc3)(c3ccccc3)c3ccccc3-5)cc2)cc1 ; c1ccc(-c2ccc(N(c3ccc4c(c3)C(c3ccccc3)(c3ccccc3)c3ccccc3-4)c3ccc4ccc5c(c4c3)C(c3ccccc3)(c3ccccc3)c3ccccc3-5)cc2)cc1]

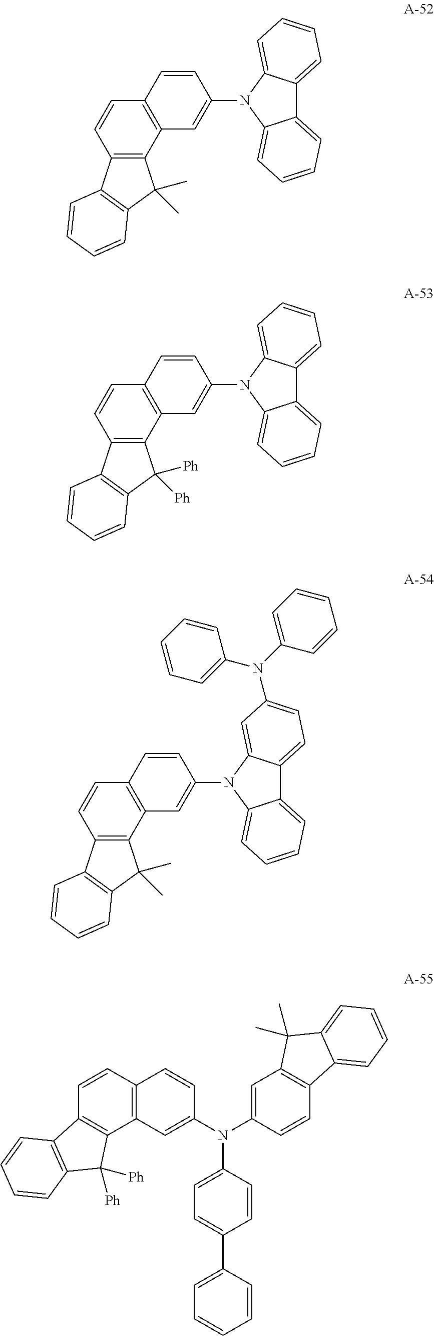 [SMILES: CC1(C)c2ccccc2-c2ccc3ccc(-n4c5ccccc5c5ccccc54)cc3c21 ; c1ccc(C2(c3ccccc3)c3ccccc3-c3ccc4ccc(-n5c6ccccc6c6ccccc65)cc4c32)cc1 ; CC1(C)c2ccccc2-c2ccc3ccc(-n4c5ccccc5c5ccc(N(c6ccccc6)c6ccccc6)cc54)cc3c21 ; CC1(C)c2ccccc2-c2ccc(N(c3ccc(-c4ccccc4)cc3)c3ccc4ccc5c(c4c3)C(c3ccccc3)(c3ccccc3)c3ccccc3-5)cc21]

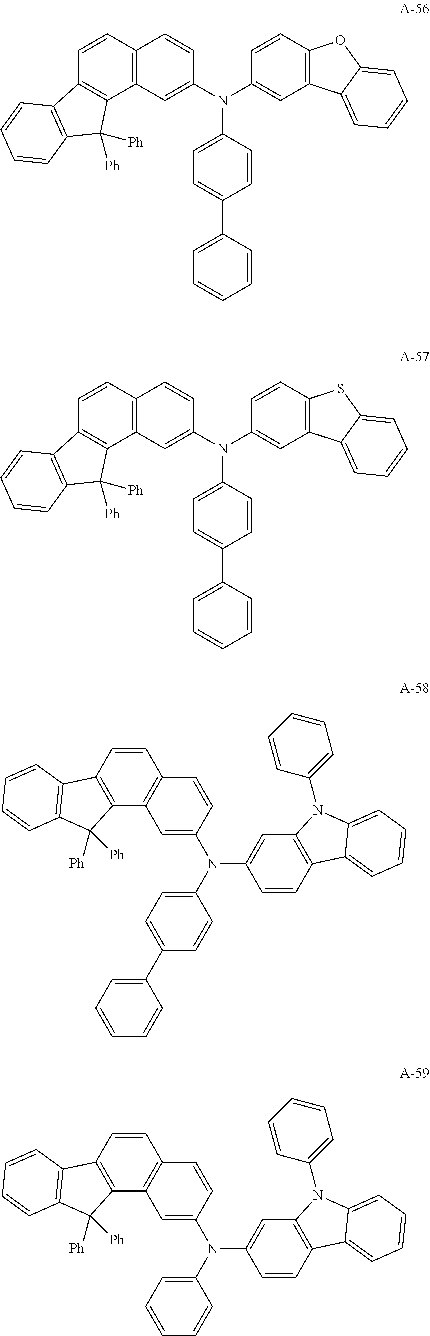 [SMILES: c1ccc(-c2ccc(N(c3ccc4ccc5c(c4c3)C(c3ccccc3)(c3ccccc3)c3ccccc3-5)c3ccc4oc5ccccc5c4c3)cc2)cc1 ; c1ccc(-c2ccc(N(c3ccc4ccc5c(c4c3)C(c3ccccc3)(c3ccccc3)c3ccccc3-5)c3ccc4sc5ccccc5c4c3)cc2)cc1 ; c1ccc(-c2ccc(N(c3ccc4ccc5c(c4c3)C(c3ccccc3)(c3ccccc3)c3ccccc3-5)c3ccc4c5ccccc5n(-c5ccccc5)c4c3)cc2)cc1 ; c1ccc(N(c2ccc3ccc4c(c3c2)C(c2ccccc2)(c2ccccc2)c2ccccc2-4)c2ccc3c4ccccc4n(-c4ccccc4)c3c2)cc1]

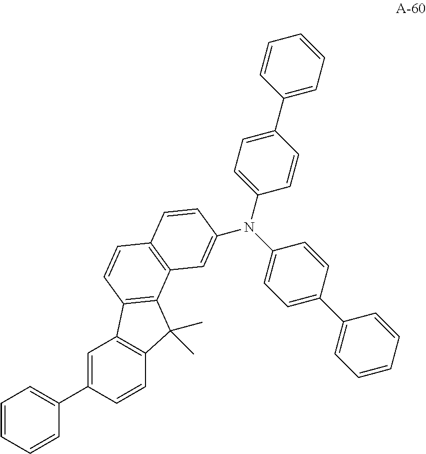 [SMILES: CC1(C)c2ccc(-c3ccccc3)cc2-c2ccc3ccc(N(c4ccc(-c5ccccc5)cc4)c4ccc(-c5ccccc5)cc4)cc3c21]

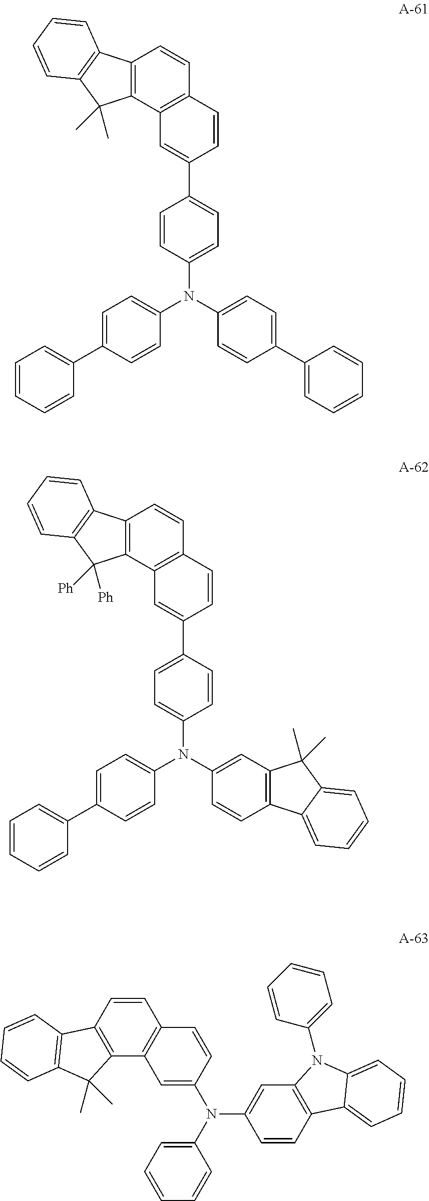 [SMILES: CC1(C)c2ccccc2-c2ccc3ccc(-c4ccc(N(c5ccc(-c6ccccc6)cc5)c5ccc(-c6ccccc6)cc5)cc4)cc3c21 ; CC1(C)c2ccccc2-c2ccc(N(c3ccc(-c4ccccc4)cc3)c3ccc(-c4ccc5ccc6c(c5c4)C(c4ccccc4)(c4ccccc4)c4ccccc4-6)cc3)cc21 ; CC1(C)c2ccccc2-c2ccc3ccc(N(c4ccccc4)c4ccc5c6ccccc6n(-c6ccccc6)c5c4)cc3c21]

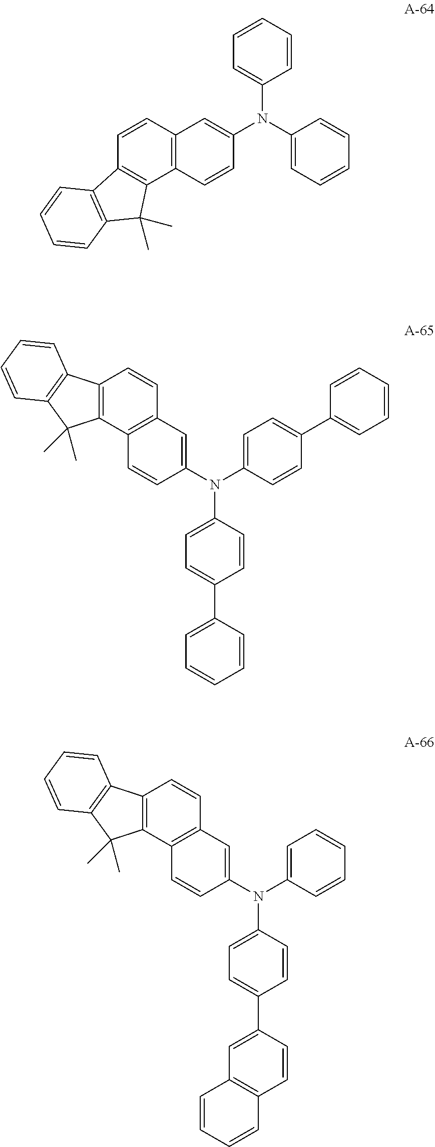 [SMILES: CC1(C)c2ccccc2-c2ccc3cc(N(c4ccccc4)c4ccccc4)ccc3c21 ; CC1(C)c2ccccc2-c2ccc3cc(N(c4ccc(-c5ccccc5)cc4)c4ccc(-c5ccccc5)cc4)ccc3c21 ; CC1(C)c2ccccc2-c2ccc3cc(N(c4ccccc4)c4ccc(-c5ccc6ccccc6c5)cc4)ccc3c21]

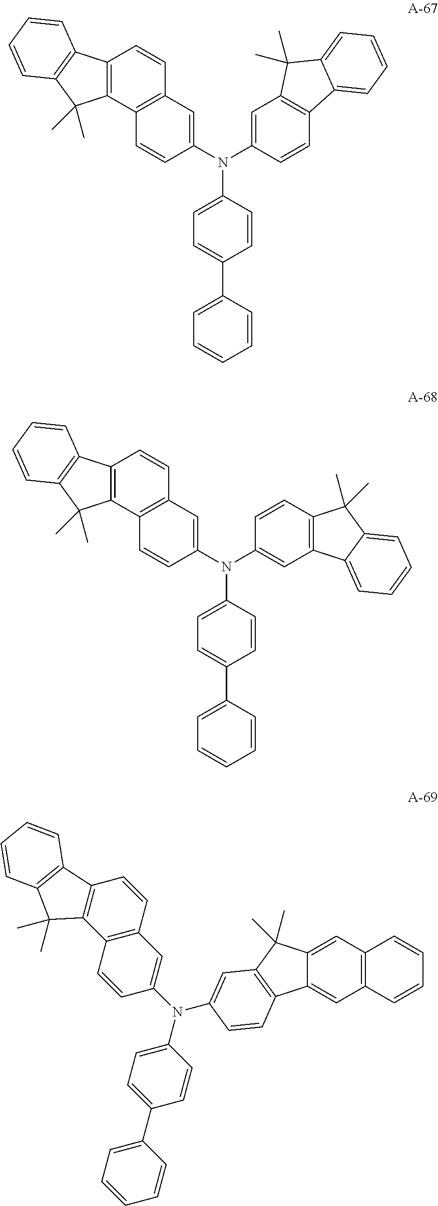 [SMILES: CC1(C)c2ccccc2-c2ccc(N(c3ccc(-c4ccccc4)cc3)c3ccc4c5c(ccc4c3)-c3ccccc3C5(C)C)cc21 ; CC1(C)c2ccccc2-c2cc(N(c3ccc(-c4ccccc4)cc3)c3ccc4c5c(ccc4c3)-c3ccccc3C5(C)C)ccc21 ; CC1(C)c2cc(N(c3ccc(-c4ccccc4)cc3)c3ccc4c5c(ccc4c3)-c3ccccc3C5(C)C)ccc2-c2cc3ccccc3cc21]

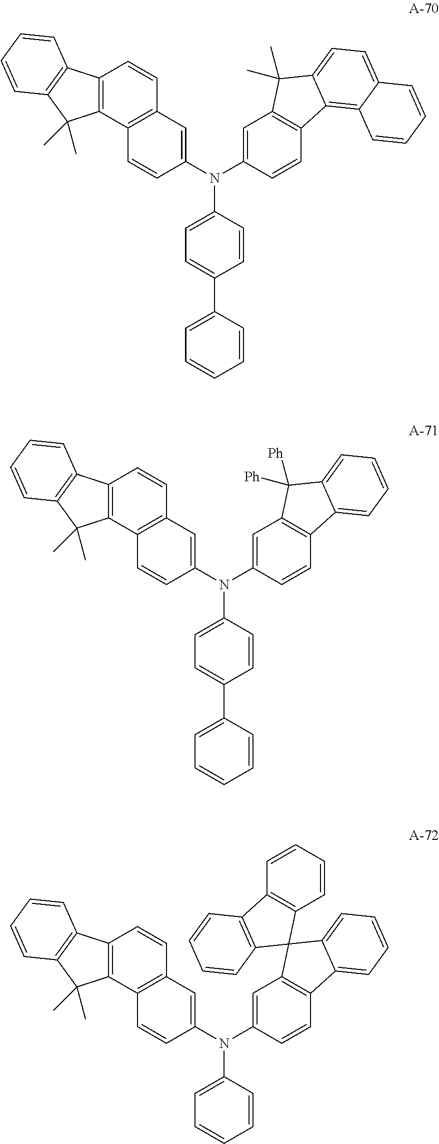 [SMILES: CC1(C)c2cc(N(c3ccc(-c4ccccc4)cc3)c3ccc4c5c(ccc4c3)-c3ccccc3C5(C)C)ccc2-c2c1ccc1ccccc21 ; CC1(C)c2ccccc2-c2ccc3cc(N(c4ccc(-c5ccccc5)cc4)c4ccc5c(c4)C(c4ccccc4)(c4ccccc4)c4ccccc4-5)ccc3c21 ; CC1(C)c2ccccc2-c2ccc3cc(N(c4ccccc4)c4ccc5c(c4)C4(c6ccccc6-c6ccccc64)c4ccccc4-5)ccc3c21]

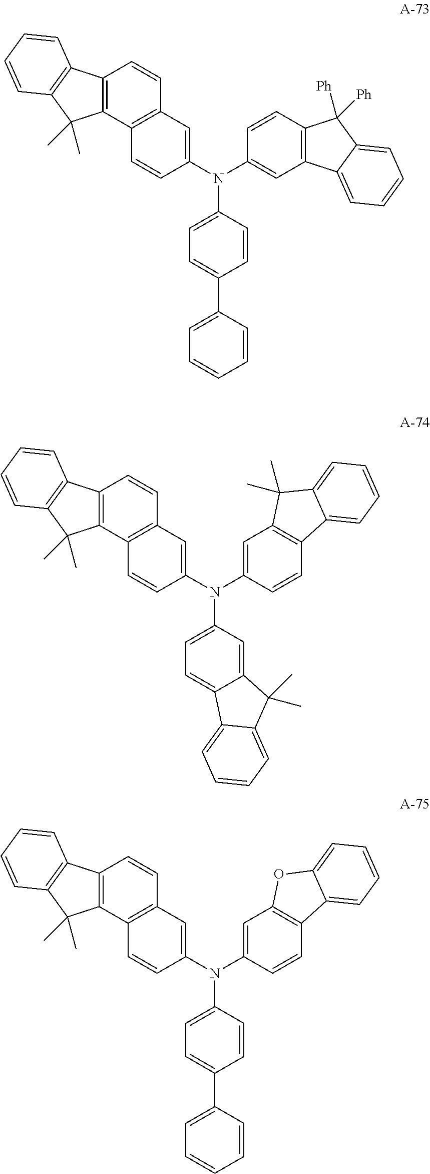 [SMILES: CC1(C)c2ccccc2-c2ccc3cc(N(c4ccc(-c5ccccc5)cc4)c4ccc5c(c4)-c4ccccc4C5(c4ccccc4)c4ccccc4)ccc3c21 ; CC1(C)c2ccccc2-c2ccc(N(c3ccc4c(c3)C(C)(C)c3ccccc3-4)c3ccc4c5c(ccc4c3)-c3ccccc3C5(C)C)cc21 ; CC1(C)c2ccccc2-c2ccc3cc(N(c4ccc(-c5ccccc5)cc4)c4ccc5c(c4)oc4ccccc45)ccc3c21]

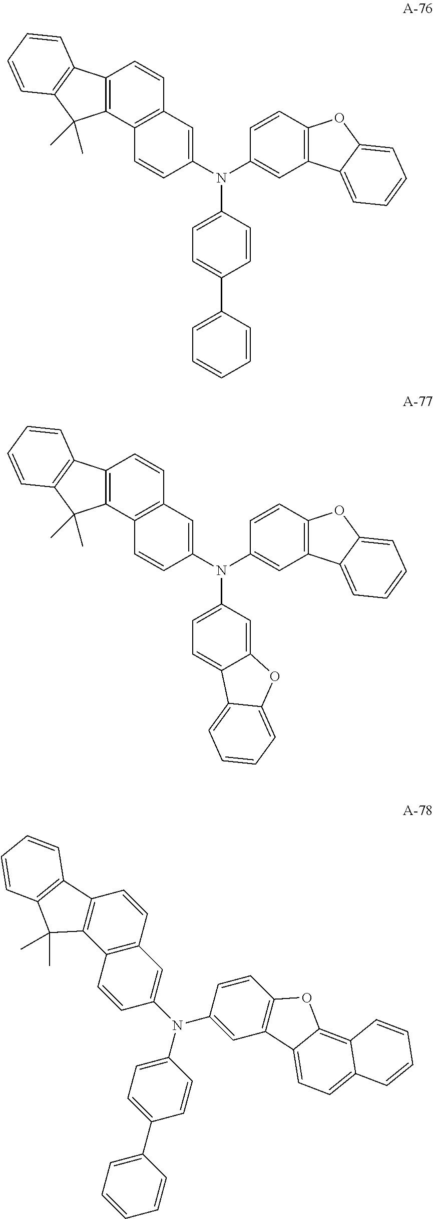 [SMILES: CC1(C)c2ccccc2-c2ccc3cc(N(c4ccc(-c5ccccc5)cc4)c4ccc5oc6ccccc6c5c4)ccc3c21 ; CC1(C)c2ccccc2-c2ccc3cc(N(c4ccc5c(c4)oc4ccccc45)c4ccc5oc6ccccc6c5c4)ccc3c21 ; CC1(C)c2ccccc2-c2ccc3cc(N(c4ccc(-c5ccccc5)cc4)c4ccc5oc6c7ccccc7ccc6c5c4)ccc3c21]

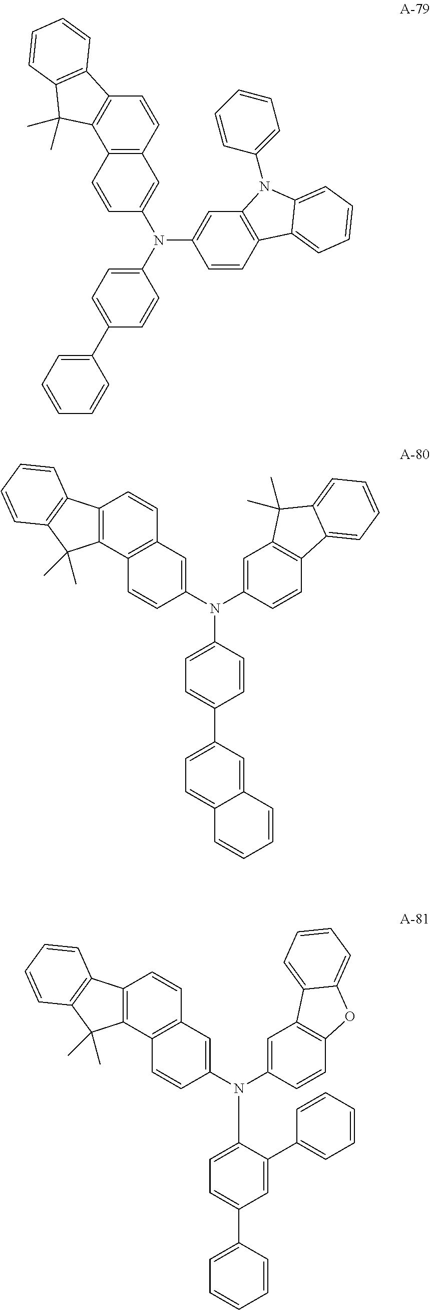 [SMILES: CC1(C)c2ccccc2-c2ccc3cc(N(c4ccc(-c5ccccc5)cc4)c4ccc5c6ccccc6n(-c6ccccc6)c5c4)ccc3c21 ; CC1(C)c2ccccc2-c2ccc(N(c3ccc(-c4ccc5ccccc5c4)cc3)c3ccc4c5c(ccc4c3)-c3ccccc3C5(C)C)cc21 ; CC1(C)c2ccccc2-c2ccc3cc(N(c4ccc5oc6ccccc6c5c4)c4ccc(-c5ccccc5)cc4-c4ccccc4)ccc3c21]

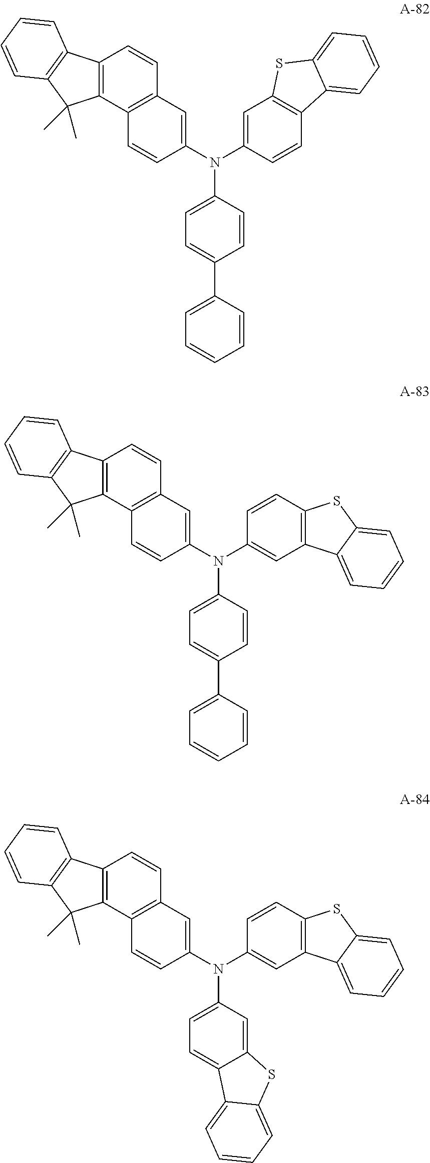 [SMILES: CC1(C)c2ccccc2-c2ccc3cc(N(c4ccc(-c5ccccc5)cc4)c4ccc5c(c4)sc4ccccc45)ccc3c21 ; CC1(C)c2ccccc2-c2ccc3cc(N(c4ccc(-c5ccccc5)cc4)c4ccc5sc6ccccc6c5c4)ccc3c21 ; CC1(C)c2ccccc2-c2ccc3cc(N(c4ccc5c(c4)sc4ccccc45)c4ccc5sc6ccccc6c5c4)ccc3c21]

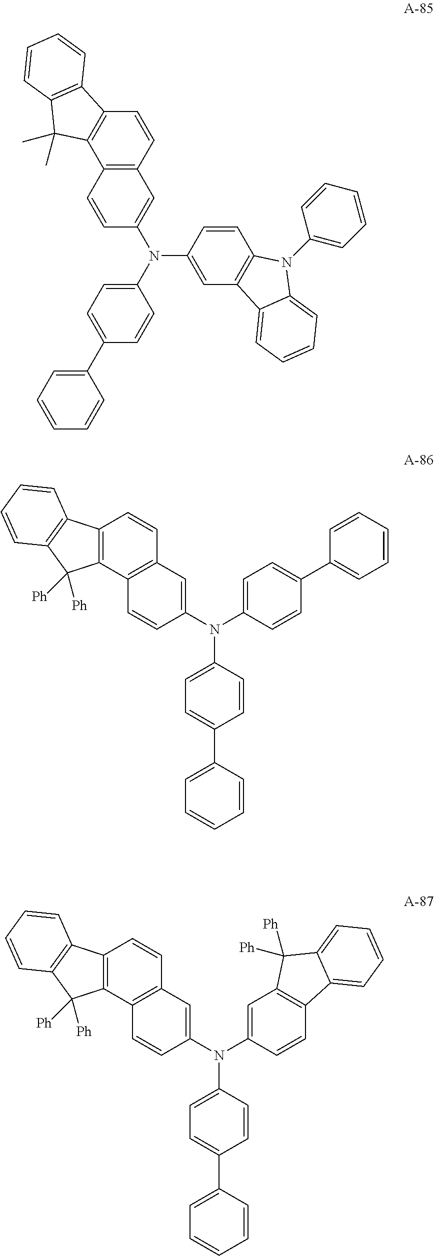 [SMILES: CC1(C)c2ccccc2-c2ccc3cc(N(c4ccc(-c5ccccc5)cc4)c4ccc5c(c4)c4ccccc4n5-c4ccccc4)ccc3c21 ; c1ccc(-c2ccc(N(c3ccc(-c4ccccc4)cc3)c3ccc4c5c(ccc4c3)-c3ccccc3C5(c3ccccc3)c3ccccc3)cc2)cc1 ; c1ccc(-c2ccc(N(c3ccc4c(c3)C(c3ccccc3)(c3ccccc3)c3ccccc3-4)c3ccc4c5c(ccc4c3)-c3ccccc3C5(c3ccccc3)c3ccccc3)cc2)cc1]

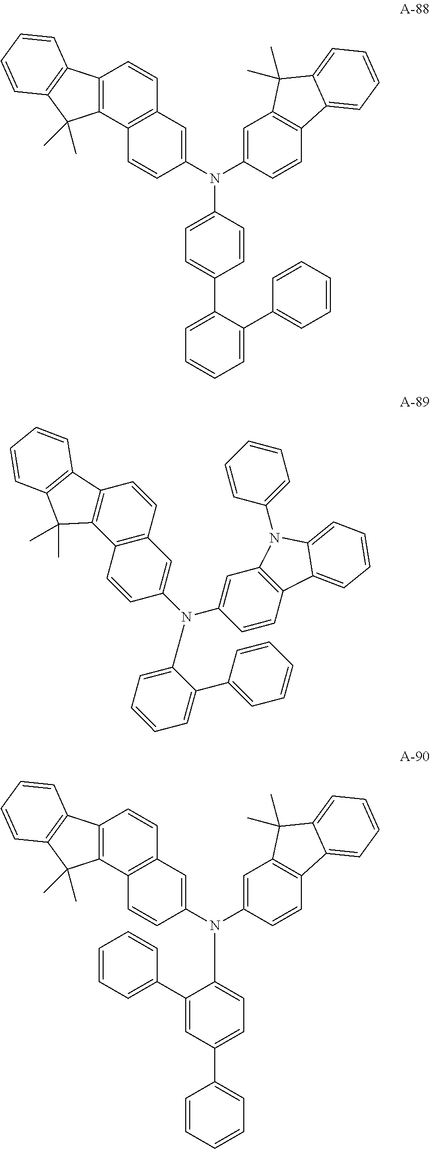 [SMILES: CC1(C)c2ccccc2-c2ccc(N(c3ccc(-c4ccccc4-c4ccccc4)cc3)c3ccc4c5c(ccc4c3)-c3ccccc3C5(C)C)cc21 ; CC1(C)c2ccccc2-c2ccc3cc(N(c4ccc5c6ccccc6n(-c6ccccc6)c5c4)c4ccccc4-c4ccccc4)ccc3c21 ; CC1(C)c2ccccc2-c2ccc(N(c3ccc4c5c(ccc4c3)-c3ccccc3C5(C)C)c3ccc(-c4ccccc4)cc3-c3ccccc3)cc21]

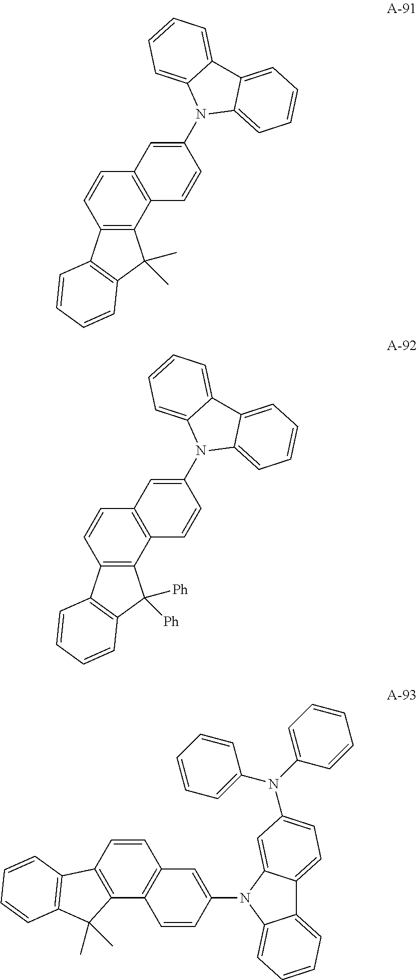 [SMILES: CC1(C)c2ccccc2-c2ccc3cc(-n4c5ccccc5c5ccccc54)ccc3c21 ; c1ccc(C2(c3ccccc3)c3ccccc3-c3ccc4cc(-n5c6ccccc6c6ccccc65)ccc4c32)cc1 ; CC1(C)c2ccccc2-c2ccc3cc(-n4c5ccccc5c5ccc(N(c6ccccc6)c6ccccc6)cc54)ccc3c21]

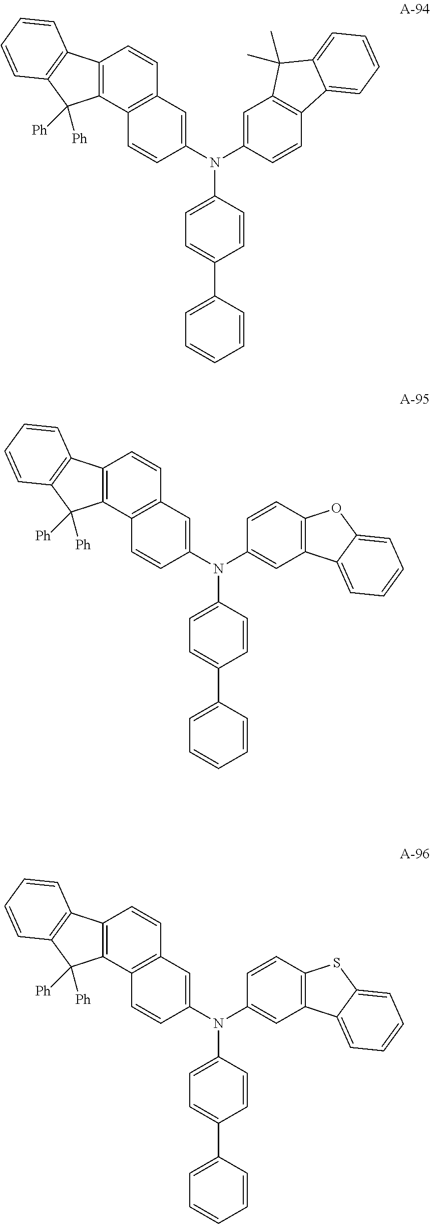 [SMILES: CC1(C)c2ccccc2-c2ccc(N(c3ccc(-c4ccccc4)cc3)c3ccc4c5c(ccc4c3)-c3ccccc3C5(c3ccccc3)c3ccccc3)cc21 ; c1ccc(-c2ccc(N(c3ccc4c5c(ccc4c3)-c3ccccc3C5(c3ccccc3)c3ccccc3)c3ccc4oc5ccccc5c4c3)cc2)cc1 ; c1ccc(-c2ccc(N(c3ccc4c5c(ccc4c3)-c3ccccc3C5(c3ccccc3)c3ccccc3)c3ccc4sc5ccccc5c4c3)cc2)cc1]

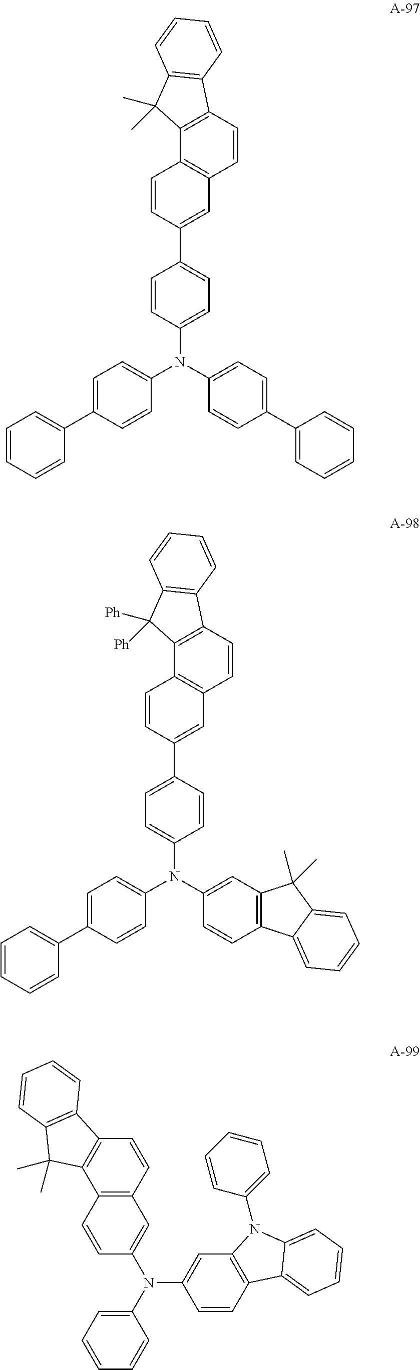 [SMILES: CC1(C)c2ccccc2-c2ccc3cc(-c4ccc(N(c5ccc(-c6ccccc6)cc5)c5ccc(-c6ccccc6)cc5)cc4)ccc3c21 ; CC1(C)c2ccccc2-c2ccc(N(c3ccc(-c4ccccc4)cc3)c3ccc(-c4ccc5c6c(ccc5c4)-c4ccccc4C6(c4ccccc4)c4ccccc4)cc3)cc21 ; CC1(C)c2ccccc2-c2ccc3cc(N(c4ccccc4)c4ccc5c6ccccc6n(-c6ccccc6)c5c4)ccc3c21]

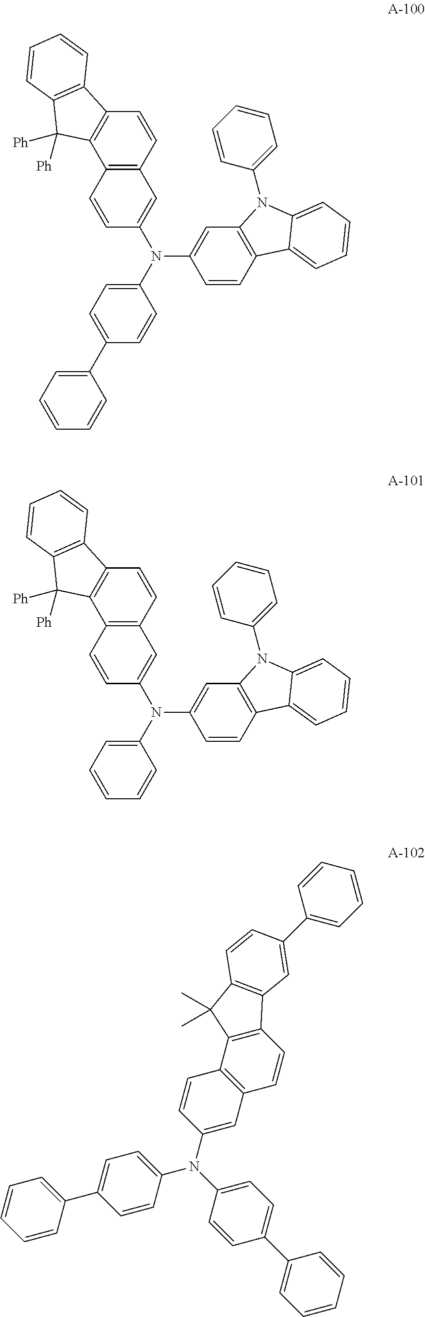 [SMILES: c1ccc(-c2ccc(N(c3ccc4c5c(ccc4c3)-c3ccccc3C5(c3ccccc3)c3ccccc3)c3ccc4c5ccccc5n(-c5ccccc5)c4c3)cc2)cc1 ; c1ccc(N(c2ccc3c4c(ccc3c2)-c2ccccc2C4(c2ccccc2)c2ccccc2)c2ccc3c4ccccc4n(-c4ccccc4)c3c2)cc1 ; CC1(C)c2ccc(-c3ccccc3)cc2-c2ccc3cc(N(c4ccc(-c5ccccc5)cc4)c4ccc(-c5ccccc5)cc4)ccc3c21]

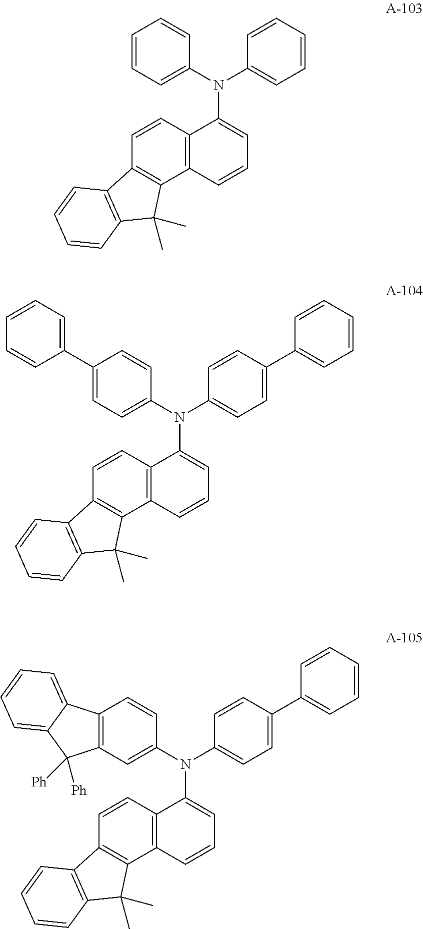 [SMILES: CC1(C)c2ccccc2-c2ccc3c(N(c4ccccc4)c4ccccc4)cccc3c21 ; CC1(C)c2ccccc2-c2ccc3c(N(c4ccc(-c5ccccc5)cc4)c4ccc(-c5ccccc5)cc4)cccc3c21 ; CC1(C)c2ccccc2-c2ccc3c(N(c4ccc(-c5ccccc5)cc4)c4ccc5c(c4)C(c4ccccc4)(c4ccccc4)c4ccccc4-5)cccc3c21]

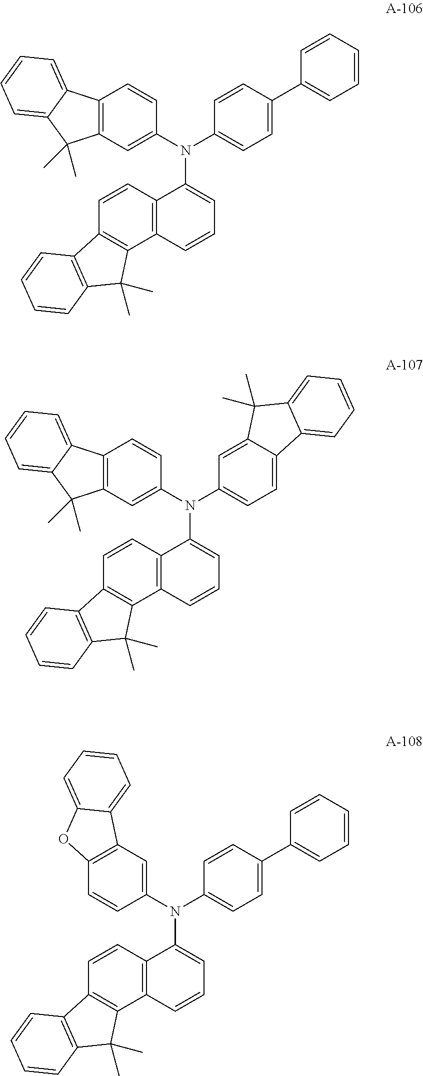 [SMILES: CC1(C)c2ccccc2-c2ccc(N(c3ccc(-c4ccccc4)cc3)c3cccc4c5c(ccc34)-c3ccccc3C5(C)C)cc21 ; CC1(C)c2ccccc2-c2ccc(N(c3ccc4c(c3)C(C)(C)c3ccccc3-4)c3cccc4c5c(ccc34)-c3ccccc3C5(C)C)cc21 ; CC1(C)c2ccccc2-c2ccc3c(N(c4ccc(-c5ccccc5)cc4)c4ccc5oc6ccccc6c5c4)cccc3c21]

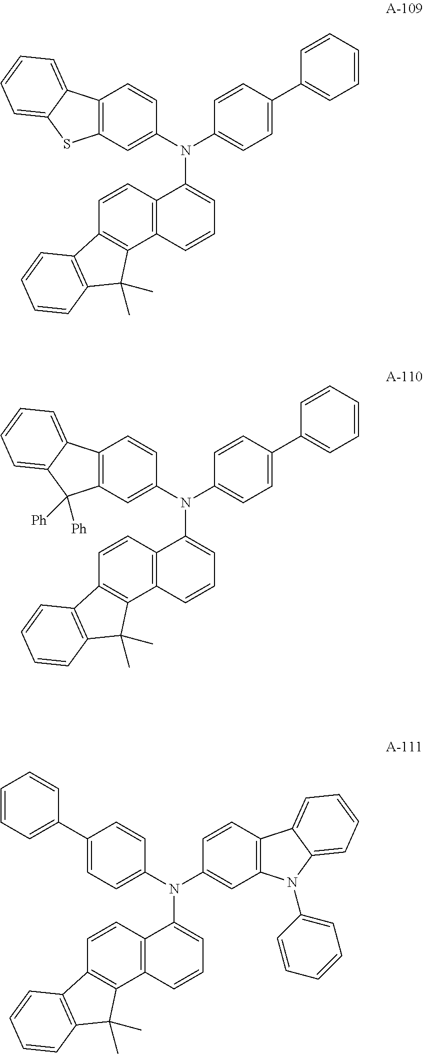 [SMILES: CC1(C)c2ccccc2-c2ccc3c(N(c4ccc(-c5ccccc5)cc4)c4ccc5c(c4)sc4ccccc45)cccc3c21 ; CC1(C)c2ccccc2-c2ccc3c(N(c4ccc(-c5ccccc5)cc4)c4ccc5c(c4)C(c4ccccc4)(c4ccccc4)c4ccccc4-5)cccc3c21 ; CC1(C)c2ccccc2-c2ccc3c(N(c4ccc(-c5ccccc5)cc4)c4ccc5c6ccccc6n(-c6ccccc6)c5c4)cccc3c21]

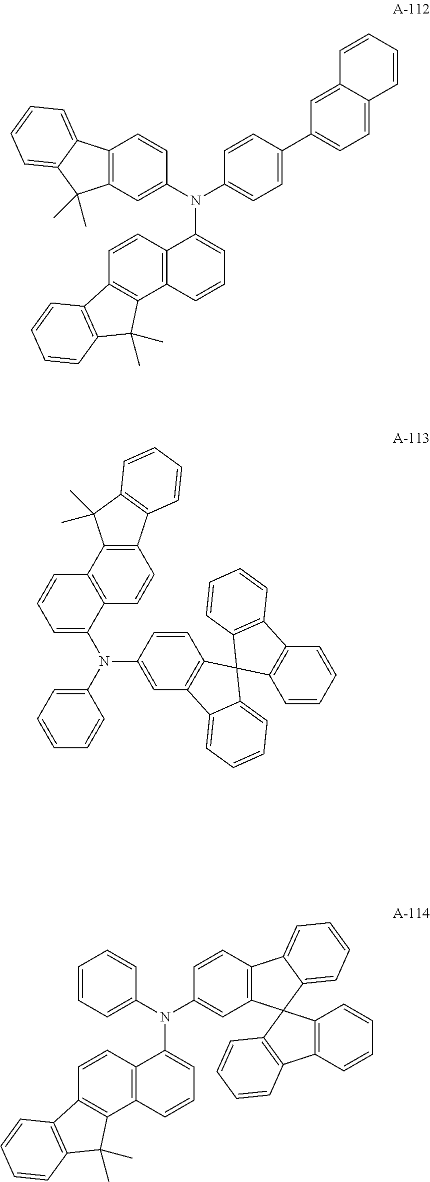 [SMILES: CC1(C)c2ccccc2-c2ccc(N(c3ccc(-c4ccc5ccccc5c4)cc3)c3cccc4c5c(ccc34)-c3ccccc3C5(C)C)cc21 ; CC1(C)c2ccccc2-c2ccc3c(N(c4ccccc4)c4ccc5c(c4)-c4ccccc4C54c5ccccc5-c5ccccc54)cccc3c21 ; CC1(C)c2ccccc2-c2ccc3c(N(c4ccccc4)c4ccc5c(c4)C4(c6ccccc6-c6ccccc64)c4ccccc4-5)cccc3c21]

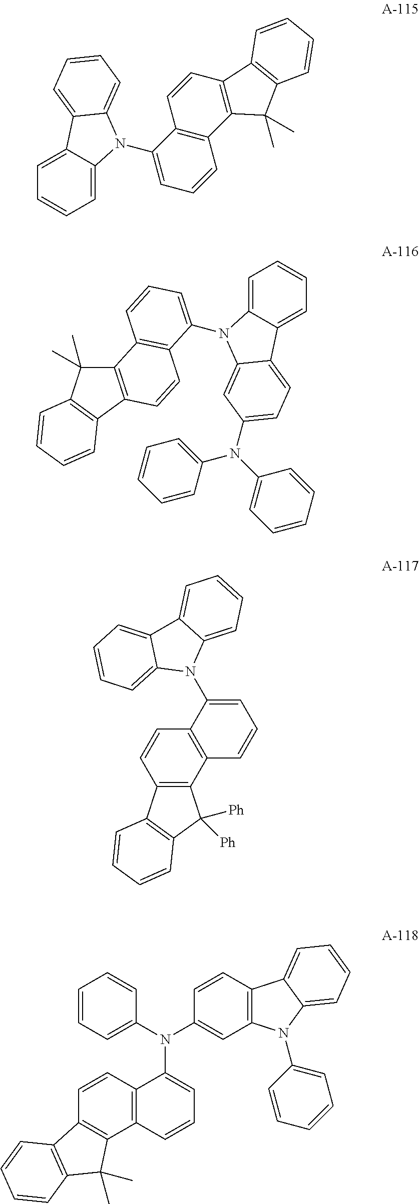 [SMILES: CC1(C)c2ccccc2-c2ccc3c(-n4c5ccccc5c5ccccc54)cccc3c21 ; CC1(C)c2ccccc2-c2ccc3c(-n4c5ccccc5c5ccc(N(c6ccccc6)c6ccccc6)cc54)cccc3c21 ; c1ccc(C2(c3ccccc3)c3ccccc3-c3ccc4c(-n5c6ccccc6c6ccccc65)cccc4c32)cc1 ; CC1(C)c2ccccc2-c2ccc3c(N(c4ccccc4)c4ccc5c6ccccc6n(-c6ccccc6)c5c4)cccc3c21]

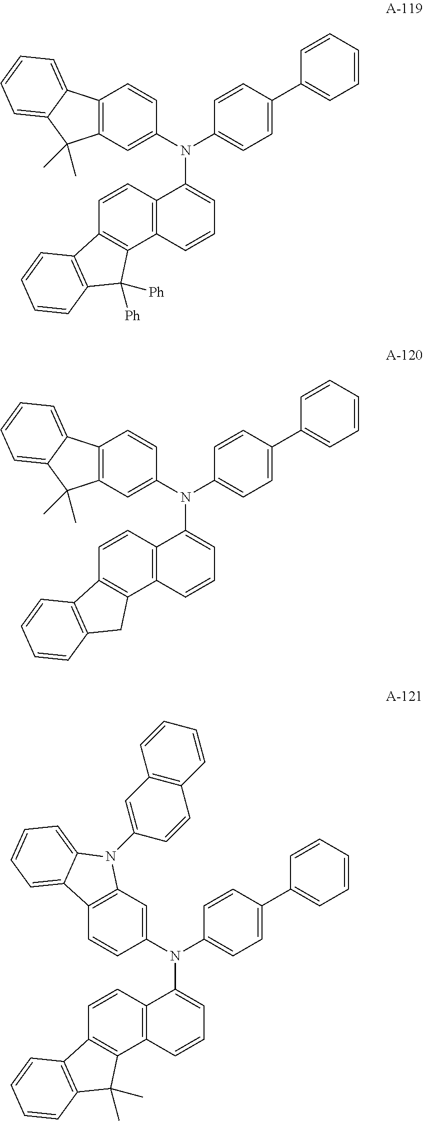 [SMILES: CC1(C)c2ccccc2-c2ccc(N(c3ccc(-c4ccccc4)cc3)c3cccc4c5c(ccc34)-c3ccccc3C5(c3ccccc3)c3ccccc3)cc21 ; CC1(C)c2ccccc2-c2ccc(N(c3ccc(-c4ccccc4)cc3)c3cccc4c5c(ccc34)-c3ccccc3C5)cc21 ; CC1(C)c2ccccc2-c2ccc3c(N(c4ccc(-c5ccccc5)cc4)c4ccc5c6ccccc6n(-c6ccc7ccccc7c6)c5c4)cccc3c21]

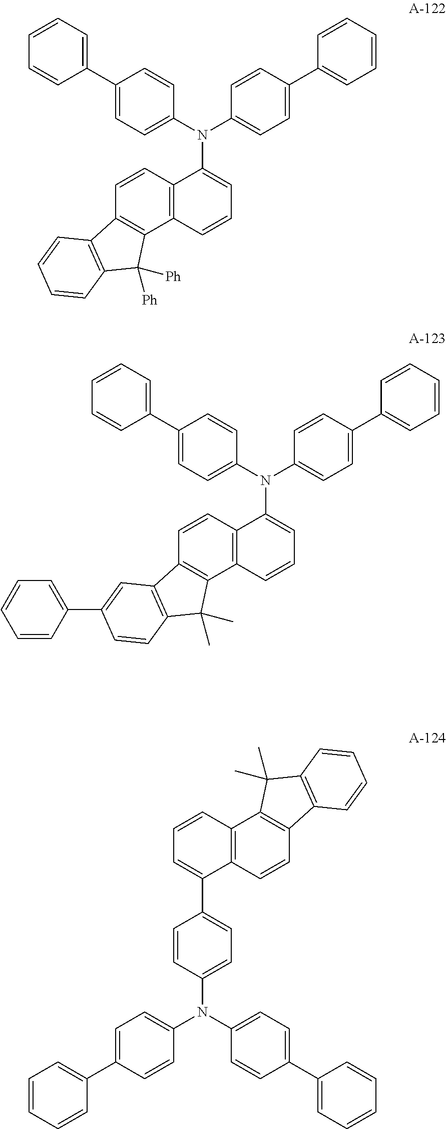 [SMILES: c1ccc(-c2ccc(N(c3ccc(-c4ccccc4)cc3)c3cccc4c5c(ccc34)-c3ccccc3C5(c3ccccc3)c3ccccc3)cc2)cc1 ; CC1(C)c2ccc(-c3ccccc3)cc2-c2ccc3c(N(c4ccc(-c5ccccc5)cc4)c4ccc(-c5ccccc5)cc4)cccc3c21 ; CC1(C)c2ccccc2-c2ccc3c(-c4ccc(N(c5ccc(-c6ccccc6)cc5)c5ccc(-c6ccccc6)cc5)cc4)cccc3c21]

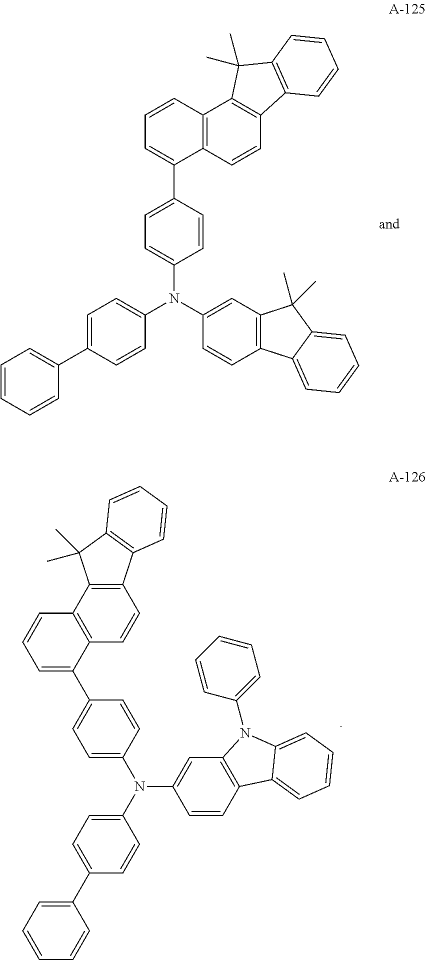 [SMILES: CC1(C)c2ccccc2-c2ccc(N(c3ccc(-c4ccccc4)cc3)c3ccc(-c4cccc5c6c(ccc45)-c4ccccc4C6(C)C)cc3)cc21 ; CC1(C)c2ccccc2-c2ccc3c(-c4ccc(N(c5ccc(-c6ccccc6)cc5)c5ccc6c7ccccc7n(-c7ccccc7)c6c5)cc4)cccc3c21]

8. An organic electroluminescent material comprising the organic electroluminescent compound according to claim 1.

9. An organic electroluminescent device comprising the organic electroluminescent compound according to claim 1.

10. The organic electroluminescent device according to claim 9, wherein the organic electroluminescent compound is contained in a hole transport layer and/or a hole auxiliary layer.
